(19) United States
(12) Patent Application Publication
(10) Pub. No.: US 2023/0142412 A1
(43) Pub. Date: May 11, 2023

(54) LIGHT EMITTING ELEMENT AND AMINE COMPOUND FOR THE SAME

(71) Applicant: Samsung Display Co., Ltd., Yongin-si (KR)

(72) Inventors: Chaeyeong KIM, Yongin-si (KR); DONGJUN KIM, Suwon-si (KR); HANKYU PAK, Suwon-si (KR); BYEONGWOOK YOO, Hwaseong-si (KR); SEOWON CHO, Asan-si (KR); SOHEE JO, Cheonan-si (KR)

(21) Appl. No.: 17/881,421

(22) Filed: Aug. 4, 2022

(30) Foreign Application Priority Data
Nov. 4, 2021 (KR) 10-2021-0150337

(51) Int. Cl. H01L 51/00; C07F 7/08

(52) U.S. Cl. CPC H01L 51/0094; C07F 7/081; C07F 7/0812; H01L 51/5056

(57) ABSTRACT

A light emitting element including a first electrode, a second electrode on the first electrode, and at least one functional layer between the first electrode and the second electrode is provided. The at least one functional layer may include an amine compound represented by Formula 1. Accordingly, the light emitting element may exhibit a long service life characteristic. In addition, the light emitting element may exhibit characteristics in which the driving voltage is reduced, and the brightness and efficiency are improved.

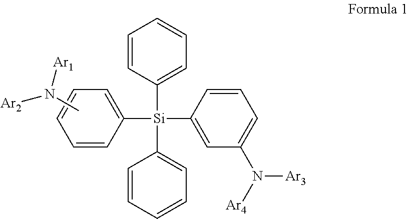

### CROSS-REFERENCE TO RELATED APPLICATION

This application claims priority to and the benefit of Korean Patent Application No. 10-2021-0150337, filed on Nov. 4, 2021, the entire content of which is hereby incorporated by reference.

### BACKGROUND

### 1. Field

Aspects of one or more embodiments of the present disclosure relate to a light emitting element and an amine compound utilized therein.

### 2. Description of the Related Art

Recently, the development of an organic electroluminescence display device as an image display device is being actively conducted. The organic electroluminescence display device includes a self-luminescent light emitting element in which holes and electrons injected from a first electrode and a second electrode recombine in an emission layer, and thus a luminescent material of the emission layer emits light to implement display.

In the application of a light emitting element to a display device, there is a demand for a light emitting element having high luminous efficiency and a long service life, and development on materials for a light emitting element capable of stably attaining such a characteristic is being continuously sought.

### SUMMARY

An aspect of one or more embodiments of the present disclosure is directed toward a light emitting element exhibiting a long service life characteristic and having a decrease in a driving voltage.

An aspect of one or more embodiments of the present disclosure is also directed toward an amine compound which is a material for a light emitting element having a long service life characteristic.

An embodiment of the present disclosure provides a light emitting element including: a first electrode; a second electrode on the first electrode; and at least one functional layer which is between the first electrode and the second electrode and includes an amine compound represented by Formula 1:

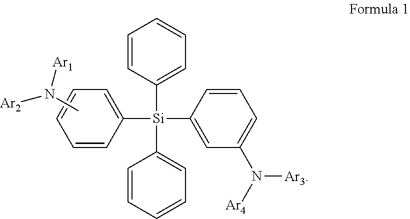

In Formula 1, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In an embodiment, Formula 1 may be represented by any one among Formula 1-1 to Formula 1-3:

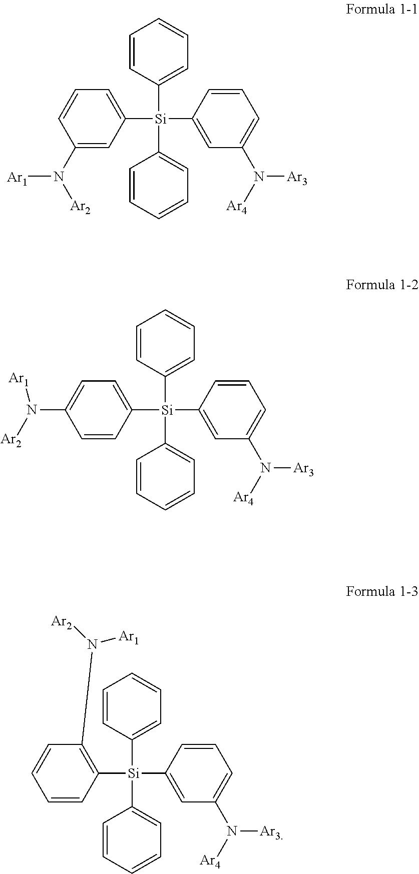

In Formula 1-1 to Formula 1-3, Ar₁ to Ar₄ may each independently be the same as defined in Formula 1.

In an embodiment, Formula 1 may be represented by Formula 2:

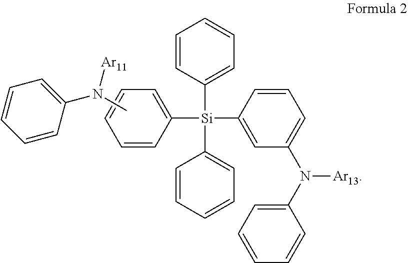

In Formula 2 above, Ar₁₁ and Ar₁₃ may each independently be a substituted or unsubstituted aryl group having 6 to 30 ring-forming carbon atoms, or a substituted or unsubstituted heteroaryl group having 2 to 30 ring-forming carbon atoms.

In an embodiment, Formula 2 above may be represented by Formula 2-1:

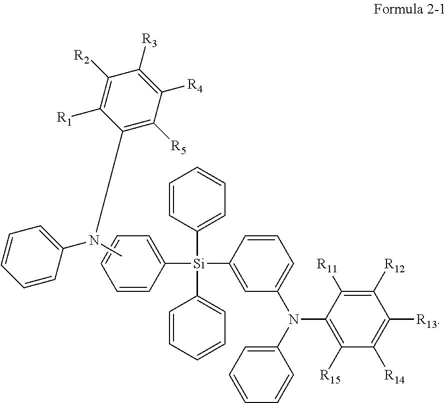

In Formula 2-1, R₁ to R₅ and R₁₁ to R₁₆ may each independently be a hydrogen atom, a substituted or unsubstituted amine group, a substituted or unsubstituted oxy group, a substituted or unsubstituted thio group, a substituted or unsubstituted alkyl group having 1 to 10 carbon atoms, a substituted or unsubstituted alkenyl group having 2 to 10 carbon atoms, or a substituted or unsubstituted aryl group having 6 to 30 ring-forming carbon atoms, and/or are bonded to an adjacent group to form a ring.

Formula 2 may be represented by Formula 2-2A or Formula 2-2B:

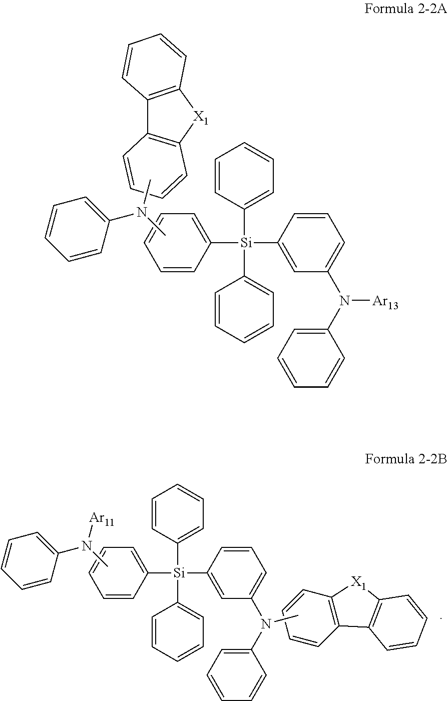

In Formula 2-2A and Formula 2-2B, X₁ is C(CH₃)₂, N(Ph), O, or S, and Ar₁₁ and Ar₁₃ may each independently be the same as defined in Formula 2 above.

In an embodiment, Ar₁ to Ar₄ may each independently be represented by any one among A-1 to A-6:

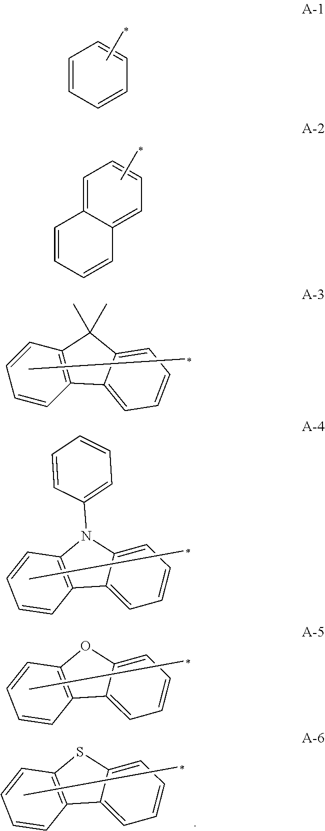

In an embodiment, Ar₁ to Ar₄ above may each independently be a substituted or unsubstituted phenyl group, a substituted or unsubstituted naphthyl group, a substituted or unsubstituted fluorenyl group, a substituted or unsubstituted carbazole group, a substituted or unsubstituted dibenzofuran group, or a substituted or unsubstituted dibenzothiophene group.

In an embodiment, in Formula 1 above, Ar₁ and Ar₃ may be the same and Ar₂ and Ar₄ may be the same.

In an embodiment, the at least one functional layer may include an emission layer, a hole transport region between the first electrode and the emission layer, and/or an electron transport region between the emission layer and the second electrode, and the hole transport region may include the amide compound.

In an embodiment, the hole transport region may include a hole injection layer on the first electrode, a hole transport layer on the hole injection layer, and an electron blocking layer on the hole transport layer, and at least one of the hole injection layer, the hole transport layer, or the electron blocking layer may include the amine compound.

In an embodiment of the present disclosure, an amine compound is represented by Formula 1.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a plan view illustrating a display device according to an embodiment of the present disclosure;

FIG. 2 is a cross-sectional view illustrating a part taken along line I-I′ of FIG. 1;

FIG. 3 is a cross-sectional view schematically illustrating a light emitting element of an embodiment of the present disclosure;

FIG. 4 is a cross-sectional view schematically illustrating a light emitting element of an embodiment of the present disclosure;

FIG. 5 is a cross-sectional view schematically illustrating a light emitting element of an embodiment of the present disclosure;

FIG. 6 is a cross-sectional view schematically illustrating a light emitting element of an embodiment of the present disclosure;

FIG. 7 is a cross-sectional view illustrating a display device according to an embodiment of the present disclosure;

FIG. 8 is a cross-sectional view illustrating a display device according to an embodiment of the present disclosure;

FIG. 9 is a cross-sectional view illustrating a display device according to an embodiment of the present disclosure; and

FIG. 10 is a cross-sectional view illustrating a display device according to an embodiment of the present disclosure.

### DETAILED DESCRIPTION

The present disclosure may be modified in many alternate forms, and thus specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In the present disclosure, when a component (or a region, a layer, a portion, etc.) is referred to as being “on,” “connected to,” or “coupled to” another component, it refers to that the component may be directly on/connected to/coupled to the other component, or that one or more third components may be therebetween.

Like reference numerals refer to like components throughout. Also, in the drawings, the thickness, the ratio, and the dimensions of components may be exaggerated for an effective description of technical contents. The term “and/or” includes all combinations of one or more of which associated configurations may define.

It will be understood that, although the terms “first,” “second,” etc. may be utilized herein to describe one or more suitable components, these components should not be limited by these terms. These terms are only utilized to distinguish one component from another. For example, a first component could be termed a second component, and, similarly, a second component could be termed a first component, without departing from the scope of the present disclosure. As utilized herein, the singular forms, “a,” “an,” and “the” are intended to include the plural forms as well, unless the context clearly indicates otherwise.

In some embodiments, terms such as “below,” “under,” “on,” and “above” may be utilized to describe the relationship between elements illustrated in the drawings. The terms are utilized as a relative concept and are described with reference to the direction indicated in the drawings.

It should be understood that the terms “comprise,” “include,” or “have” are intended to specify the presence of stated features, integers, steps, operations, components, parts, or combinations thereof in the disclosure, but do not preclude the presence or addition of one or more other features, integers, steps, operations, components, parts, or combinations thereof.

Unless otherwise defined, all terms (including technical and scientific terms) utilized herein have the same meaning as commonly understood by one of ordinary skill in the art to which the present disclosure belongs. In some embodiments, it will be understood that terms, such as those defined in commonly utilized dictionaries, should be interpreted as having a meaning that is consistent with their meaning in the context of the relevant art and will not be interpreted in an idealized or overly formal sense unless expressly so defined herein.

Hereinafter, a light emitting element and an amine compound according to an embodiment of the present disclosure will be described with reference to the drawings.

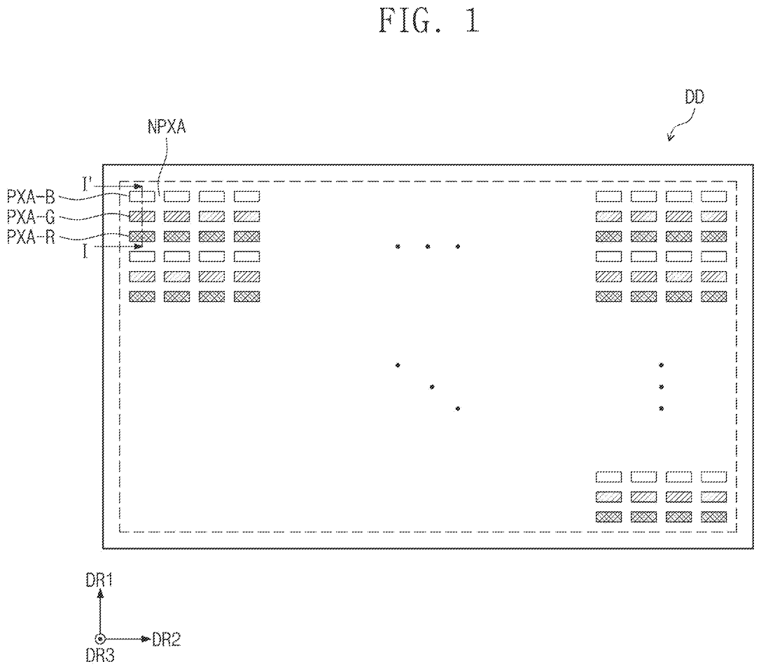

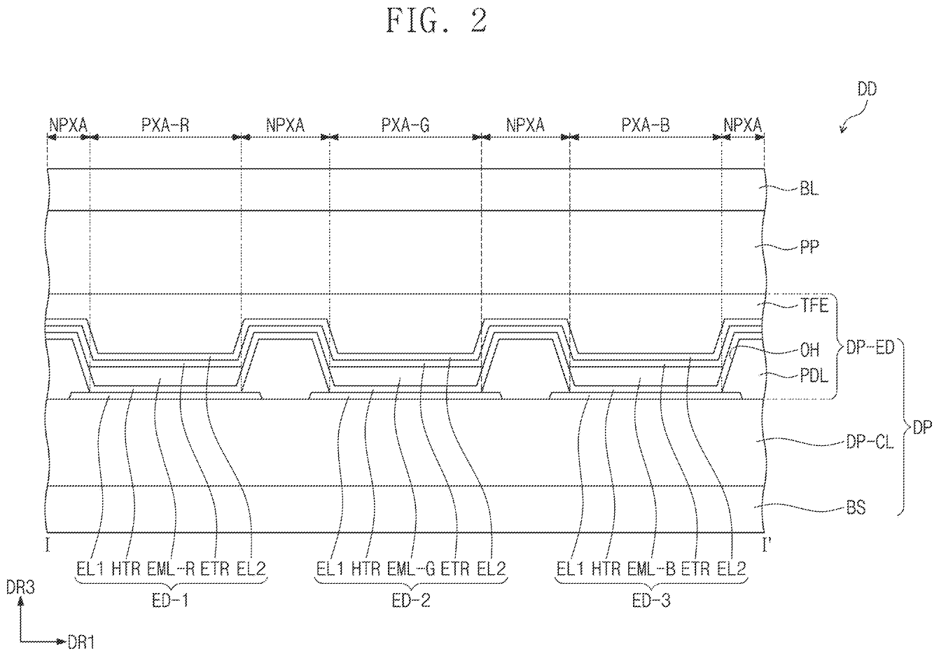

FIG. 1 is a plan view illustrating an embodiment of a display device DD. FIG. 2 is a cross-sectional view of the display device DD of the embodiment. FIG. 2 is a cross-sectional view illustrating a part taken along line I-I′ of FIG. 1.

The display device DD may include a display panel DP and an optical layer PP on the display panel DP. The display panel DP may include light emitting elements ED-1, ED-2, and ED-3. The display device DD may include a plurality of light emitting elements ED-1, ED-2, and ED-3. The optical layer PP may be on the display panel DP and control reflected light in the display panel DP due to external light. The optical layer PP may include, for example, a polarization layer or a color filter layer. In some embodiments, the optical layer PP may not be provided (e.g., may be excluded) from the display device DD of an embodiment.

A base substrate BL may be on the optical layer PP. The base substrate BL may be a member which provides a base surface on which the optical layer PP disposed. The base substrate BL may be a glass substrate, a metal substrate, a plastic substrate, etc. However, the embodiment of the present disclosure is not limited thereto, and the base substrate BL may be an inorganic layer, an organic layer, and/or a composite material layer. In some embodiments, the base substrate BL may not be provided.

The display device DD according to an embodiment may further include a filling layer. The filling layer may be between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 between (e.g., defined by) portions of the pixel defining film PDL, and an encapsulation layer TFE on the light emitting elements ED-1, ED-2, and ED-3.

The base layer BS may be a member which provides a base surface on which the display element layer DP-ED is disposed. The base layer BS may be a glass substrate, a metal substrate, a plastic substrate, etc. However, the embodiment of the present disclosure is not limited thereto, and the base layer BS may be an inorganic layer, an organic layer, and/or a composite material layer.

In an embodiment, the circuit layer DP-CL is disposed on the base layer BS, and the circuit layer DP-CL may include a plurality of transistors. Each of the transistors may include a control electrode, an input electrode, and an output electrode. For example, the circuit layer DP-CL may include a switching transistor and a driving transistor in order to drive the light emitting elements ED-1, ED-2, and ED-3 of the display element layer DP-ED.

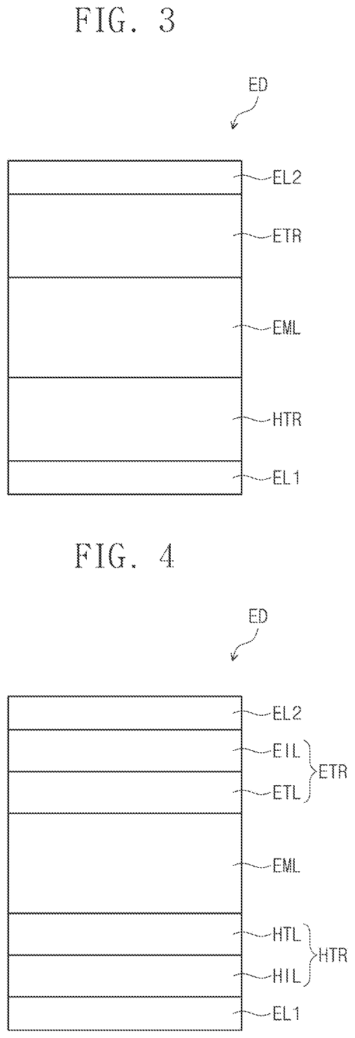

Each of the light emitting elements ED-1, ED-2, and ED-3 may have a structure of a light emitting element ED of an embodiment according to FIGS. 3 to 6, which will be described later. Each of the light emitting elements ED-1, ED-2 and ED-3 may include a first electrode EL1, a hole transport region HTR, emission layers EML-R, EML-G and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are in openings OH defined in the pixel defining film PDL, and the hole transport region HTR, the electron transport region ETR, and the second electrode EL2 are provided as a common layer in the entire light emitting elements ED-1, ED-2, and ED-3. However, the embodiment of the present disclosure is not limited thereto, the hole transport region HTR and the electron transport region ETR in an embodiment may be provided by being patterned inside the opening OH defined in the pixel defining film PDL. For example, the hole transport region HTR, the emission layers EML-R, EML-G, and EML-B, and the electron transport region ETR of the light emitting elements ED-1, ED-2, and ED-3 in an embodiment may be provided by being patterned in an inkjet printing method.

The encapsulation layer TFE may cover the light emitting elements ED-1, ED-2 and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect (reduce moisture/oxygen) the display element layer DP-ED from moisture/oxygen, and the encapsulation-organic film may protect the display element layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not limited thereto. The encapsulation-organic film may include an acrylic-based compound, an epoxy-based compound, and/or the like. The encapsulation-organic film may include a photopolymerizable organic material, but the embodiment of the present disclosure is not limited thereto.

The encapsulation layer TFE may be disposed on the second electrode EL2 and may be disposed filling the opening OH.

Referring to FIGS. 1 and 2, the display device DD may include a non-light emitting region NPXA and light emitting regions PXA-R, PXA-G and PXA-B. The light emitting regions PXA-R, PXA-G and PXA-B may be regions in which light generated by the respective light emitting elements ED-1, ED-2 and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting regions NPXA may be regions between the adjacent light emitting regions PXA-R, PXA-G, and PXA-B, which correspond to portions of the pixel defining film PDL. In the disclosure, the light emitting regions PXA-R, PXA-G, and PXA-B may respectively correspond to pixels. The pixel defining film PDL may divide the light emitting elements ED-1, ED-2, and ED-3. The emission layers EML-R, EML-G and EML-B of the light emitting elements ED-1, ED-2 and ED-3 may be in openings OH defined in the pixel defining film PDL and separated from each other.

The light emitting regions PXA-R, PXA-G and PXA-B may be divided into a plurality of groups according to the color of light generated from the light emitting elements ED-1, ED-2 and ED-3. In the display device DD of an embodiment shown in FIGS. 1 and 2, three light emitting regions PXA-R, PXA-G, and PXA-B which emit red light, green light, and blue light, respectively are illustrated. For example, the display device DD of an embodiment may include the red light emitting region PXA-R, the green light emitting region PXA-G, and the blue light emitting region PXA-B that are separated from each other.

In the display device DD according to an embodiment, the plurality of light emitting elements ED-1, ED-2 and ED-3 may emit light beams having wavelengths different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may emit light beams in substantially the same wavelength range or at least one light emitting element may emit a light beam in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B may be arranged with each other along the second directional axis DR2. In some embodiments, a red light emitting region PXA-R, a green light emitting region PXA-G, and a blue light emitting region PXA-B may be alternately arranged with each other in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this embodiment, the areas of the light emitting regions PXA-R, PXA-G, and PXA-B may refer to areas when viewed on a plane defined by the first directional axis DR1 and the second directional axis DR2. (DR3 is a third direction which is normal or perpendicular to the plane defined by the first direction DR1 and the second direction DR2).

An arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display device DD. For example, the arrangement form of the light emitting regions PXA-R, PXA-G, and PXA-B may be a PENTILE® arrangement form (for example, an RGBG matrix, an RGBG structure, or RGBG matrix structure) or a diamond (e.g., Diamond Pixel™) arrangement form. PENTILE® is a duly registered trademark of Samsung Display Co., Ltd. Diamond Pixel™ is the atoms of Samsung's OLED displays, consisting of red, blue, and green (RGB) screen dots in the shape of diamonds.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but the embodiment of the present disclosure is not limited thereto.

Hereinafter, FIGS. 3 to 6 are cross-sectional views schematically illustrating light emitting elements according to embodiments. Each of the light emitting elements ED according to embodiments may include a first electrode EL1, a hole transport region HTR, an emission layer EML, an electron transport region ETR, and a second electrode EL2 that are sequentially stacked.

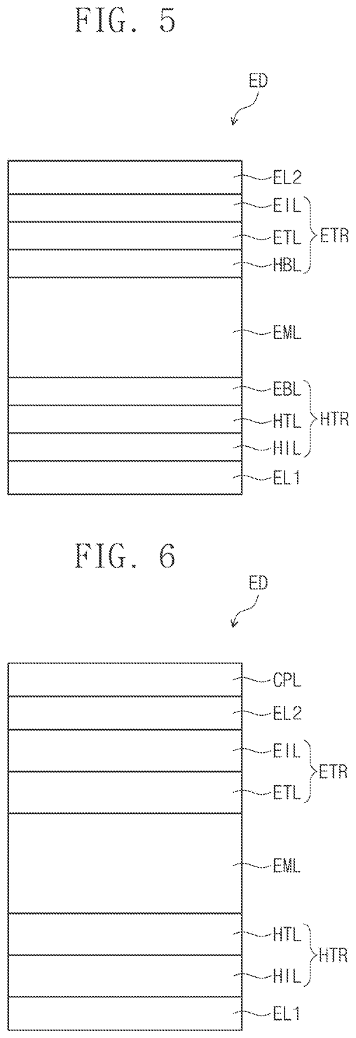

Compared to FIG. 3, FIG. 4 illustrates a cross-sectional view of a light emitting element ED of an embodiment, in which a hole transport region HTR includes a hole injection layer HIL and a hole transport layer HTL, and an electron transport region ETR includes an electron injection layer EIL and an electron transport layer ETL. Compared to FIG. 3, FIG. 5 illustrates a cross-sectional view of a light emitting element ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared to FIG. 4, FIG. 6 illustrates a cross-sectional view of a light emitting element ED of an embodiment including a capping layer CPL on a second electrode EL2.

In an embodiment, the light emitting element ED may include an amine compound in at least one functional layer between the first electrode EL1 and the second electrode EL2. The at least one functional layer may include a hole transport region HTR, an emission layer EML, and an electron transport region ETR. The amine compound may contain at least two amine groups indirectly linked to a silicon atom.

In the disclosure, the term “substituted or unsubstituted” may refer to substituted or unsubstituted with at least one substituent selected from the group including (e.g., consisting of) a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In some embodiments, each of the substituents exemplified above may be substituted or unsubstituted. For example, a biphenyl group may be interpreted as (represented as) an aryl group or a phenyl group substituted with a phenyl group.

In the disclosure, the phrase “bonded to an adjacent group to form a ring” may indicate that one is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

In the disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. Two methyl groups in 4,5-dimethylphenanthrene may be interpreted as “adjacent groups” to each other.

In the disclosure, examples of the halogen atom may include a fluorine atom, a chlorine atom, a bromine atom, or an iodine atom.

In the disclosure, the alkyl group may be a linear, branched or cyclic type or kind. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

In the disclosure, an alkenyl group refers to a hydrocarbon group including at least one carbon double bond in the middle or terminal of an alkyl group having 2 or more carbon atoms. The alkenyl group may be linear or branched. The carbon number is not limited, but is 2 to 30, 2 to 20 or 2 to 10. Examples of the alkenyl group include a vinyl group, a 1-butenyl group, a 1-pentenyl group, a 1,3-butadienyl aryl group, a styrenyl group, a styrylvinyl group, etc., without limitation.

The hydrocarbon ring group herein refers to any functional group or substituent derived from an aliphatic hydrocarbon ring. The hydrocarbon ring group may be a saturated hydrocarbon ring group having 5 to 30 ring-forming carbon atoms.

In the disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the present disclosure is not limited thereto.

The heterocyclic group herein refers to any suitable functional group or substituent derived from a ring including at least one of B, O, N, P, Si, or Se as a heteroatom. When the heterocyclic group includes two or more heteroatoms, the two or more heteroatoms may be the same as or different from each other. The heterocyclic group may be a monocyclic heterocyclic group or a polycyclic heterocyclic group that includes a heteroaryl group. The number of ring-forming carbon atoms in the heterocyclic group may be 2 to 30, 2 to 20, or 2 to 10. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the disclosure, the heteroaryl group may include at least one of B, O, N, P, Si, or S as a heteroatom. When the heteroaryl group contains two or more heteroatoms, the two or more heteroatoms may be the same as or different from each other. The heteroaryl group may be a monocyclic heteroaryl group or polycyclic heteroaryl group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the present disclosure is not limited thereto.

In the disclosure, the above description of the aryl group may be applied to an arylene group except that the arylene group is a divalent group. The above description of the heteroaryl group may be applied to a heteroarylene group except that the heteroarylene group is a divalent group.

The boron group herein may refer to a boron atom that is bonded to the alkyl group or the aryl group as defined above. The boron group includes an alkyl boron group and/or an aryl boron group. Examples of the boron group may include a dimethylboron group, a diethylboron group, a t-butylmethylboron group, a diphenylboron group, a phenylboron group, etc., but the embodiment of the present disclosure is not limited thereto.

In the disclosure, a silyl group includes an alkylsilyl group and an arylsilyl group. Examples of the silyl group may include a trimethylsilyl group, a triethylsilyl group, a t-butyldimethylsilyl group, a ethyldimethylsilyl group, a propyldimethylsilyl group, a triphenylsilyl group, a diphenylsilyl group, a phenylsilyl group, etc., but the embodiment of the present disclosure is not limited thereto.

In the disclosure, a thio group may include an alkylthio group and an arylthio group. The thio group may refer to a sulfur atom that is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the disclosure, an oxy group may refer to an oxygen atom that is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not limited, but may be, for example, 1 to 20 or 1 to 10. Examples of the oxy group include methoxy, ethoxy, n-propoxy, isopropoxy, butoxy, pentyloxy, hexyloxy, octyloxy, nonyloxy, decyloxy, benzyloxy, etc., but the embodiment of the present disclosure is not limited thereto.

In the disclosure, the number of carbon atoms in an amine group is not limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but the embodiment of the present disclosure is not limited thereto.

In the disclosure, the alkyl group selected from among an alkylthio group, an alkylsulfoxy group, an alkyl oxy group, an alkyl amino group, an alkyl boron group, an alkyl silyl group, and an alkyl amine group is the same as the examples of the alkyl group described above.

In the disclosure, the aryl group selected from among an aryloxy group, an arylthio group, an arylsulfoxy group, an arylamino group, an arylboron group, an arylsilyl group, and an arylamine group is the same as the examples of the aryl group described above.

In the disclosure, a direct linkage may refer to a single bond. In the disclosure,

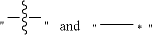

refer to a position to be connected.

The amine compound of an embodiment may be represented by Formula 1. The light emitting element ED may include an amine compound represented by Formula 1:

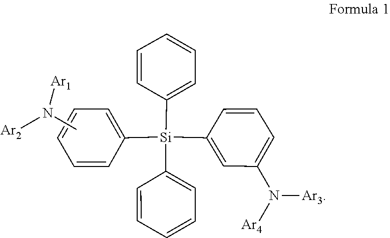

In Formula 1, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms. For example, Ar₁ to Ar₄ may each independently be a substituted or unsubstituted phenyl group, a substituted or unsubstituted naphthyl group, a substituted or unsubstituted fluorenyl group, a substituted or unsubstituted carbazole group, a substituted or unsubstituted dibenzofuran group, or a substituted or unsubstituted dibenzothiophene group. For example, any one among Ar₁ and Ar₂ and/or any one among Ar₁ and Ar₄ may be a phenyl group.

In an embodiment, Ar₁ to Ar₄ may each independently be represented by any one among A-1 to A-6. A-1 represents an unsubstituted phenyl group, and A-2 represents an unsubstituted naphthyl group. A-3 represents a dimethylfluorenyl group, and A-4 represents a carbazole group in which a phenyl group is bonded to a nitrogen atom. A-5 represents an unsubstituted a dibenzofuran group, and A-6 represents an unsubstituted dibenzothiophene group.

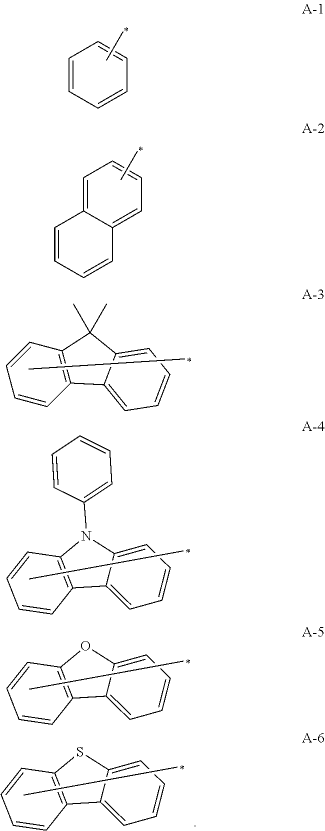

For example, A-3 may be represented by any one among A-31 to A-34. A-4 may be represented by A-41 or A-42. A-5 may be represented by A-51 or A-52. A-6 may be represented by A-61 or A-62.

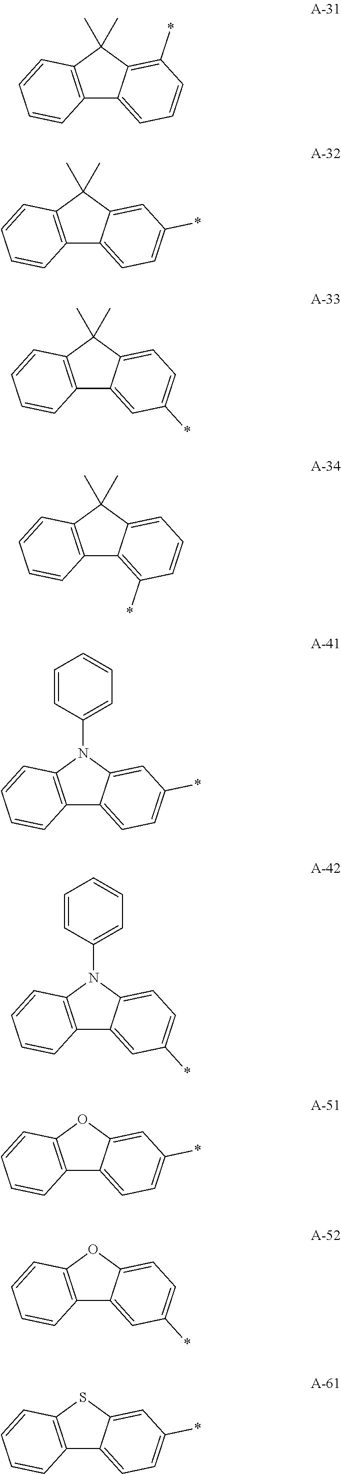

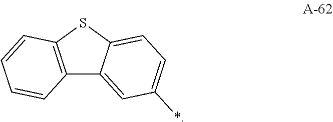

A-31 to A-34 are distinguished from one another by specifying a bond position in A-3, and A-41 and A-42 are distinguished from one another by specifying a bond position in A-4. A-51 and A-52 are distinguished from one another by specifying a bond position in A-5, and A-61 and A-62 are distinguished from one another by specifying a bond position in A-6.

In the amine compound represented by Formula 1, each of two amine groups indirectly bonded to the silicon atom contains two substituents, and at least one substituent in the two amine groups may be the same. For example, in Formula 1, Ar₁ and Ar₃ may be the same and Ar₂ and Ar₄ may be the same.

In Formula 1, the amine group to which Ar₃ and Ar₄ are bonded may be bonded to a carbon atom at the meta-position to the carbon atom to which the silicon atom is bonded. The amine group to which Ar₁ and Ar₂ are bonded may be bonded to a carbon atom at the ortho-position to the carbon atom to which the silicon atom is bonded.

In an embodiment, Formula 1 may be represented by any one among Formula 1-1 to Formula 1-3. Formula 1-1 to Formula 1-3 are different in that in Formula 1, the position relation between the amine group, to which Ar₁ and Ar₂ are bonded, and the silicon atom is different.

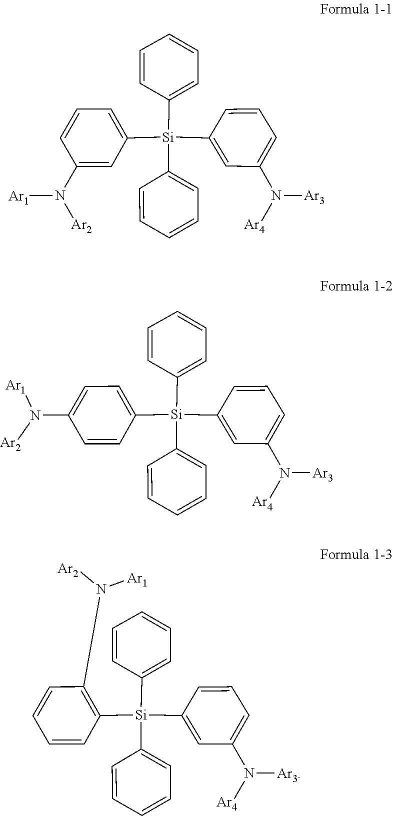

In Formula 1-1 to Formula 1-3, the same as described in Formula 1 may be applied to Ar₁ to Ar₄. Formula 1-1 represents the embodiment in which in Formula 1, the position relation between the amine group, to which Ar₁ and Ar₂ are bonded, and the silicon atom is meta. Formula 1-2 represents the embodiment in which in Formula 1, the position relation between the amine group, to which Ar₁ and Ar₂ are bonded, and the silicon atom is para. Formula 1-3 represents the embodiment in which in Formula 1, the position relation between the amine group, to which Ar₁ and Ar₂ are bonded, and the silicon atom is ortho.

Formula 1 may be represented by Formula 2. Formula 2 represents the embodiment in which in Formula 1, any one among Ar₁ and Ar₂ is an unsubstituted phenyl group, and/or any one among Ar₃ and Ar₄ is an unsubstituted phenyl group.

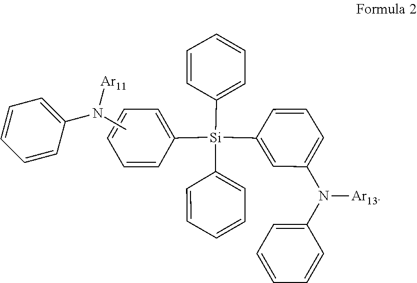

In Formula 2, Ar₁₁ and Ar₁₃ may each independently be a substituted or unsubstituted aryl group having 6 to 30 ring-forming carbon atoms, or a substituted or unsubstituted heteroaryl group having 2 to 30 ring-forming carbon atoms. In Formula 2, Ar₁₁ may be any one among Ar₁ and Ar₂ in Formula 1, and Ar₁₃ may be any one among Ar₃ and Ar₄ in Formula 1. In Formula 2, the amine group, to which Ar₁₃ is bonded, and the silicon atom may be in the meta-position relation. In Formula 2, the amine group, to which Ar₁₁ is bonded, and the silicon atom may be in the meta-, para-, or ortho-position relation.

In an embodiment, Formula 2 may be represented by Formula 2-1. Formula 2-1 represents the case where Ar₁₁ and Ar₁₃ are substituted or unsubstituted phenyl groups in Formula 2.

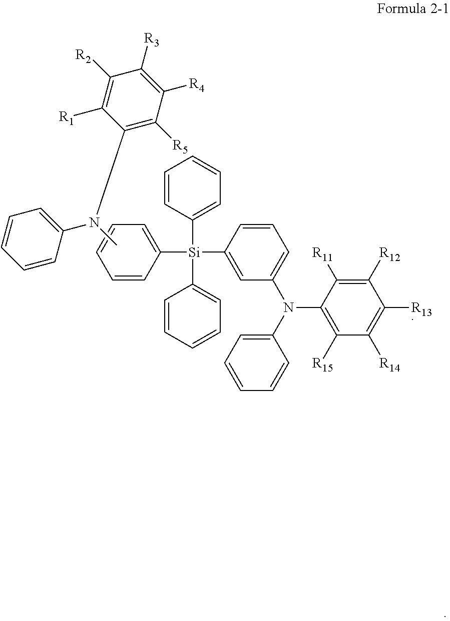

In Formula 2-1, R₁ to R₅ may each independently be a hydrogen atom, a substituted or unsubstituted amine group, a substituted or unsubstituted oxy group, a substituted or unsubstituted thio group, a substituted or unsubstituted alkyl group having 1 to 10 carbon atoms, a substituted or unsubstituted alkenyl group having 2 to 10 carbon atoms, or a substituted or unsubstituted aryl group having 6 to 30 ring-forming carbon atoms, and/or may be bonded to an adjacent group to form a ring. In Formula 2-1, the amine group, to which a phenyl group including R₁ to R₅ is bonded, and the silicon atom may be in the meta-, para-, or ortho-position relation.

For example, R₁ and R₂ may be vinyl groups, and R₁ and R₂ may be bonded to form an unsubstituted naphthyl group. R₂ may be an isopropyl group, R₃ may be a phenyl group, and R₂ and R₃ may be bonded to form a dimethylfluorenyl group. R₃ may be a phenylamine group, R₄ may be a phenyl group, and R₃ and R₄ may be bonded to form a carbazole group substituted with a phenyl group. R₃ may be a thio group, R₄ may be a phenyl group, and R₃ and R₄ may be bonded to form an unsubstituted dibenzothiophene group. R₃ may be an oxy group, R₄ may be a phenyl group, and R₃ and R₄ may be bonded to form an unsubstituted dibenzofuran group. However, these are merely examples, and the examples that R₁ to R₅ are bonded to form a ring are not limited thereto.

R₁₁ to R₁₅ may each independently be a hydrogen atom, a substituted or unsubstituted amine group, a substituted or unsubstituted oxy group, a substituted or unsubstituted thio group, a substituted or unsubstituted alkyl group having 1 to 10 carbon atoms, a substituted or unsubstituted alkenyl group having 2 to 10 carbon atoms, or a substituted or unsubstituted aryl group having 6 to 30 ring-forming carbon atoms, or may be bonded to an adjacent group to form a ring. For example, R₁₃ and R₁₄ may be vinyl groups, and R₁₃ and R₁₄ may be bonded to form an unsubstituted naphthyl group. R₁₃ may be an isopropyl group, R₁₄ may be a phenyl group, and R₁₃ and R₁₄ may be bonded to form a dimethylfluorenyl group. R₁₂ may be a phenylamine group, R₁₃ may be a phenyl group, and R₁₂ and R₁₃ may be bonded to form a carbazole group substituted with a phenyl group.

R₁₃ may be a thio group, R₁₄ may be a phenyl group, and R₁₃ and R₁₄ may be bonded to form an unsubstituted dibenzothiophene group. R₁₃ may be an oxy group, R₁₄ may be a phenyl group, and R₁₃ and R₁₄ may be bonded to form an unsubstituted dibenzofuran group. However, these are merely examples, and the examples that R₁₁ to R₁₅ are bonded to form a ring are not limited thereto.

In some embodiments, Formula 2 may be represented by Formula 2-2A or Formula 2-2B. Formula 2-2A represents the embodiment in which in Formula 2, Ar₁₁ is a tricyclic group containing X₁ as a ring-forming atom. Formula 2-2B represents the embodiment in which in Formula 2, Ar₁₃ is a tricyclic group containing X₁ as a ring-forming atom.

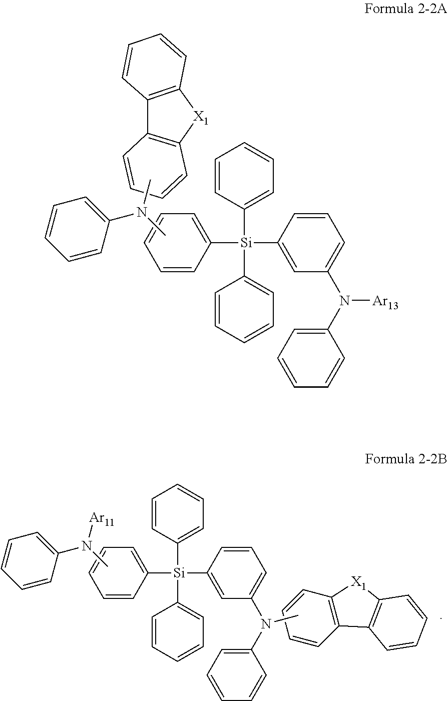

In Formula 2-2A and Formula 2-2B, the same as described in Formula 2 may be applied to Ar₁₁ and Ar₁₃. In Formula 2-2A and Formula 2-2B, X₁ may be C(CH₃)₂, N(Ph), O, or S. Ph of N(Ph) is a phenyl group.

When X₁ is C(CH₃)₂, the cyclic group containing X₁ may be a dimethylfluorenyl group. When X₁ is N(Ph), the cyclic group containing X₁ may be a carbazole group substituted with a phenyl group. When X₁ is O, the cyclic group containing X₁ may be an unsubstituted dibenzofuran group. When X₁ is S, the cyclic group containing X₁ may be an unsubstituted dibenzothiophene group.

Formula 2-2 may be represented by Formula 2-2C. Formula 2-2C represents the embodiment in which in Formula 2, Ar₁₁ is a tricyclic group containing X₁ as a ring-forming atom, and Ar₁₃ is a tricyclic group containing X₂ as a ring-forming atom. In some embodiments, Formula 2-2C may represent the embodiment in which in Formula 2-2A, Ar₁₃ is a tricyclic group containing X₂ as a ring-forming atom.

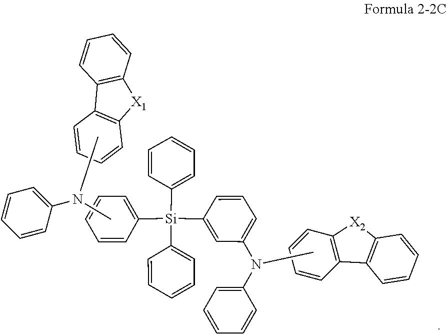

In Formula 2-2C, X₁ may be C(CH₃)₂, N(Ph), O, or S. X₂ may be C(CH₃)₂, N(Ph), O, or S. X₁ and X₂ may be the same as or different from each other. For example, X₁ and X₂ may be the same as C(CH₃)₂. X₁ and X₂ may be the same as O. X₁ and X₂ may be the same as S. In some embodiments, any one among X₁ and X₂ may be C(CH₃)₂, and the other (i.e., substituent that is not C(CH₃)₂) may be N(Ph), 0, or S. Any one among X₁ and X₂ may be O, and the other (i.e., substituent that is not O) may be S.

The amine compound of an embodiment may be represented by any one among compounds in Compound Group 1. The light emitting element ED of an embodiment may include any one among the compounds of Compound Group 1:

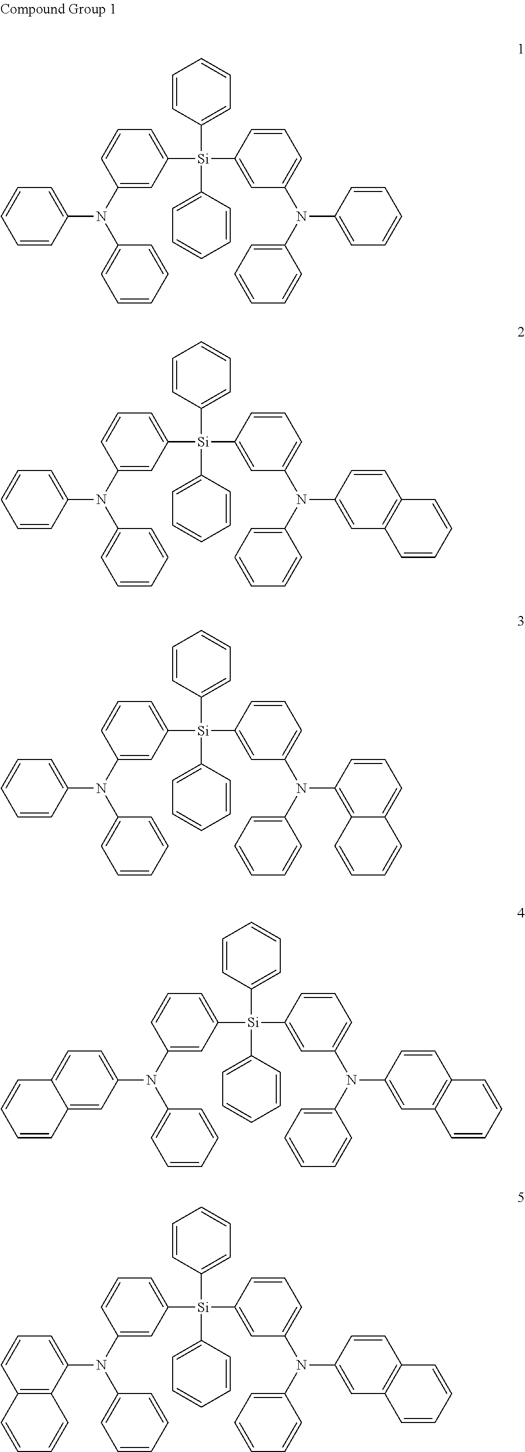

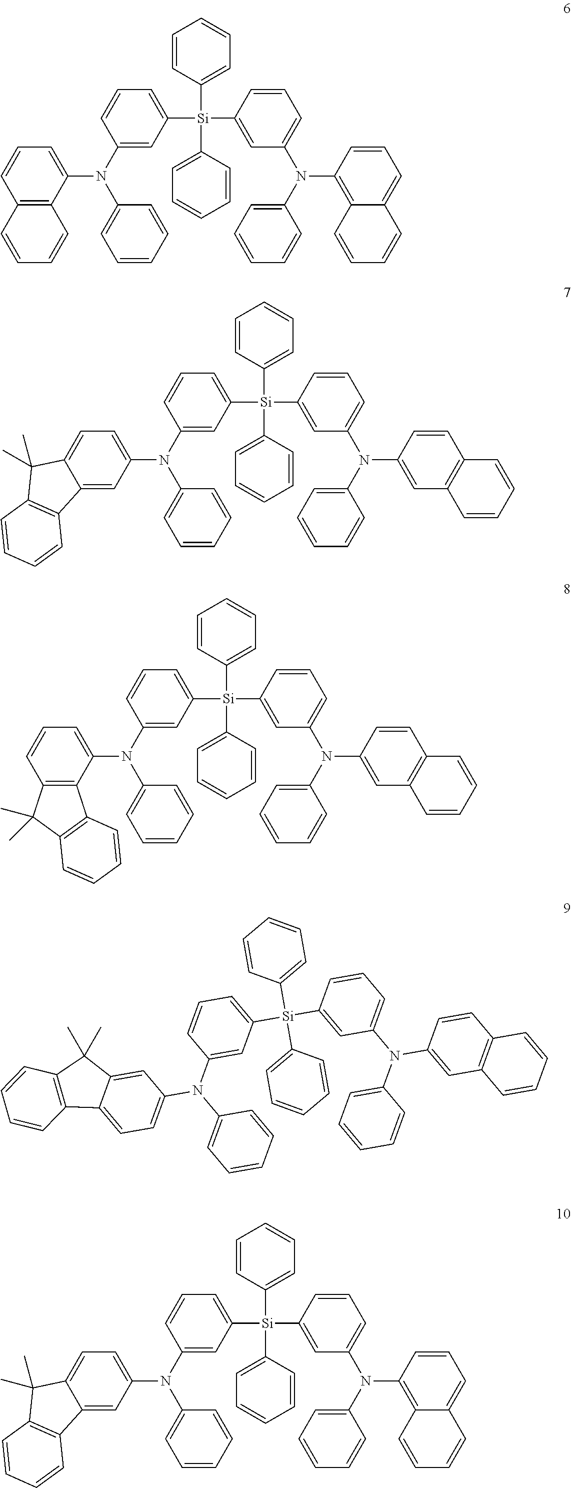

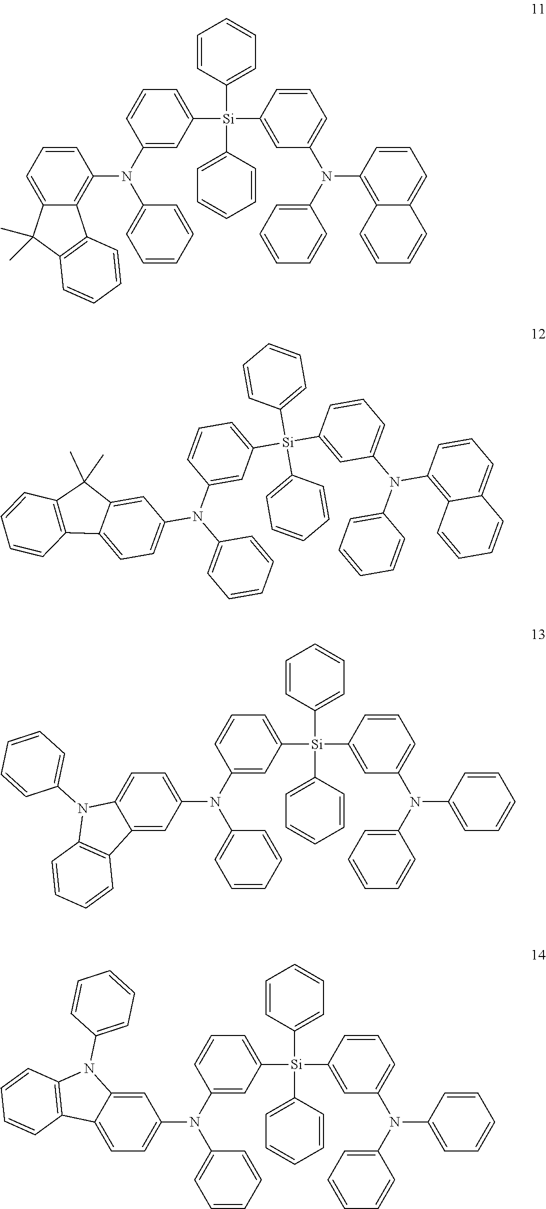 [SMILES: CC1(C)c2ccccc2-c2c(N(c3ccccc3)c3cccc([Si](c4ccccc4)(c4ccccc4)c4cccc(N(c5ccccc5)c5cccc6ccccc56)c4)c3)cccc21 ; CC1(C)c2ccccc2-c2ccc(N(c3ccccc3)c3cccc([Si](c4ccccc4)(c4ccccc4)c4cccc(N(c5ccccc5)c5cccc6ccccc56)c4)c3)cc21 ; c1ccc(N(c2ccccc2)c2cccc([Si](c3ccccc3)(c3ccccc3)c3cccc(N(c4ccccc4)c4ccc5c(c4)c4ccccc4n5-c4ccccc4)c3)c2)cc1 ; c1ccc(N(c2ccccc2)c2cccc([Si](c3ccccc3)(c3ccccc3)c3cccc(N(c4ccccc4)c4ccc5c6ccccc6n(-c6ccccc6)c5c4)c3)c2)cc1]

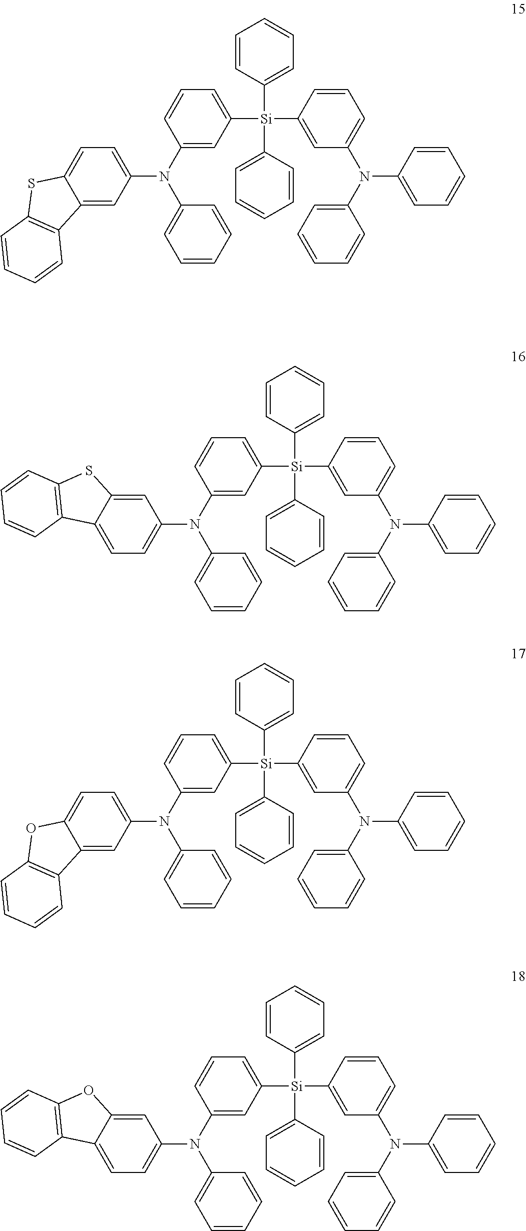 [SMILES: c1ccc(N(c2ccccc2)c2cccc([Si](c3ccccc3)(c3ccccc3)c3cccc(N(c4ccccc4)c4ccc5sc6ccccc6c5c4)c3)c2)cc1 ; c1ccc(N(c2ccccc2)c2cccc([Si](c3ccccc3)(c3ccccc3)c3cccc(N(c4ccccc4)c4ccc5c(c4)sc4ccccc45)c3)c2)cc1 ; c1ccc(N(c2ccccc2)c2cccc([Si](c3ccccc3)(c3ccccc3)c3cccc(N(c4ccccc4)c4ccc5oc6ccccc6c5c4)c3)c2)cc1 ; c1ccc(N(c2ccccc2)c2cccc([Si](c3ccccc3)(c3ccccc3)c3cccc(N(c4ccccc4)c4ccc5c(c4)oc4ccccc45)c3)c2)cc1]

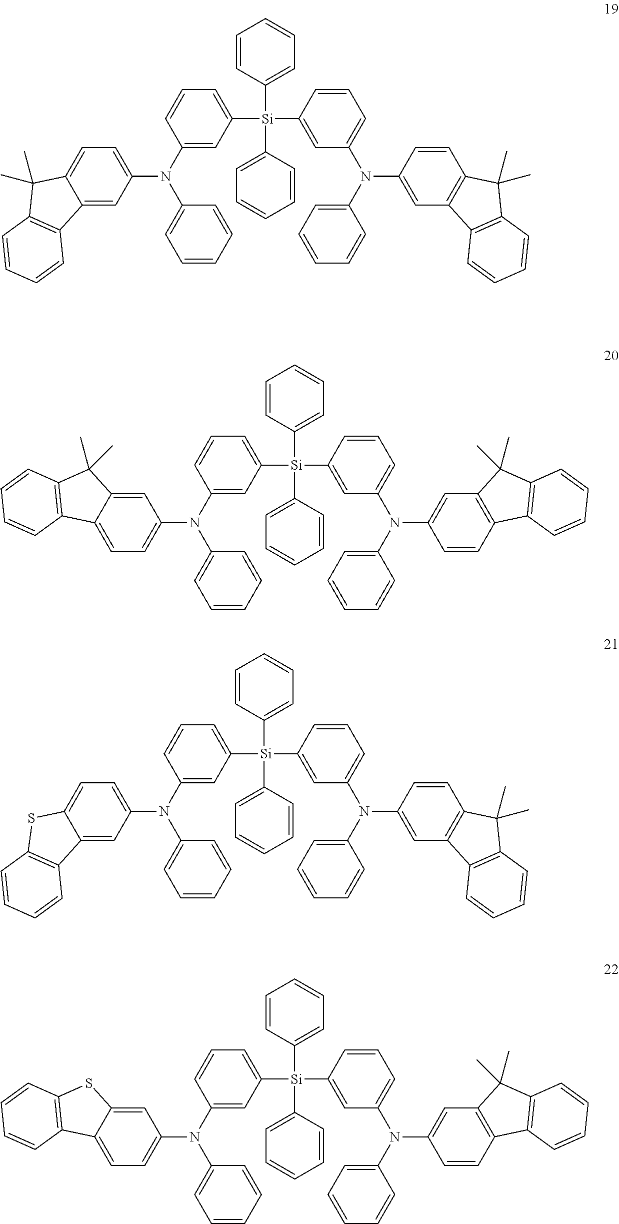

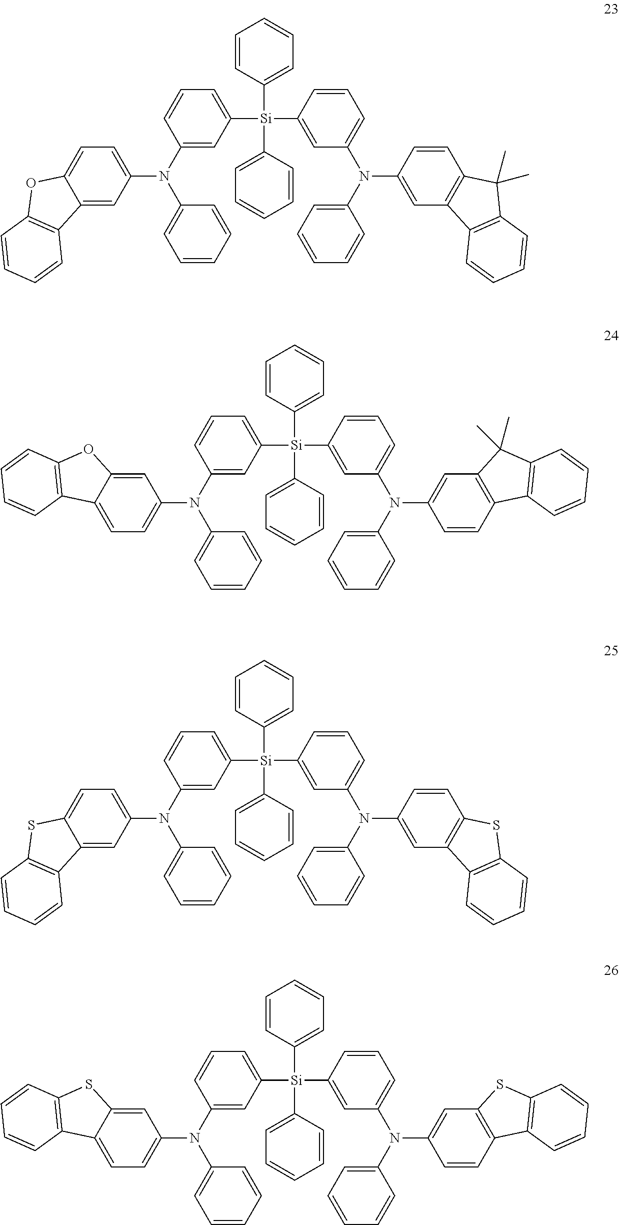 [SMILES: CC1(C)c2ccccc2-c2cc(N(c3ccccc3)c3cccc([Si](c4ccccc4)(c4ccccc4)c4cccc(N(c5ccccc5)c5ccc6oc7ccccc7c6c5)c4)c3)ccc21 ; CC1(C)c2ccccc2-c2ccc(N(c3ccccc3)c3cccc([Si](c4ccccc4)(c4ccccc4)c4cccc(N(c5ccccc5)c5ccc6c(c5)oc5ccccc56)c4)c3)cc21 ; c1ccc(N(c2cccc([Si](c3ccccc3)(c3ccccc3)c3cccc(N(c4ccccc4)c4ccc5sc6ccccc6c5c4)c3)c2)c2ccc3sc4ccccc4c3c2)cc1 ; c1ccc(N(c2cccc([Si](c3ccccc3)(c3ccccc3)c3cccc(N(c4ccccc4)c4ccc5c(c4)sc4ccccc45)c3)c2)c2ccc3c(c2)sc2ccccc23)cc1]

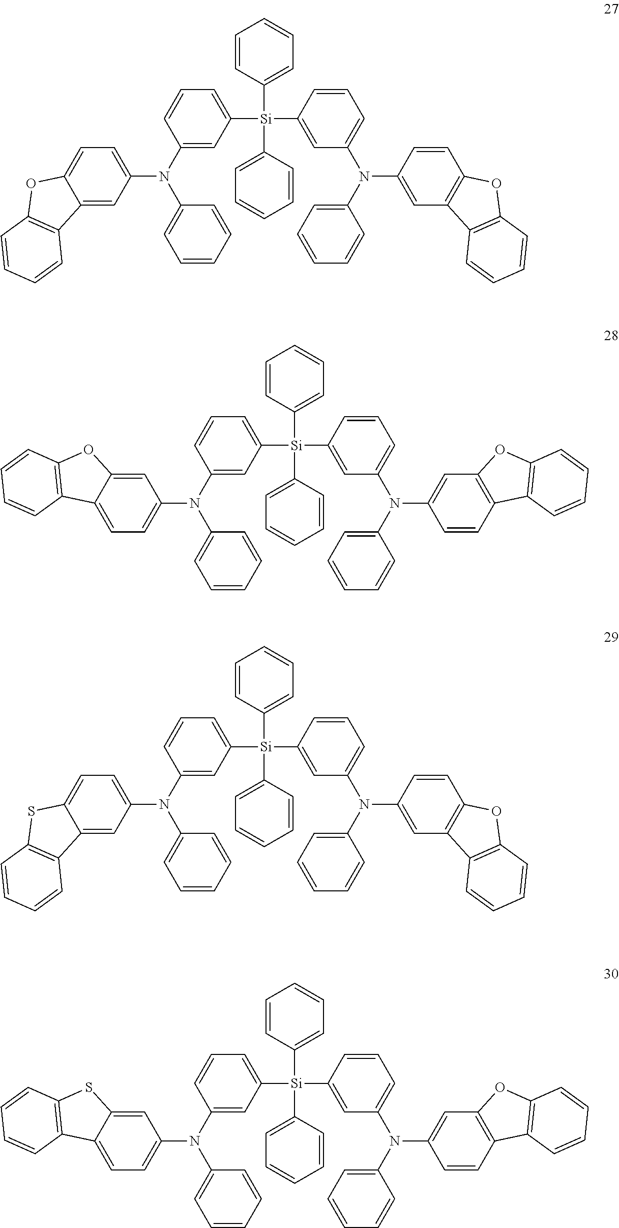 [SMILES: c1ccc(N(c2cccc([Si](c3ccccc3)(c3ccccc3)c3cccc(N(c4ccccc4)c4ccc5oc6ccccc6c5c4)c3)c2)c2ccc3oc4ccccc4c3c2)cc1 ; c1ccc(N(c2cccc([Si](c3ccccc3)(c3ccccc3)c3cccc(N(c4ccccc4)c4ccc5c(c4)oc4ccccc45)c3)c2)c2ccc3c(c2)oc2ccccc23)cc1 ; c1ccc(N(c2cccc([Si](c3ccccc3)(c3ccccc3)c3cccc(N(c4ccccc4)c4ccc5sc6ccccc6c5c4)c3)c2)c2ccc3oc4ccccc4c3c2)cc1 ; c1ccc(N(c2cccc([Si](c3ccccc3)(c3ccccc3)c3cccc(N(c4ccccc4)c4ccc5c(c4)sc4ccccc45)c3)c2)c2ccc3c(c2)oc2ccccc23)cc1]

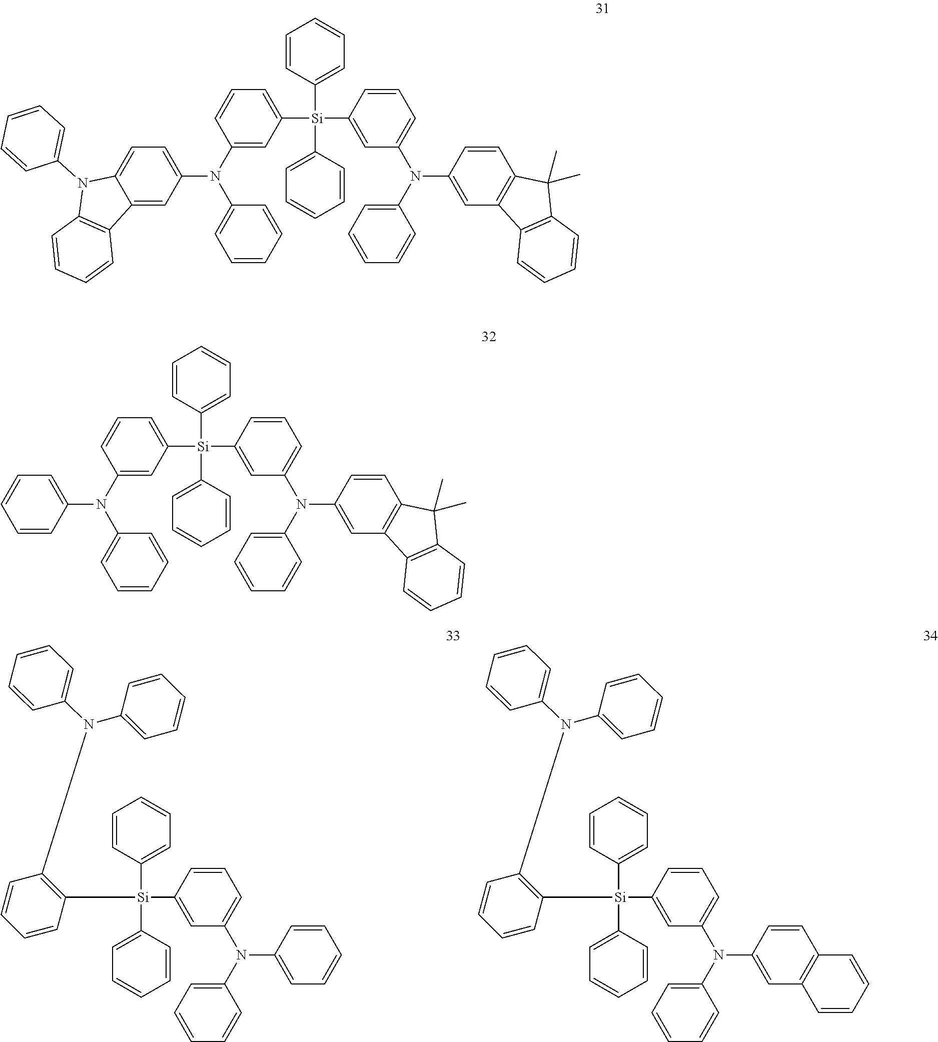 [SMILES: CC1(C)c2ccccc2-c2cc(N(c3ccccc3)c3cccc([Si](c4ccccc4)(c4ccccc4)c4cccc(N(c5ccccc5)c5ccc6c(c5)c5ccccc5n6-c5ccccc5)c4)c3)ccc21 ; CC1(C)c2ccccc2-c2cc(N(c3ccccc3)c3cccc([Si](c4ccccc4)(c4ccccc4)c4cccc(N(c5ccccc5)c5ccccc5)c4)c3)ccc21 ; c1ccc(N(c2ccccc2)c2cccc([Si](c3ccccc3)(c3ccccc3)c3ccccc3N(c3ccccc3)c3ccccc3)c2)cc1 ; c1ccc(N(c2cccc([Si](c3ccccc3)(c3ccccc3)c3ccccc3N(c3ccccc3)c3ccccc3)c2)c2ccc3ccccc3c2)cc1]

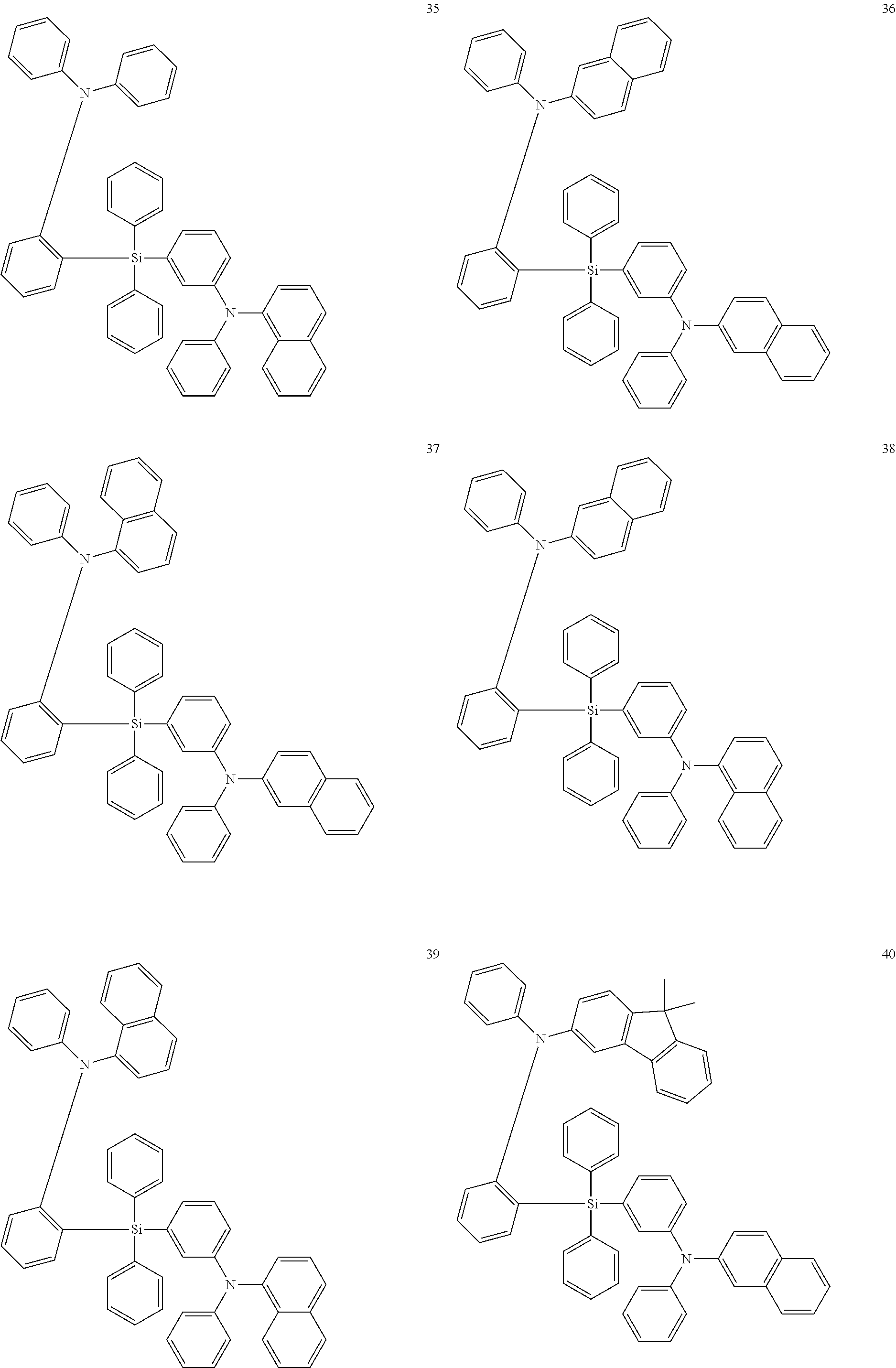

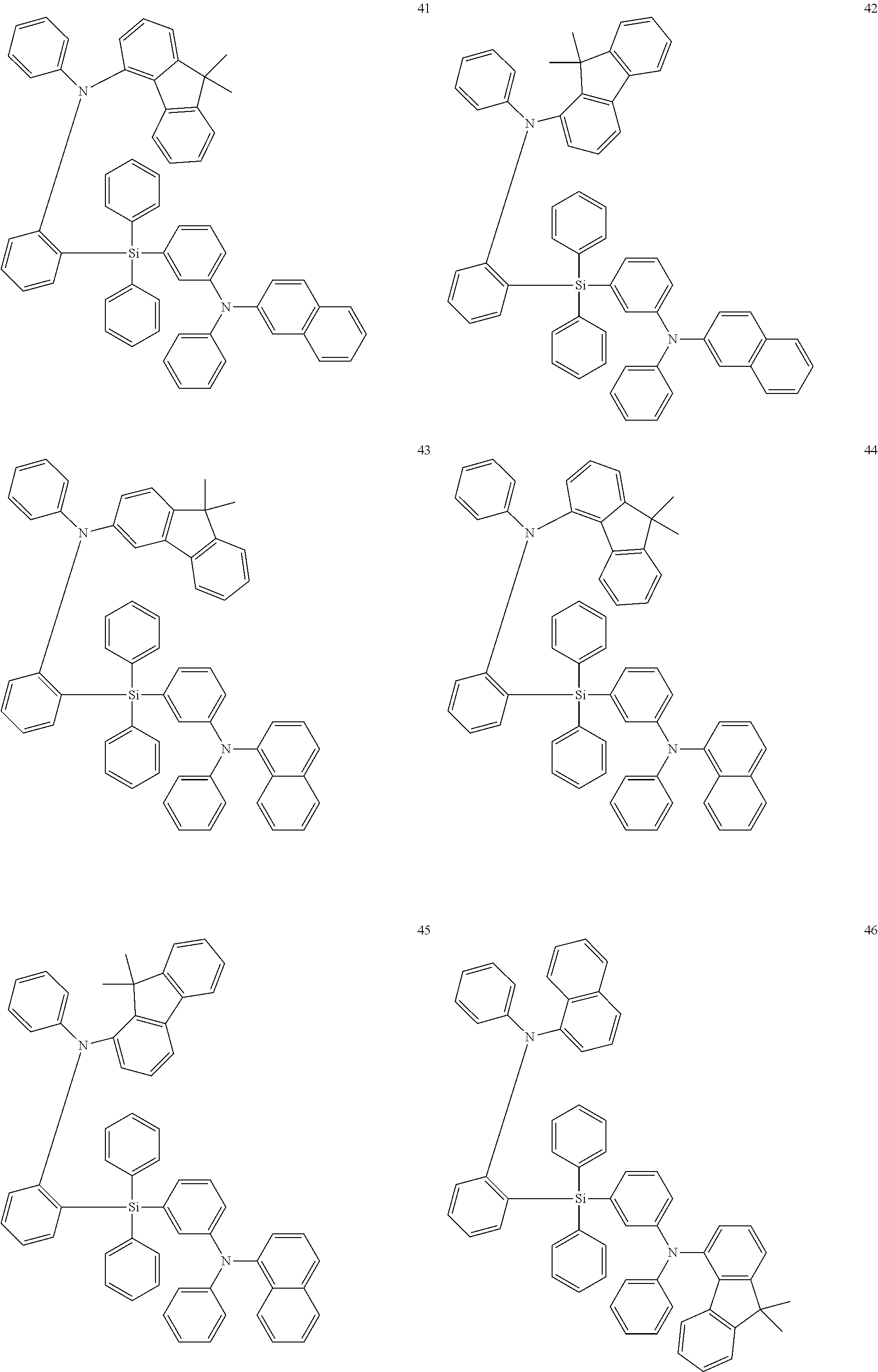

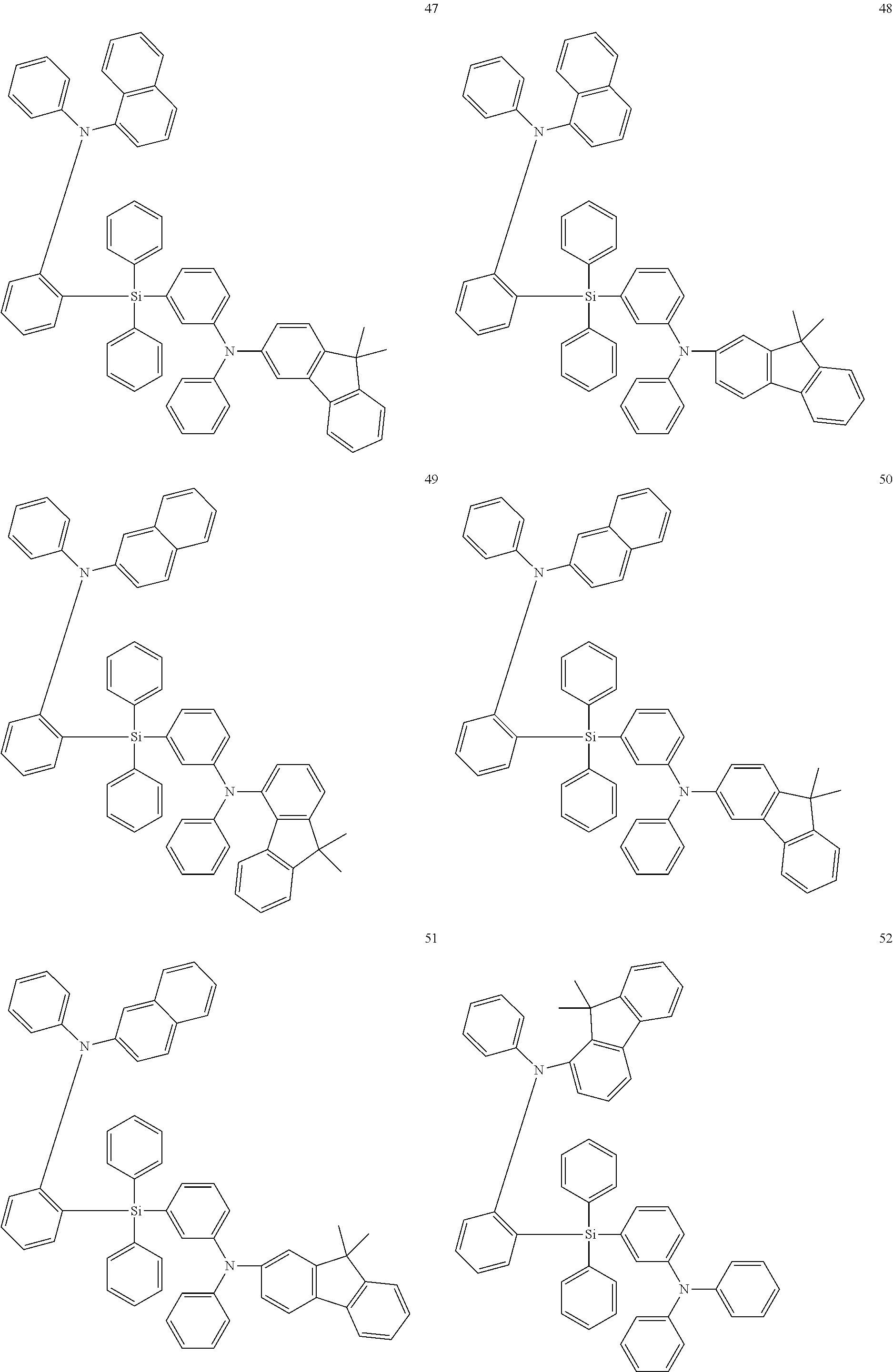

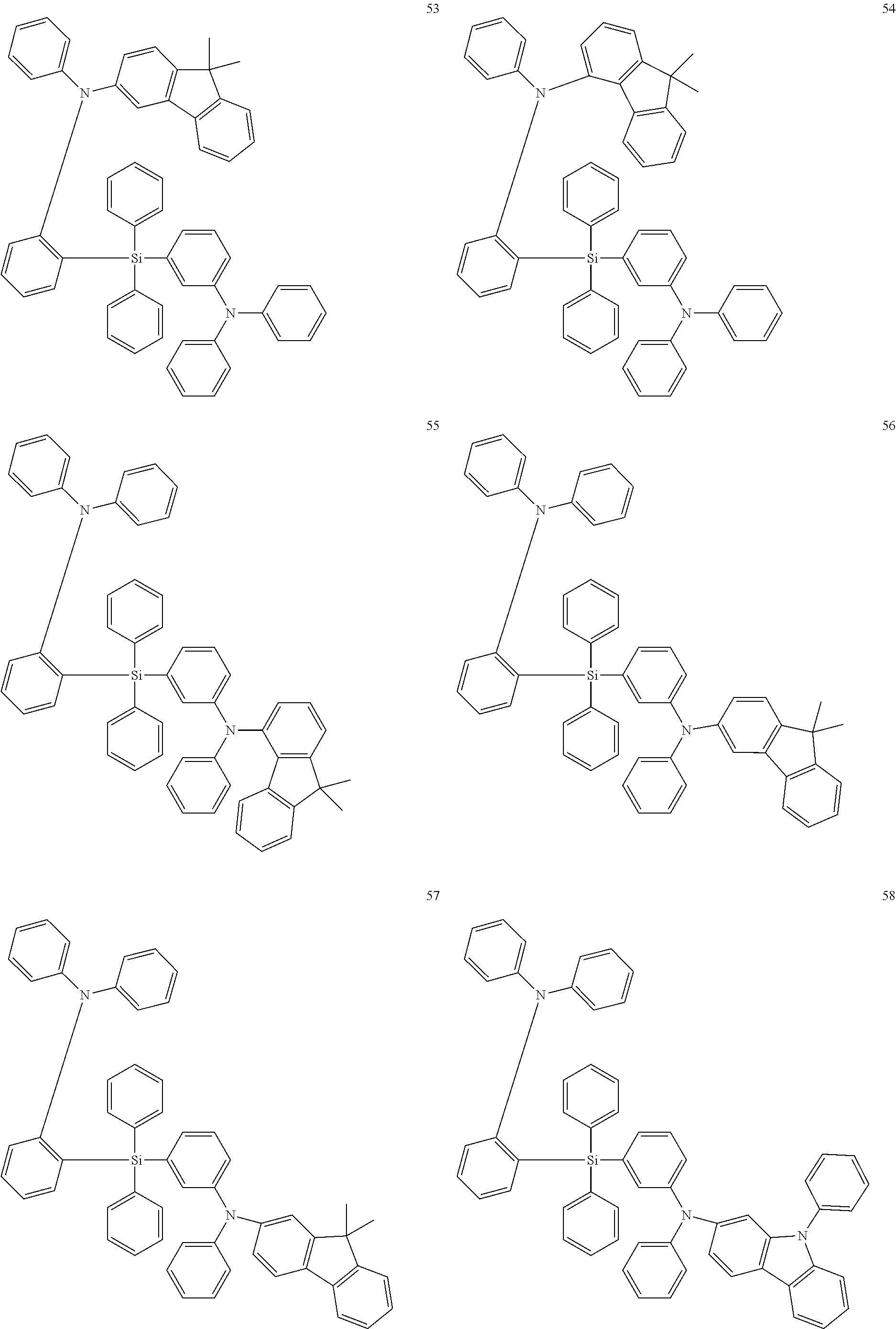

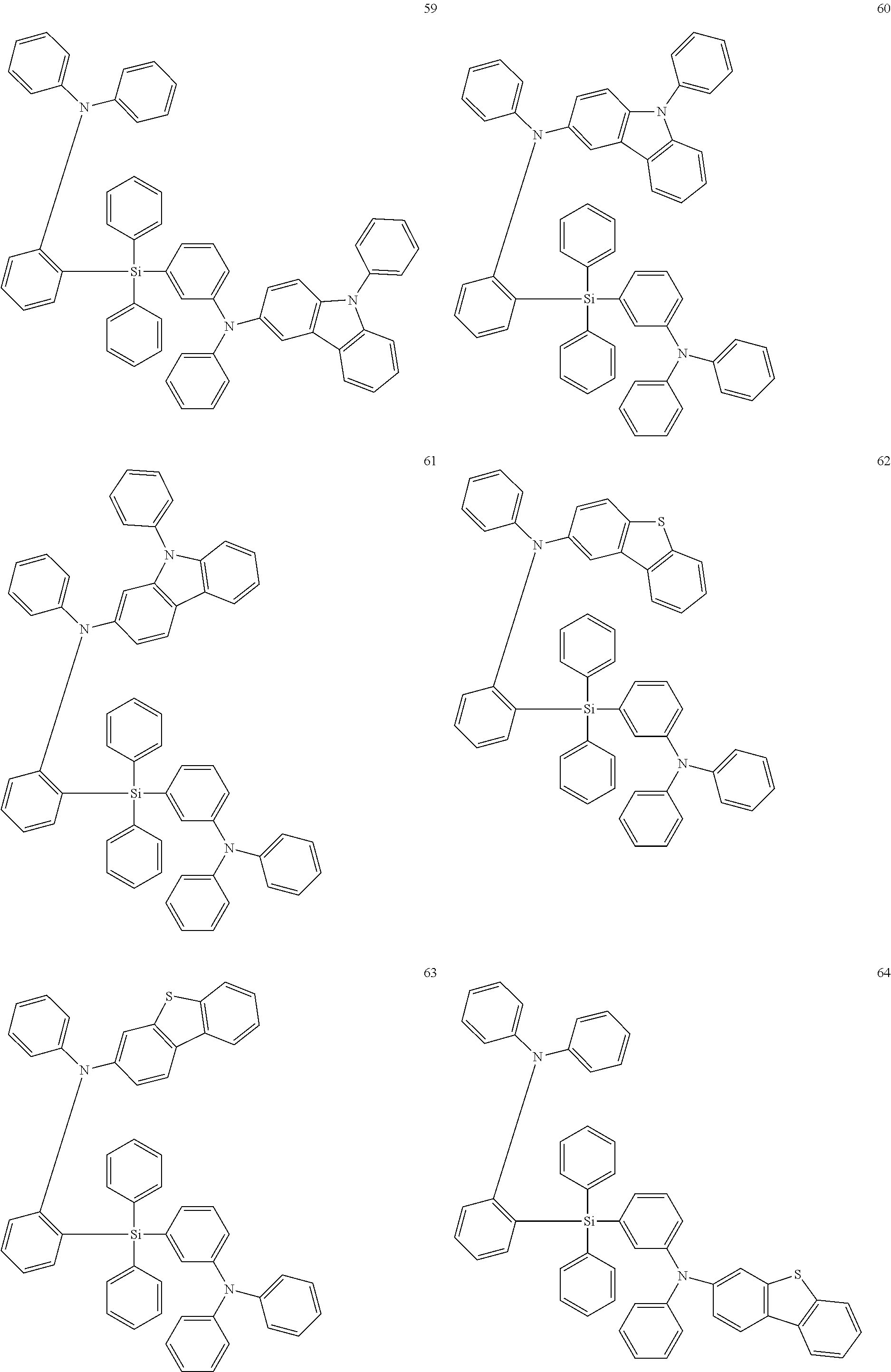

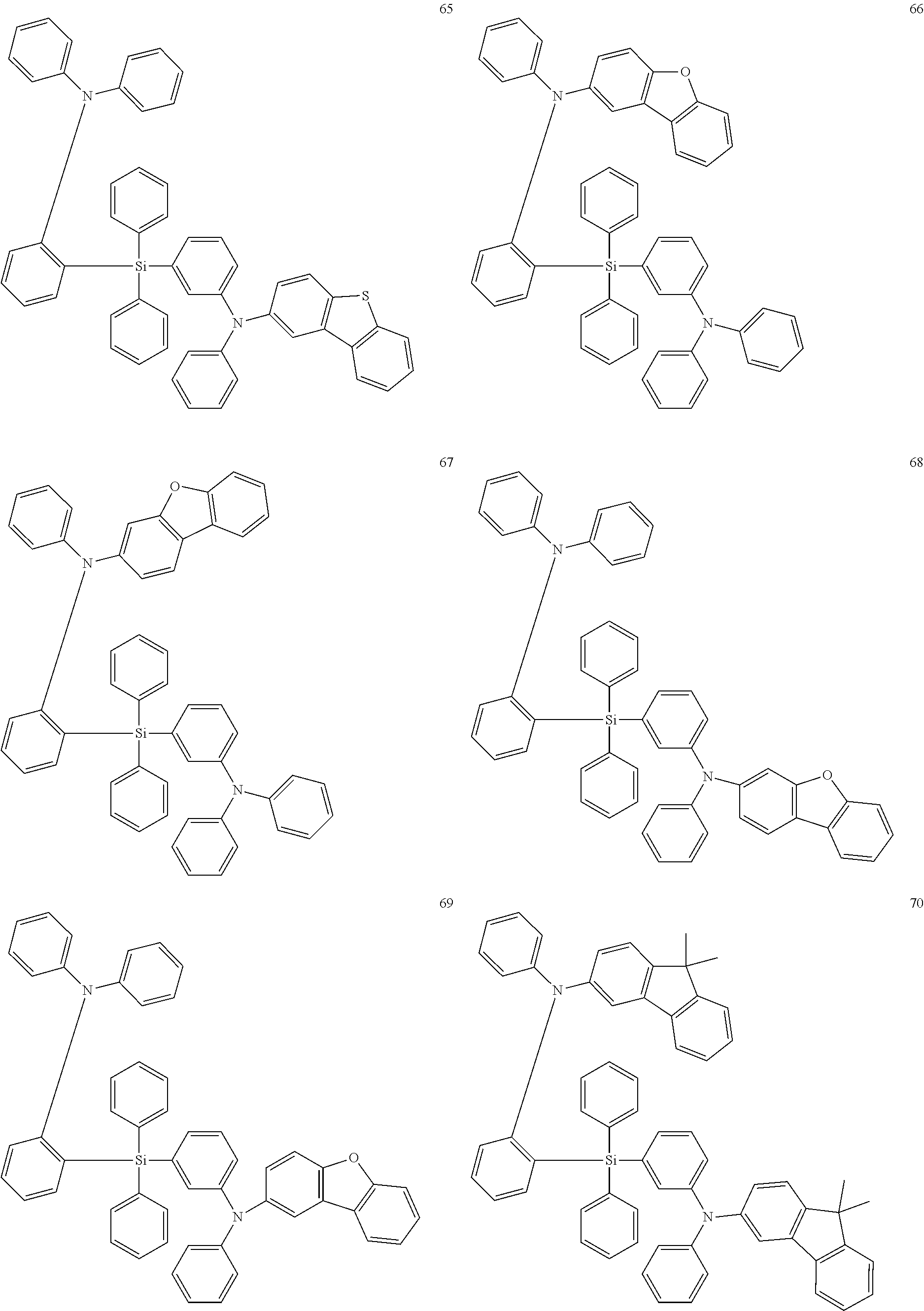

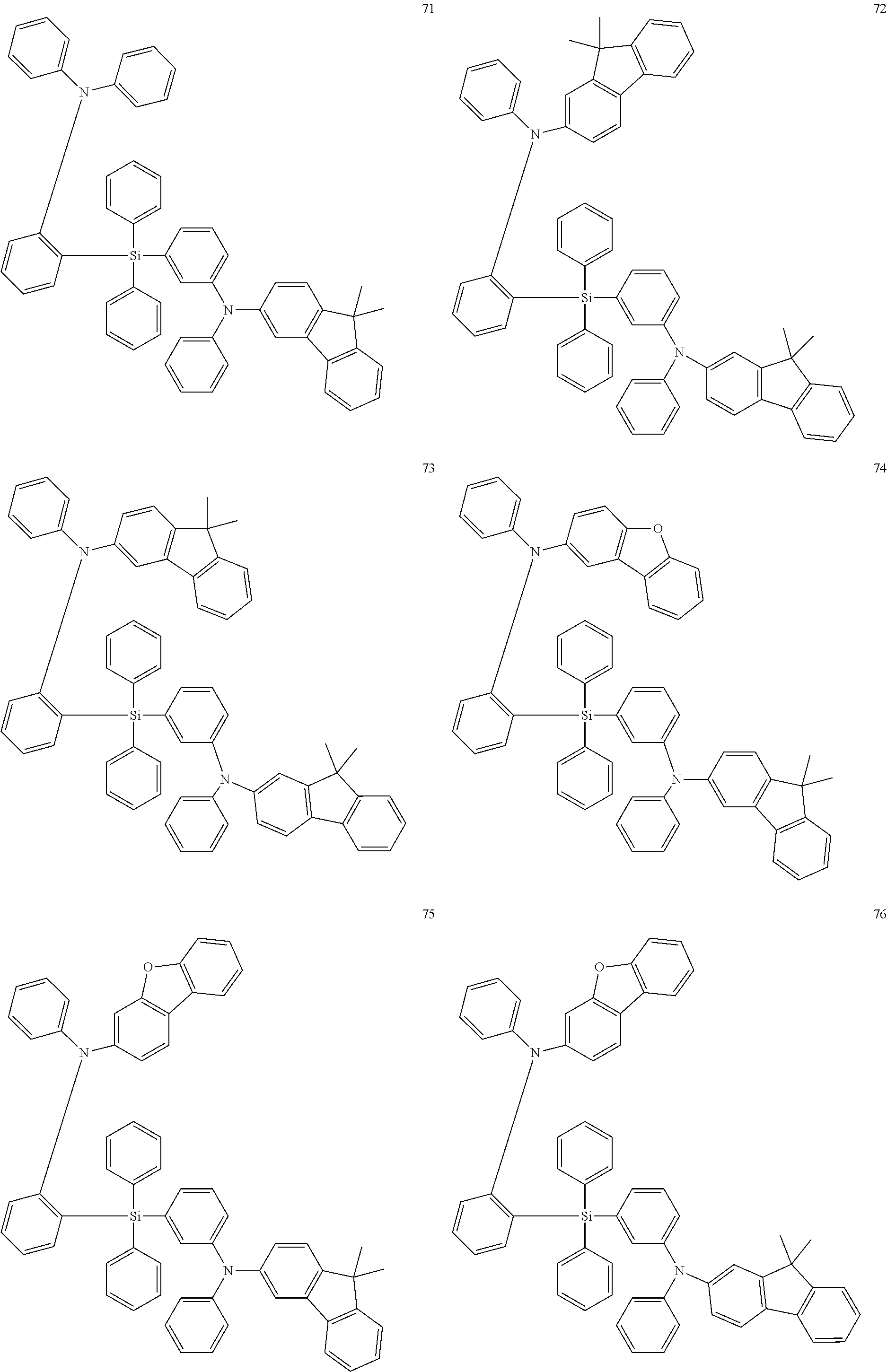

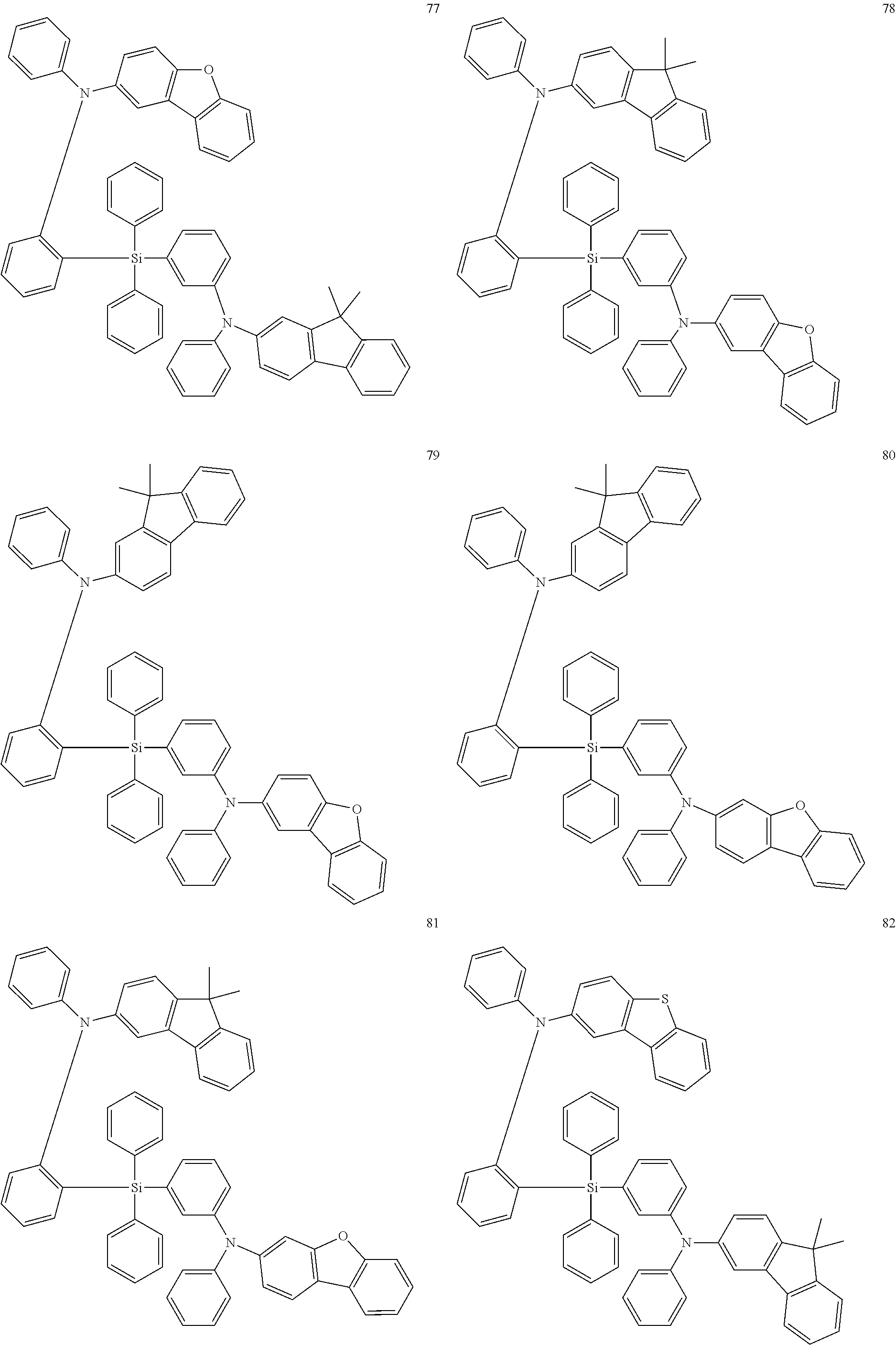

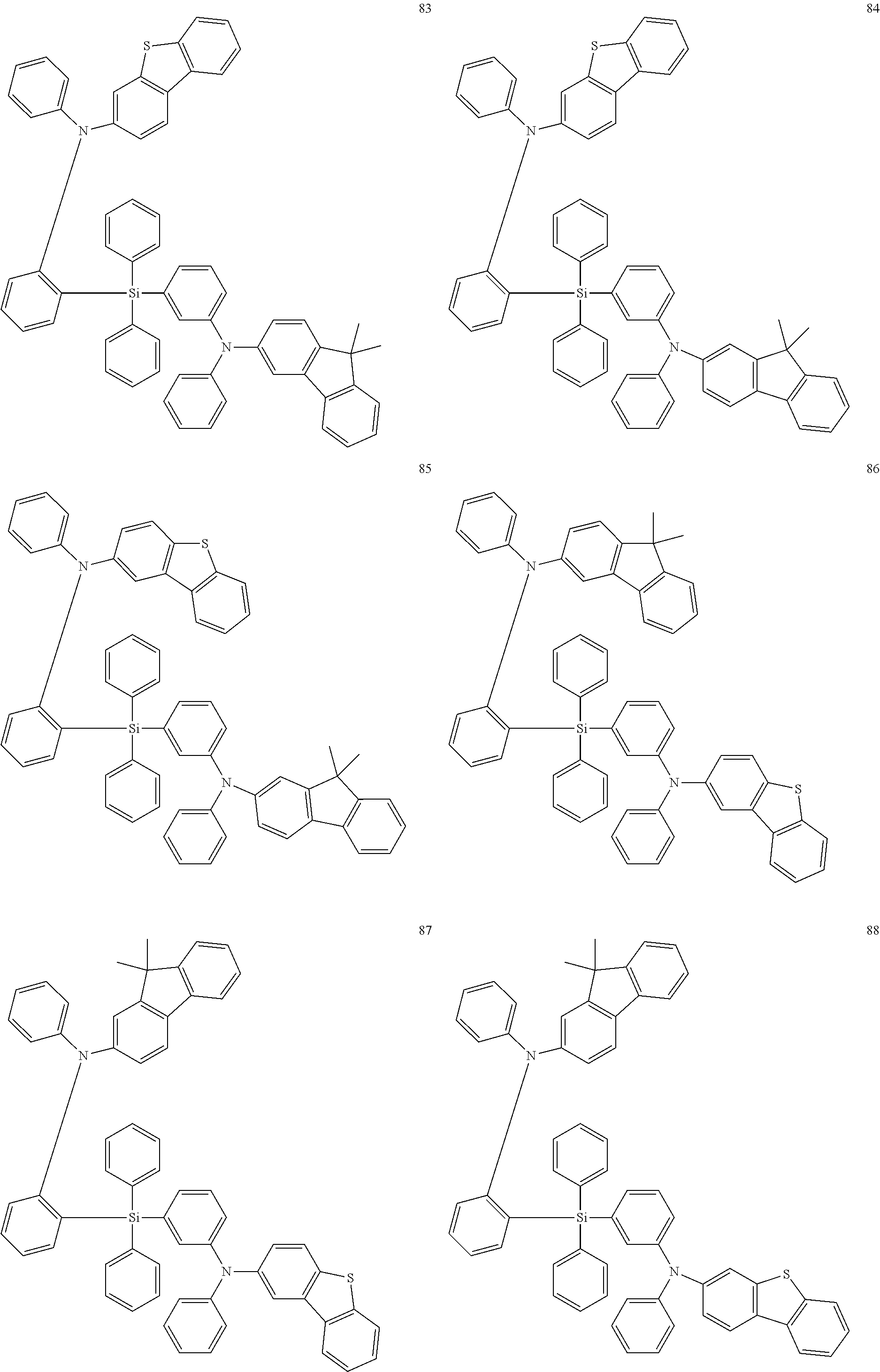

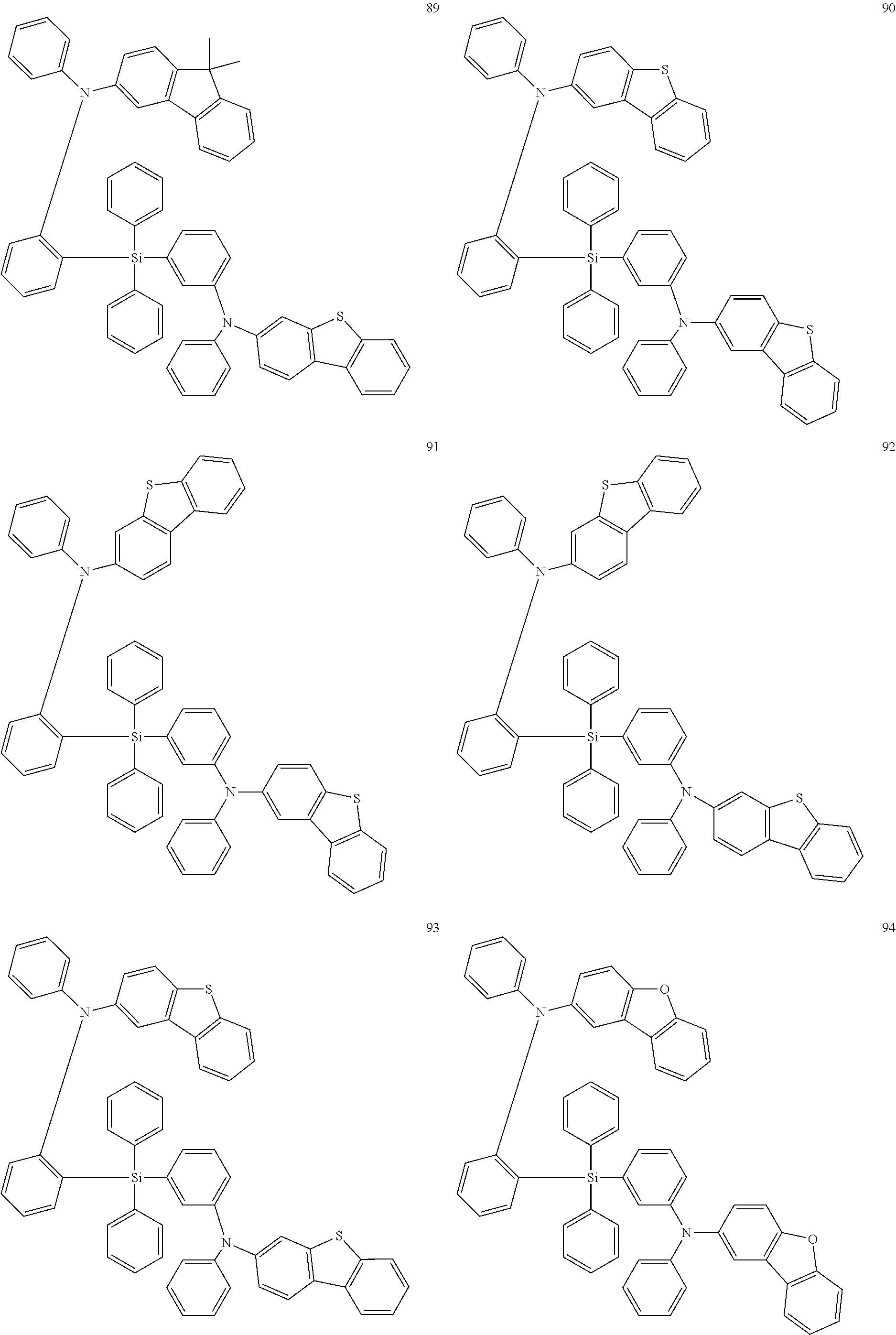

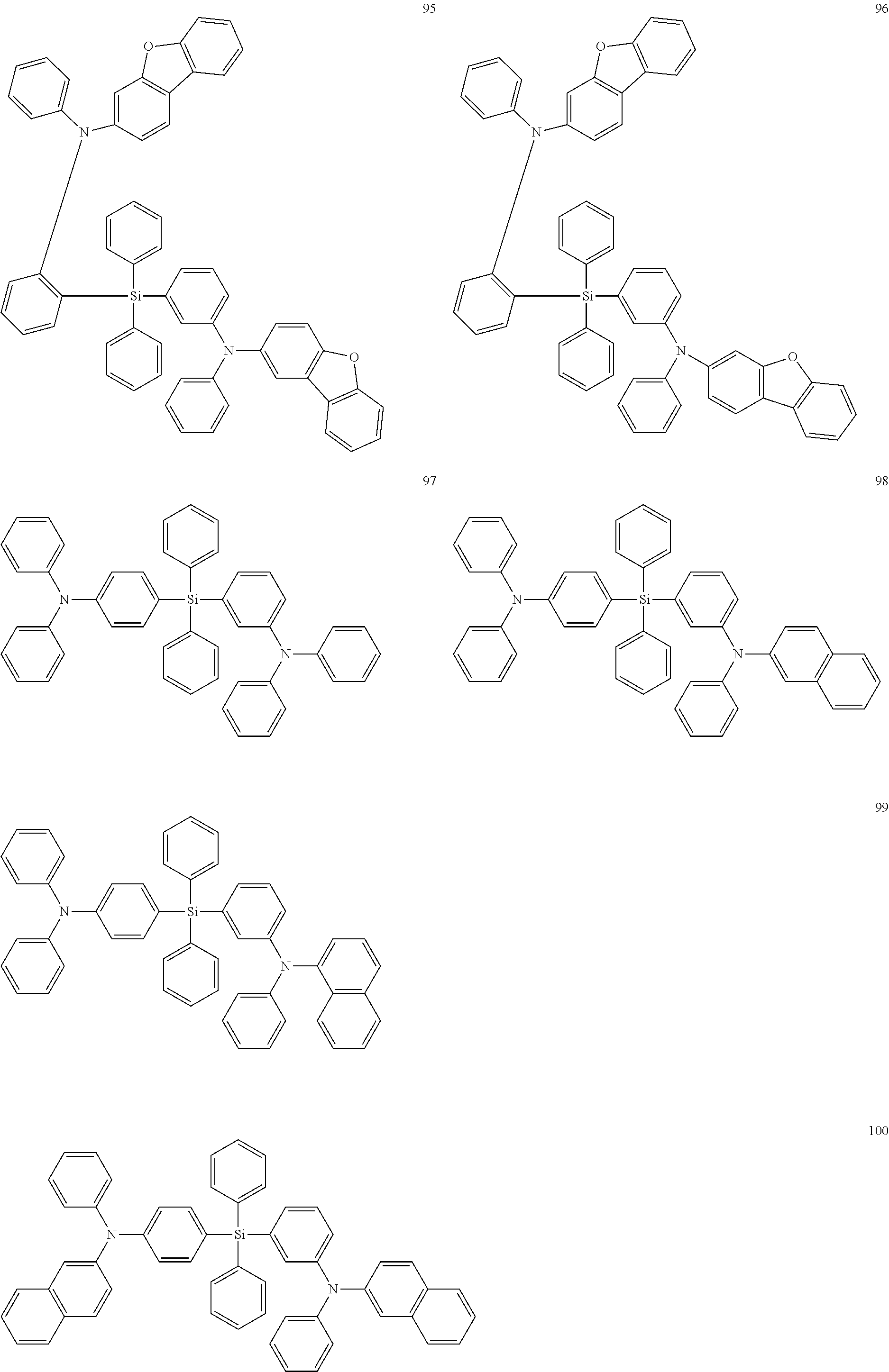

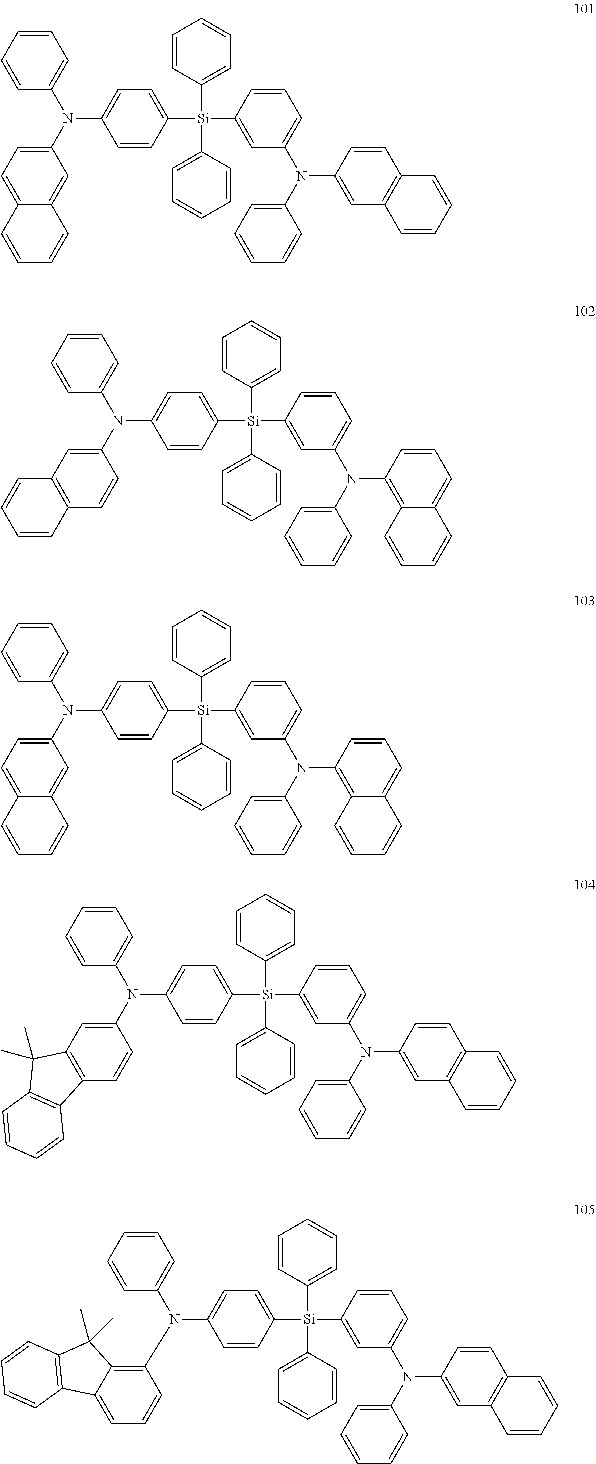

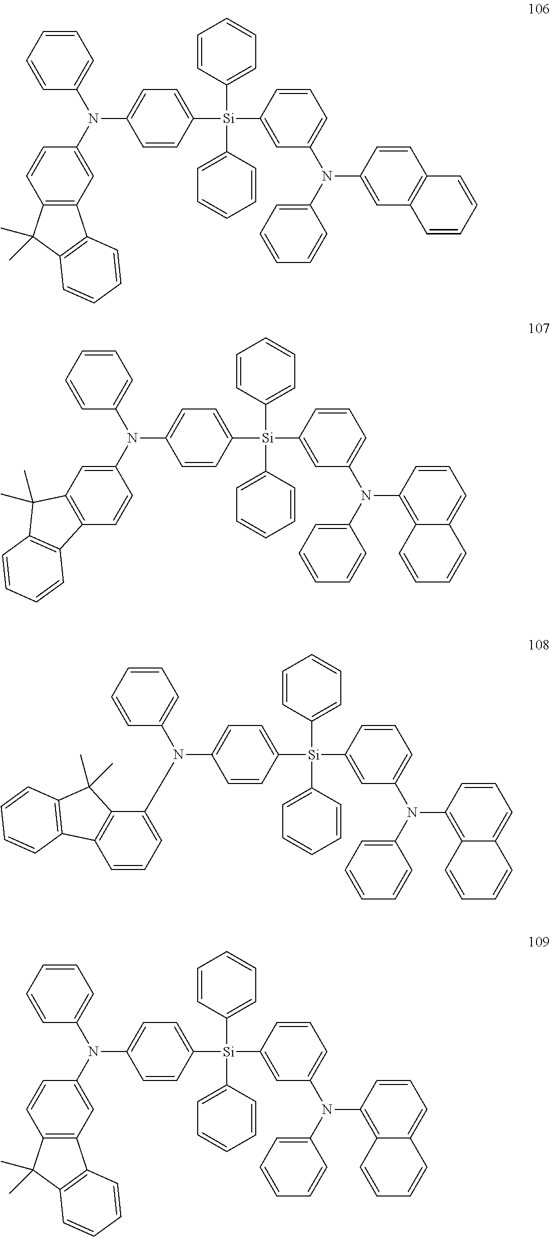 [SMILES: CC1(C)c2ccccc2-c2cc(N(c3ccccc3)c3ccc([Si](c4ccccc4)(c4ccccc4)c4cccc(N(c5ccccc5)c5ccc6ccccc6c5)c4)cc3)ccc21 ; CC1(C)c2ccccc2-c2ccc(N(c3ccccc3)c3ccc([Si](c4ccccc4)(c4ccccc4)c4cccc(N(c5ccccc5)c5cccc6ccccc56)c4)cc3)cc21 ; CC1(C)c2ccccc2-c2cccc(N(c3ccccc3)c3ccc([Si](c4ccccc4)(c4ccccc4)c4cccc(N(c5ccccc5)c5cccc6ccccc56)c4)cc3)c21 ; CC1(C)c2ccccc2-c2cc(N(c3ccccc3)c3ccc([Si](c4ccccc4)(c4ccccc4)c4cccc(N(c5ccccc5)c5cccc6ccccc56)c4)cc3)ccc21]

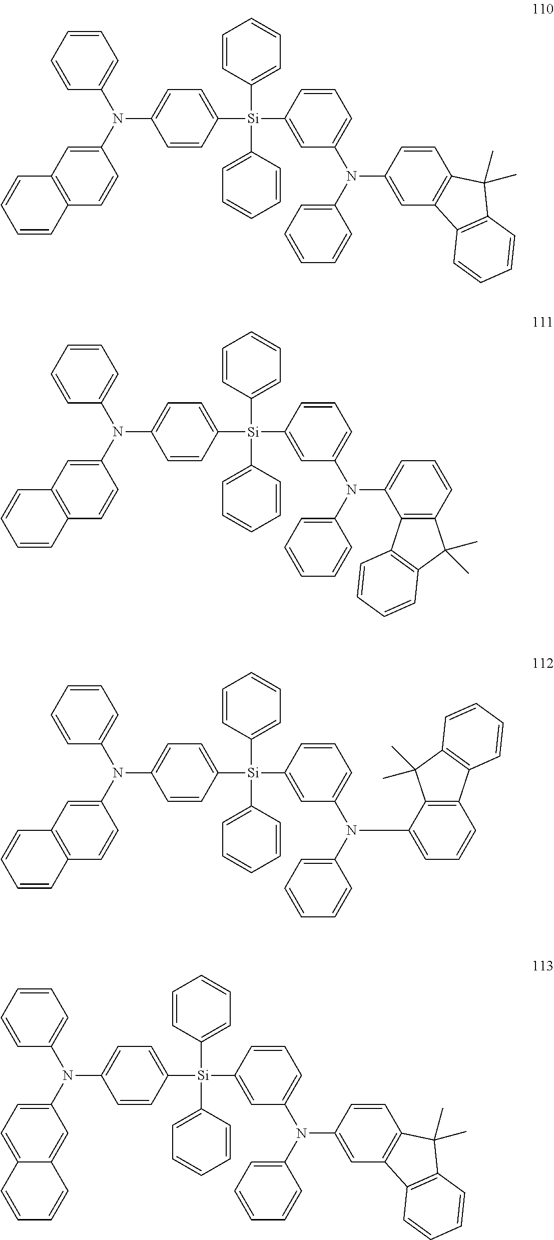 [SMILES: CC1(C)c2ccccc2-c2cc(N(c3ccccc3)c3cccc([Si](c4ccccc4)(c4ccccc4)c4ccc(N(c5ccccc5)c5ccc6ccccc6c5)cc4)c3)ccc21 ; CC1(C)c2ccccc2-c2c(N(c3ccccc3)c3cccc([Si](c4ccccc4)(c4ccccc4)c4ccc(N(c5ccccc5)c5ccc6ccccc6c5)cc4)c3)cccc21 ; CC1(C)c2ccccc2-c2cccc(N(c3ccccc3)c3cccc([Si](c4ccccc4)(c4ccccc4)c4ccc(N(c5ccccc5)c5ccc6ccccc6c5)cc4)c3)c21 ; CC1(C)c2ccccc2-c2cc(N(c3ccccc3)c3cccc([Si](c4ccccc4)(c4ccccc4)c4ccc(N(c5ccccc5)c5ccc6ccccc6c5)cc4)c3)ccc21]

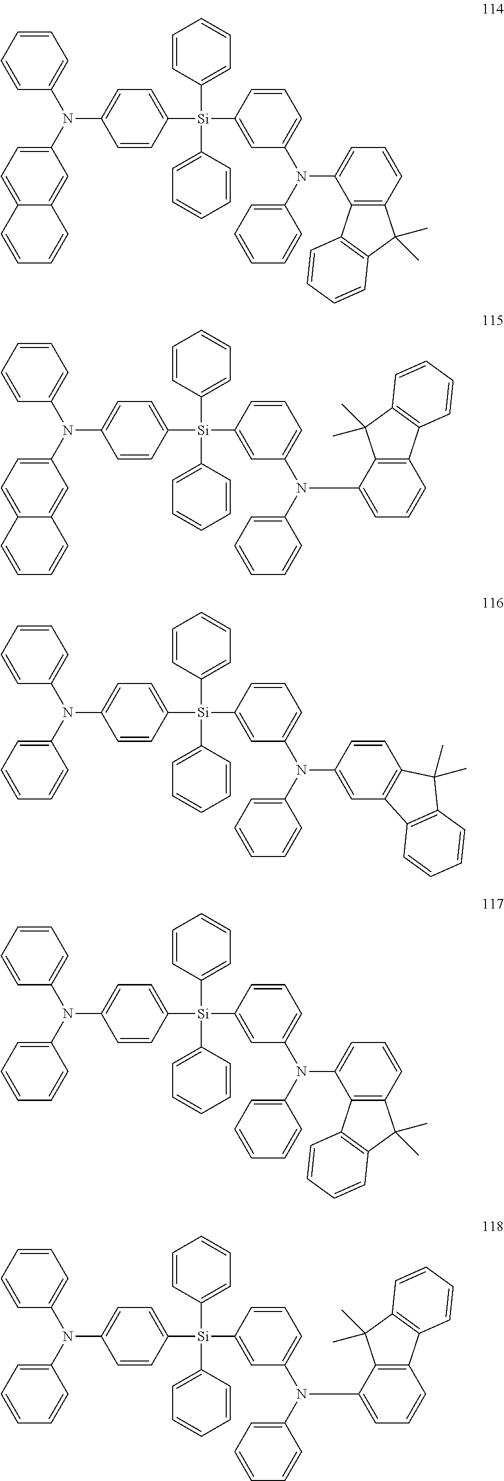

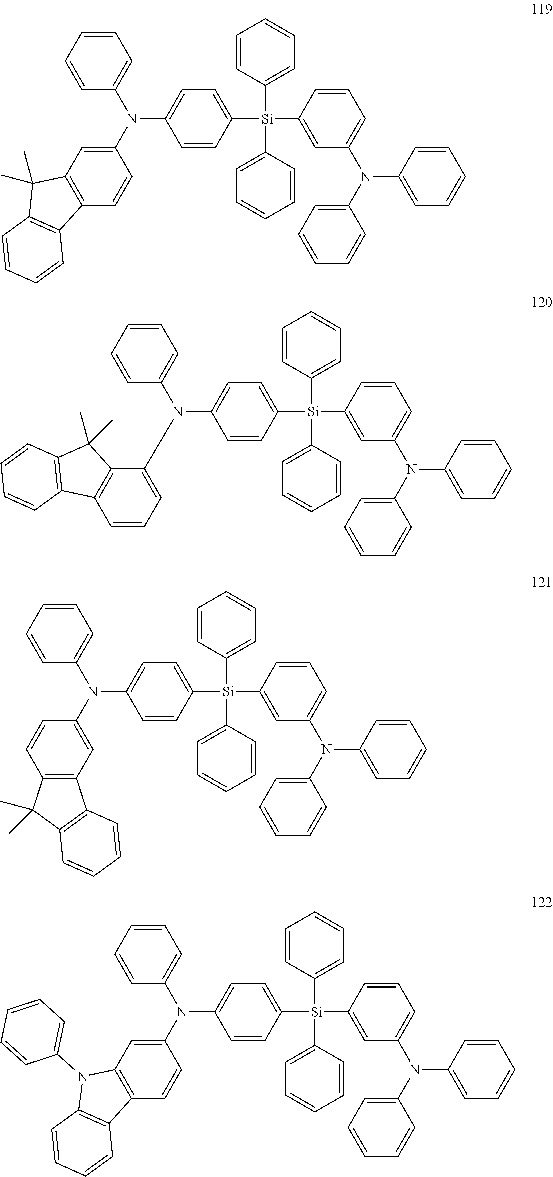 [SMILES: CC1(C)c2ccccc2-c2ccc(N(c3ccccc3)c3ccc([Si](c4ccccc4)(c4ccccc4)c4cccc(N(c5ccccc5)c5ccccc5)c4)cc3)cc21 ; CC1(C)c2ccccc2-c2cccc(N(c3ccccc3)c3ccc([Si](c4ccccc4)(c4ccccc4)c4cccc(N(c5ccccc5)c5ccccc5)c4)cc3)c21 ; CC1(C)c2ccccc2-c2cc(N(c3ccccc3)c3ccc([Si](c4ccccc4)(c4ccccc4)c4cccc(N(c5ccccc5)c5ccccc5)c4)cc3)ccc21 ; c1ccc(N(c2ccccc2)c2cccc([Si](c3ccccc3)(c3ccccc3)c3ccc(N(c4ccccc4)c4ccc5c6ccccc6n(-c6ccccc6)c5c4)cc3)c2)cc1]

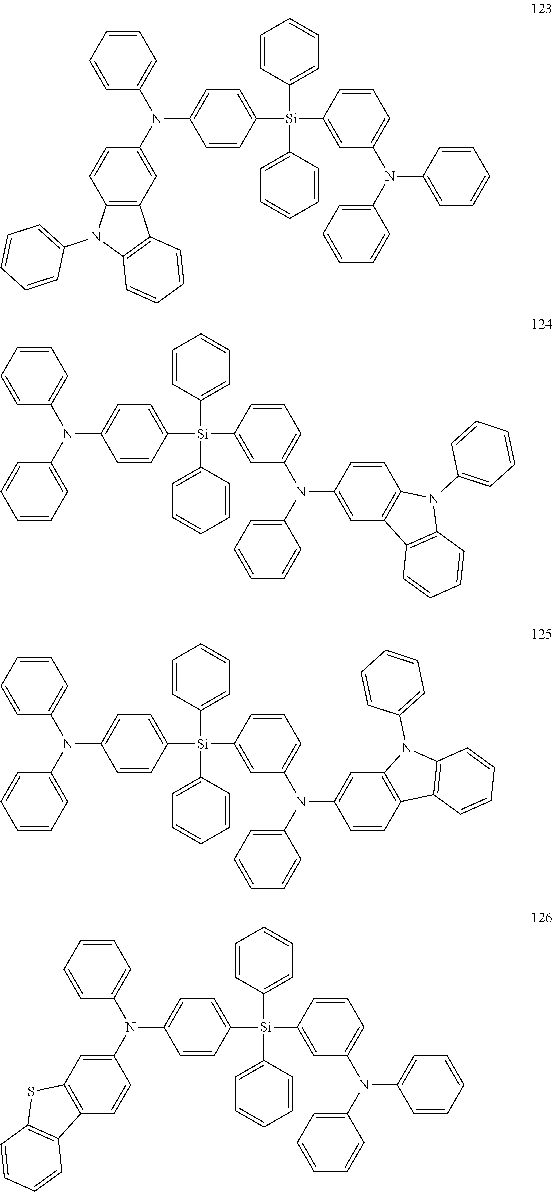

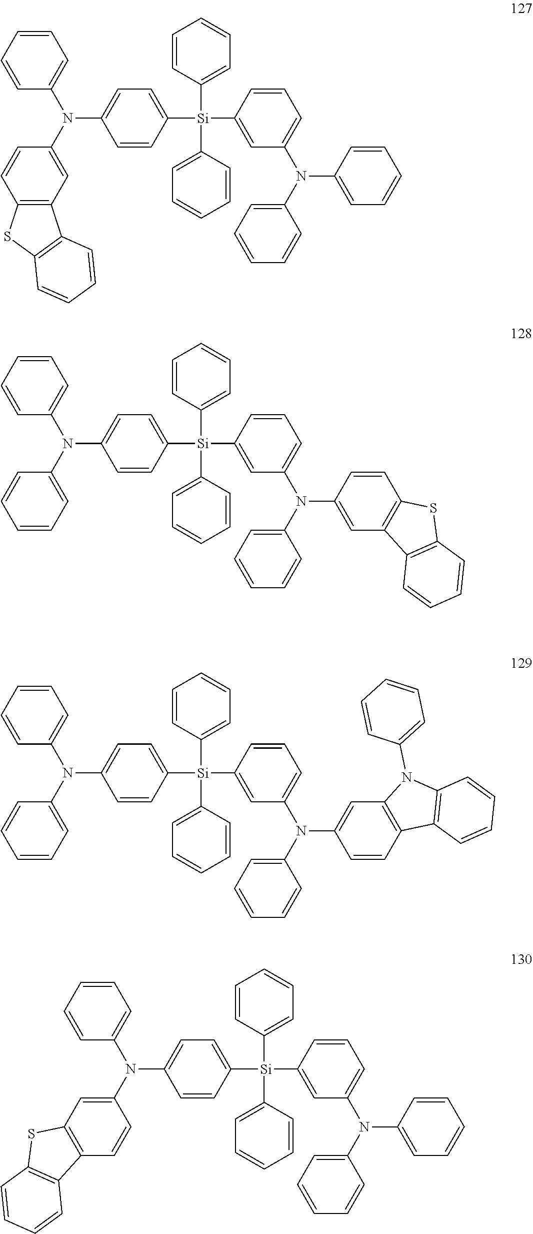 [SMILES: c1ccc(N(c2ccccc2)c2cccc([Si](c3ccccc3)(c3ccccc3)c3ccc(N(c4ccccc4)c4ccc5sc6ccccc6c5c4)cc3)c2)cc1 ; c1ccc(N(c2ccccc2)c2ccc([Si](c3ccccc3)(c3ccccc3)c3cccc(N(c4ccccc4)c4ccc5sc6ccccc6c5c4)c3)cc2)cc1 ; c1ccc(N(c2ccccc2)c2ccc([Si](c3ccccc3)(c3ccccc3)c3cccc(N(c4ccccc4)c4ccc5c6ccccc6n(-c6ccccc6)c5c4)c3)cc2)cc1 ; c1ccc(N(c2ccccc2)c2cccc([Si](c3ccccc3)(c3ccccc3)c3ccc(N(c4ccccc4)c4ccc5c(c4)sc4ccccc45)cc3)c2)cc1]

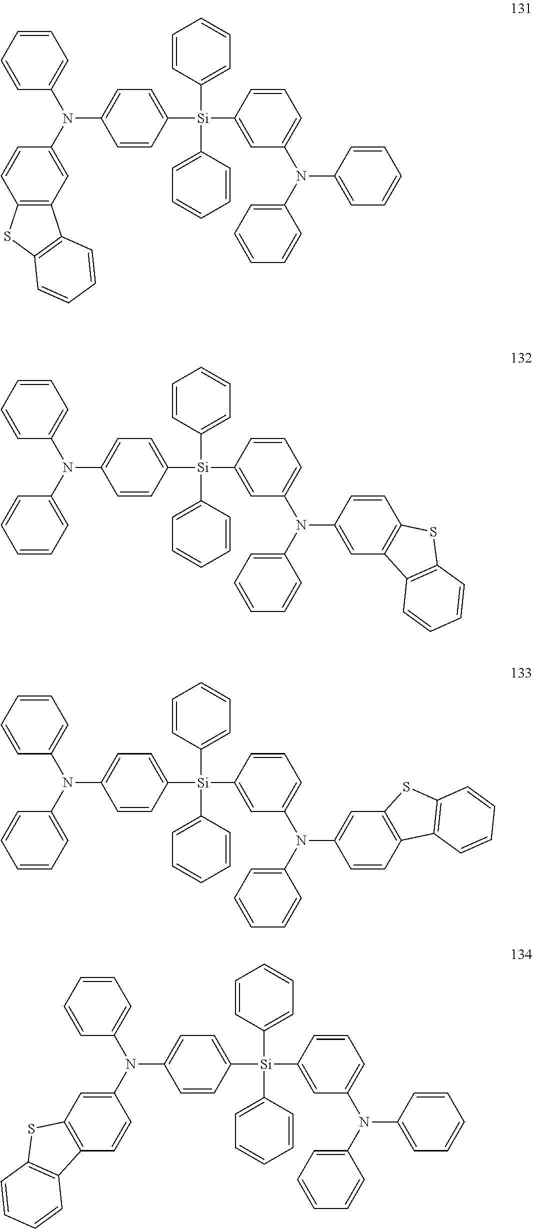

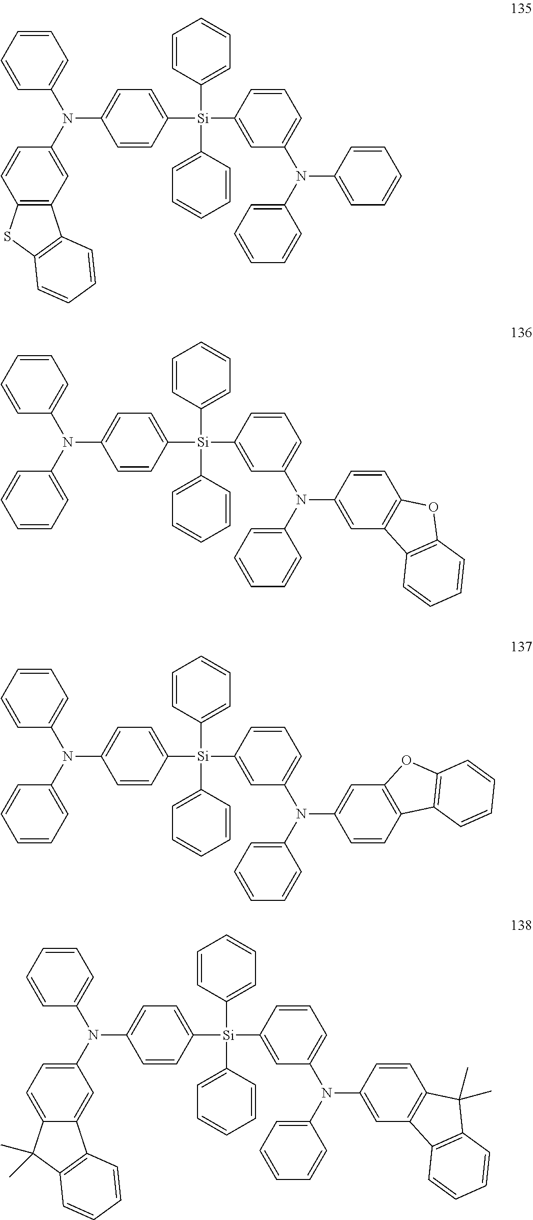

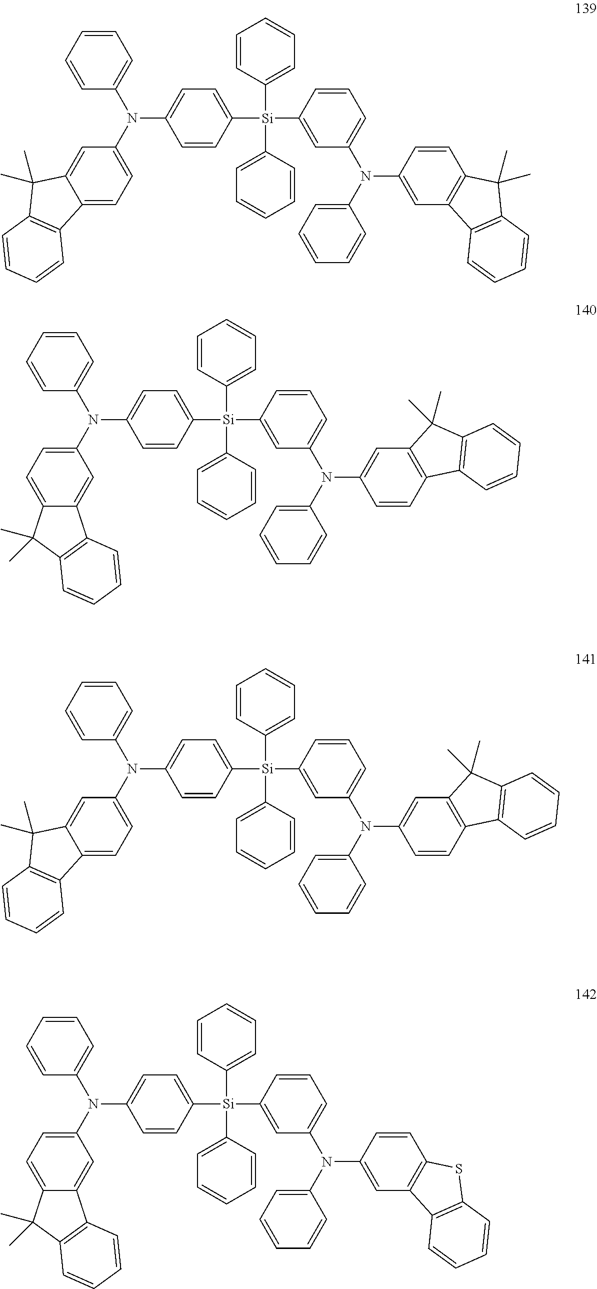

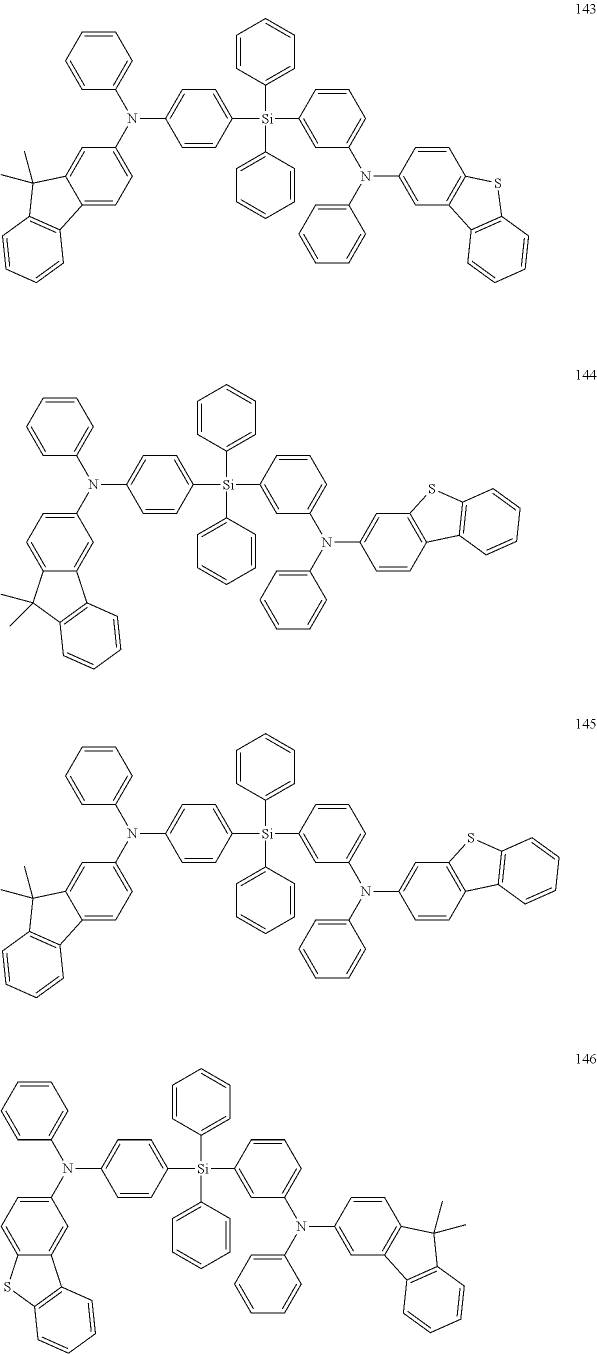 [SMILES: CC1(C)c2ccccc2-c2ccc(N(c3ccccc3)c3ccc([Si](c4ccccc4)(c4ccccc4)c4cccc(N(c5ccccc5)c5ccc6sc7ccccc7c6c5)c4)cc3)cc21 ; CC1(C)c2ccccc2-c2cc(N(c3ccccc3)c3ccc([Si](c4ccccc4)(c4ccccc4)c4cccc(N(c5ccccc5)c5ccc6c(c5)sc5ccccc56)c4)cc3)ccc21 ; CC1(C)c2ccccc2-c2ccc(N(c3ccccc3)c3ccc([Si](c4ccccc4)(c4ccccc4)c4cccc(N(c5ccccc5)c5ccc6c(c5)sc5ccccc56)c4)cc3)cc21 ; CC1(C)c2ccccc2-c2cc(N(c3ccccc3)c3cccc([Si](c4ccccc4)(c4ccccc4)c4ccc(N(c5ccccc5)c5ccc6sc7ccccc7c6c5)cc4)c3)ccc21]

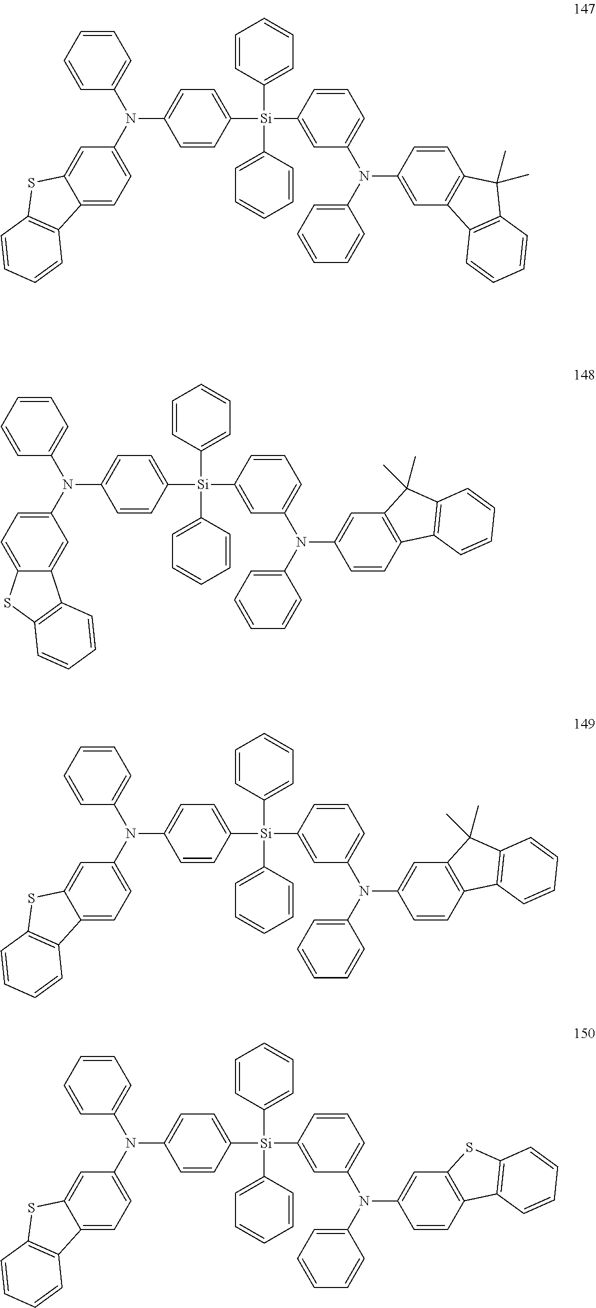 [SMILES: CC1(C)c2ccccc2-c2cc(N(c3ccccc3)c3cccc([Si](c4ccccc4)(c4ccccc4)c4ccc(N(c5ccccc5)c5ccc6c(c5)sc5ccccc56)cc4)c3)ccc21 ; CC1(C)c2ccccc2-c2ccc(N(c3ccccc3)c3cccc([Si](c4ccccc4)(c4ccccc4)c4ccc(N(c5ccccc5)c5ccc6sc7ccccc7c6c5)cc4)c3)cc21 ; CC1(C)c2ccccc2-c2ccc(N(c3ccccc3)c3cccc([Si](c4ccccc4)(c4ccccc4)c4ccc(N(c5ccccc5)c5ccc6c(c5)sc5ccccc56)cc4)c3)cc21 ; c1ccc(N(c2ccc([Si](c3ccccc3)(c3ccccc3)c3cccc(N(c4ccccc4)c4ccc5c(c4)sc4ccccc45)c3)cc2)c2ccc3c(c2)sc2ccccc23)cc1]

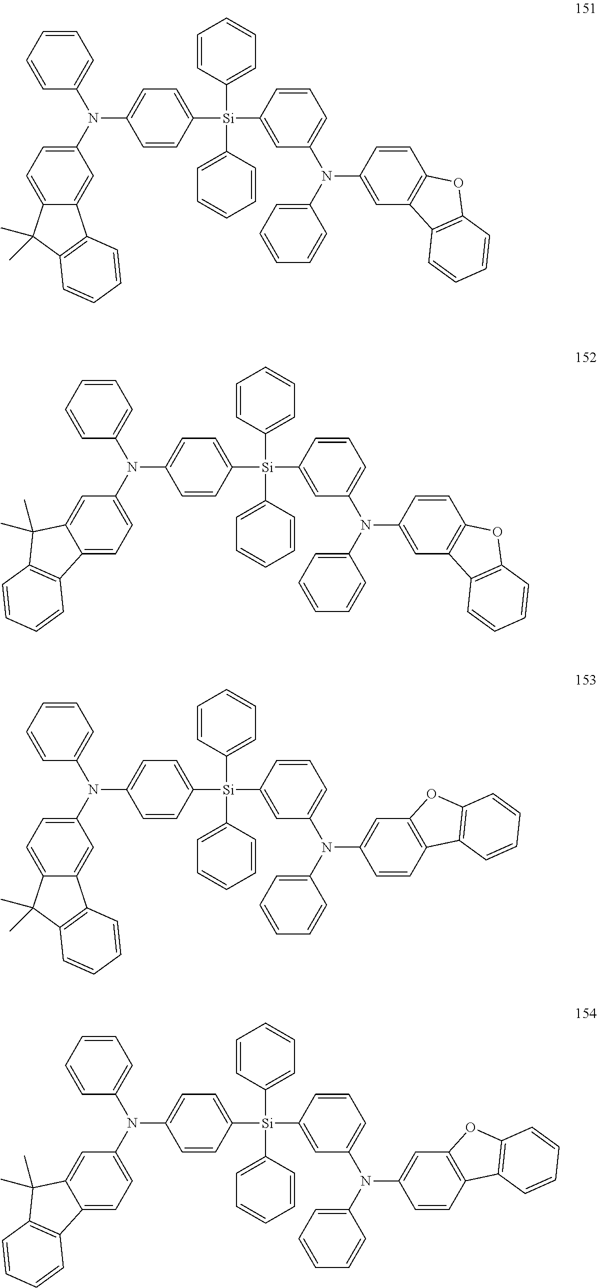 [SMILES: CC1(C)c2ccccc2-c2cc(N(c3ccccc3)c3ccc([Si](c4ccccc4)(c4ccccc4)c4cccc(N(c5ccccc5)c5ccc6oc7ccccc7c6c5)c4)cc3)ccc21 ; CC1(C)c2ccccc2-c2ccc(N(c3ccccc3)c3ccc([Si](c4ccccc4)(c4ccccc4)c4cccc(N(c5ccccc5)c5ccc6oc7ccccc7c6c5)c4)cc3)cc21 ; CC1(C)c2ccccc2-c2cc(N(c3ccccc3)c3ccc([Si](c4ccccc4)(c4ccccc4)c4cccc(N(c5ccccc5)c5ccc6c(c5)oc5ccccc56)c4)cc3)ccc21 ; CC1(C)c2ccccc2-c2ccc(N(c3ccccc3)c3ccc([Si](c4ccccc4)(c4ccccc4)c4cccc(N(c5ccccc5)c5ccc6c(c5)oc5ccccc56)c4)cc3)cc21]

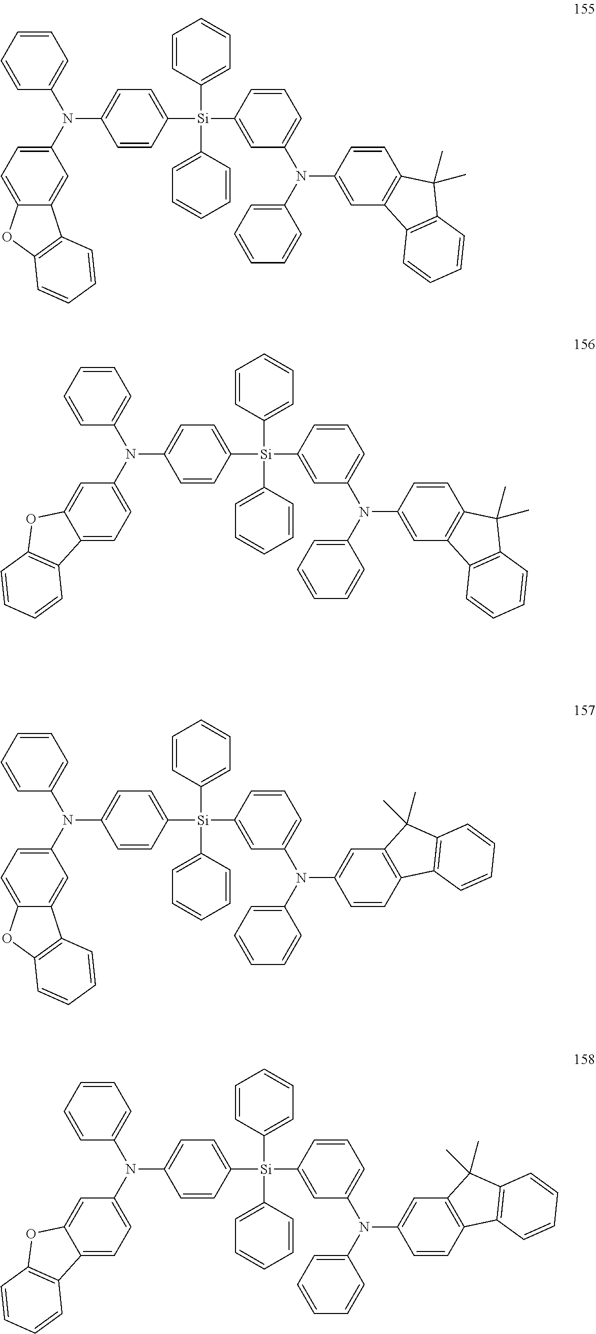 [SMILES: CC1(C)c2ccccc2-c2cc(N(c3ccccc3)c3cccc([Si](c4ccccc4)(c4ccccc4)c4ccc(N(c5ccccc5)c5ccc6oc7ccccc7c6c5)cc4)c3)ccc21 ; CC1(C)c2ccccc2-c2cc(N(c3ccccc3)c3cccc([Si](c4ccccc4)(c4ccccc4)c4ccc(N(c5ccccc5)c5ccc6c(c5)oc5ccccc56)cc4)c3)ccc21 ; CC1(C)c2ccccc2-c2ccc(N(c3ccccc3)c3cccc([Si](c4ccccc4)(c4ccccc4)c4ccc(N(c5ccccc5)c5ccc6oc7ccccc7c6c5)cc4)c3)cc21 ; CC1(C)c2ccccc2-c2ccc(N(c3ccccc3)c3cccc([Si](c4ccccc4)(c4ccccc4)c4ccc(N(c5ccccc5)c5ccc6c(c5)oc5ccccc56)cc4)c3)cc21]

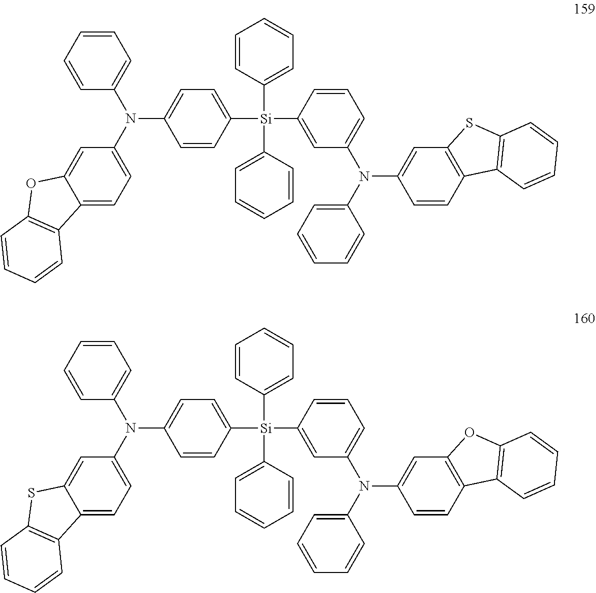 [SMILES: c1ccc(N(c2ccc([Si](c3ccccc3)(c3ccccc3)c3cccc(N(c4ccccc4)c4ccc5c(c4)sc4ccccc45)c3)cc2)c2ccc3c(c2)oc2ccccc23)cc1 ; c1ccc(N(c2cccc([Si](c3ccccc3)(c3ccccc3)c3ccc(N(c4ccccc4)c4ccc5c(c4)sc4ccccc45)cc3)c2)c2ccc3c(c2)oc2ccccc23)cc1]

For the amine compound of an embodiment, four phenyl groups may be bonded to the silicon atom, and amine groups may be bonded to two phenyl groups spaced apart from each other (separated from one another) with interposing one phenyl group among the four phenyl groups therebetween. The amine group bonded to any one phenyl group among the two phenyl groups may be in the meta-position relation with the silicon atom. The amine group bonded to the other phenyl group among the two phenyl groups may be in the meta-, para-, or ortho-position relation with the silicon atom.

The amine compound of an embodiment may contain two amine groups indirectly bonded to the silicon atom, and thus hole transport properties may be improved and a band gap may be expanded. The amine compound containing two amine groups indirectly bonded to the silicon atom may have a different substituent of the amine group in the two amine groups, thereby changing a highest occupied molecular orbital (HOMO) energy level, and the refractive index of the molecule. Accordingly, the light emitting element ED including the amine compound in the hole transport region HTR may exhibit characteristics in which the exciton generation efficiency and luminous efficiency are improved.

The amine compound of an embodiment may include, as a central structure, the silicon atom to which two amine groups are bonded, thereby exhibiting a low refractive characteristic. For example, the amine compound may have a refractive index of about 1.6 to about 1.7. Accordingly, the light emitting element ED including the amine compound may be manufactured to have a desired or suitable refractive index, thereby exhibiting an improved (increased) luminous efficiency characteristic.

The amine compound containing two amine groups indirectly bonded to the silicon atom may have a large (high) molecular weight, thereby exhibiting a high glass transition temperature characteristic. The amine compound of an embodiment may include an amine group at the meta-position to the silicon atom, and thus a steric hindrance may be increased and the intermolecular interaction may be minimized or reduced. The amine compound containing an amine group at the meta-position to the silicon atom may have a high triplet energy level, thereby exhibiting an excellent or suitable electron blocking characteristic.

The amine compound of an embodiment may contribute to improving the service life of the light emitting element ED, improving the brightness and efficiency, and reducing the driving voltage. The light emitting element ED of an embodiment may include the amine compound in the hole transport region HTR, thereby exhibiting a long service life characteristic. In some embodiments, the light emitting element ED including the amine compound may exhibit characteristics in which the driving voltage is reduced, and the brightness and efficiency are improved.

Referring to FIGS. 3A to 3B, the first electrode EL1 has conductivity (e.g., is a conductor). The first electrode EL1 may be formed of a metal material, a metal alloy, and/or a conductive compound. The first electrode EL1 may be an anode or a cathode. However, the embodiment of the present disclosure is not limited thereto. In some embodiments, the first electrode EL1 may be a pixel electrode. The first electrode EU may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, Zn, compound comprising one or more of the foregoing elements, combinations of two or more of the foregoing elements or compounds, a mixture of the foregoing elements or compounds, and/or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, and/or a compound or mixture thereof (e.g., a mixture of Ag and Mg). In some embodiments, the first electrode EU may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiment of the present disclosure is not limited thereto. The embodiments, of the present disclosure are not limited thereto, and the first electrode EL1 may include the above-described metal material(s), combination(s) of at least two metal materials of the above-described metal materials, oxide(s) of the above-described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method. The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

At least one of the hole injection layer HIL, the hole transport layer HTL, or the electron blocking layer EBL may include the amine compound of an embodiment. For example, at least one of the hole injection HTL or the electron blocking layer EBL may include the amine compound of an embodiment.

The hole transport region HTR may further include compounds which will be described below. The hole transport region HTR may include a compound represented by Formula H-1:

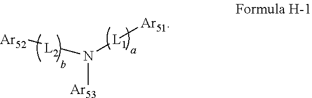

In Formula H-1 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. When a or b is an integer of 2 or greater, a plurality of L₁s and L₂s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₅₁ and Ar₅₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₅₃ may be a substituted or unsubstituted aryl group having 6 to 30 ring-forming carbon atoms.

The compound represented by Formula H-1 may be a monoamine compound. In some embodiments, the compound represented by Formula H-1 may be a diamine compound in which at least one among Ar₅₁ to Ar₅₃ includes the amine group as a substituent. In some embodiments, the compound represented by Formula H-1 may be a carbazole-based compound containing a substituted or unsubstituted carbazole group in at least one of Ar₅₁ or Ar₅₂, or a fluorene-based compound containing a substituted or unsubstituted fluorene group in at least one of Ar₅₁ or Ar₅₂.

The compound represented by Formula H-1 may be represented by any one among the compounds of Compound Group H. However, the compounds listed in Compound Group H are examples, and the compounds represented by Formula H-1 are not limited to those represented by Compound Group H:

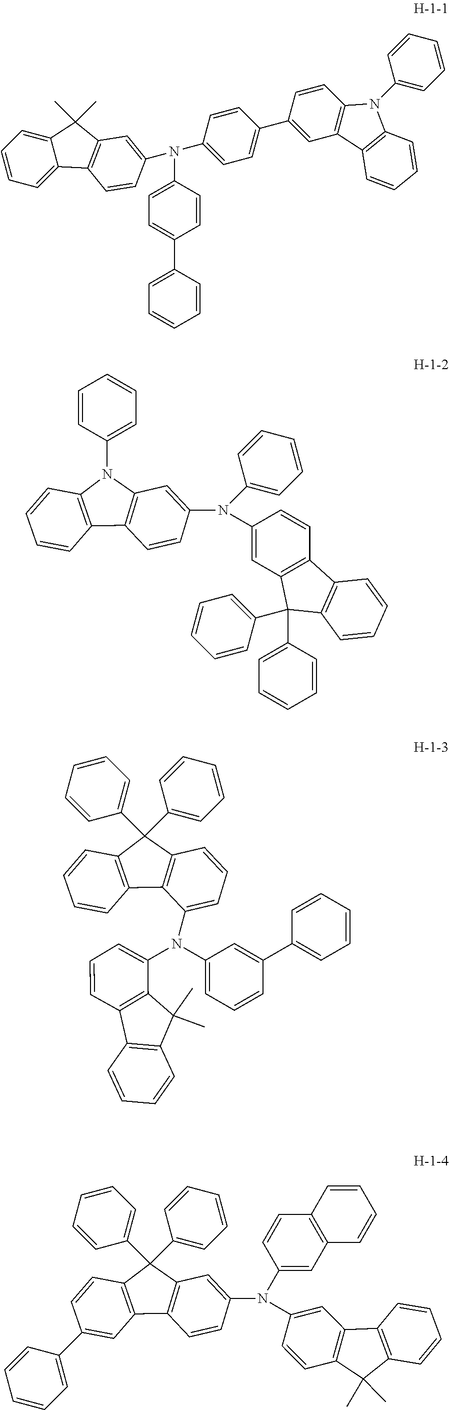 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

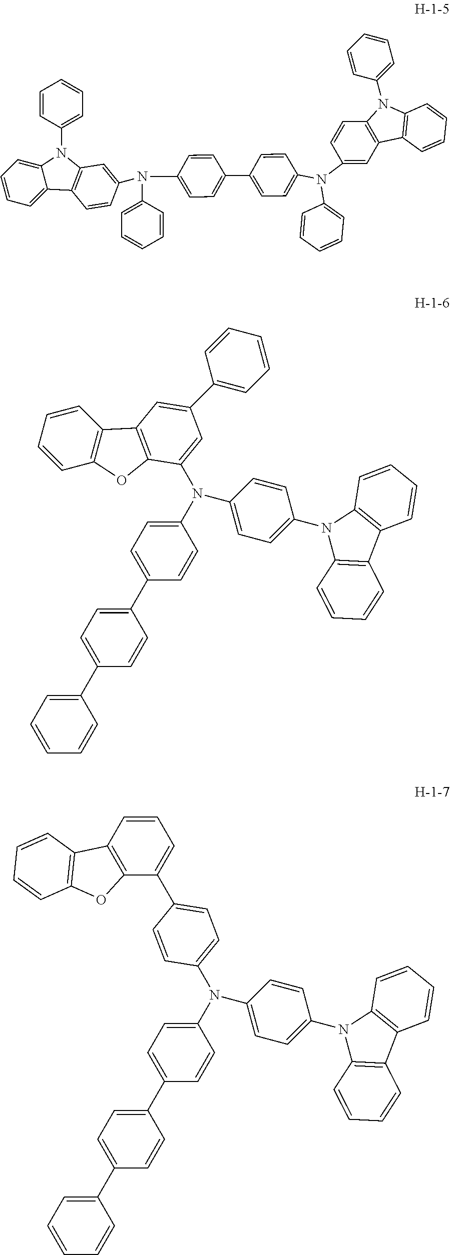 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

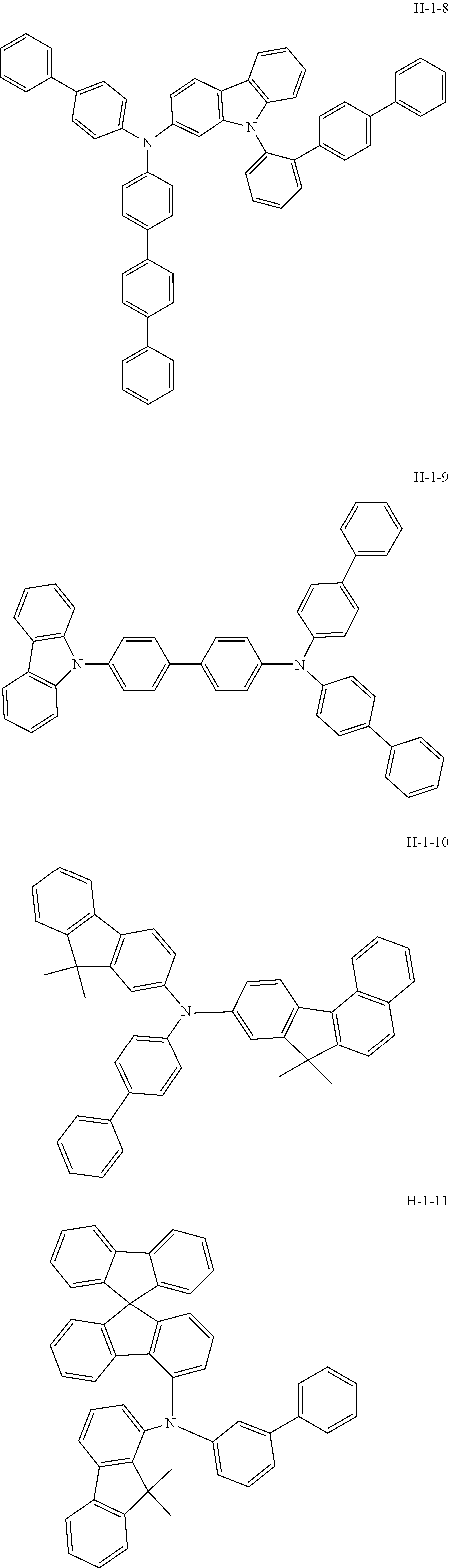

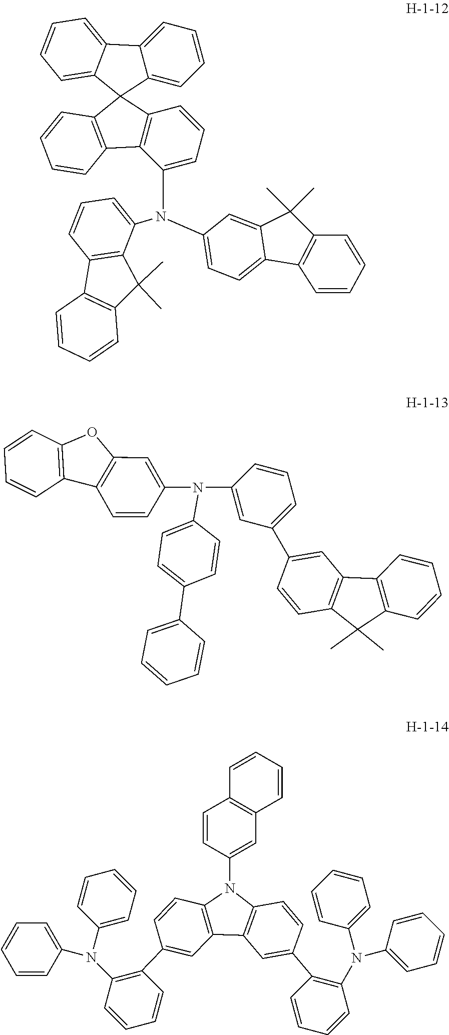

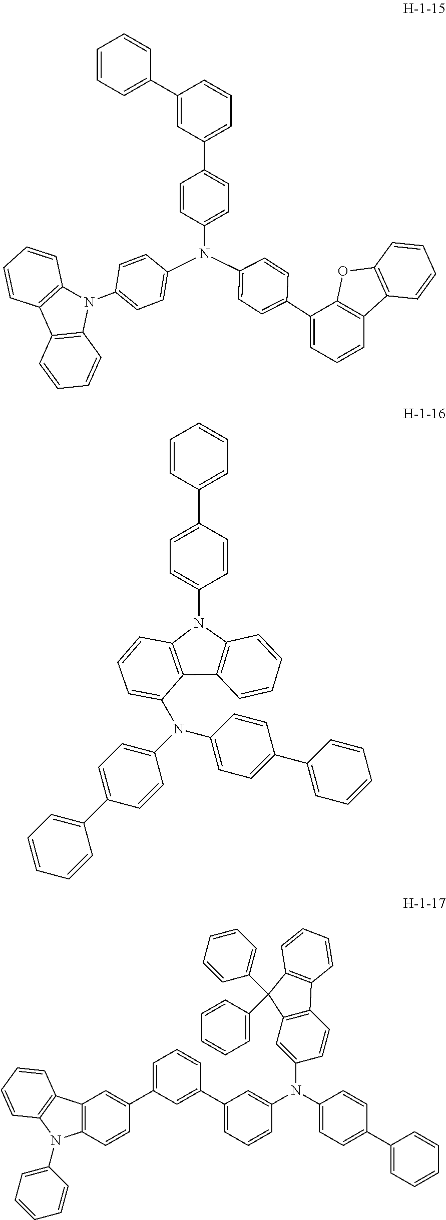 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

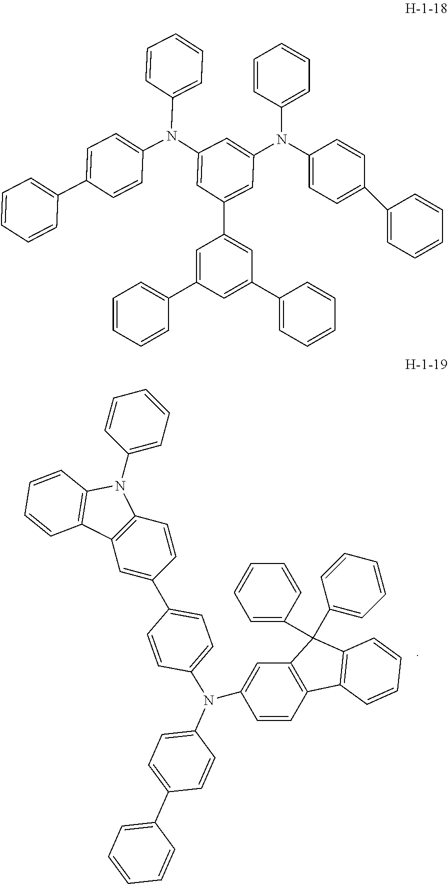

The hole transport region HTR may further include a phthalocyanine compound such as copper phthalocyanine;

N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-Tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

In some embodiments, the hole transport region HTR may include carbazole derivatives such as N-phenyl carbazole and/or polyvinyl carbazole, fluorene derivatives, N,N′-bis(3-methylphenyl)-N,N′-diphenyl-[1,1-biphenyl]-4,4′-diamine (TPD), triphenylamine derivatives such as 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP), etc. The hole transport region HTR may include the above-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 30 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the above-described ranges, satisfactory (suitable) hole transport properties may be achieved without a substantial increase in a driving voltage.

The hole transport region HTR may further include a charge generating material to increase conductivity in addition to the above-described materials. The charge generating material may be dispersed substantially uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as CuI and RbI, a quinone derivative such as tetracyanoquinodimethane (TCNQ) and 2,3,5,6-tetrafluoro-7,7′8,8-tetracyanoquinodimethane (F4-TCNQ), a metal oxide such as tungsten oxide and molybdenum oxide, a cyano group-containing compound such as dipyrazino[2,3-f: 2′,3′-h] quinoxaline-2,3,6,7,10,11-hexacarbonitrile (HATCN), 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the embodiment of the present disclosure is not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be contained in the hole transport region HTR may be utilized as a material to be contained in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In the light emitting element ED of an embodiment, the emission layer EML may include an anthracene derivative, a pyrene derivative, a fluoranthene derivative, a chrysene derivative, a dehydrobenzanthracene derivative, or a triphenylene derivative. For example, the emission layer EML may include the anthracene derivative or the pyrene derivative.

In each light emitting element ED of embodiments illustrated in FIGS. 3 to 6, the emission layer EML may include a host and a dopant, and the emission layer EML may include a compound represented by Formula E-1. The compound represented by Formula E-1 may be utilized as a fluorescent host material.

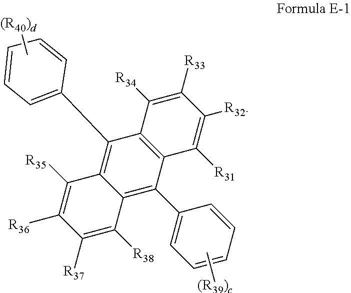

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one among Compound E1 to Compound E19:

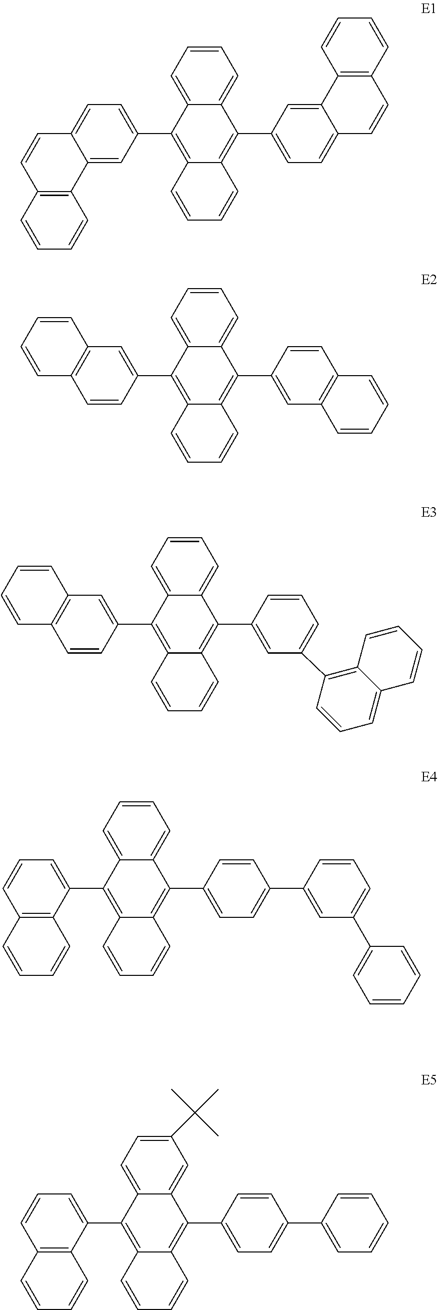

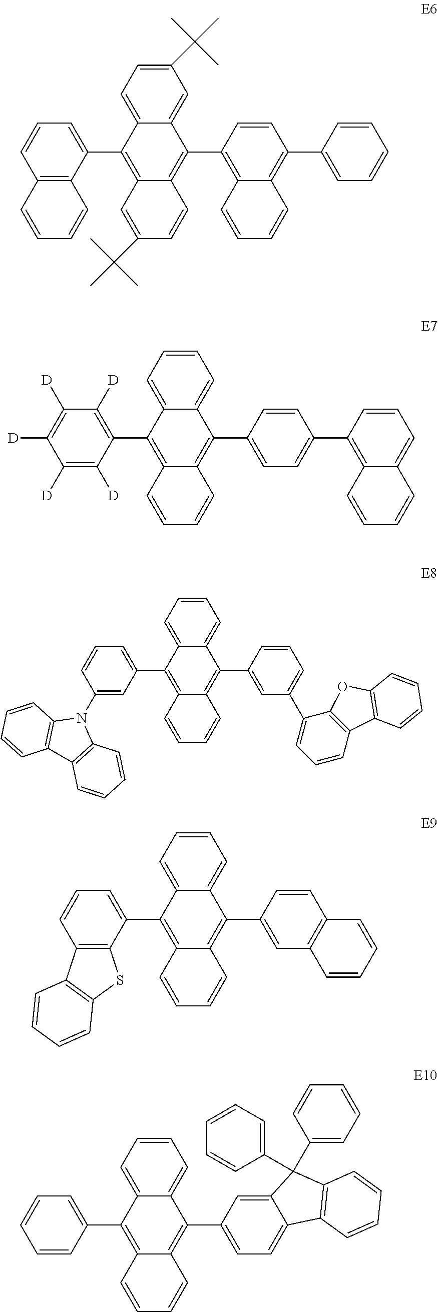

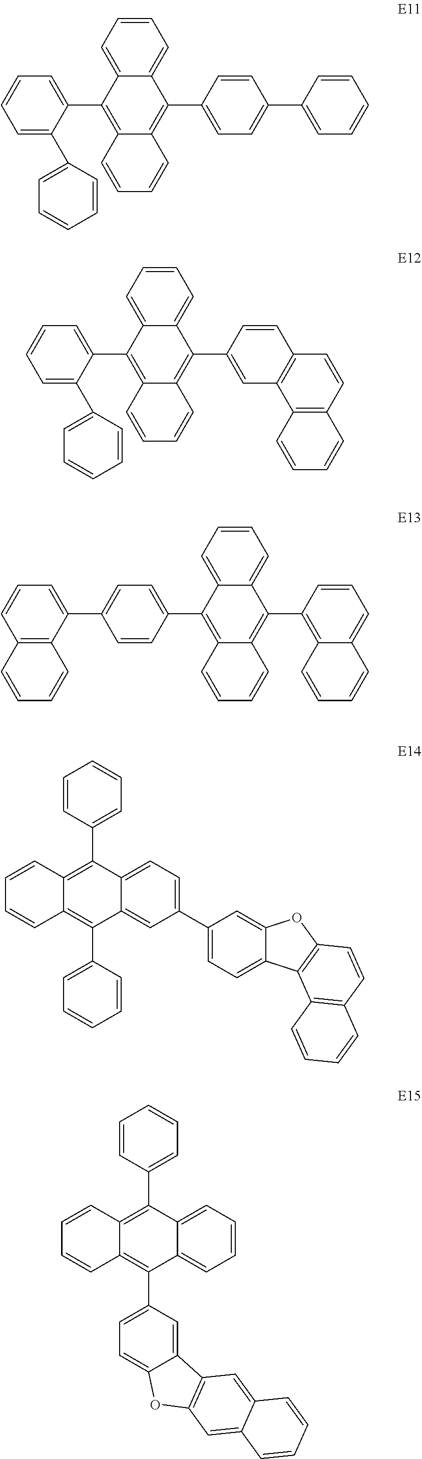

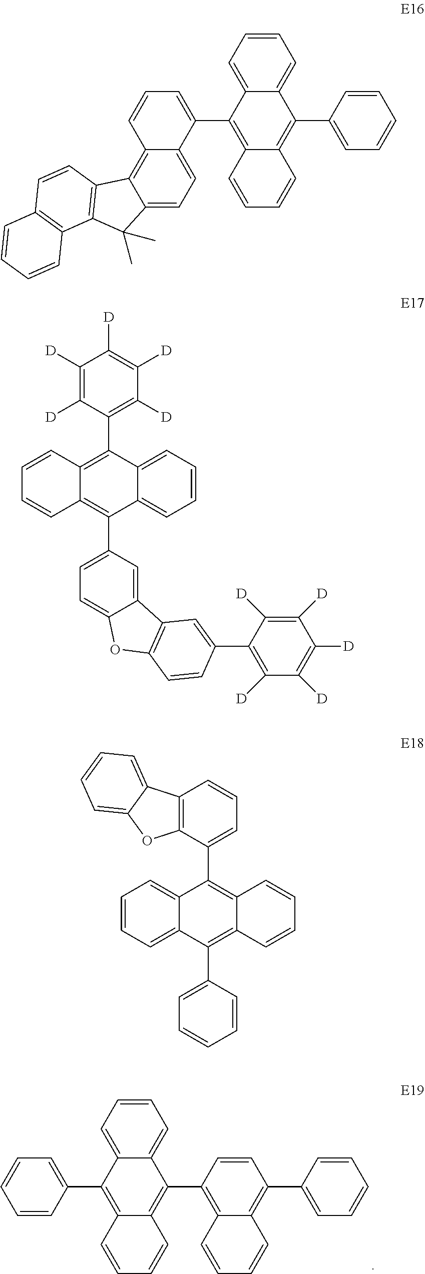

In an embodiment, the emission layer EML may include a compound represented by Formula E-2a or Formula E-2b. The compound represented by Formula E-2a or Formula E-2b may be utilized as a phosphorescent host material.

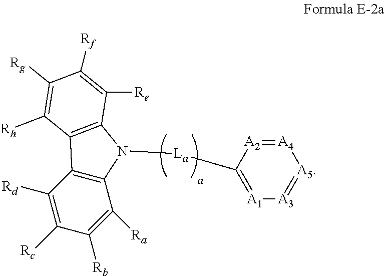

In Formula E-2a, a may be an integer of 0 to 10, Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is an integer of 2 or more, a plurality of Lₐ's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, etc. as a ring-forming atom.

In Formula E-2a, two or three selected from among A₁ to A₅ may be N, and the rest may be CRᵢ.

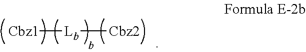

In Formula E-2b, Cbz1 and Cbz2 may each independently be an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. b is an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among the compounds of Compound Group E-2. However, the compounds listed in Compound Group E-2 are examples, and the compound represented by Formula E-2a or Formula E-2b is not limited to those represented in Compound Group E-2.

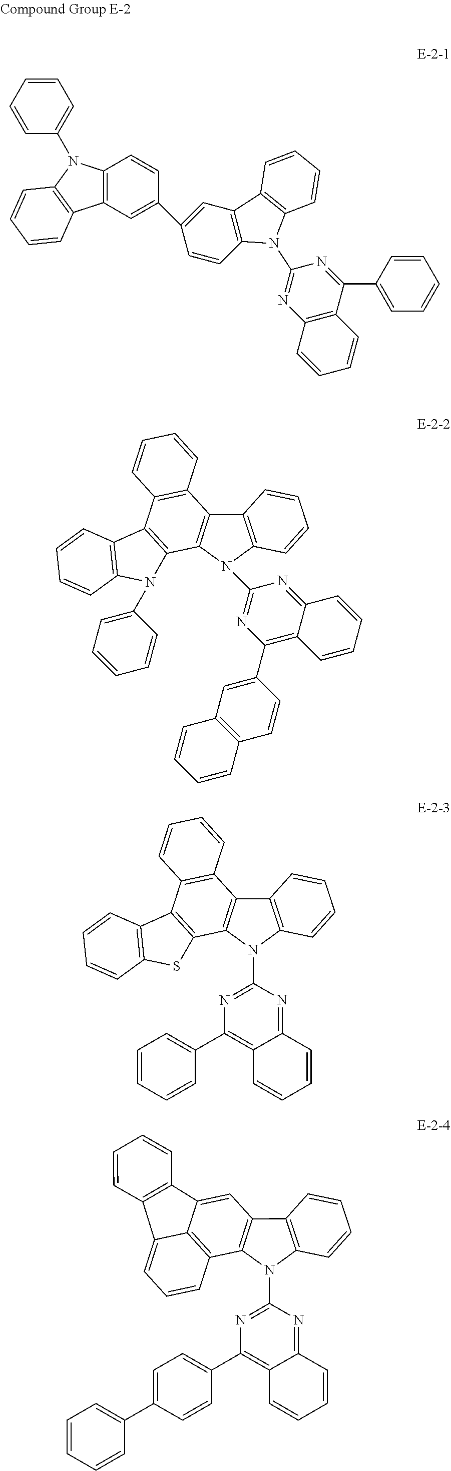

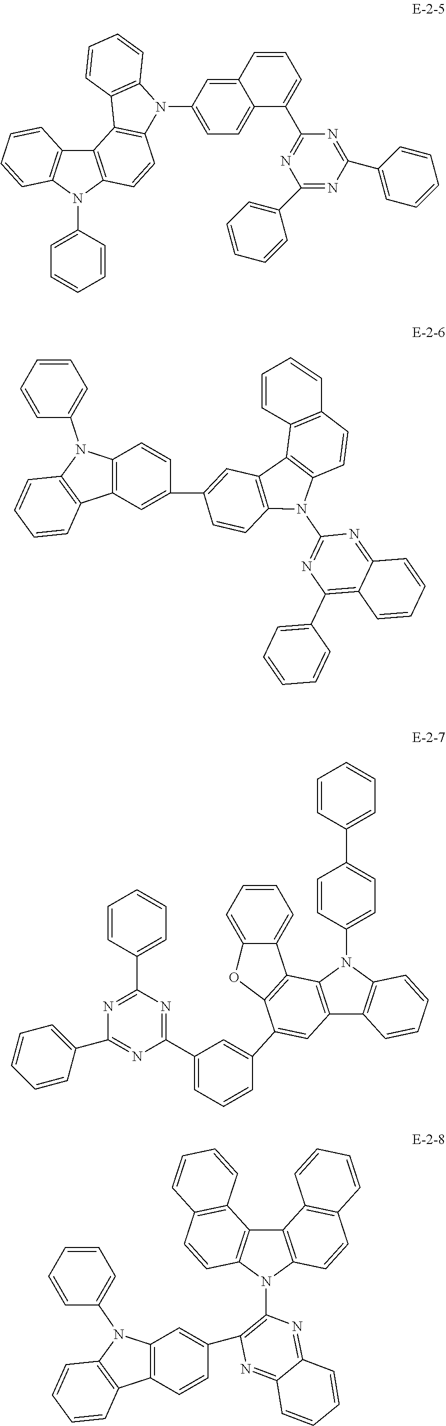

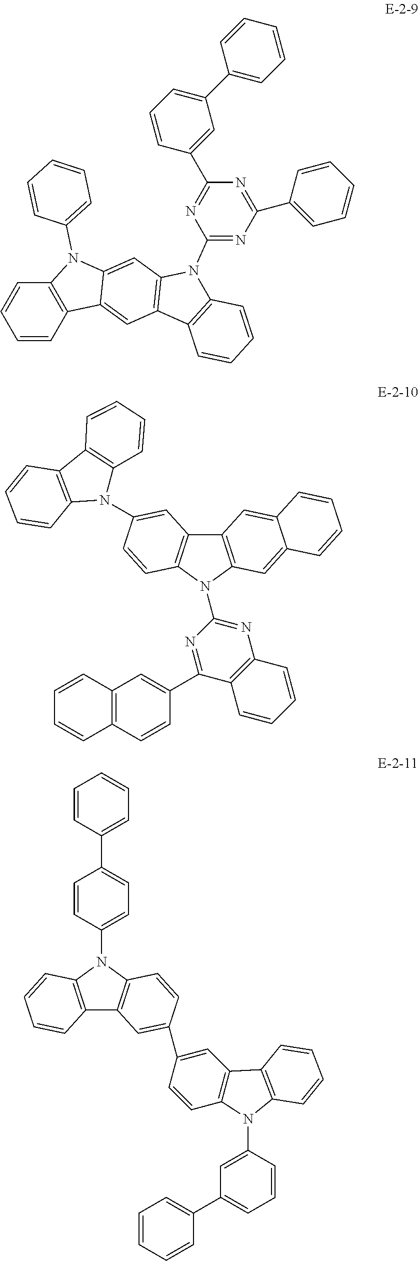

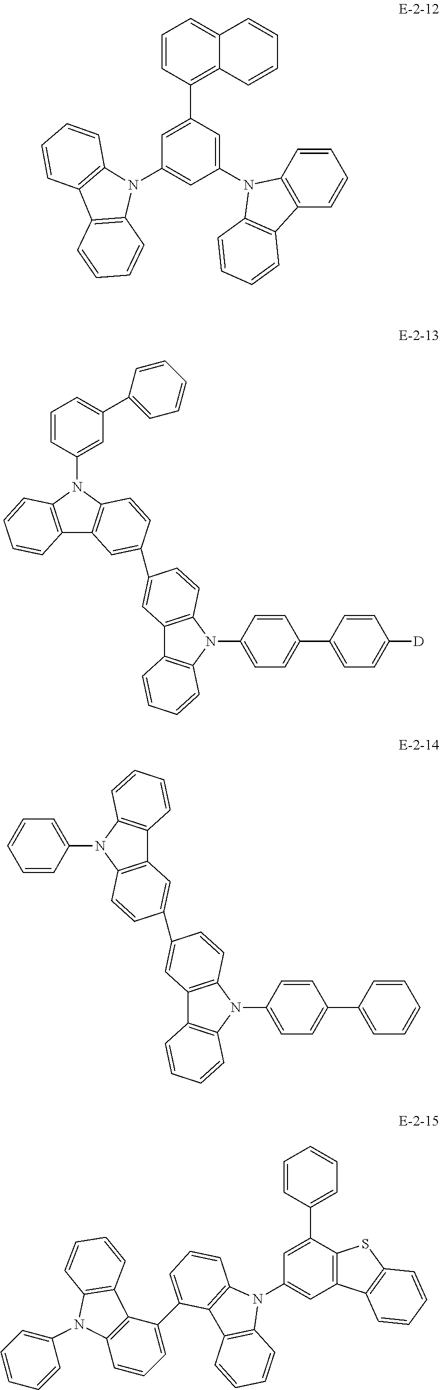 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

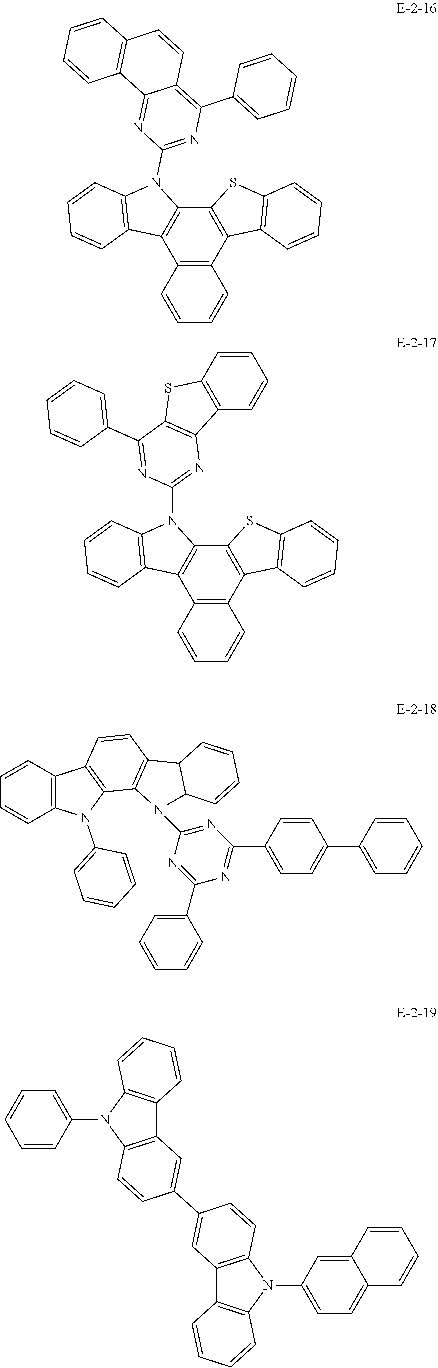

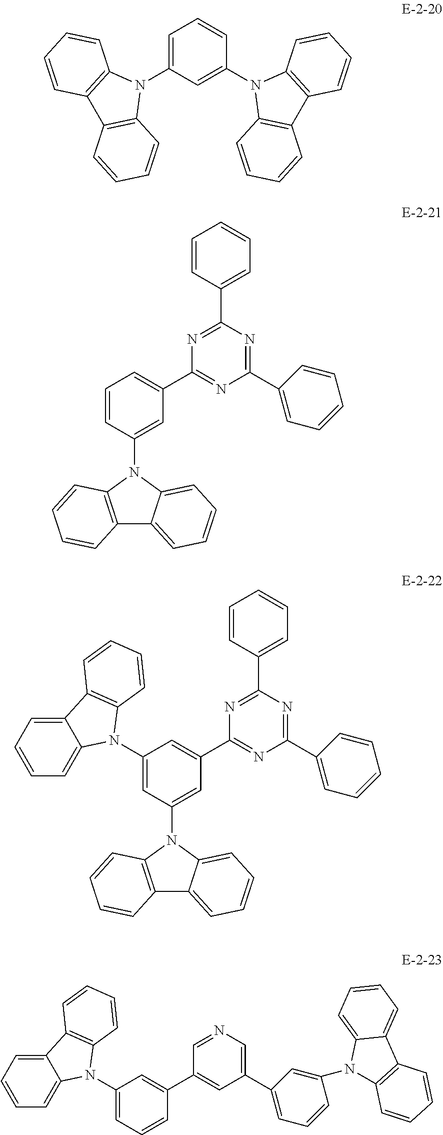 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

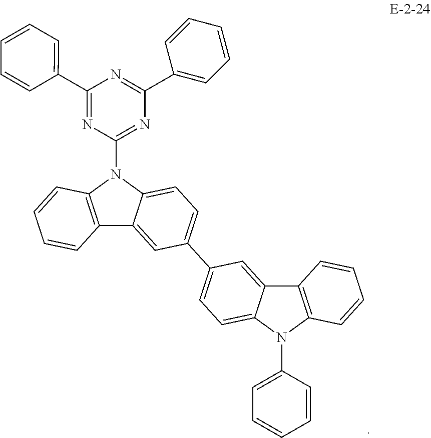 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the present disclosure is not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as a host material.

The emission layer EML may include a compound represented by Formula M-a or Formula M-b. The compound represented by Formula M-a or Formula M-b may be utilized as a phosphorescence dopant material.

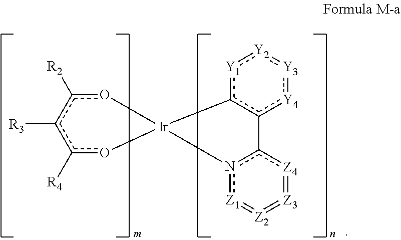

In Formula M-a above, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant. The compound represented by Formula M-a may be represented by any one among Compound M-a1 to Compound M-a25. However, Compounds M-a1 to M-a25 are example, and the compound represented by Formula M-a is not limited to those represented by Compounds M-a1 to M-a25.

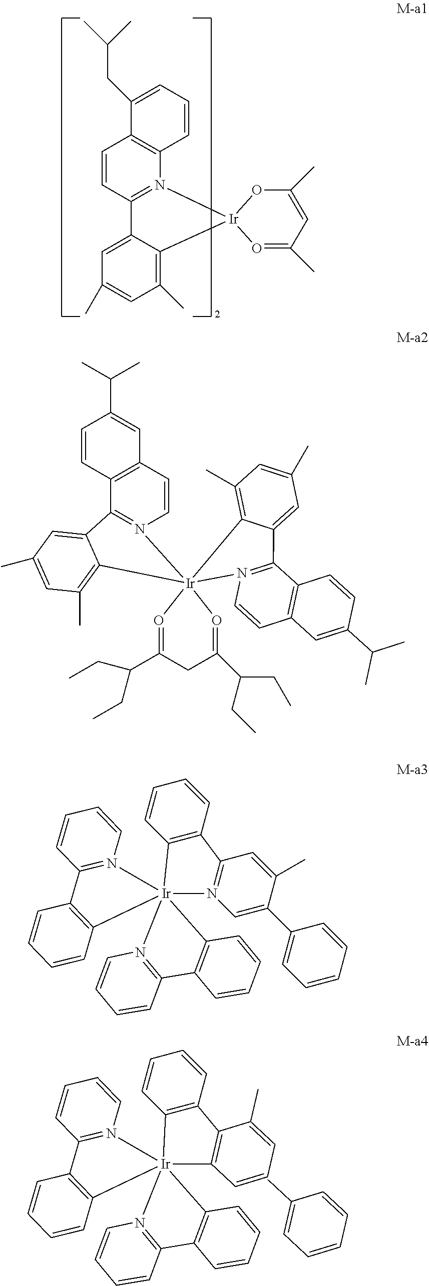

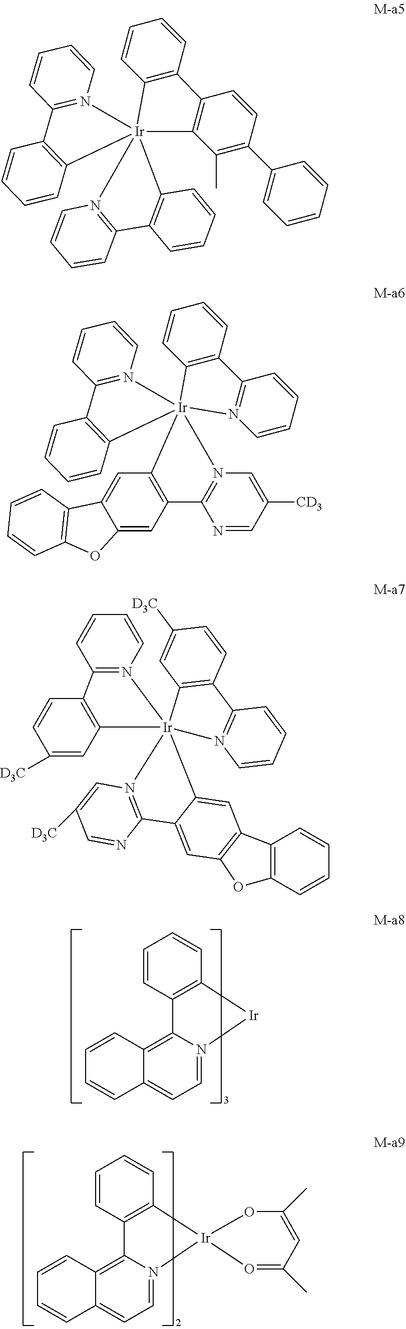

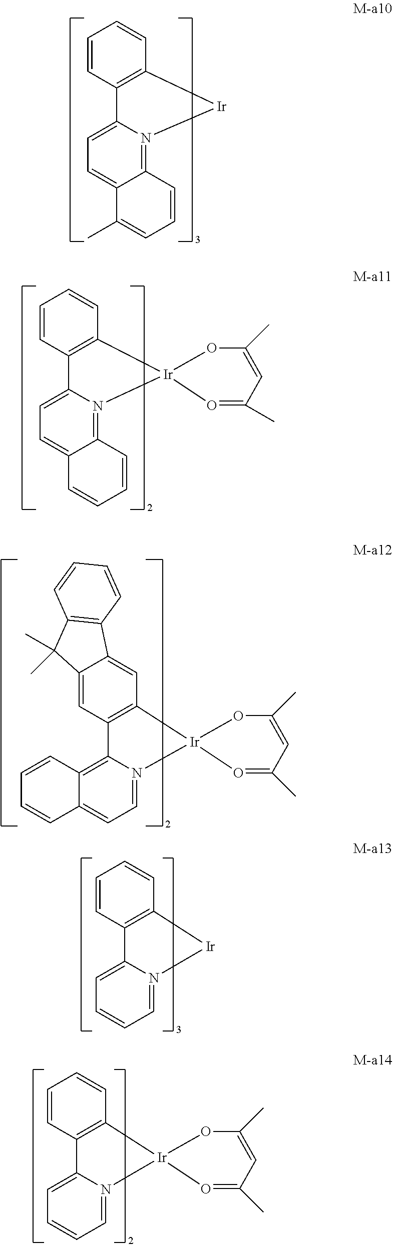

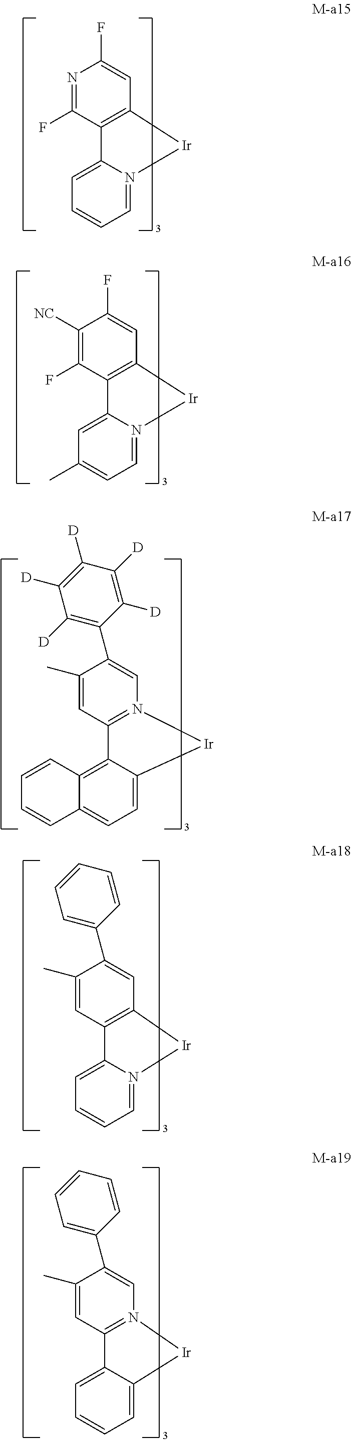

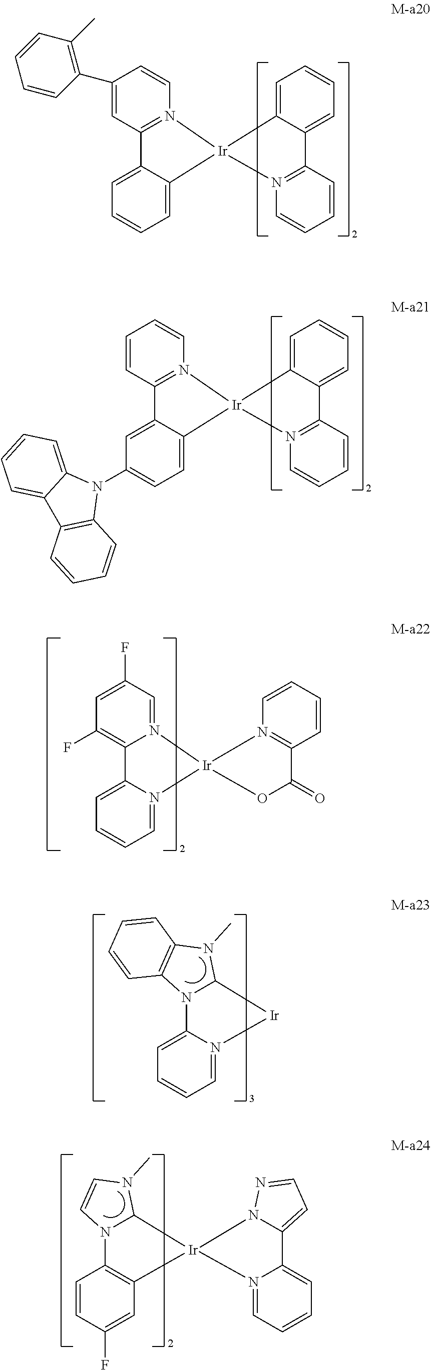

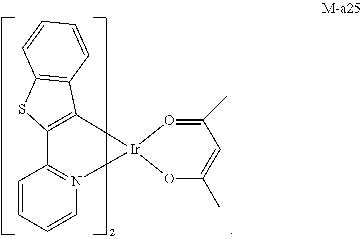

Formula M-a1 and Formula M-a2 may be utilized as a red dopant material. Formula M-a3 to Formula M-a7 may be utilized as a green dopant material.

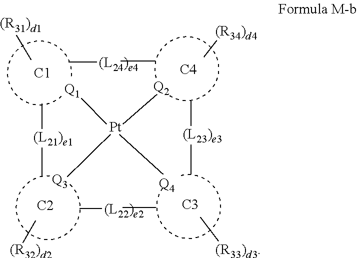

In Formula M-b, Q₁ to Q₄ may each independently be C or N, and C1 to C4 may each independently be a substituted or unsubstituted hydrocarbon ring having 5 to 30 ring-forming carbon atoms, or a substituted or unsubstituted heterocycle having 2 to 30 ring-forming carbon atoms. L₂₁ to L₂₄ may each independently be a direct linkage,

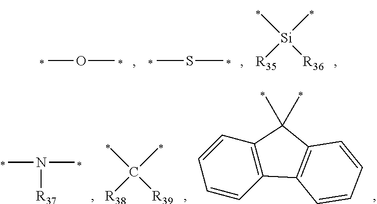

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and el to e4 may each independently be 0 or 1. R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring, and d1 to d4 may each independently be an integer of 0 to 4.

The compound represented by Formula M-b may be utilized as a blue phosphorescence dopant or a green phosphorescence dopant. The compound represented by Formula M-b may be represented by any one among the compounds below. However, the compounds below are examples, and the compound represented by Formula M-b is not limited to those represented by the compounds below.

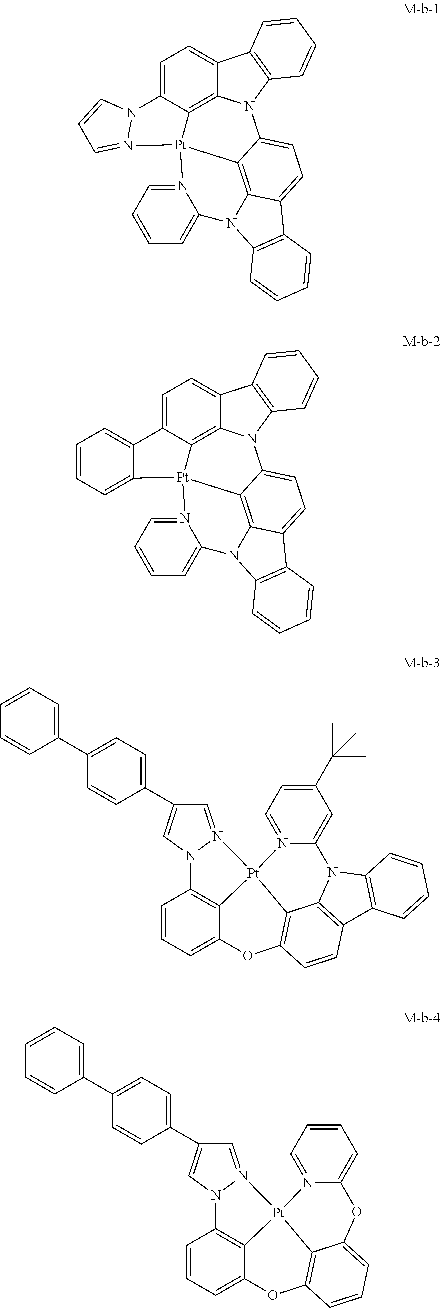

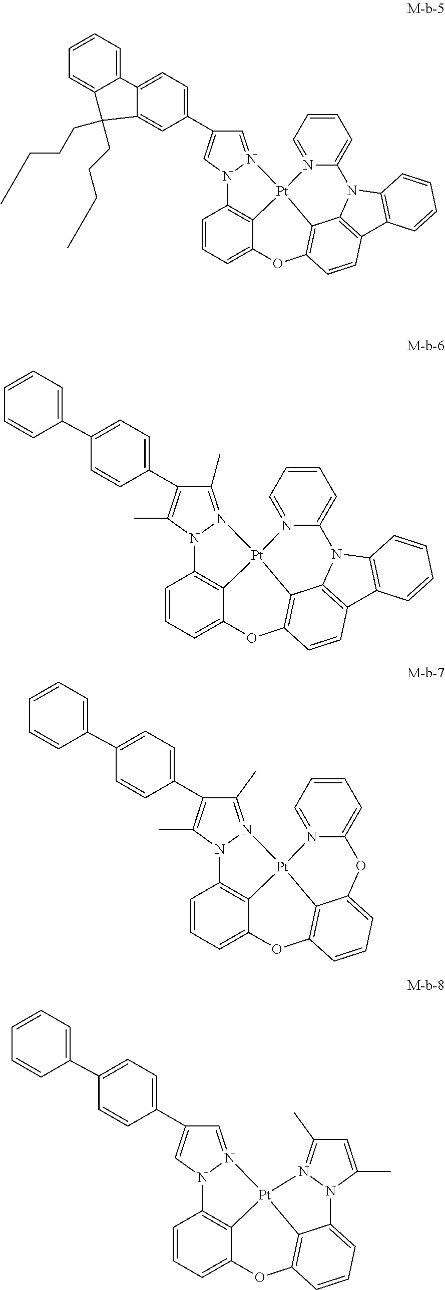

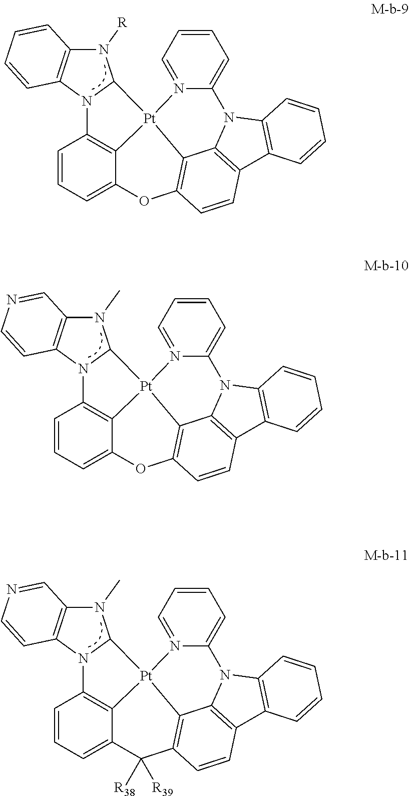

In the compounds, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may include a compound represented by any one among Formula F-a to Formula F-c. The compound represented by Formula F-a or Formula F-c may be utilized as a fluorescence dopant material.

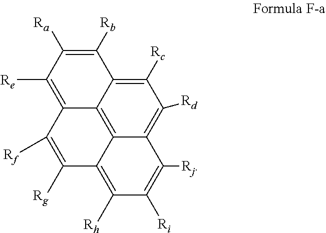

In Formula F-a above, two selected from among Rₐ to Rⱼ may each independently be substituted with

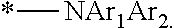

The substituents, which are not substituted with

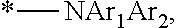

among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In

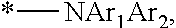

Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

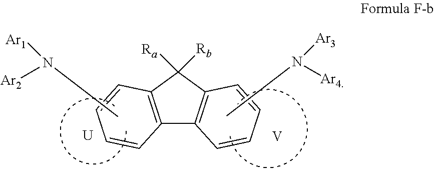

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

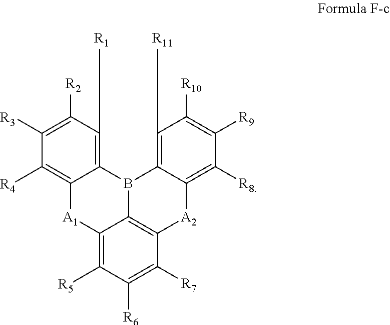

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring.

In Formula F-c, A₁ and A₂ may each independently be bonded to substituents of an adjacent ring to form a condensed ring. For example, when A₁ and A₂ may each independently be NRₘ, A₁ may be bonded to R₄ or R₅ to form a ring. In some embodiments, A₂ may be bonded to R₇ or R₈ to form a ring.

In an embodiment, the emission layer EML may include, as a suitable dopant material, styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl(DPAVBi), perylene and the derivatives thereof (e.g., 2,5,8,11-tetra-t-butylperylene (TBP)), pyrene and the derivatives thereof (e.g., 1,1-dipyrene, 1,4-dipyrenylbenzene, 1,4-bis(N,N-diphenylamino)pyrene), etc.

The emission layer EML may include a suitable phosphorescent dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be utilized as a phosphorescent dopant. For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), or platinum octaethyl porphyrin (PtOEP) may be utilized as a phosphorescence dopant. However, the embodiment of the present disclosure is not limited thereto.

The emission layer EML may include a quantum dot material. The core of the quantum dot may be selected from among a Group II-VI compound, a Group III-VI compound, a Group compound, a Group III-V compound, a Group III-II-V compound, a Group IV-VI compound, a Group IV element, a Group IV compound, and one or more combinations thereof.

The Group II-VI compound may be selected from the group including (e.g., consisting of) a binary compound selected from the group including (e.g., consisting of) CdSe, CdTe, CdS, ZnS, ZnSe, ZnTe, ZnO, HgS, HgSe, HgTe, MgSe, MgS, and one or more mixtures thereof, a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more mixtures thereof, and a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and one or more mixtures thereof.

The Group III-VI compound may include a binary compound such as In₂S₃ and/or In₂Se₃, a ternary compound such as InGaS₃ and/or InGaSe₃, or one or more combinations thereof.

The Group compound may a ternary compound selected from the group including (e.g., consisting of) AgInS, AgInS₂, CuInS, CuInS₂, AgGaS₂, CuGaS₂ CuGaO₂, AgGaO₂, AgAlO₂, and one or more mixtures thereof, or a quaternary compound such as AgInGaS₂ and/or CuInGaS₂.

The Group III-V compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and one or more mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and one or more mixtures thereof, and a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and one or more mixtures thereof. The Group III-V compound may further include a Group II metal. For example, InZnP, etc. may be selected as a Group III-II-V compound.

The Group IV-VI compound may be selected from the group including (e.g., consisting of) a binary compound selected from the group including (e.g., consisting of) SnS, SnSe, SnTe, PbS, PbSe, PbTe, and one or more mixtures thereof, a ternary compound selected from the group including (e.g., consisting of) SnSeS, SnSeTe, SnSTe, PbSeS, PbSeTe, PbSTe, SnPbS, SnPbSe, SnPbTe, and one or more mixtures thereof, and a quaternary compound selected from the group including (e.g., consisting of) SnPbSSe, SnPbSeTe, SnPbSTe, and one or more mixtures thereof. The Group IV element may be selected from the group including (e.g., consisting of) Si, Ge, and one or more mixtures thereof. The Group IV compound may be a binary compound selected from the group including (e.g., consisting of) SiC, SiGe, and one or more mixtures thereof.

In this embodiment, a binary compound, a ternary compound, or a quaternary compound may be present in particles in a substantially uniform concentration distribution, or may be present in substantially the same particle in a partially different concentration distribution. In some embodiments, a core/shell structure in which one quantum dot surrounds another quantum dot may also be possible. The core/shell structure may have a concentration gradient in which the concentration of elements present in the shell decreases toward the core.

In some embodiments, a quantum dot may have the above-described core-shell structure including a core containing nanocrystals and a shell around (e.g., surrounding) the core. The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An example of the shell of the quantum dot may include a metal or non-metal oxide, a semiconductor compound, or one or more combinations thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but the embodiment of the present disclosure is not limited thereto.

Also, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

The quantum dot may have a full width of half maximum (FWHM) of a light emission wavelength spectrum of about 45 nm or less, about 40 nm or less, and about 30 nm or less, and color purity or color reproducibility may be improved (increased) in the above range. In some embodiments, light emitted through such a quantum dot is emitted in all directions, and thus a wide viewing angle may be improved (increased).

In some embodiments, although the form of a quantum dot is not limited as long as it is a form commonly utilized in the art, for example, a quantum dot in the form of spherical, pyramidal, multi-arm, or cubic nanoparticles, nanotubes, nanowires, nanofibers, nanoparticles, etc. may be utilized.

The quantum dot may control the color of emitted light according to the particle size thereof, and accordingly, the quantum dot may have one or more suitable emission colors such as blue, red, and green.

In each light emitting element ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may be formed by utilizing one or more suitable methods such as a vacuum deposition method, a spin coating method, a cast method, a Langmuir-Blodgett (LB) method, an inkjet printing method, a laser printing method, a laser induced thermal imaging (LITI) method, etc. The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL and a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may include a compound represented by Formula ET-1:

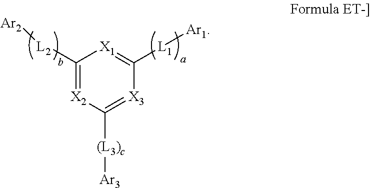

In Formula ET-1, at least one among X₁ to X₃ is N, and the rest (the substituents that are not N) are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1-biphenyl-4-olato)aluminum (BAlq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or one or more mixtures thereof.

In some embodiments, the electron transport regions ETR may include a metal halide such as LiF, NaCl, CsF, RbCl, RbI, CuI, and/or KI, a lanthanide metal such as Yb, and/or a co-deposited material of the metal halide and the lanthanide metal. For example, the electron transport region ETR may include KI:Yb, RbI:Yb, LiF:Yb, etc. as a co-deposited material. The electron transport region ETR may be formed utilizing a metal oxide such as Li₂O and/or BaO, or 8-hydroxyl-lithium quinolate (Liq), etc., but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but the embodiment of the present disclosure is not limited thereto.

The electron transport region ETR may include the above-described compounds of the electron transport region in at least one of the electron injection layer EIL, the electron transport layer ETL, or the hole blocking layer HBL. When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory (suitable) electron transport characteristics may be obtained without a substantial increase in a driving voltage.

When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described range, satisfactory (suitable) electron injection characteristics may be obtained without a substantial increase in a driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EU is an anode, the second electrode EL2 may be a cathode, and when the first electrode EL1 is a cathode, the second electrode EL2 may be an anode. The second electrode EL2 may include at least one selected from among Ag, Mg, Cu, Al, Pt, Pd, Au, Ni, Nd, Ir, Cr, Li, Ca, LiF, Mo, Ti, W, In, Sn, Zn, compounds comprising one or more of the foregoing elements, combinations of two or more of the foregoing elements or compounds, mixtures of two or more of the foregoing elements or compounds, and/or an oxide thereof.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or one or more compounds or mixtures thereof (e.g., AgMg, AgYb, or MgAg). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, and/or the like.

The second electrode EL2 may be connected with an auxiliary electrode. When the second electrode EL2 is connected with the auxiliary electrode, the resistance of the second electrode EL2 may decrease.

A capping layer CPL may further be disposed on the second electrode EL2 of the light emitting element ED of an embodiment. The capping layer CPL may include a multilayer or a single layer.

In an embodiment, the capping layer CPL may be an organic layer and/or an inorganic layer. For example, when the capping layer CPL contains an inorganic material, the inorganic material may include an alkaline metal compound (for example, LiF), an alkaline earth metal compound (for example, MgF₂), SiON, SiNₓ, SiOy, etc.

For example, when the capping layer CPL includes an organic material, the organic material may include a-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or an epoxy resin, or acrylate such as methacrylate. However, the embodiment of the present disclosure is not limited thereto, and the capping layer CPL may include at least one among Compounds P1 to P5:

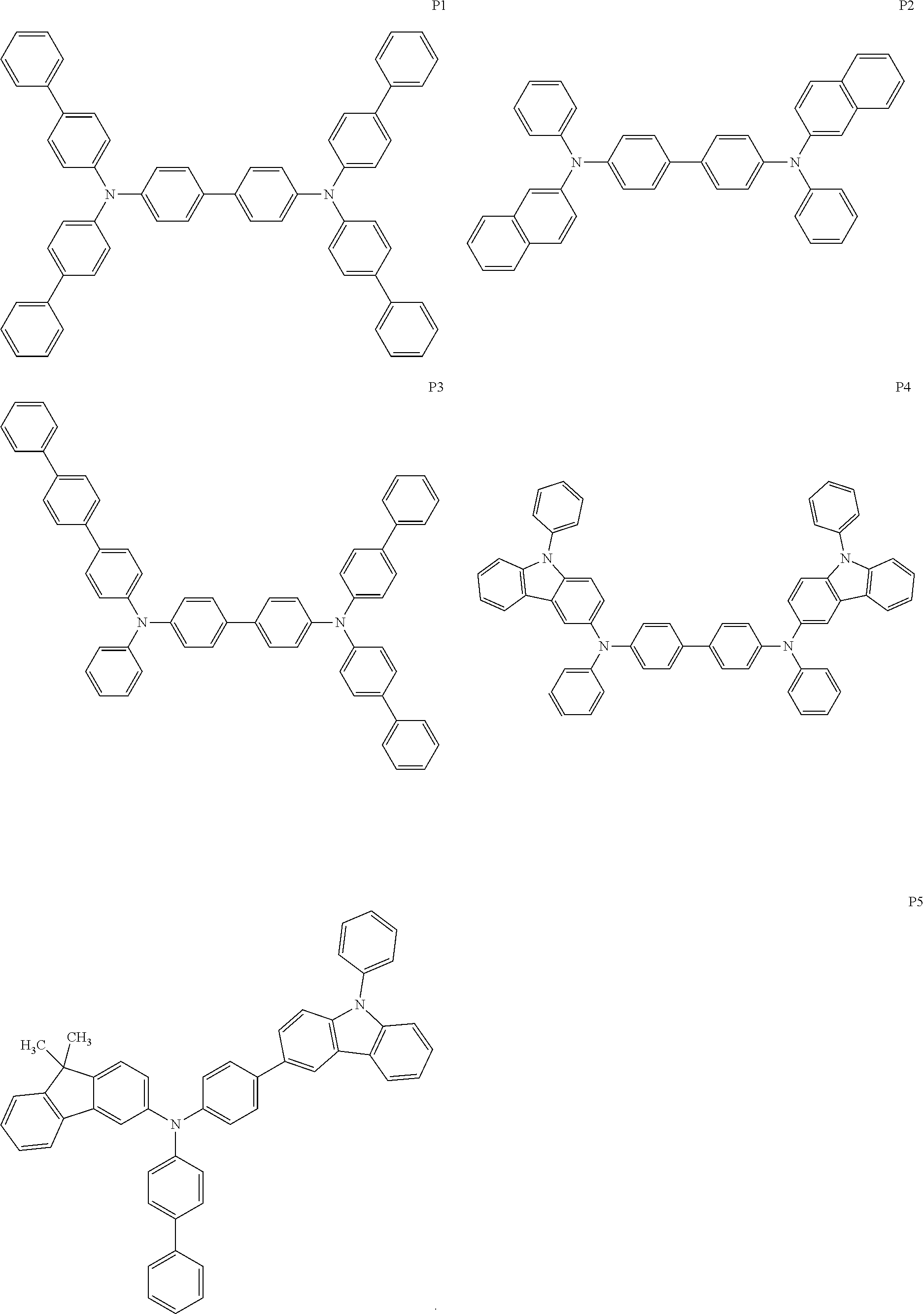

The refractive index of the capping layer CPL may be about 1.6 or more. For example, the refractive index of the capping layer CPL may be about 1.6 or more with respect to light in a wavelength range of about 550 nm to about 660 nm.

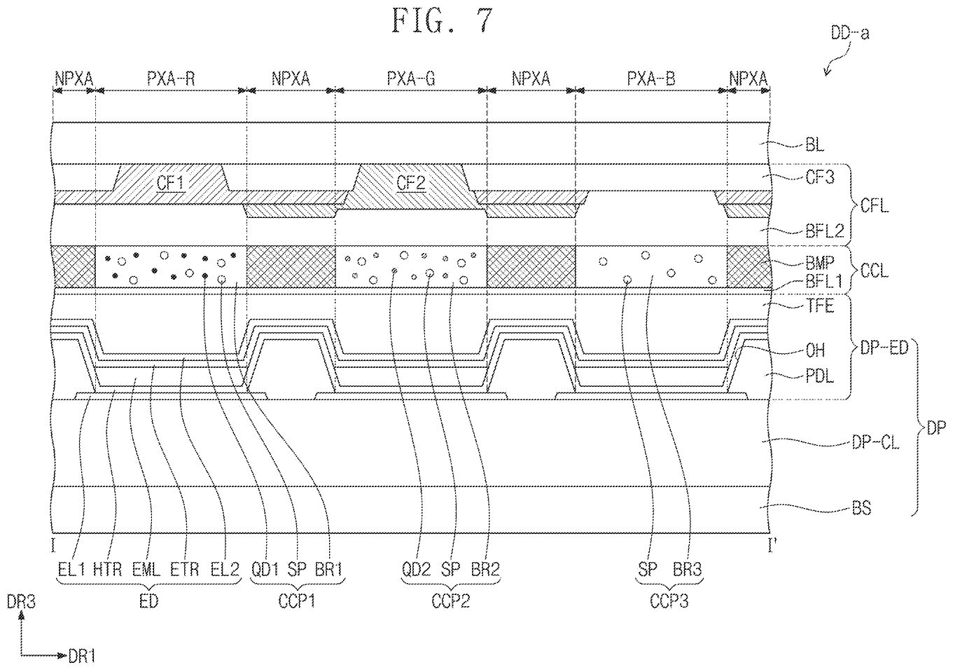

Each of FIGS. 7 to 10 is a cross-sectional view of a display device according to an embodiment of the present disclosure. Hereinafter, in describing the display devices of embodiments with reference to FIGS. 7 to 10, the duplicated features which have been described in FIGS. 1 to 6 may not be described again, but their differences will be primarily described.

Referring to FIG. 7, the display device DD according to an embodiment may include a display panel DP including a display element layer DP-ED, a light control layer CCL on the display panel DP, and a color filter layer CFL.

In an embodiment illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. The structures of the light emitting elements of FIGS. 3 to 6 as described above may be equally applied to the structure of the light emitting element ED illustrated in FIG. 7.

Referring to FIG. 7, the light emission layer EML in the display device DD-a may be in an opening OH defined in a pixel defining film PDL. For example, the emission layer EML, which is divided by the pixel defining film PDL and provided corresponding to each light emitting regions PXA-R, PXA-G, and PXA-B, may emit light in substantially the same wavelength range. In the display device DD of an embodiment, the emission layer EML may emit blue light. In an embodiment, the emission layer EML may be provided as a common layer in the entire light emitting regions PXA-R, PXA-G, and PXA-B.

The light control layer CCL may be on the display panel DP. The light control layer CCL may include a light conversion body. The light conversion body may be a quantum dot, a phosphor, and/or the like. The light conversion body may emit provided light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 7, divided patterns BMP may be disposed between the light control parts CCP1, CCP2 and CCP3 which are spaced apart (separated) from each other, but the embodiment of the present disclosure is not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same as described above may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow silica. The scatterer SP may include any one among TiO₂, ZnO, Al₂O₃, SiO₂, and hollow silica, or may be a mixture or mixtures of at least two materials selected from among TiO₂, ZnO, Al₂O₃, SiO₂, and hollow silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. The barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may further include an organic film. The barrier layers BFL1 and BFL2 may be formed of a single layer or a plurality of layers.

In the display device DD of an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and/or a pigment or dye. The first filter CF1 may include a red pigment or dye, the second filter CF2 may include a green pigment or dye, and the third filter CF3 may include a blue pigment or dye.

The embodiment of the present disclosure is not limited thereto, and the third filter CF3 may not include (e.g., may exclude) a pigment or dye. The third filter CF3 may include a polymeric photosensitive resin and may not include (e.g., may exclude) a pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated but be provided as one filter. The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may be a member which provides a base surface in which the color filter layer CFL, the light control layer CCL, and/or the like are disposed. The base substrate BL may be a glass substrate, a metal substrate, a plastic substrate, etc. However, the embodiment of the present disclosure is not limited thereto, and the base substrate BL may be an inorganic layer, an organic layer, and/or a composite material layer. In some embodiments, the base substrate BL may not be provided.

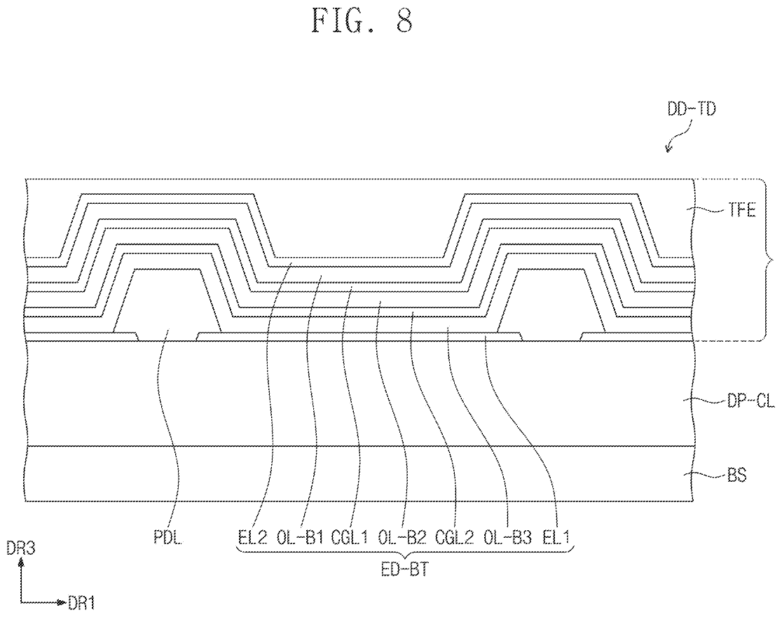

FIG. 8 is a cross-sectional view illustrating a portion of a display device according to an embodiment of the present disclosure. FIG. 8 illustrates a cross-sectional view of a part corresponding to the display panel DP of FIG. 7. In the display device DD-TD of an embodiment, the light emitting element ED-BT may include a plurality of light emitting structures OL-B1, OL-B2, and OL-B3. The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR disposed with the emission layer EML (FIG. 7) therebetween. For example, the light emitting element ED-BT included in the display device DD-TD of an embodiment may be a light emitting element having a tandem structure and including a plurality of emission layers.

In an embodiment illustrated in FIG. 8, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may emit white light.

A charge generation layers CGL1 and CGL2 may be between two of the neighboring light emitting structures OL-B1, OL-B2, and OL-B3. The charge generation layers CGL1 and CGL2 may include a p-type or kind charge generation layer and/or an n-type or kind charge generation layer.

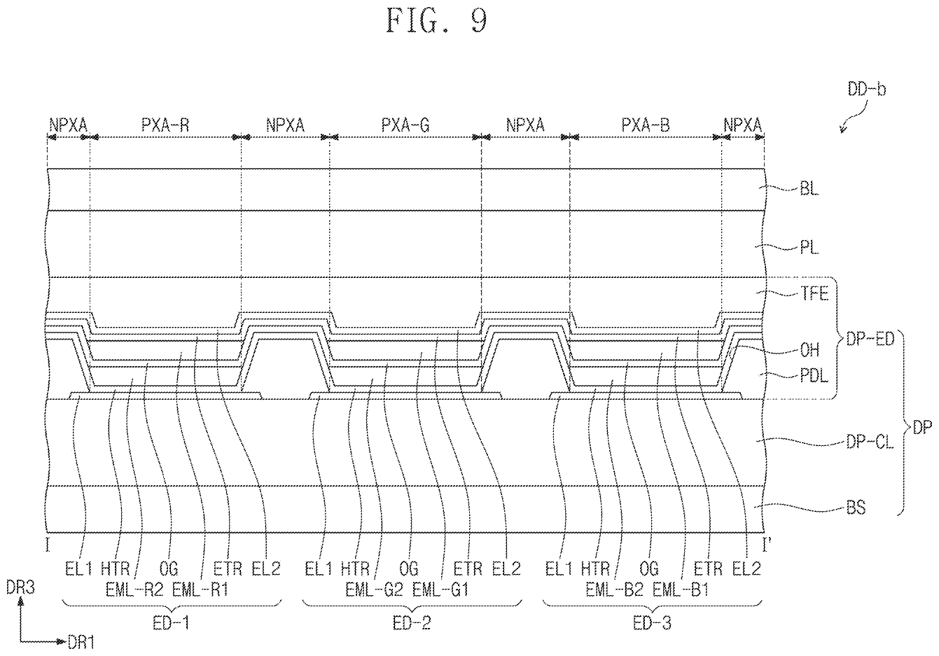

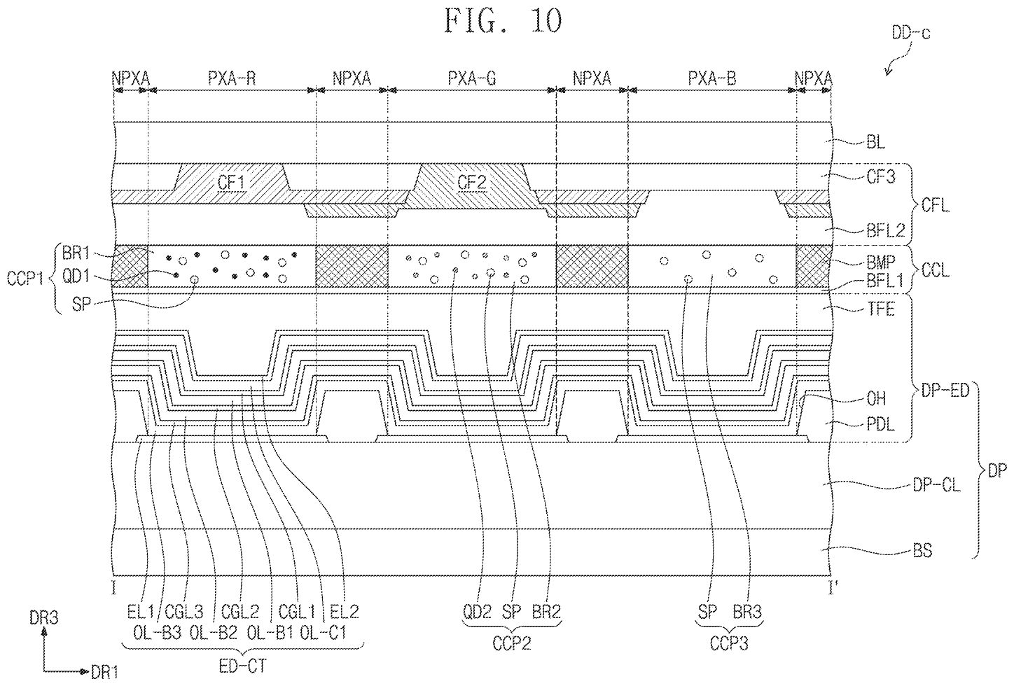

Referring to FIG. 9, the display device DD-b may include light emitting elements ED-1, ED-2, and ED-3 in which two emission layers are stacked. Unlike FIG. 2, FIG. 9 illustrates that two emission layers are provided in each of the first to third light emitting elements ED-1, ED-2, and ED-3. In each of the first to third light emitting elements ED-1, ED-2, and ED-3, the two emission layers may emit light in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be between the hole transport region HTR and the emission auxiliary part OG. The second red emission layer EML-R2, the second green emission layer EML-G2, and the second blue emission layer EML-B2 may be between the emission auxiliary part OG and the electron transport region ETR.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

An optical auxiliary layer PL may be on the display element layer DP-ED. The optical auxiliary layer PL may include a polarizing layer. The optical auxiliary layer PL may be on the display panel DP and control reflected light in the display panel DP due to external light. The optical auxiliary layer PL in the display device according to an embodiment may not be provided.

Unlike FIGS. 7 and 8, FIG. 10 illustrates that a display device DD-c includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be between the first to fourth light emitting structures OL-B1, OL-B2, OL-B3, and OL-C1. The charge generation layers CGL1, CGL2 and CGL3 may include a p-type or kind charge generation layer and/or an n-type or kind charge generation layer. Among the four light emitting structures, the first to third light emitting structures OL-B1, OL-B2, and OL-B3 may emit blue light, and the fourth light emitting structure OL-C1 may emit green light. However, the embodiment of the present disclosure is not limited thereto, and the first to fourth light emitting structures OL-B1, OL-B2, OL-B3, and OL-C1 may emit light beams in different wavelength regions.

Hereinafter, with reference to Examples and Comparative Examples, an amine compound according to an embodiment of the present disclosure and a light emitting element of an embodiment of the present disclosure will be described in more detail. In some embodiments, Examples described are only illustrations to assist the understanding of the present disclosure, and the scope of the present disclosure is not limited thereto.

### Examples

### 1. Synthesis of Amine Compound of Example

First, a synthetic method of the amine compound according to the current embodiment will be described in more detail by illustrating synthetic methods of Compounds 1, 13, 19, 21, 31, 32, 53, 60, 98, and 124. In some embodiments, in the following descriptions, the synthetic method of the amine compound is provided as an example, but the synthetic method of the compound according to an embodiment of the present disclosure is not limited to Examples.

### (1) Synthesis of Compound 1

Amine Compound 1 according to an example may be synthesized by, for example, the steps (e.g., acts or tasks) shown in Reaction Scheme 1:

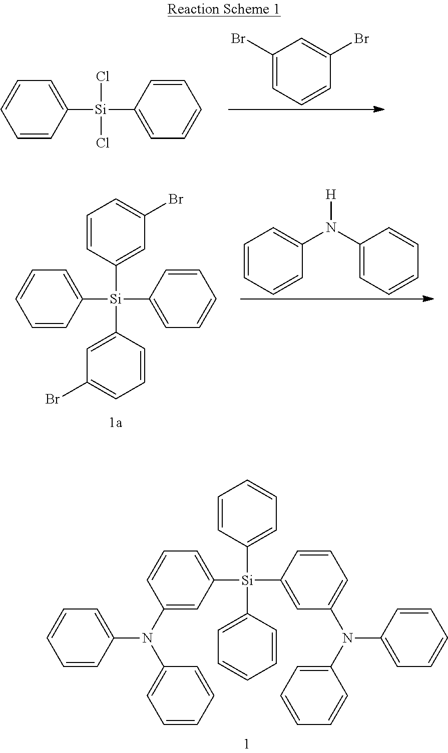

### Synthesis of Intermediate 1a

1,3-dibromobenzene (2.0 eq.) and 2.5M N-butyllithium solution (2.0 eq.) were dissolved in 500 mL of diethyl ether, and then the mixture was stirred at about −78° C. for about 2 hours in a nitrogen atmosphere. Dichlorodiphenylsilane (1.0 eq.) was added thereto, and the resultant mixture was slowly stirred at room temperature. When the reaction was terminated, the resulting product was washed three times with water and then diethyl ether to obtain an organic layer. The obtained organic layer was dried over magnesium sulfate (MgSO₄), and then dried under reduced pressure. The resulting product was purified by column chromatography to obtain Intermediate 1a. (yield: 60%)

### Synthesis of Compound 1

Intermediate 1a (1.0 eq.), diphenylamine (2.4 eq.), tris(dibenzylideneacetone)dipalladium(0) (0.05 eq.), tri-tert-butylphosphine (0.10 eq.), and sodium tert-butoxide (3.0 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Compound 1. (yield: 62%)

### (2) Synthesis of Compound 13

Amine Compound 13 according to an example may be synthesized by, for example, the steps shown in Reaction Scheme 2:

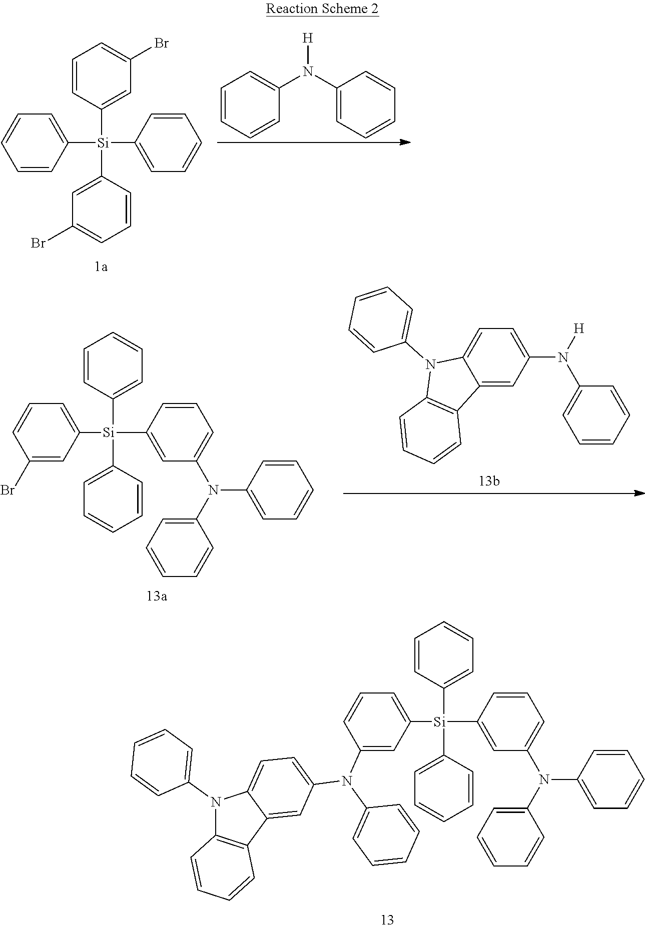

### Synthesis of Intermediate 13a

Intermediate 1a (1.0 eq.), diphenylamine (1.2 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 13a. (yield: 68%)

### Synthesis of Intermediate 13b

Aniline (1.0 eq.), 3-bromo-9-phenyl-9H-carbazole (1.1 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 13b. (yield: 61%)

### Synthesis of Compound 13

Intermediate 13a (1.0 eq.), Intermediate 13b (1.2 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Compound 13. (yield: 65%)

### (3) Synthesis of Compound 19

Amine Compound 19 according to an example may be synthesized by, for example, the steps shown in Reaction Scheme 3:

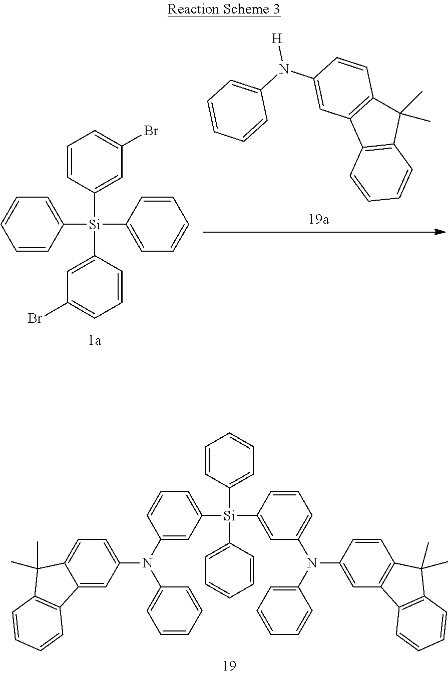

### Synthesis of Intermediate 19a

Aniline (1.0 eq.), 3-bromo-9.9-dimethyl-9H-fluorene (1.1 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 19a. (yield: 63%)

### Synthesis of Compound 19

Intermediate 1a (1.0 eq.), Intermediate 19a (2.2 eq.), tris(dibenzylideneacetone)dipalladium(0) (0.05 eq.), tri-tert-butylphosphine (0.10 eq.), and sodium tert-butoxide (3.0 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Compound 19. (yield: 68%)

### (4) Synthesis of Compound 21

Amine Compound 21 according to an example may be synthesized by, for example, the steps shown in Reaction Scheme 4:

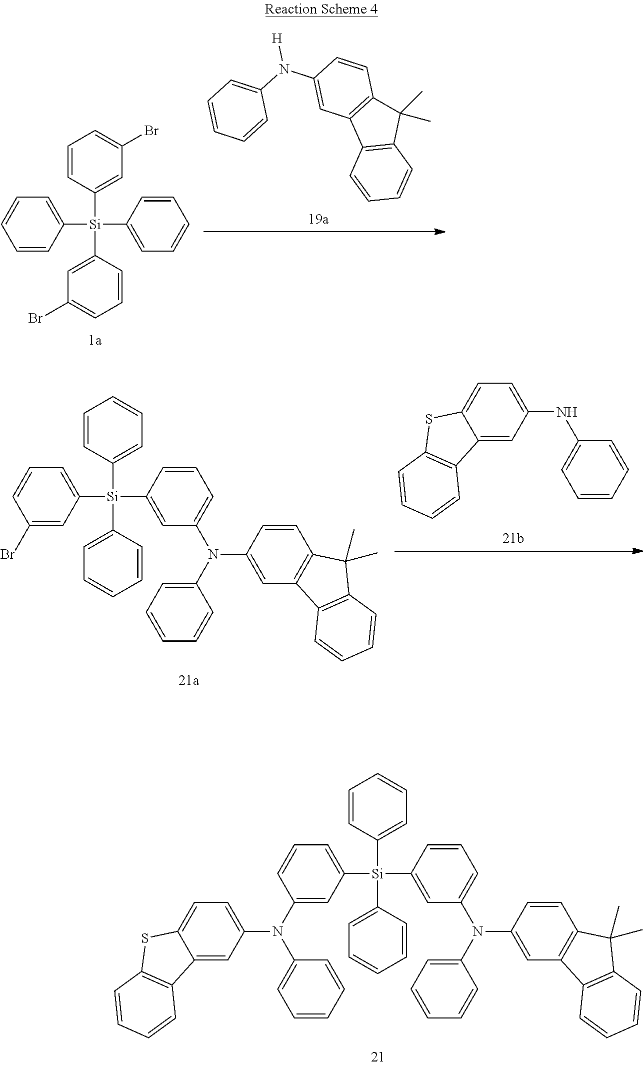 [SMILES: Brc1cccc([Si](c2ccccc2)(c2ccccc2)c2cccc(Br)c2)c1 ; CC1(C)c2ccccc2-c2cc(Nc3ccccc3)ccc21 ; CC1(C)c2ccccc2-c2cc(N(c3ccccc3)c3cccc([Si](c4ccccc4)(c4ccccc4)c4cccc(Br)c4)c3)ccc21 ; c1ccc(Nc2ccc3sc4ccccc4c3c2)cc1 ; CC1(C)c2ccccc2-c2cc(N(c3ccccc3)c3cccc([Si](c4ccccc4)(c4ccccc4)c4cccc(N(c5ccccc5)c5ccc6sc7ccccc7c6c5)c4)c3)ccc21]

### Synthesis of Intermediate 21a

Intermediate 1a (1.0 eq.), Intermediate 19a (1.1 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 21a. (yield: 62%)

### Synthesis of Intermediate 21b

Aniline (1.0 eq.), 2-bromodibenzo[b,d]thiophene (1.1 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 21b. (yield: 60%)

### Synthesis of Compound 21

Intermediate 21a (1.0 eq.), Intermediate 21b (1.2 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Compound 21. (yield: 65%)

### (5) Synthesis of Compound 31

Amine Compound 31 according to an example may be synthesized by, for example, the steps shown in Reaction Scheme 5:

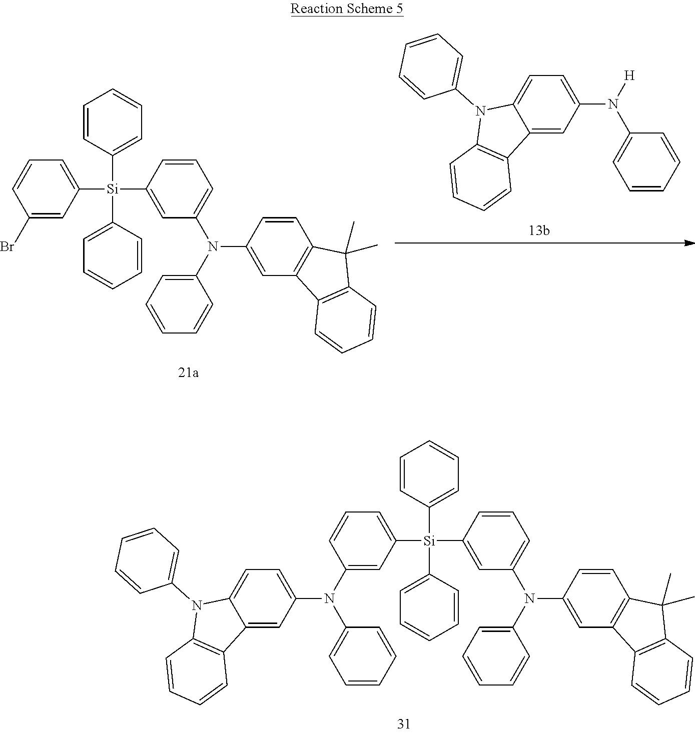 [SMILES: CC1(C)c2ccccc2-c2cc(N(c3ccccc3)c3cccc([Si](c4ccccc4)(c4ccccc4)c4cccc(Br)c4)c3)ccc21 ; c1ccc(Nc2ccc3c(c2)c2ccccc2n3-c2ccccc2)cc1 ; CC1(C)c2ccccc2-c2cc(N(c3ccccc3)c3cccc([Si](c4ccccc4)(c4ccccc4)c4cccc(N(c5ccccc5)c5ccc6c(c5)c5ccccc5n6-c5ccccc5)c4)c3)ccc21]

### Synthesis of Compound 31

Intermediate 21a (1.0 eq.), Intermediate 13b (1.2 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Compound 31. (yield: 60%)

### (6) Synthesis of Compound 32

Amine Compound 32 according to an example may be synthesized by, for example, the steps shown in Reaction Scheme 6:

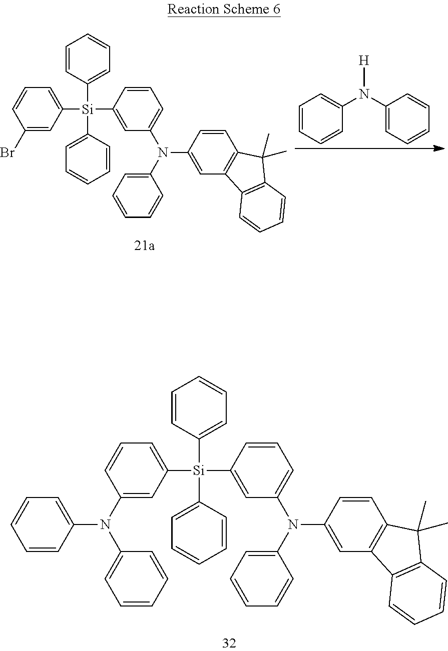

### Synthesis of Compound 32

Intermediate 21a (1.0 eq.), diphenylamine (1.2 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Compound 32. (yield: 63%)

### (7) Synthesis of Compound 53

Amine Compound 53 according to an example may be synthesized by, for example, the steps shown in Reaction Scheme 7:

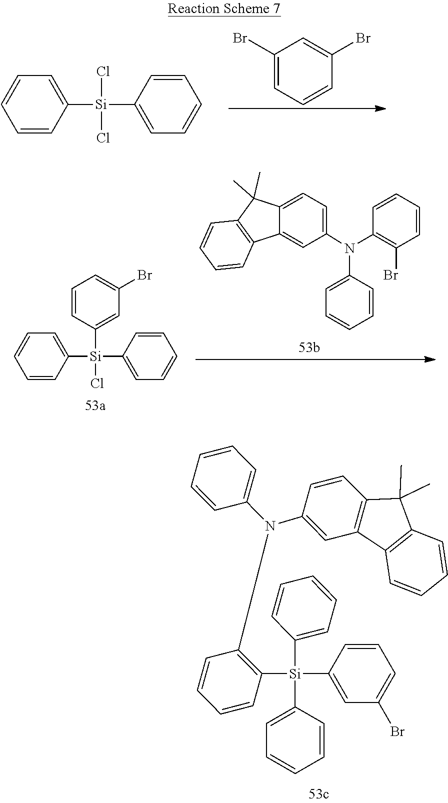 [SMILES: Cl[Si](Cl)(c1ccccc1)c1ccccc1 ; Brc1cccc(Br)c1 ; Cl[Si](c1ccccc1)(c1ccccc1)c1cccc(Br)c1 ; CC1(C)c2ccccc2-c2cc(N(c3ccccc3)c3ccccc3Br)ccc21 ; CC1(C)c2ccccc2-c2cc(N(c3ccccc3)c3ccccc3[Si](c3ccccc3)(c3ccccc3)c3cccc(Br)c3)ccc21]

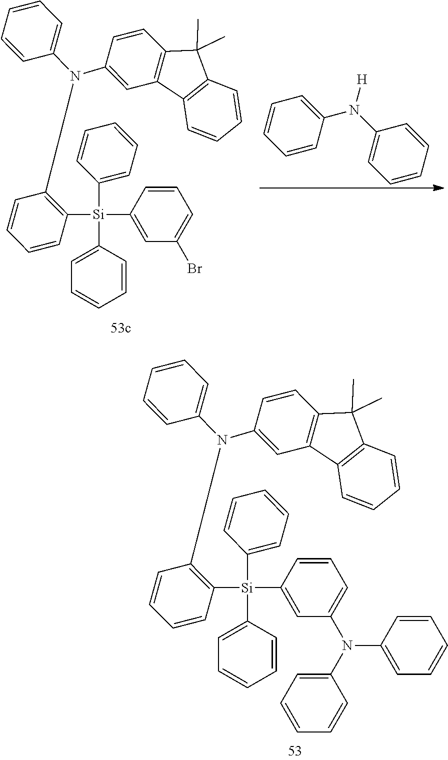

### Synthesis of Intermediate 53a

1,3-dibromobenzene (1.0 eq.) and 2.5M N-butyllithium solution (1.0 eq.) were dissolved in 500 mL of diethyl ether, and then the mixture was stirred at about −78° C. for about 2 hours in a nitrogen atmosphere. Dichlorodiphenylsilane (1.0 eq.) was added thereto, and the resultant mixture was slowly stirred at room temperature. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 53a. (yield: 58%)

### Synthesis of Intermediate 53b

Intermediate 53a (1.0 eq.), 1,2-dibromobenzene (1.1 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 53b. (yield: 59%)

### Synthesis of Intermediate 53c

Intermediate 53b (1.0 eq.) and 2.5M N-butyllithium solution (1.0 eq.) were dissolved in 100 mL of tetrahydrofuran, and then the mixture was stirred at about −78° C. for about 2 hours in a nitrogen atmosphere. Intermediate 53a (1.0 eq.) was added thereto, and the resultant mixture was slowly stirred at room temperature. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 53c. (yield: 60%)

### Synthesis of Compound 53

Intermediate 53c (1.0 eq.), diphenylamine (1.2 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Compound 53. (yield: 67%)

### (8) Synthesis of Compound 60

Amine Compound 60 according to an example may be synthesized by, for example, the steps shown in Reaction Scheme 8:

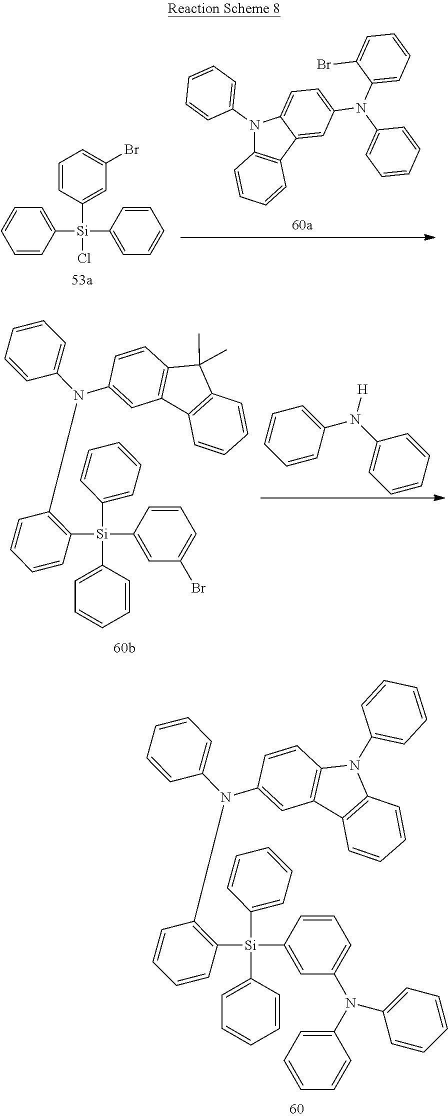

### Synthesis of Intermediate 60a

Intermediate 13b (1.0 eq.), 1,2-dibromobenzene (1.1 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 60a. (yield: 58%)

### Synthesis of Intermediate 60b

Intermediate 53a (1.0 eq.) and 2.5M N-butyllithium solution (1.0 eq.) were dissolved in 100 mL of tetrahydrofuran, and then the mixture was stirred at about −78° C. for about 2 hours in a nitrogen atmosphere. Intermediate 60a (1.0 eq.) was added thereto, and the resultant mixture was slowly stirred at room temperature. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 60b. (yield: 57%)

### Synthesis of Compound 60

Intermediate 60b (1.0 eq.), diphenylamine (1.2 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Compound 60. (yield: 63%)

### (9) Synthesis of Compound 98

Amine Compound 98 according to an example may be synthesized by, for example, the steps shown in Reaction Scheme 9:

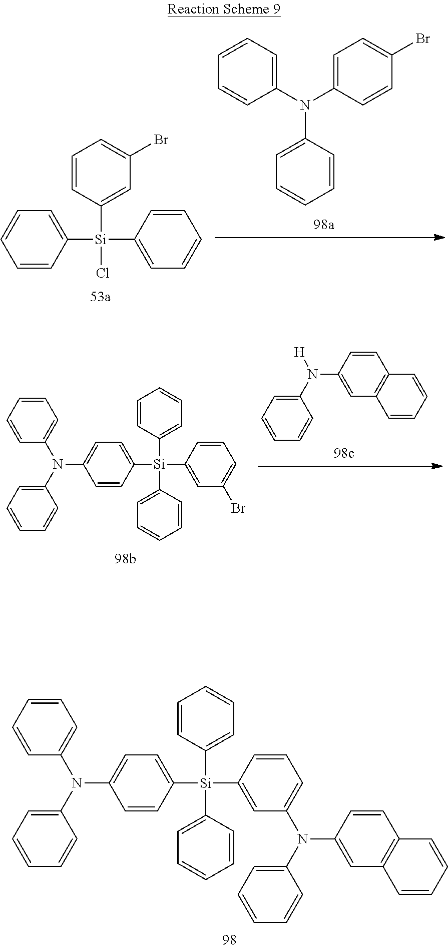 [SMILES: Cl[Si](c1ccccc1)(c1ccccc1)c1cccc(Br)c1 ; Brc1ccc(N(c2ccccc2)c2ccccc2)cc1 ; Brc1cccc([Si](c2ccccc2)(c2ccccc2)c2ccc(N(c3ccccc3)c3ccccc3)cc2)c1 ; c1ccc(Nc2ccc3ccccc3c2)cc1 ; c1ccc(N(c2ccccc2)c2ccc([Si](c3ccccc3)(c3ccccc3)c3cccc(N(c4ccccc4)c4ccc5ccccc5c4)c3)cc2)cc1]

### Synthesis of Intermediate 98a

Diphenylamine (1.0 eq.), 1,4-dibromobenzene (1.1 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 98a. (yield: 68%)

### Synthesis of Intermediate 98b

Intermediate 53a (1.0 eq.) and 2.5M N-butyllithium solution (1.0 eq.) were dissolved in 100 mL of tetrahydrofuran, and then the mixture was stirred at about −78° C. for about 2 hours in a nitrogen atmosphere. Intermediate 98a (1.0 eq.) was added thereto, and the resultant mixture was slowly stirred at room temperature. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 98b. (yield: 59%)

### Synthesis of Intermediate 98c

Aniline (1.0 eq.), 2-bromonaphthalene (1.1 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Intermediate 98c. (yield: 69%)

### Synthesis of Compound 98

Intermediate 98b (1.0 eq.), Intermediate 98c (1.2 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Compound 98. (yield: 66%)

### (10) Synthesis of Compound 124

Amine Compound 124 according to an example may be synthesized by, for example, the steps shown in Reaction Scheme 10:

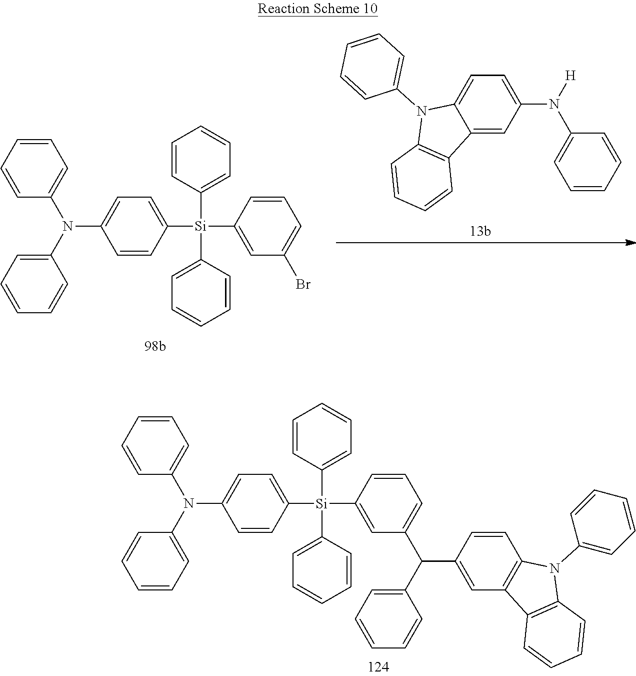 [SMILES: Brc1cccc([Si](c2ccccc2)(c2ccccc2)c2ccc(N(c3ccccc3)c3ccccc3)cc2)c1 ; c1ccc(Nc2ccc3c(c2)c2ccccc2n3-c2ccccc2)cc1 ; c1ccc(C(c2cccc([Si](c3ccccc3)(c3ccccc3)c3ccc(N(c4ccccc4)c4ccccc4)cc3)c2)c2ccc3c(c2)c2ccccc2n3-c2ccccc2)cc1]

### Synthesis of Compound 124

Intermediate 98b (1.0 eq.), Intermediate 13b (1.2 eq.), tris(dibenzylideneacetone)dipalladium(0) (0.05 eq.), tri-tert-butylphosphine (0.10 eq.), and sodium tert-butoxide (1.5 eq.) were dissolved in 50 mL of toluene, and then the mixture was stirred at about 80° C. for about 1 hour in a nitrogen atmosphere. When the reaction was terminated, the resulting product was washed three times with water and then diethyl ether to obtain an organic layer. The obtained organic layer was dried over MgSO₄, and then dried under reduced pressure. The resulting product was purified by column chromatography to obtain Compound 124. (yield: 68%)

### 2. Manufacture and Evaluation of Light Emitting Elements

### (1) Manufacture of Light Emitting Elements

Light emitting elements including an amine compound of an example or Comparative Example Compound in a hole transport layer were manufactured as follows. Compounds 1, 13, 19, 21, 31, 32, 53, 60, 98, and 124 which are the amine compounds of examples were utilized as a hole transport layer material to manufacture the light emitting elements of Examples 1 to 10, respectively. Comparative Example Compounds C1 to C6 were utilized as a hole transport layer material to manufacture the light emitting elements of Comparative Examples 1 to 6, respectively. N,N′-di(naphthalene-1-yl)-N,N′-diphenyl-benzidine (NPB) was utilized as Comparative Example Compound C1.

For a first electrode, an ITO glass substrate of about 15 Ω/cm² (a thickness of about 1,200 Å) made by Corning Co. was cut to a size of 50 mm×50 mm×0.7 mm, cleansed by ultrasonic waves utilizing isopropyl alcohol and pure water for about 5 minutes, and then irradiated with ultraviolet rays for about 30 minutes and exposed to ozone and cleansed. The glass substrate was installed on a vacuum deposition apparatus.

On the upper portion of the first electrode, NPD, a suitable compound, was deposited in vacuum to form a 600 Å-thick hole injection layer, and then Comparative Example Compound or Example Compound as a hole transporting compound was deposited in vacuum to form a 300 Å-thick hole transport layer.

On the upper portion of the hole transport layer, 9,10-di(naphthalen-2-yl)anthracene (ADN), which is a suitable compound, as a blue fluorescent host and 4,4′-bis[2-(4-(N,N-diphenylamino)phenyl)vinyl]biphenyl (DPAVBi), which is a suitable compound, as a blue fluorescent dopant were co-deposited at a weight ratio of 98:2 to form a 300 Å-thick emission layer.

On the upper portion of the emission layer, Alq₃ was deposited to form a 300 Å-thick electron transport layer, and then on the upper portion of the electron transport layer, LiF, which is a alkali metal halide, was deposited to form 10 Å-thick electron injection layer. Then, Al was deposited in vacuum to form a 3000 Å-thick second electrode of LiF/Al.

### Materials Used to Manufacture Light Emitting Elements

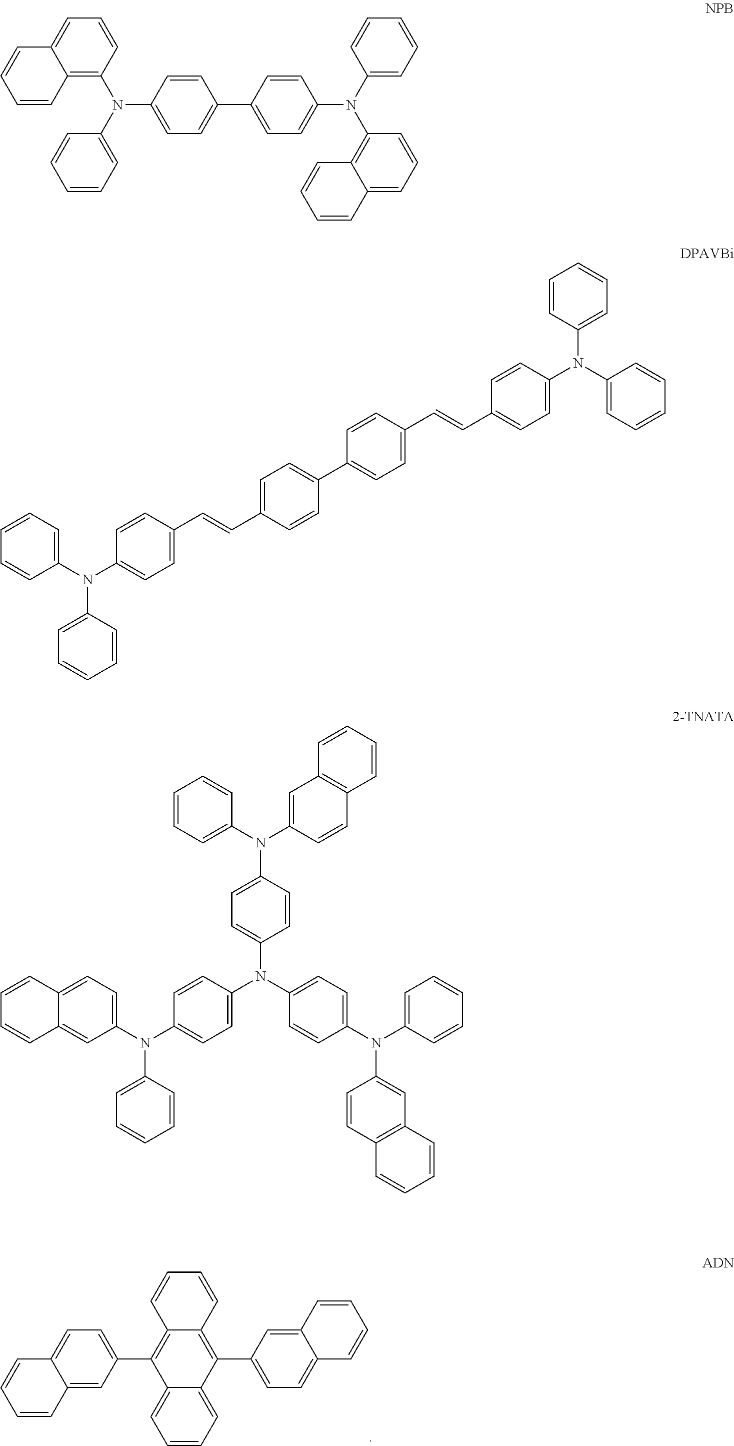

Example Compounds and Comparative Example Compounds utilized in Examples 1 to 10 and Comparative Examples 1 to 6 are listed in Table 1.

TABLE 1

| | |
|---|---|
| Comparative Example Compound C1 | 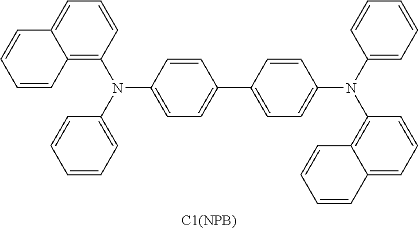 [SMILES: c1ccc(N(c2ccc(-c3ccc(N(c4ccccc4)c4cccc5ccccc45)cc3)cc2)c2cccc3ccccc23)cc1 ; "C1(NPB)"] |
| Comparative Example Compound C2 | 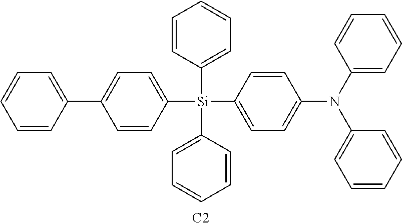 |
| Comparative Example Compound C3 | 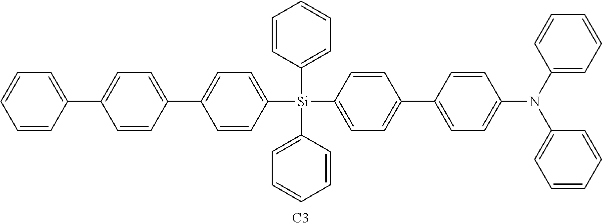 |
| Comparative Example Compound C4 | 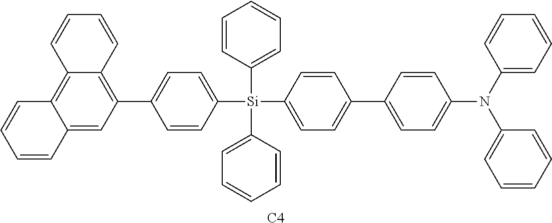 |
| Comparative Example Compound C5 | 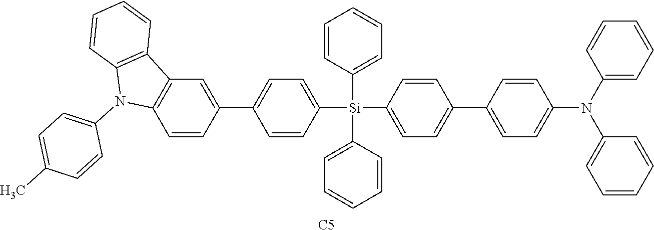 [SMILES: Cc1ccc(-n2c3ccccc3c3cc(-c4ccc([Si](c5ccccc5)(c5ccccc5)c5ccc(-c6ccc(N(c7ccccc7)c7ccccc7)cc6)cc5)cc4)ccc32)cc1 ; "C5"] |
| Comparative Example Compound C6 | 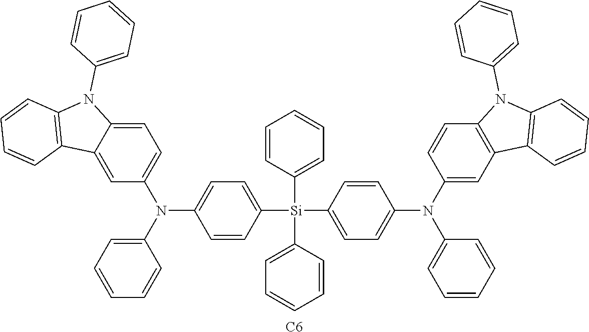 [SMILES: c1ccc(N(c2ccc([Si](c3ccccc3)(c3ccccc3)c3ccc(N(c4ccccc4)c4ccc5c(c4)c4ccccc4n5-c4ccccc4)cc3)cc2)c2ccc3c(c2)c2ccccc2n3-c2ccccc2)cc1 ; "C6"] |
| Compound 1 | 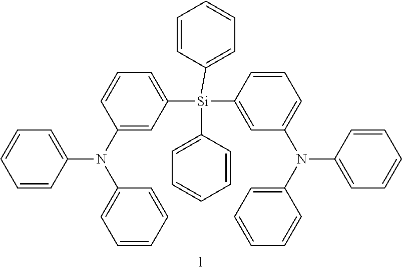 [SMILES: c1ccc(N(c2ccccc2)c2cccc([Si](c3ccccc3)(c3ccccc3)c3cccc(N(c4ccccc4)c4ccccc4)c3)c2)cc1 ; "1"] |
| Compound 13 | 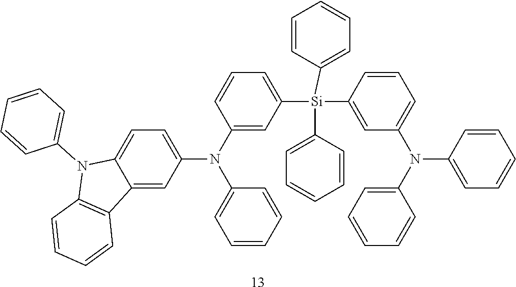 |
| Compound 19 | 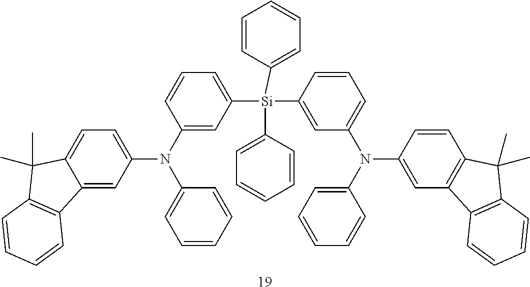 |
| Compound 21 | 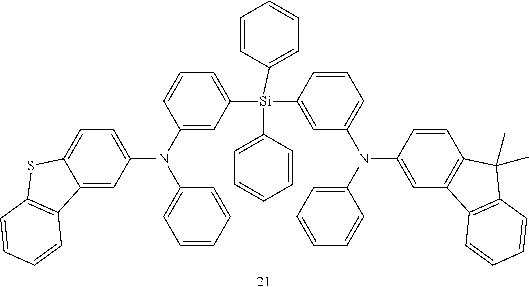 [SMILES: CC1(C)c2ccccc2-c2cc(N(c3ccccc3)c3cccc([Si](c4ccccc4)(c4ccccc4)c4cccc(N(c5ccccc5)c5ccc6sc7ccccc7c6c5)c4)c3)ccc21 ; "21"] |
| Compound 31 | 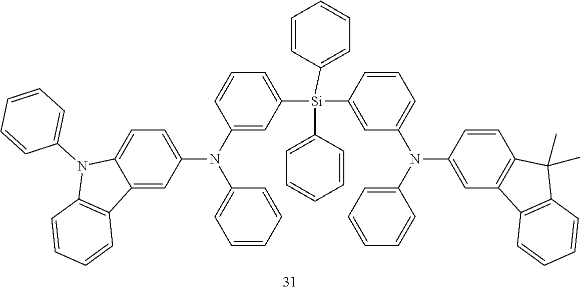 |
| Compound 32 | 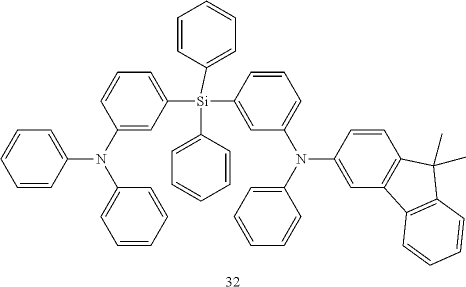 |
| Compound 53 | 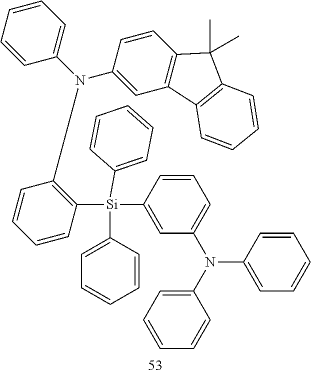 |
| Compound 60 | 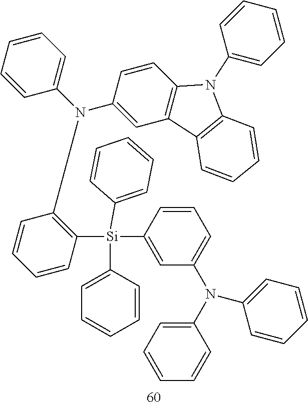 |
| Compound 98 | 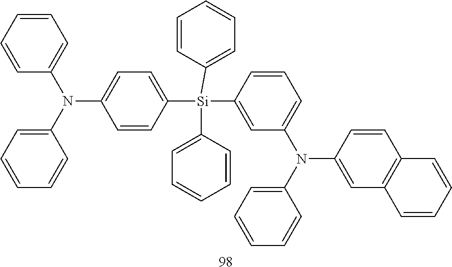 |
| Compound 124 | 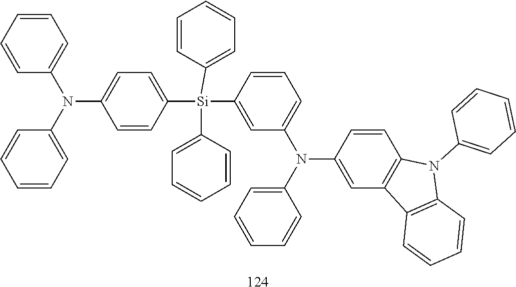 |
| — | |

### (2) Evaluation of Light Emitting Element Property

Properties of the light emitting elements of Examples and Comparative Examples are evaluated and listed in Table 2. Driving voltages, brightnesses, and efficiencies of the light emitting elements of Examples and Comparative Examples were measured with respect to a current density of 50 mA/cm². The driving voltages, brightnesses, and efficiencies were determined by utilizing IVL Q2000 made by ENC Technology Co., Ltd. Half service lives of the light emitting elements of Examples and Comparative Examples were measured with respect to a current density of 100 mA/cm². The half service lives were determined by utilizing LTS1004DC made by ENC Technology Co., Ltd., and by measuring a time taken to reduce the brightness to half of an initial brightness.

TABLE 2

| Examples of | Hole | Driving | | | | Half |
|---|---|---|---|---|---|---|
| manufactured | transport | voltage | Brightness | Efficiency | Luminous | service |
| elements | layer | (V) | (cd/m²) | (cd/A) | color | life (hr) |
| Comparative | Comparative | 7.05 | 2540 | 5.08 | Blue | 240 |
| Example 1 | Example | | | | | |
| | Compound | | | | | |
| | C1 (NPB) | | | | | |
| Comparative | Comparative | 5.30 | 3005 | 6.01 | Blue | 270 |
| Example 2 | Example | | | | | |
| | Compound | | | | | |
| | C2 | | | | | |
| Comparative | Comparative | 4.59 | 3105 | 6.21 | Blue | 268 |
| Example 3 | Example | | | | | |
| | Compound | | | | | |
| | C3 | | | | | |
| Comparative | Comparative | 5.41 | 3010 | 6.02 | Blue | 280 |
| Example 4 | Example | | | | | |
| | Compound | | | | | |
| | C4 | | | | | |
| Comparative | Comparative | 4.90 | 3190 | 6.38 | Blue | 310 |
| Example 5 | Example | | | | | |
| | Compound | | | | | |
| | C5 | | | | | |
| Comparative | Comparative | 4.85 | 3020 | 6.23 | Blue | 300 |
| Example 6 | Example | | | | | |
| | Compound | | | | | |
| | C6 | | | | | |
| Example 1 | Compound | 4.80 | 3200 | 6.40 | Blue | 330 |
| | 1 | | | | | |
| Example 2 | Compound | 4.11 | 3300 | 6.60 | Blue | 510 |
| | 13 | | | | | |
| Example 3 | Compound | 4.20 | 3210 | 6.42 | Blue | 480 |
| | 19 | | | | | |
| Example 4 | Compound | 4.13 | 3250 | 6.50 | Blue | 515 |
| | 21 | | | | | |
| Example 5 | Compound | 4.12 | 3180 | 6.36 | Blue | 505 |
| | 31 | | | | | |
| Example 6 | Compound | 4.30 | 3350 | 6.70 | Blue | 490 |
| | 32 | | | | | |
| Example 7 | Compound | 4.25 | 3280 | 6.56 | Blue | 375 |
| | 53 | | | | | |
| Example 8 | Compound | 4.05 | 3150 | 6.30 | Blue | 380 |
| | 60 | | | | | |
| Example 9 | Compound | 4.20 | 3260 | 6.52 | Blue | 470 |
| | 98 | | | | | |
| Example 10 | Compound | 4.15 | 3170 | 6.34 | Blue | 495 |
| | 124 | | | | | |

Referring to Table 2, it may be seen that the light emitting elements of Comparative Example 3, and Examples 1 to 10 have reduced driving voltages compared to the light emitting elements of Comparative Examples 1, 2 and 4 to 6. It may be seen that the light emitting elements of Examples 2 to 10 exhibit reduced driving voltages compared to the light emitting element of Comparative Example 3.

It may be seen that the light emitting elements of Examples 1 to 10 have the brightnesses and efficiencies higher than those of the light emitting elements of Comparative Examples 1 to 4 and 6. It may be seen that the light emitting elements of Examples 1 to 4, 6, 7, and 9 have improved brightnesses and efficiencies compared to the light emitting element of Comparative Example 5.

It may be seen that the light emitting elements of Examples 1 to 10 have half service lives superior to the light emitting elements of Comparative Example 1 to 6. The light emitting elements of Examples 1 to 10 include Compounds 1, 13, 19, 21, 31, 32, 53, 60, 98, and 124, respectively, which are the amine compounds of Examples.

Compounds 1, 13, 19, 21, 31, 32, 53, 60, 98, and 124 each have four phenyl groups that are bonded to the silicon atom, and an amine group is bonded to two phenyl groups among the four phenyl groups. The amine group bonded to one phenyl group among the two phenyl groups is in the meta-, ortho-, or para-position relation with the silicon atom, and the amine group bonded to the other phenyl group is in the meta-position relation with the silicon atom. Accordingly, the amine compound of an example may contribute to reducing the driving voltage of the light emitting element, and improving (increasing) the brightness and efficiency. In some embodiments, the light emitting element including the amine compound of an example may exhibit a long service life characteristic.

The light emitting element of Comparative Example 1 includes Comparative Example Compound C1, and NPB as Comparative Example Compound C1 includes two amine groups, but does not include a silicon atom. The light emitting elements of Comparative Examples 2 to 5 include Comparative Example Compounds C2 to C5, and Comparative Example Compounds C2 to C5 include only one amine group. The light emitting element of Comparative Example 6 includes Comparative Example Compound C6 which includes two amine groups bonded via a phenyl group to the silicon atom and the two amine groups are in the para-position relation with the silicon atom. Accordingly, it is believed that the light emitting elements of Comparative Examples 1, 2, and 4 to 6 exhibit a characteristic in which the driving voltages are not reduced, the light emitting elements of Comparative Examples 1 to 4 and 6 exhibit a characteristic in which the brightnesses and efficiencies are low, and the light emitting elements of Comparative Examples 1 to 6 exhibit a characteristic in which the service lives are short.

The light emitting element of an example may include a first electrode, a second electrode disposed on the first electrode, and at least one functional layer disposed between the first electrode and the second electrode. The at least one functional layer may include the amine compound of an embodiment.

For the amine compound of an example, four phenyl groups may be bonded to the silicon atom, and amine groups may be bonded to two phenyl groups among the four phenyl groups. The amine group bonded to one phenyl group among the two phenyl groups may be in the meta-position relation with the silicon atom. The amine compound including two amine groups may have improvement in a hole transport property, and may have minimized or reduced intermolecular interaction. Accordingly, the light emitting element including the amine compound of an example may exhibit a long service life characteristic. In some embodiments, the light emitting element including the amine compound of an example may exhibit characteristics in which the driving voltage is reduced, and the brightness and efficiency are improved (increased).

A light emitting element of an embodiment includes an amine compound of an embodiment, and thus may exhibit the characteristics in which the driving voltage is reduced, the brightness and efficiency are improved, and a service life is excellent or suitable.

An amine compound of an embodiment may contribute to reducing the driving voltage of the light emitting element, improving the brightness and efficiency, and improving a service life (increasing lifetime of device).

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The light emitting element (or device) or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to preferred embodiments of the present disclosure, it will be understood that the present disclosure should not be limited to these preferred embodiments but one or more suitable changes and modifications can be made by those skilled in the art without departing from the spirit and scope of the present disclosure as defined by the following claims and equivalents thereof.

Accordingly, the technical scope of the present disclosure is not intended to be limited to the contents set forth in the detailed description of the disclosure, but is intended to be defined by the appended claims and equivalents thereof.

What is claimed is:

1. A light emitting element comprising:
a first electrode;
a second electrode on the first electrode; and
at least one functional layer which is between the first electrode and the second electrode and comprises an amine compound represented by Formula 1: 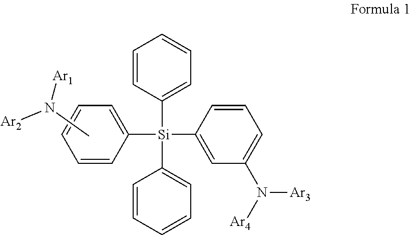
wherein, in Formula 1,
Ar₁ to Ar₄ are each independently a substituted or unsubstituted aryl group having 6 to 30 ring-forming carbon atoms, or a substituted or unsubstituted heteroaryl group having 2 to 30 ring-forming carbon atoms.

2. The light emitting element of claim 1, wherein Formula 1 is represented by any one among Formula 1-1 to Formula 1-3: 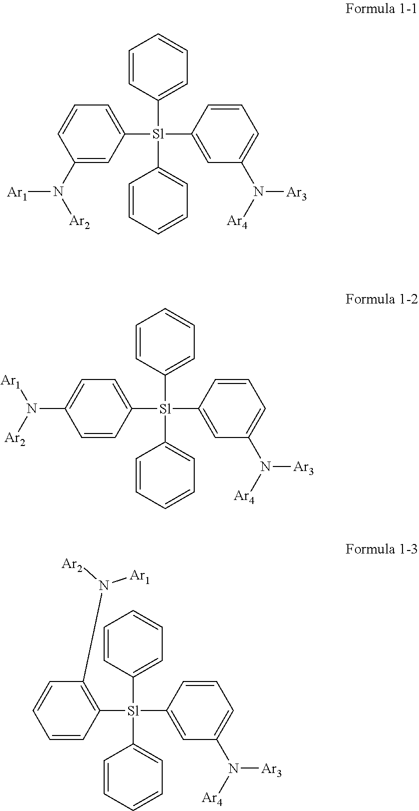
wherein, in Formula 1-1 to Formula 1-3,
Ar₁ to Ar₄ are the same as defined in Formula 1.

3. The light emitting element of claim 1, wherein Formula 1 is represented by Formula 2: 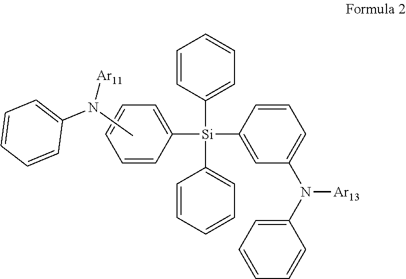
wherein, in Formula 2,
Ar₁₁ and Ar₁₃ are each independently a substituted or unsubstituted aryl group having 6 to 30 ring-forming carbon atoms, or a substituted or unsubstituted heteroaryl group having 2 to 30 ring-forming carbon atoms.

4. The light emitting element of claim 3, wherein Formula 2 is represented by Formula 2-1: 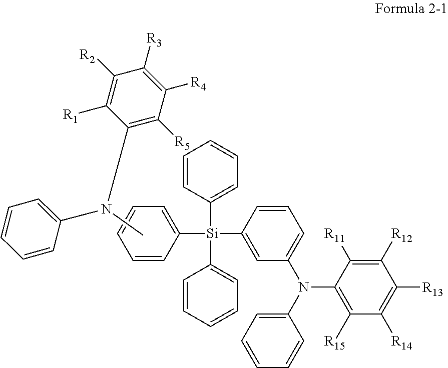
wherein, in Formula 2-1,
R₁ to R₅ and R₁₁ to R₁₅ are each independently a hydrogen atom, a substituted or unsubstituted amine group, a substituted or unsubstituted oxy group, a substituted or unsubstituted thio group, a substituted or unsubstituted alkyl group having 1 to 10 carbon atoms, a substituted or unsubstituted alkenyl group having 2 to 10 carbon atoms, or a substituted or unsubstituted aryl group having 6 to 30 ring-forming carbon atoms, and/or are bonded to an adjacent group to form a ring.

5. The light emitting element of claim 3, wherein Formula 2 is represented by Formula 2-2A or Formula 2-2B: 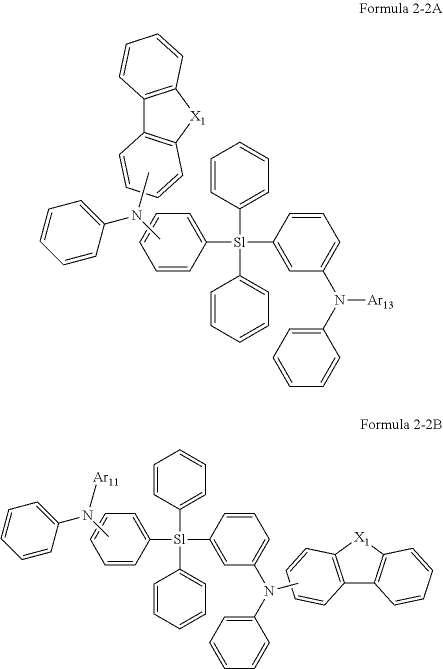
wherein, in Formulae 2-2A and 2-2B,
X₁ is C(CH₃)₂, N(Ph), O, or S, and
Ar₁₁ and Ar₁₃ are the same as defined in Formula 2.

6. The light emitting element of claim 1, wherein Ar₁ to Ar₄ are each independently represented by any one among A-1 to A-6:

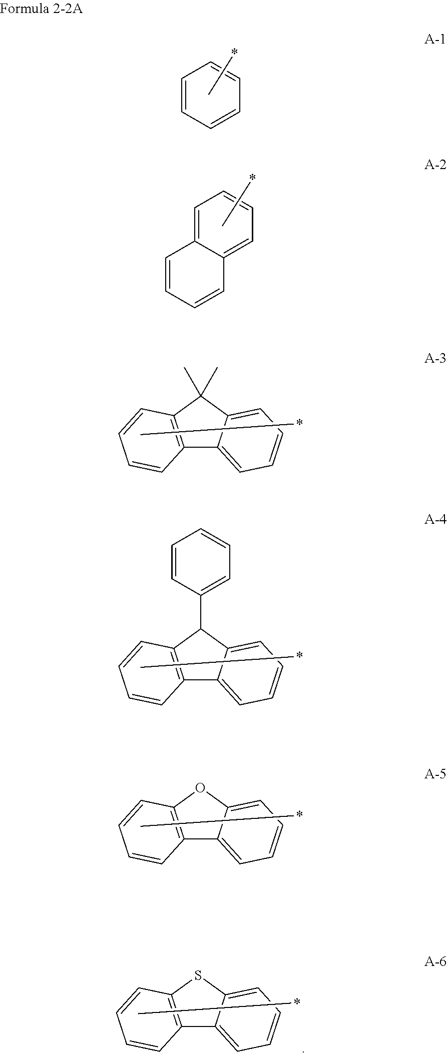

7. The light emitting element of claim 1, wherein Ar₁ to Ar₄ are each independently a substituted or unsubstituted phenyl group, a substituted or unsubstituted naphthyl group, a substituted or unsubstituted fluorenyl group, a substituted or unsubstituted carbazole group, a substituted or unsubstituted dibenzofuran group, or a substituted or unsubstituted dibenzothiophene group.

8. The light emitting element of claim 1, wherein, in Formula 1, Ar₁ and Ar₃ are the same and Ar₂ and Ar₄ are the same.

9. The light emitting element of claim 1, wherein the at least one functional layer comprises an emission layer, a hole transport region between the first electrode and the emission layer, and an electron transport region between the emission layer and the second electrode, and
the hole transport region comprises the amine compound.

10. The light emitting element of claim 9, wherein the hole transport region comprises a hole injection layer on the first electrode, a hole transport layer on the hole injection layer, and an electron blocking layer on the hole transport layer, and
at least one of the hole injection layer, the hole transport layer, or the electron blocking layer comprises the amine compound.

11. The light emitting element of claim 1, wherein the amine compound is represented by any one among compounds of Compound Group 1:

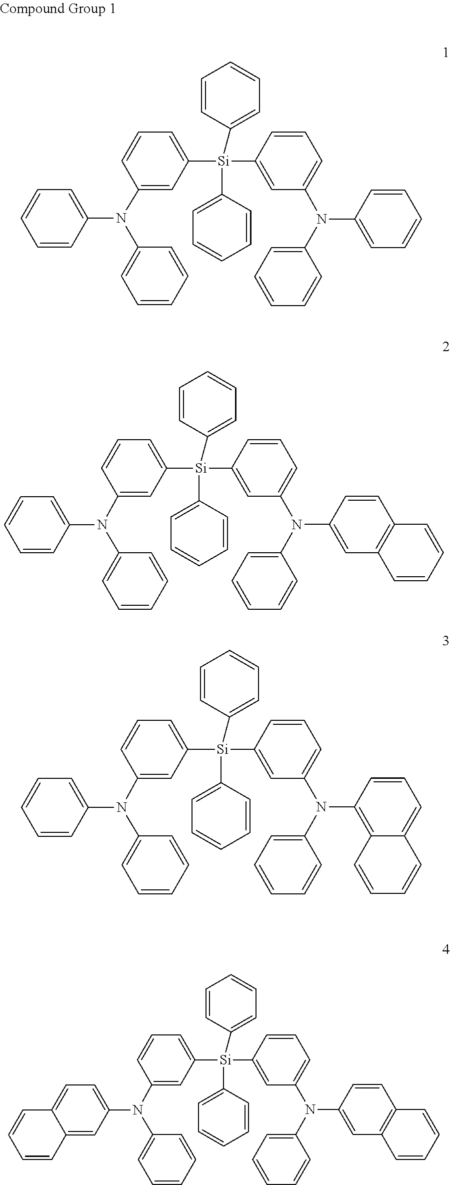

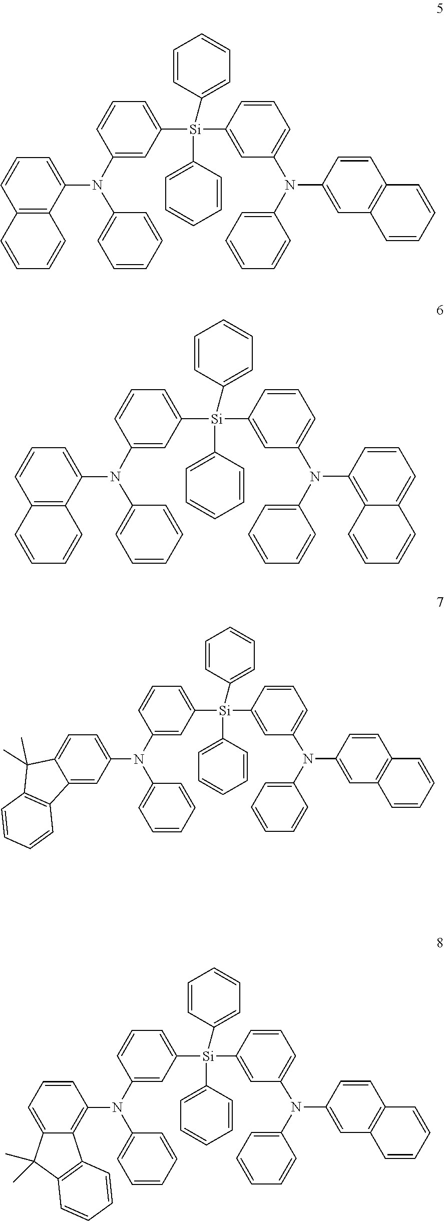 [SMILES: c1ccc(N(c2cccc([Si](c3ccccc3)(c3ccccc3)c3cccc(N(c4ccccc4)c4cccc5ccccc45)c3)c2)c2ccc3ccccc3c2)cc1 ; c1ccc(N(c2cccc([Si](c3ccccc3)(c3ccccc3)c3cccc(N(c4ccccc4)c4cccc5ccccc45)c3)c2)c2cccc3ccccc23)cc1 ; CC1(C)c2ccccc2-c2cc(N(c3ccccc3)c3cccc([Si](c4ccccc4)(c4ccccc4)c4cccc(N(c5ccccc5)c5ccc6ccccc6c5)c4)c3)ccc21 ; CC1(C)c2ccccc2-c2c(N(c3ccccc3)c3cccc([Si](c4ccccc4)(c4ccccc4)c4cccc(N(c5ccccc5)c5ccc6ccccc6c5)c4)c3)cccc21]

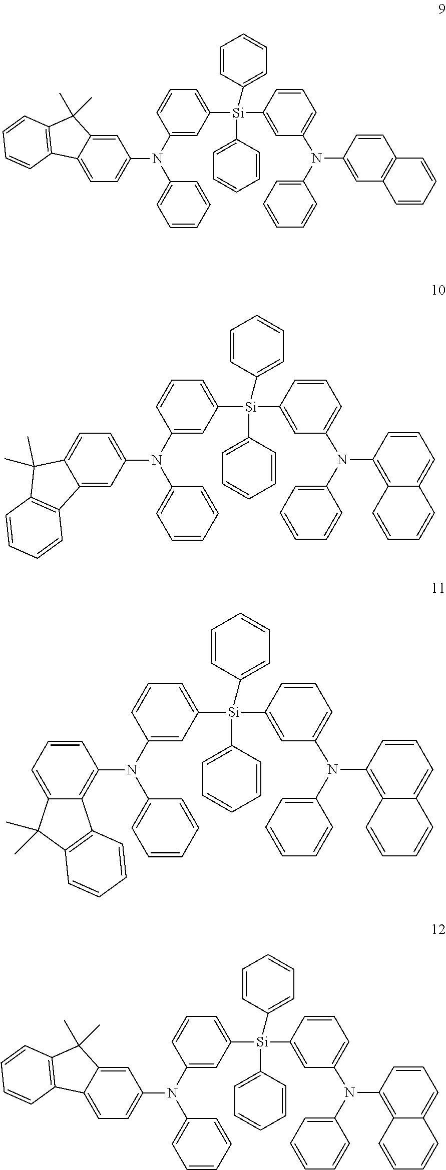 [SMILES: CC1(C)c2ccccc2-c2ccc(N(c3ccccc3)c3cccc([Si](c4ccccc4)(c4ccccc4)c4cccc(N(c5ccccc5)c5ccc6ccccc6c5)c4)c3)cc21 ; CC1(C)c2ccccc2-c2cc(N(c3ccccc3)c3cccc([Si](c4ccccc4)(c4ccccc4)c4cccc(N(c5ccccc5)c5cccc6ccccc56)c4)c3)ccc21 ; CC1(C)c2ccccc2-c2c(N(c3ccccc3)c3cccc([Si](c4ccccc4)(c4ccccc4)c4cccc(N(c5ccccc5)c5cccc6ccccc56)c4)c3)cccc21 ; CC1(C)c2ccccc2-c2ccc(N(c3ccccc3)c3cccc([Si](c4ccccc4)(c4ccccc4)c4cccc(N(c5ccccc5)c5cccc6ccccc56)c4)c3)cc21]

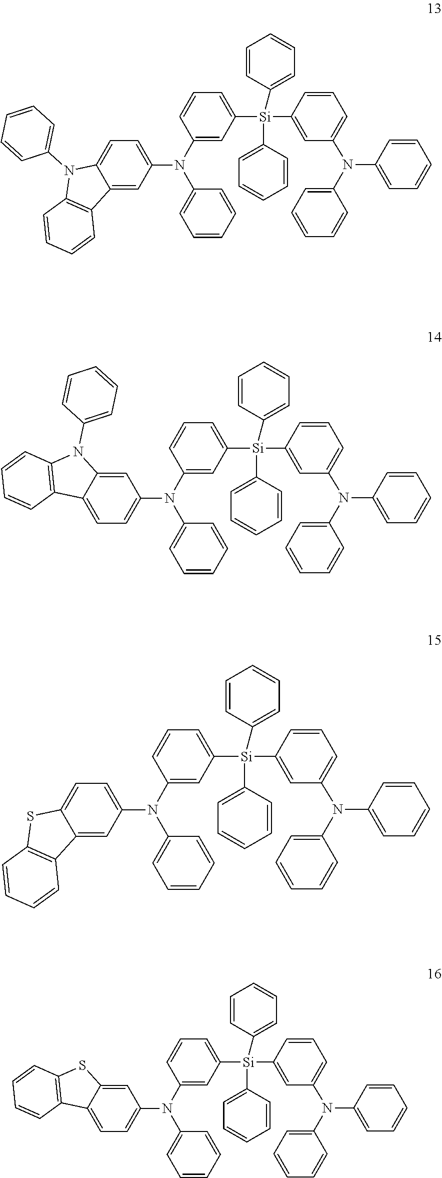 [SMILES: c1ccc(N(c2ccccc2)c2cccc([Si](c3ccccc3)(c3ccccc3)c3cccc(N(c4ccccc4)c4ccc5c(c4)c4ccccc4n5-c4ccccc4)c3)c2)cc1 ; c1ccc(N(c2ccccc2)c2cccc([Si](c3ccccc3)(c3ccccc3)c3cccc(N(c4ccccc4)c4ccc5c6ccccc6n(-c6ccccc6)c5c4)c3)c2)cc1 ; c1ccc(N(c2ccccc2)c2cccc([Si](c3ccccc3)(c3ccccc3)c3cccc(N(c4ccccc4)c4ccc5sc6ccccc6c5c4)c3)c2)cc1 ; c1ccc(N(c2ccccc2)c2cccc([Si](c3ccccc3)(c3ccccc3)c3cccc(N(c4ccccc4)c4ccc5c(c4)sc4ccccc45)c3)c2)cc1]

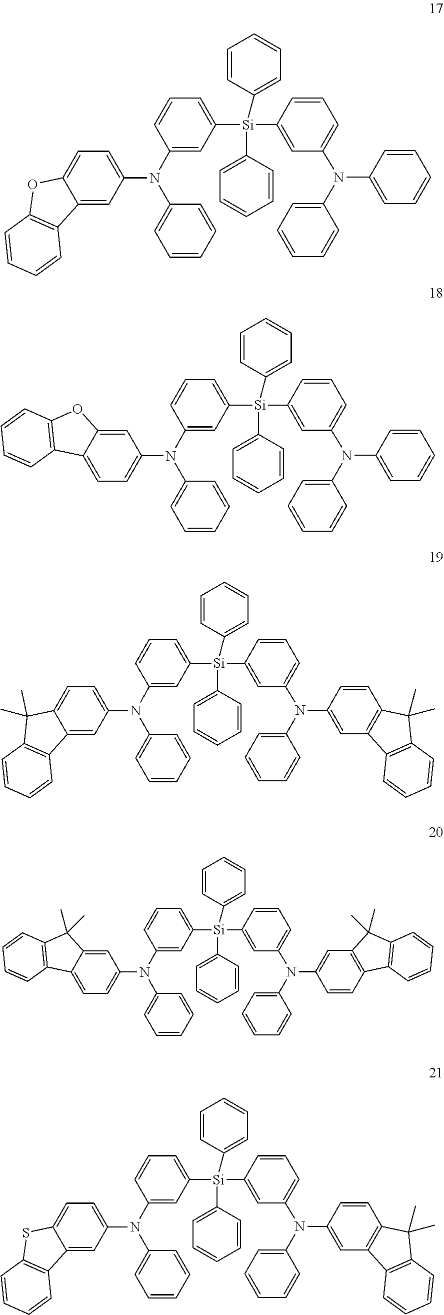

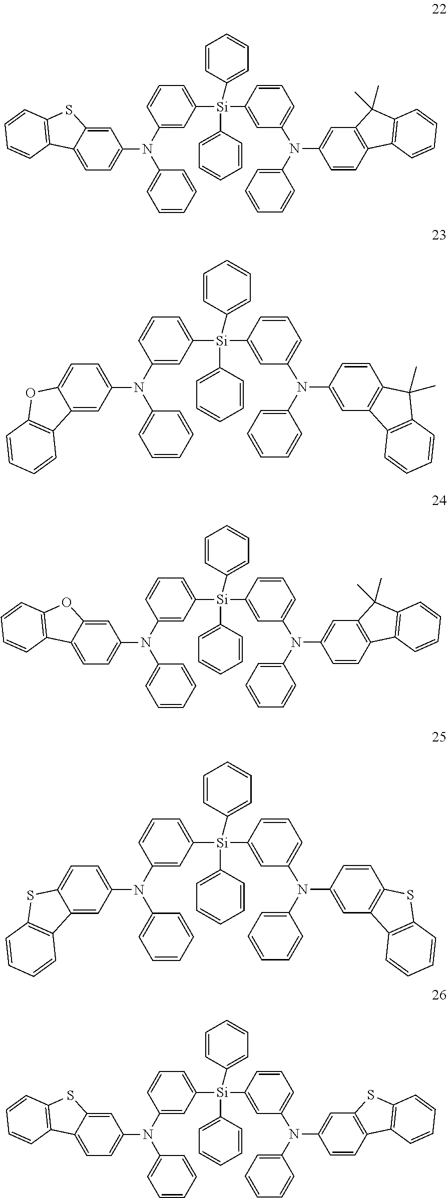

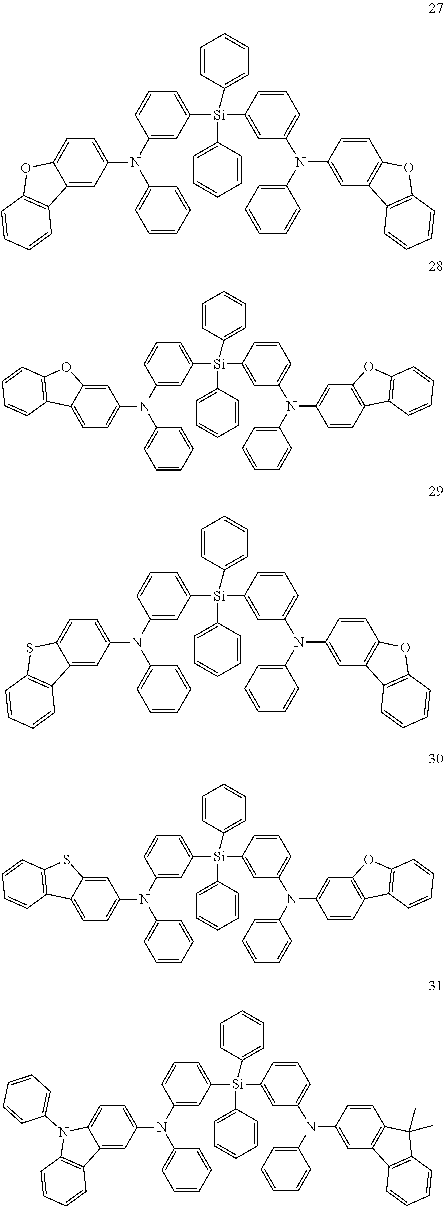

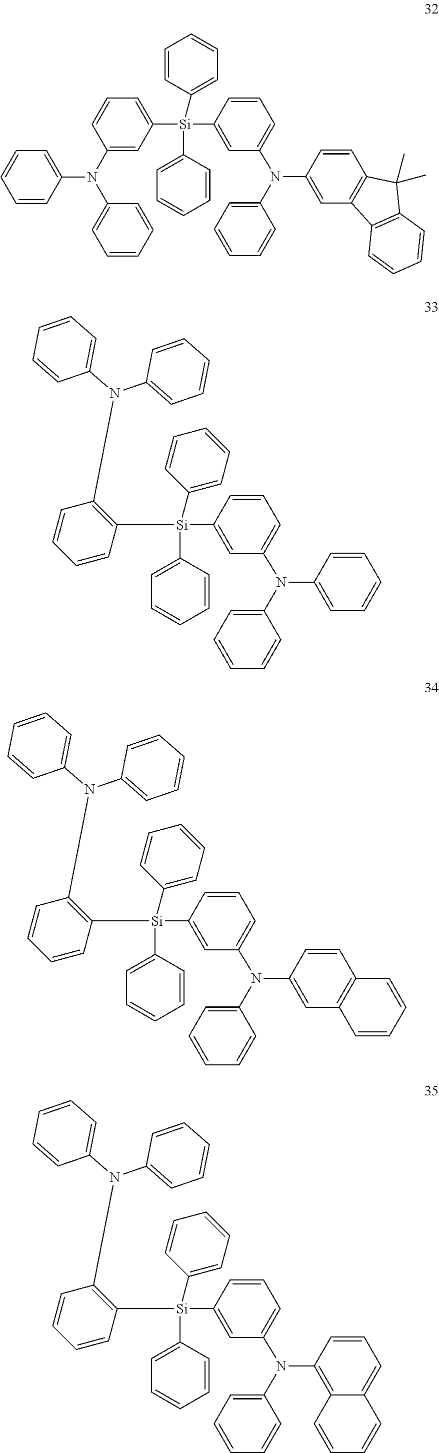 [SMILES: CC1(C)c2ccccc2-c2cc(N(c3ccccc3)c3cccc([Si](c4ccccc4)(c4ccccc4)c4cccc(N(c5ccccc5)c5ccccc5)c4)c3)ccc21 ; c1ccc(N(c2ccccc2)c2cccc([Si](c3ccccc3)(c3ccccc3)c3ccccc3N(c3ccccc3)c3ccccc3)c2)cc1 ; c1ccc(N(c2cccc([Si](c3ccccc3)(c3ccccc3)c3ccccc3N(c3ccccc3)c3ccccc3)c2)c2ccc3ccccc3c2)cc1 ; c1ccc(N(c2ccccc2)c2ccccc2[Si](c2ccccc2)(c2ccccc2)c2cccc(N(c3ccccc3)c3cccc4ccccc34)c2)cc1]

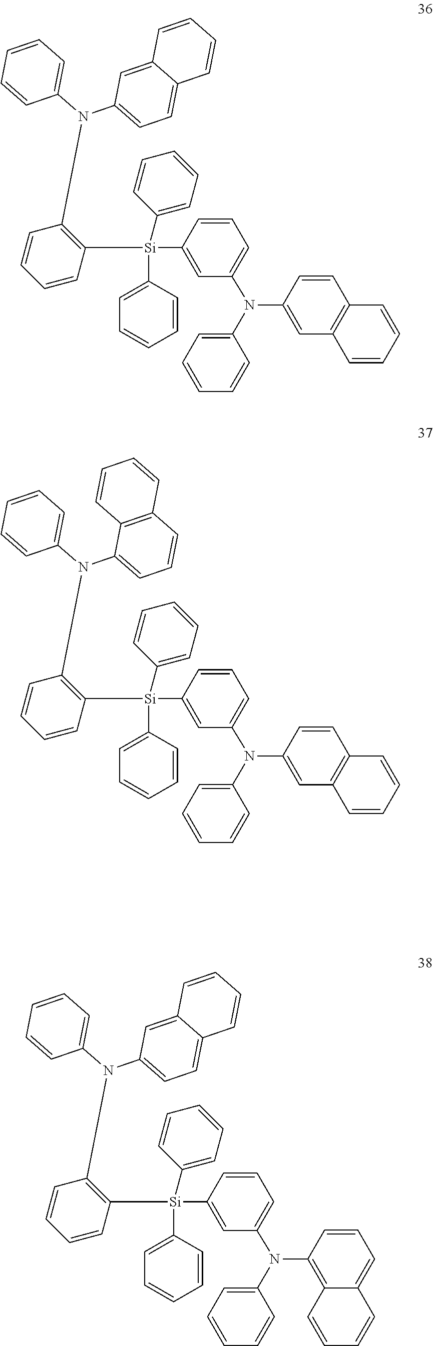 [SMILES: c1ccc(N(c2cccc([Si](c3ccccc3)(c3ccccc3)c3ccccc3N(c3ccccc3)c3ccc4ccccc4c3)c2)c2ccc3ccccc3c2)cc1 ; c1ccc(N(c2cccc([Si](c3ccccc3)(c3ccccc3)c3ccccc3N(c3ccccc3)c3cccc4ccccc34)c2)c2ccc3ccccc3c2)cc1 ; c1ccc(N(c2ccc3ccccc3c2)c2ccccc2[Si](c2ccccc2)(c2ccccc2)c2cccc(N(c3ccccc3)c3cccc4ccccc34)c2)cc1]

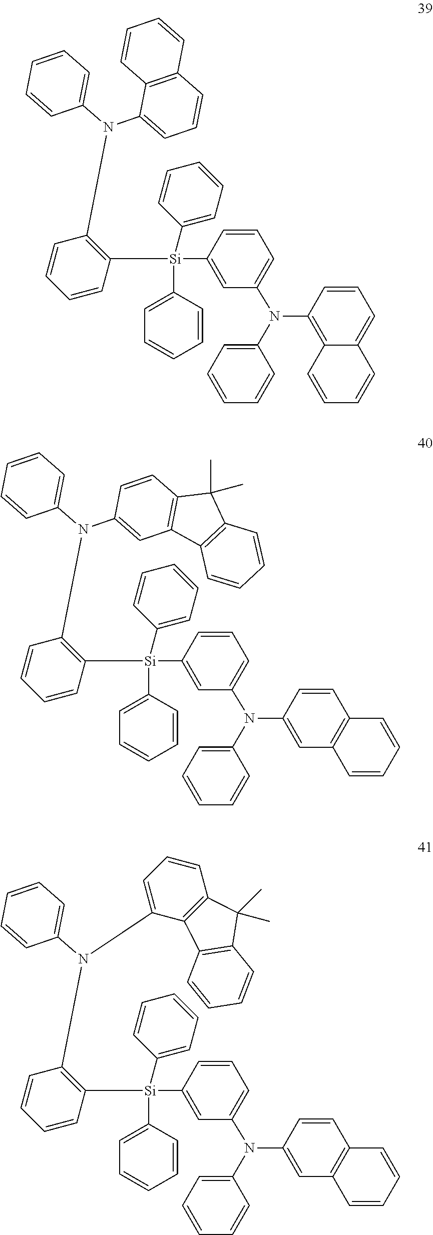 [SMILES: c1ccc(N(c2cccc([Si](c3ccccc3)(c3ccccc3)c3ccccc3N(c3ccccc3)c3cccc4ccccc34)c2)c2cccc3ccccc23)cc1 ; CC1(C)c2ccccc2-c2cc(N(c3ccccc3)c3ccccc3[Si](c3ccccc3)(c3ccccc3)c3cccc(N(c4ccccc4)c4ccc5ccccc5c4)c3)ccc21 ; CC1(C)c2ccccc2-c2c(N(c3ccccc3)c3ccccc3[Si](c3ccccc3)(c3ccccc3)c3cccc(N(c4ccccc4)c4ccc5ccccc5c4)c3)cccc21]

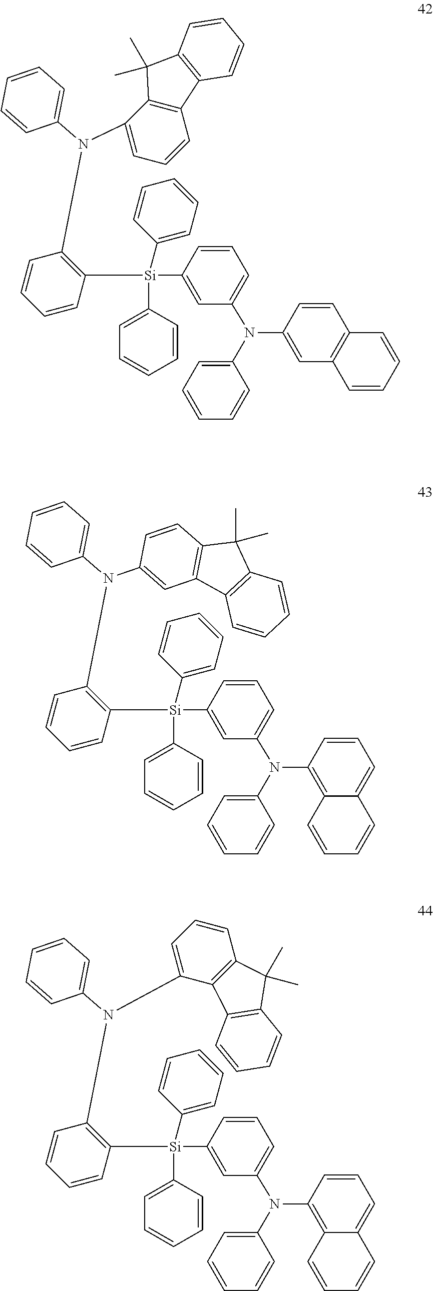 [SMILES: CC1(C)c2ccccc2-c2cccc(N(c3ccccc3)c3ccccc3[Si](c3ccccc3)(c3ccccc3)c3cccc(N(c4ccccc4)c4ccc5ccccc5c4)c3)c21 ; CC1(C)c2ccccc2-c2cc(N(c3ccccc3)c3ccccc3[Si](c3ccccc3)(c3ccccc3)c3cccc(N(c4ccccc4)c4cccc5ccccc45)c3)ccc21 ; CC1(C)c2ccccc2-c2c(N(c3ccccc3)c3ccccc3[Si](c3ccccc3)(c3ccccc3)c3cccc(N(c4ccccc4)c4cccc5ccccc45)c3)cccc21]

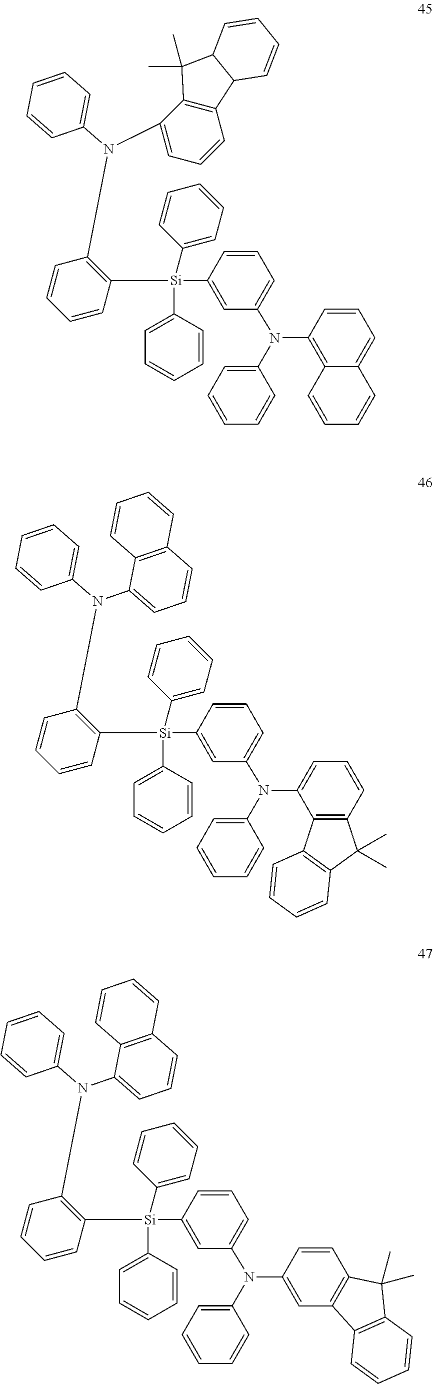 [SMILES: CC1(C)c2c(cccc2N(c2ccccc2)c2ccccc2[Si](c2ccccc2)(c2ccccc2)c2cccc(N(c3ccccc3)c3cccc4ccccc34)c2)C2C=CC=CC21 ; CC1(C)c2ccccc2-c2c(N(c3ccccc3)c3cccc([Si](c4ccccc4)(c4ccccc4)c4ccccc4N(c4ccccc4)c4cccc5ccccc45)c3)cccc21 ; CC1(C)c2ccccc2-c2cc(N(c3ccccc3)c3cccc([Si](c4ccccc4)(c4ccccc4)c4ccccc4N(c4ccccc4)c4cccc5ccccc45)c3)ccc21]

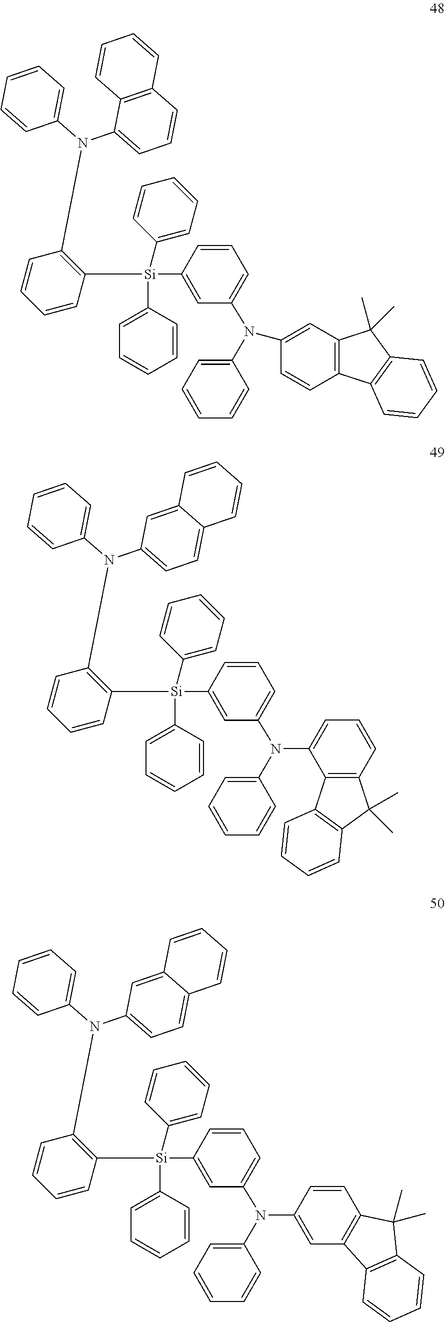

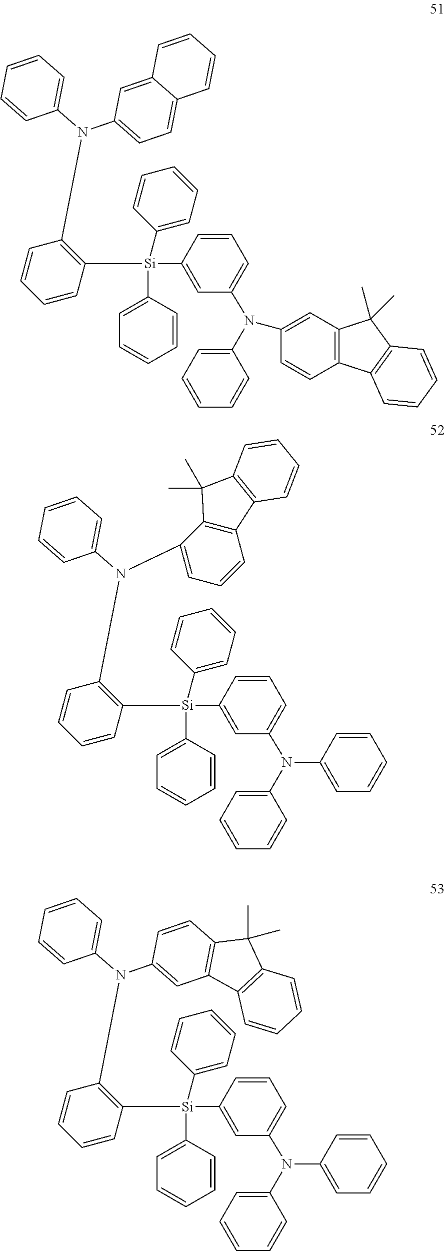

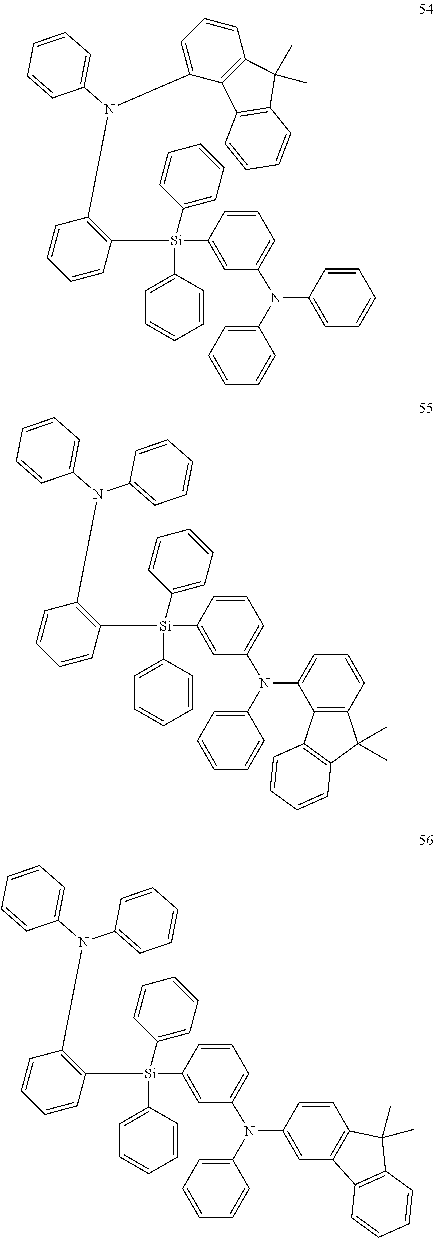 [SMILES: CC1(C)c2ccccc2-c2c(N(c3ccccc3)c3ccccc3[Si](c3ccccc3)(c3ccccc3)c3cccc(N(c4ccccc4)c4ccccc4)c3)cccc21 ; CC1(C)c2ccccc2-c2c(N(c3ccccc3)c3cccc([Si](c4ccccc4)(c4ccccc4)c4ccccc4N(c4ccccc4)c4ccccc4)c3)cccc21 ; CC1(C)c2ccccc2-c2cc(N(c3ccccc3)c3cccc([Si](c4ccccc4)(c4ccccc4)c4ccccc4N(c4ccccc4)c4ccccc4)c3)ccc21]

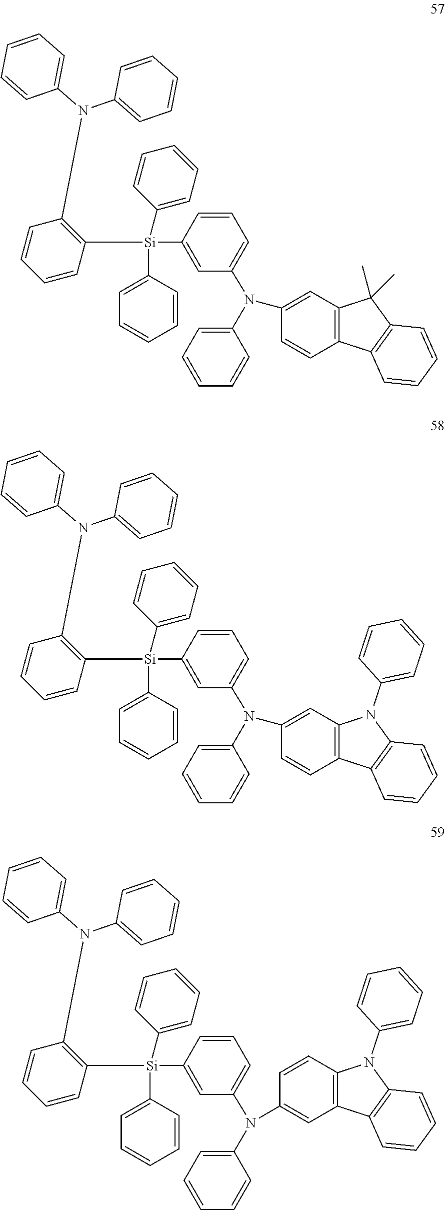 [SMILES: CC1(C)c2ccccc2-c2ccc(N(c3ccccc3)c3cccc([Si](c4ccccc4)(c4ccccc4)c4ccccc4N(c4ccccc4)c4ccccc4)c3)cc21 ; c1ccc(N(c2cccc([Si](c3ccccc3)(c3ccccc3)c3ccccc3N(c3ccccc3)c3ccccc3)c2)c2ccc3c4ccccc4n(-c4ccccc4)c3c2)cc1 ; c1ccc(N(c2cccc([Si](c3ccccc3)(c3ccccc3)c3ccccc3N(c3ccccc3)c3ccccc3)c2)c2ccc3c(c2)c2ccccc2n3-c2ccccc2)cc1]

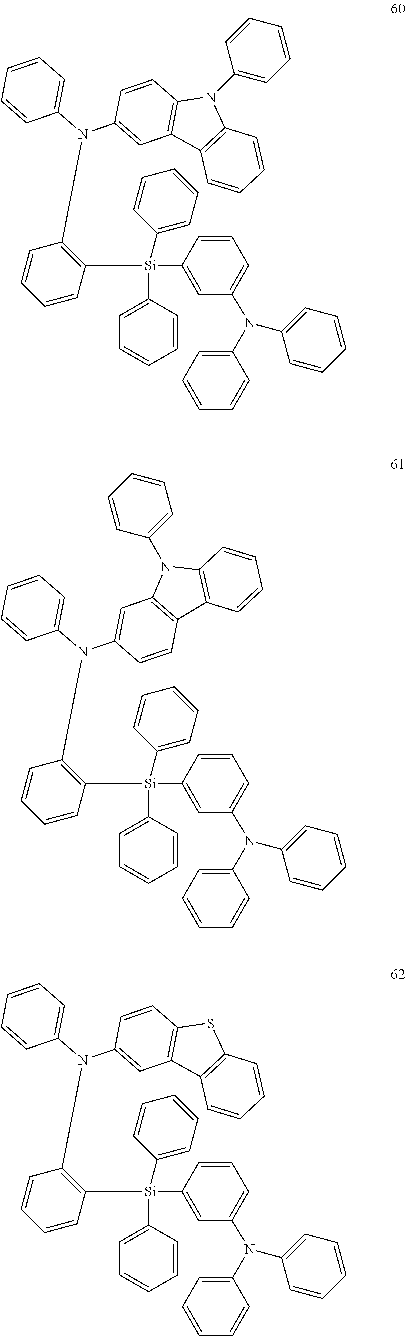 [SMILES: c1ccc(N(c2ccccc2)c2cccc([Si](c3ccccc3)(c3ccccc3)c3ccccc3N(c3ccccc3)c3ccc4c(c3)c3ccccc3n4-c3ccccc3)c2)cc1 ; c1ccc(N(c2ccccc2)c2cccc([Si](c3ccccc3)(c3ccccc3)c3ccccc3N(c3ccccc3)c3ccc4c5ccccc5n(-c5ccccc5)c4c3)c2)cc1 ; c1ccc(N(c2ccccc2)c2cccc([Si](c3ccccc3)(c3ccccc3)c3ccccc3N(c3ccccc3)c3ccc4sc5ccccc5c4c3)c2)cc1]

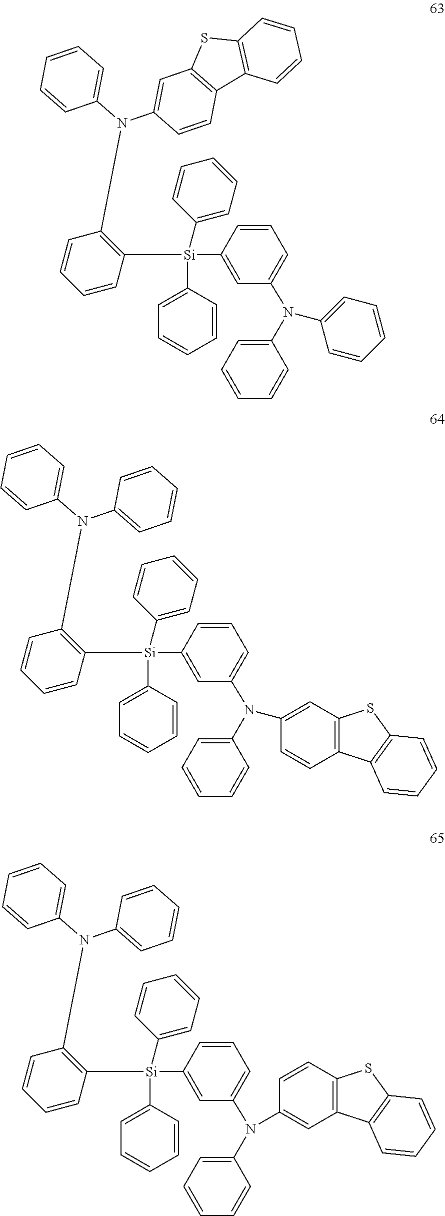 [SMILES: c1ccc(N(c2ccccc2)c2cccc([Si](c3ccccc3)(c3ccccc3)c3ccccc3N(c3ccccc3)c3ccc4c(c3)sc3ccccc34)c2)cc1 ; c1ccc(N(c2cccc([Si](c3ccccc3)(c3ccccc3)c3ccccc3N(c3ccccc3)c3ccccc3)c2)c2ccc3c(c2)sc2ccccc23)cc1 ; c1ccc(N(c2cccc([Si](c3ccccc3)(c3ccccc3)c3ccccc3N(c3ccccc3)c3ccccc3)c2)c2ccc3sc4ccccc4c3c2)cc1]

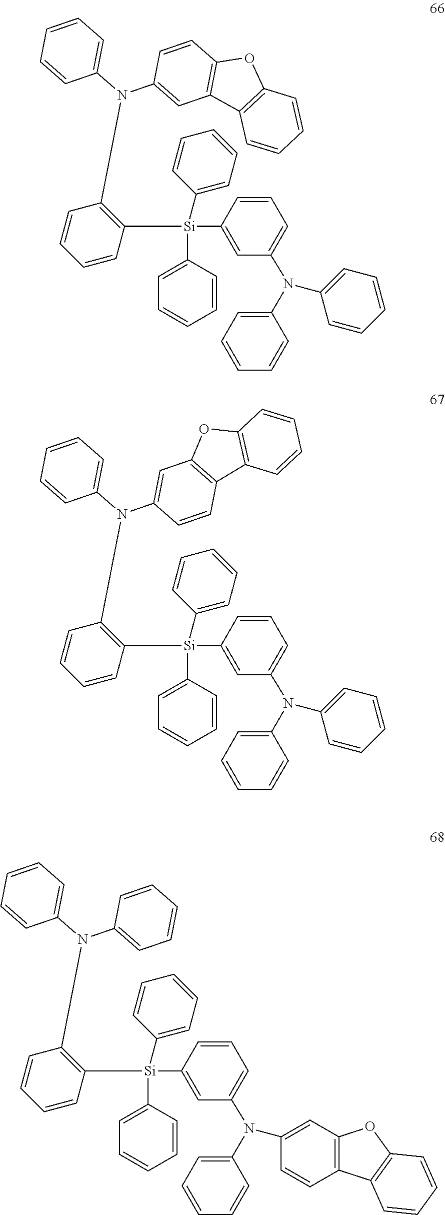

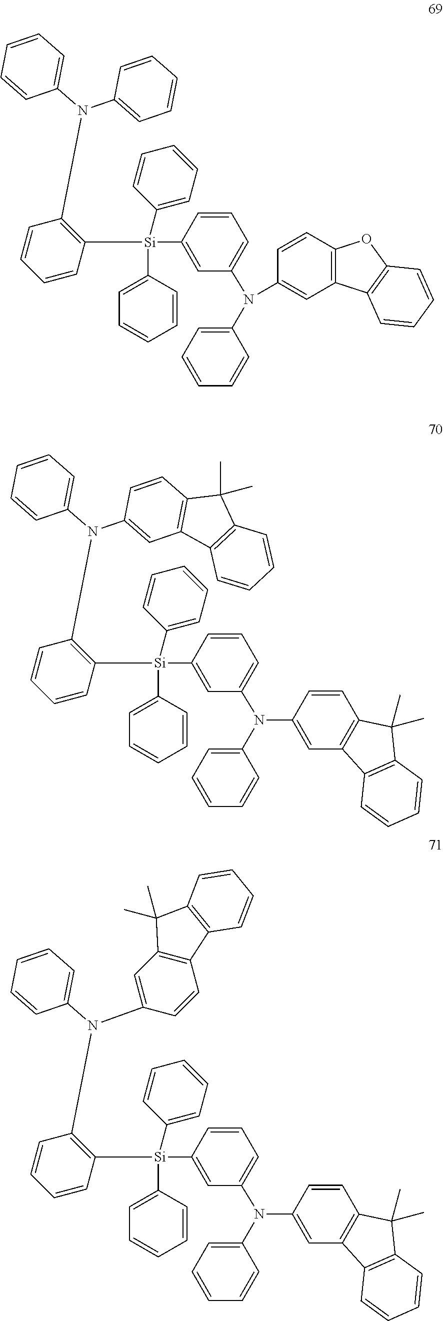 [SMILES: c1ccc(N(c2cccc([Si](c3ccccc3)(c3ccccc3)c3ccccc3N(c3ccccc3)c3ccccc3)c2)c2ccc3oc4ccccc4c3c2)cc1 ; CC1(C)c2ccccc2-c2cc(N(c3ccccc3)c3cccc([Si](c4ccccc4)(c4ccccc4)c4ccccc4N(c4ccccc4)c4ccc5c(c4)-c4ccccc4C5(C)C)c3)ccc21 ; CC1(C)c2ccccc2-c2cc(N(c3ccccc3)c3cccc([Si](c4ccccc4)(c4ccccc4)c4ccccc4N(c4ccccc4)c4ccc5c(c4)C(C)(C)c4ccccc4-5)c3)ccc21]

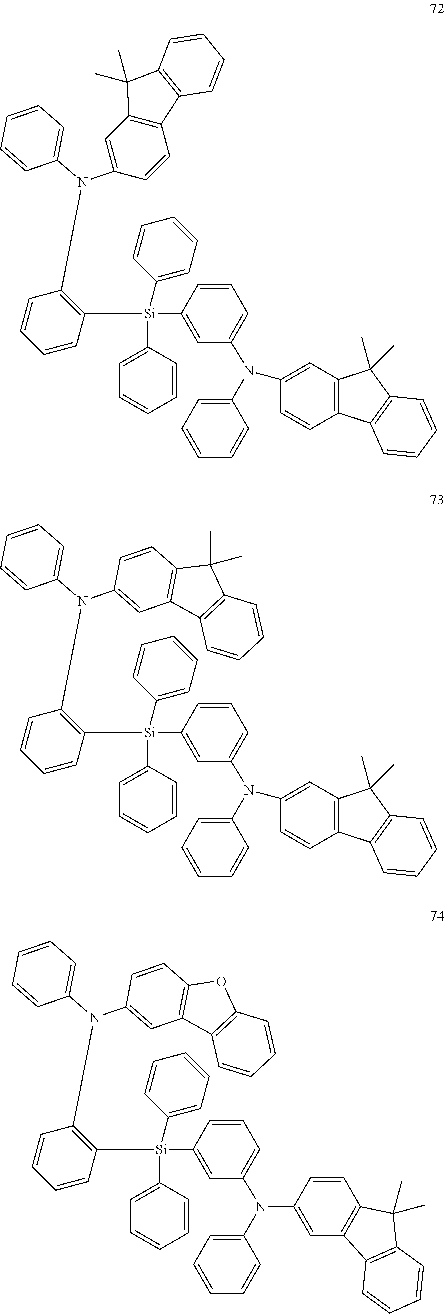 [SMILES: CC1(C)c2ccccc2-c2ccc(N(c3ccccc3)c3cccc([Si](c4ccccc4)(c4ccccc4)c4ccccc4N(c4ccccc4)c4ccc5c(c4)C(C)(C)c4ccccc4-5)c3)cc21 ; CC1(C)c2ccccc2-c2cc(N(c3ccccc3)c3ccccc3[Si](c3ccccc3)(c3ccccc3)c3cccc(N(c4ccccc4)c4ccc5c(c4)C(C)(C)c4ccccc4-5)c3)ccc21 ; CC1(C)c2ccccc2-c2cc(N(c3ccccc3)c3cccc([Si](c4ccccc4)(c4ccccc4)c4ccccc4N(c4ccccc4)c4ccc5oc6ccccc6c5c4)c3)ccc21]

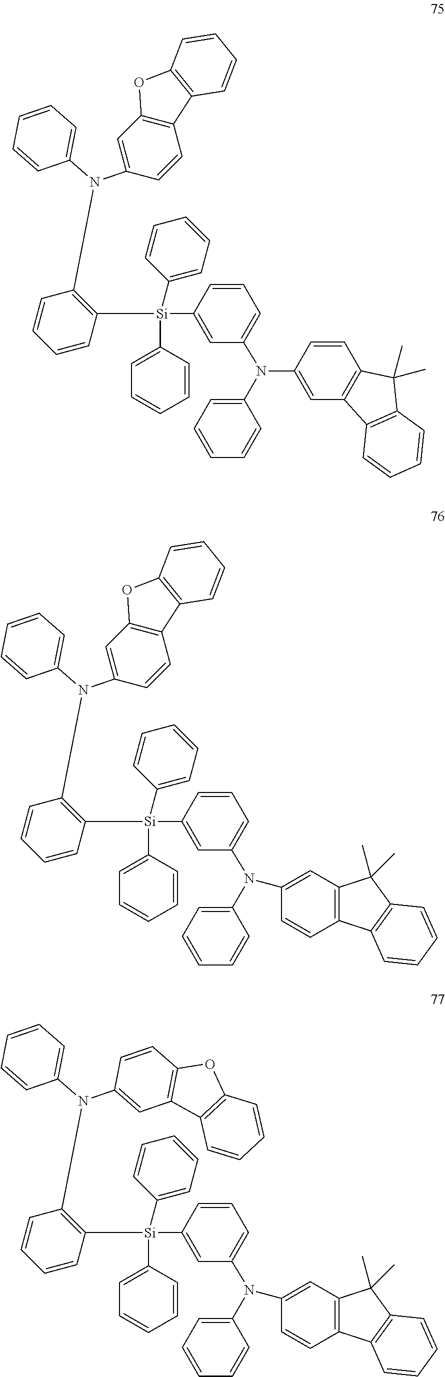 [SMILES: CC1(C)c2ccccc2-c2cc(N(c3ccccc3)c3cccc([Si](c4ccccc4)(c4ccccc4)c4ccccc4N(c4ccccc4)c4ccc5c(c4)oc4ccccc45)c3)ccc21 ; CC1(C)c2ccccc2-c2ccc(N(c3ccccc3)c3cccc([Si](c4ccccc4)(c4ccccc4)c4ccccc4N(c4ccccc4)c4ccc5c(c4)oc4ccccc45)c3)cc21 ; CC1(C)c2ccccc2-c2ccc(N(c3ccccc3)c3cccc([Si](c4ccccc4)(c4ccccc4)c4ccccc4N(c4ccccc4)c4ccc5oc6ccccc6c5c4)c3)cc21]

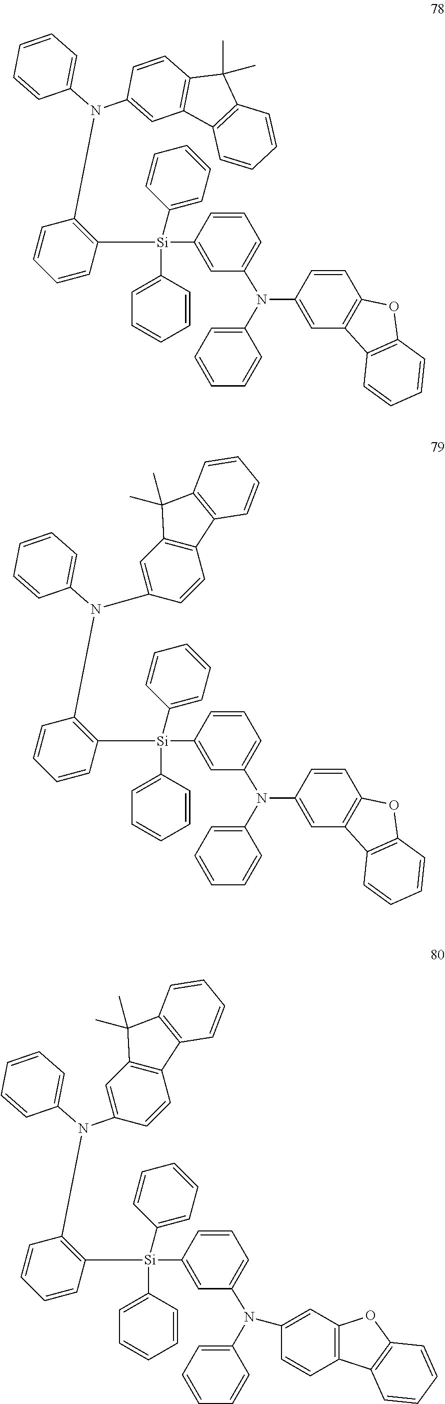 [SMILES: CC1(C)c2ccccc2-c2cc(N(c3ccccc3)c3ccccc3[Si](c3ccccc3)(c3ccccc3)c3cccc(N(c4ccccc4)c4ccc5oc6ccccc6c5c4)c3)ccc21 ; CC1(C)c2ccccc2-c2ccc(N(c3ccccc3)c3ccccc3[Si](c3ccccc3)(c3ccccc3)c3cccc(N(c4ccccc4)c4ccc5oc6ccccc6c5c4)c3)cc21 ; CC1(C)c2ccccc2-c2ccc(N(c3ccccc3)c3ccccc3[Si](c3ccccc3)(c3ccccc3)c3cccc(N(c4ccccc4)c4ccc5c(c4)oc4ccccc45)c3)cc21]

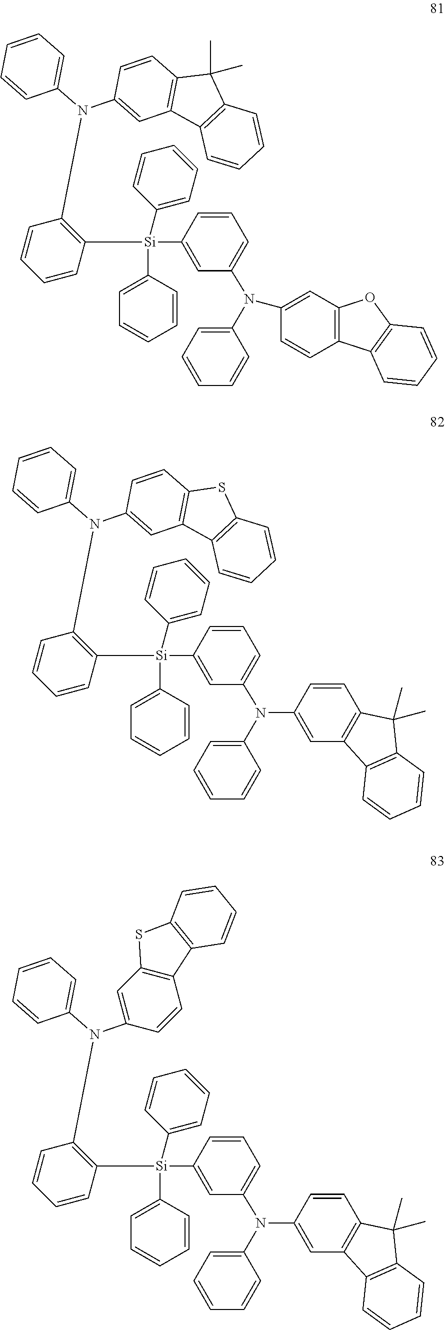 [SMILES: CC1(C)c2ccccc2-c2cc(N(c3ccccc3)c3ccccc3[Si](c3ccccc3)(c3ccccc3)c3cccc(N(c4ccccc4)c4ccc5c(c4)oc4ccccc45)c3)ccc21 ; CC1(C)c2ccccc2-c2cc(N(c3ccccc3)c3cccc([Si](c4ccccc4)(c4ccccc4)c4ccccc4N(c4ccccc4)c4ccc5sc6ccccc6c5c4)c3)ccc21 ; CC1(C)c2ccccc2-c2cc(N(c3ccccc3)c3cccc([Si](c4ccccc4)(c4ccccc4)c4ccccc4N(c4ccccc4)c4ccc5c(c4)sc4ccccc45)c3)ccc21]

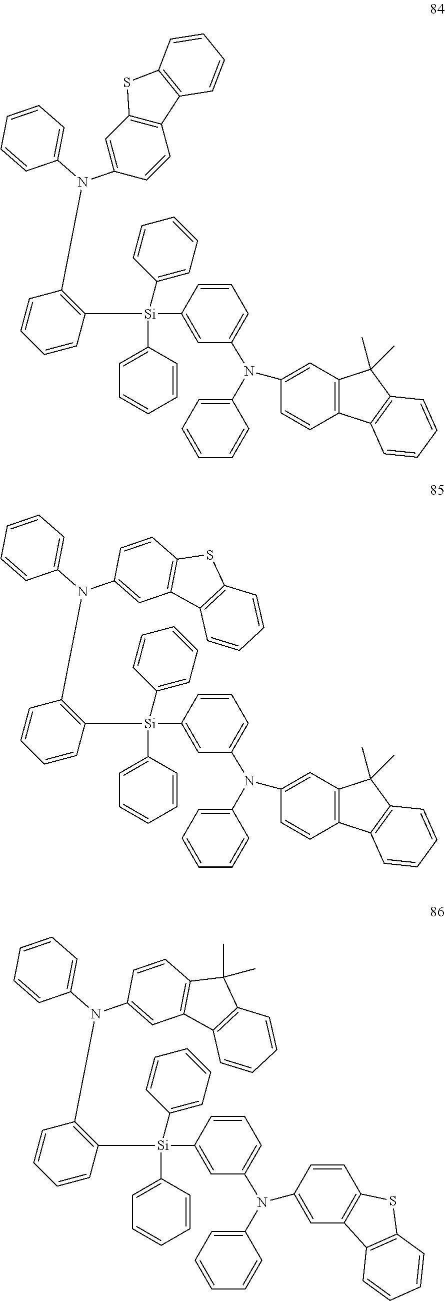 [SMILES: CC1(C)c2ccccc2-c2ccc(N(c3ccccc3)c3cccc([Si](c4ccccc4)(c4ccccc4)c4ccccc4N(c4ccccc4)c4ccc5c(c4)sc4ccccc45)c3)cc21 ; CC1(C)c2ccccc2-c2ccc(N(c3ccccc3)c3cccc([Si](c4ccccc4)(c4ccccc4)c4ccccc4N(c4ccccc4)c4ccc5sc6ccccc6c5c4)c3)cc21 ; CC1(C)c2ccccc2-c2cc(N(c3ccccc3)c3ccccc3[Si](c3ccccc3)(c3ccccc3)c3cccc(N(c4ccccc4)c4ccc5sc6ccccc6c5c4)c3)ccc21]

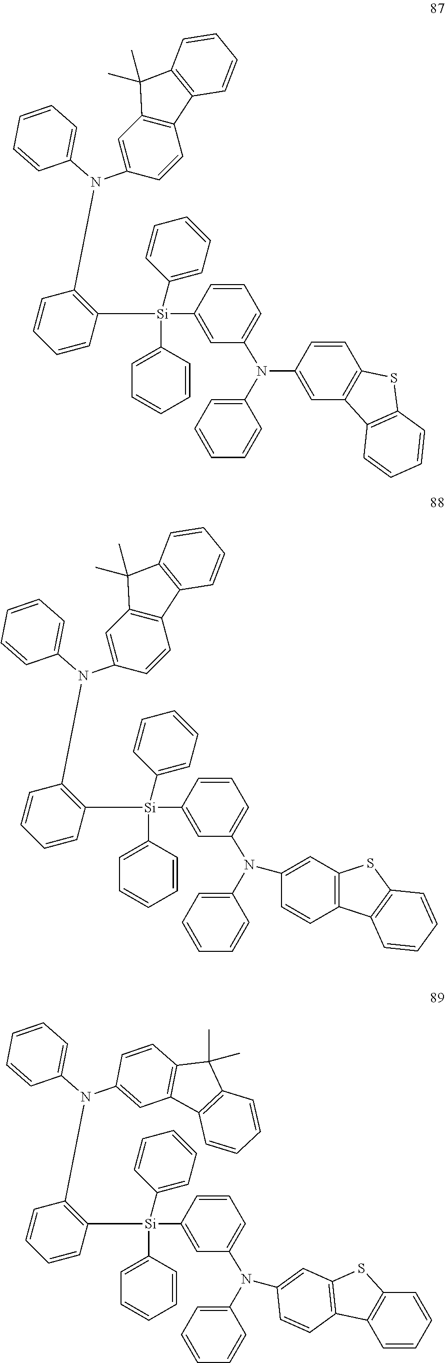 [SMILES: CC1(C)c2ccccc2-c2ccc(N(c3ccccc3)c3ccccc3[Si](c3ccccc3)(c3ccccc3)c3cccc(N(c4ccccc4)c4ccc5sc6ccccc6c5c4)c3)cc21 ; CC1(C)c2ccccc2-c2ccc(N(c3ccccc3)c3ccccc3[Si](c3ccccc3)(c3ccccc3)c3cccc(N(c4ccccc4)c4ccc5c(c4)sc4ccccc45)c3)cc21 ; CC1(C)c2ccccc2-c2cc(N(c3ccccc3)c3ccccc3[Si](c3ccccc3)(c3ccccc3)c3cccc(N(c4ccccc4)c4ccc5c(c4)sc4ccccc45)c3)ccc21]

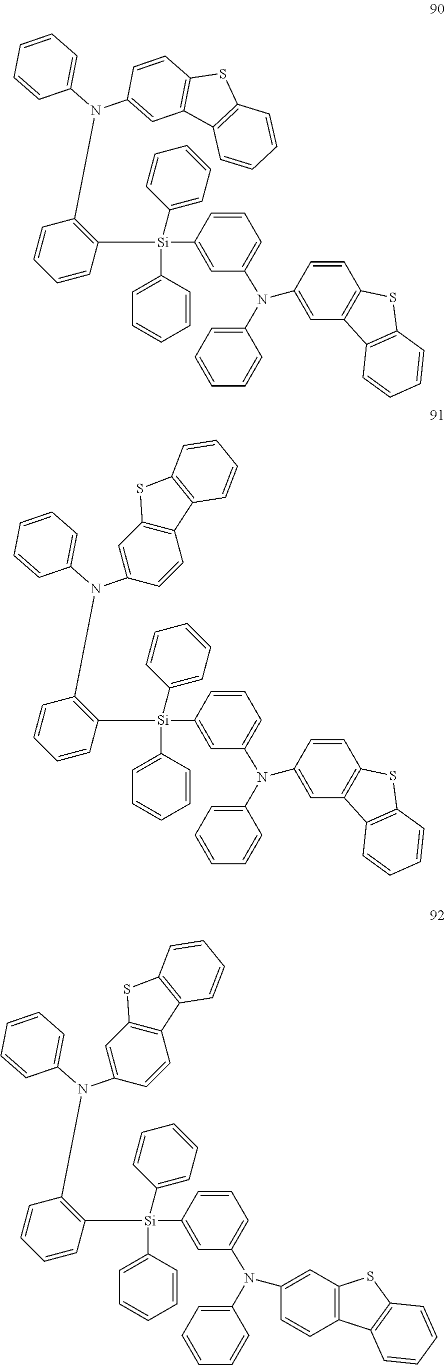 [SMILES: c1ccc(N(c2cccc([Si](c3ccccc3)(c3ccccc3)c3ccccc3N(c3ccccc3)c3ccc4sc5ccccc5c4c3)c2)c2ccc3sc4ccccc4c3c2)cc1 ; c1ccc(N(c2cccc([Si](c3ccccc3)(c3ccccc3)c3ccccc3N(c3ccccc3)c3ccc4c(c3)sc3ccccc34)c2)c2ccc3sc4ccccc4c3c2)cc1 ; c1ccc(N(c2cccc([Si](c3ccccc3)(c3ccccc3)c3ccccc3N(c3ccccc3)c3ccc4c(c3)sc3ccccc34)c2)c2ccc3c(c2)sc2ccccc23)cc1]

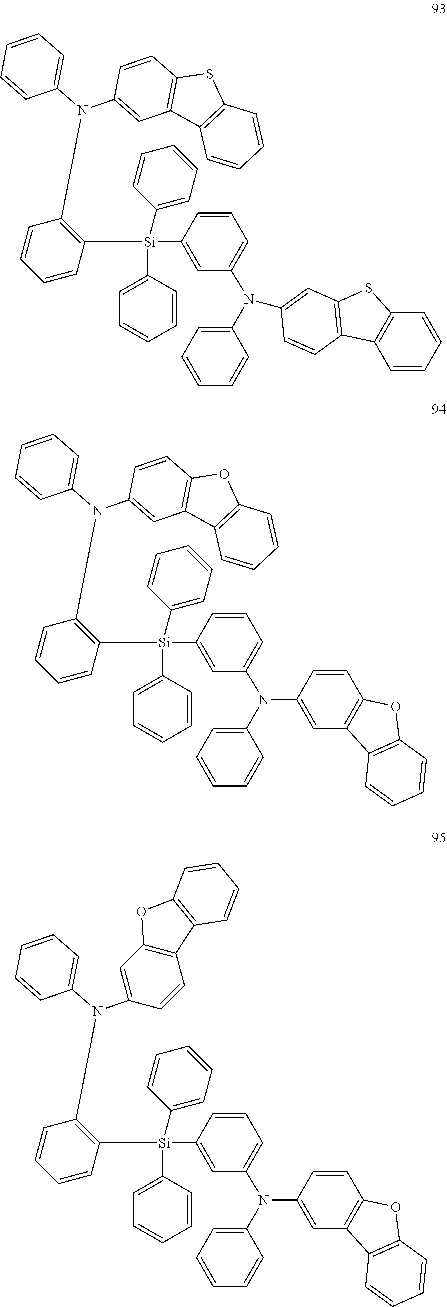 [SMILES: c1ccc(N(c2cccc([Si](c3ccccc3)(c3ccccc3)c3ccccc3N(c3ccccc3)c3ccc4sc5ccccc5c4c3)c2)c2ccc3c(c2)sc2ccccc23)cc1 ; c1ccc(N(c2cccc([Si](c3ccccc3)(c3ccccc3)c3ccccc3N(c3ccccc3)c3ccc4oc5ccccc5c4c3)c2)c2ccc3oc4ccccc4c3c2)cc1 ; c1ccc(N(c2cccc([Si](c3ccccc3)(c3ccccc3)c3ccccc3N(c3ccccc3)c3ccc4c(c3)oc3ccccc34)c2)c2ccc3oc4ccccc4c3c2)cc1]

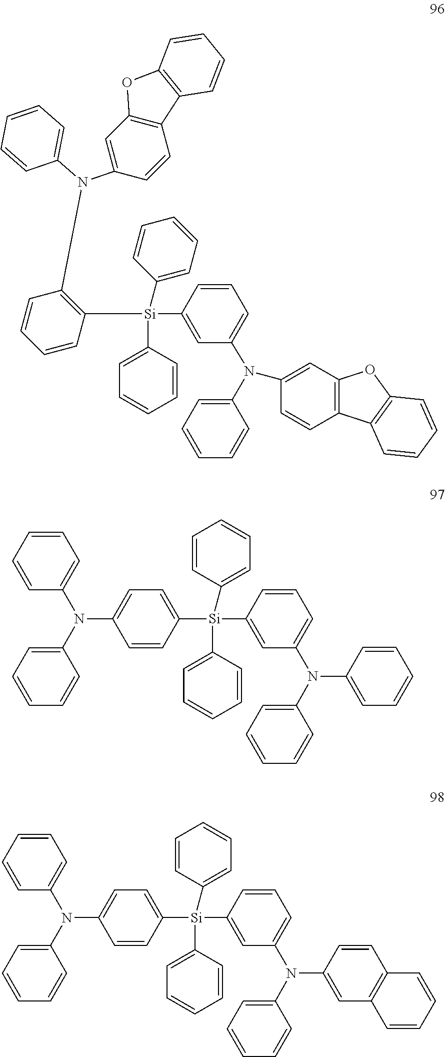 [SMILES: c1ccc(N(c2cccc([Si](c3ccccc3)(c3ccccc3)c3ccccc3N(c3ccccc3)c3ccc4c(c3)oc3ccccc34)c2)c2ccc3c(c2)oc2ccccc23)cc1 ; c1ccc(N(c2ccccc2)c2ccc([Si](c3ccccc3)(c3ccccc3)c3cccc(N(c4ccccc4)c4ccccc4)c3)cc2)cc1 ; c1ccc(N(c2ccccc2)c2ccc([Si](c3ccccc3)(c3ccccc3)c3cccc(N(c4ccccc4)c4ccc5ccccc5c4)c3)cc2)cc1]

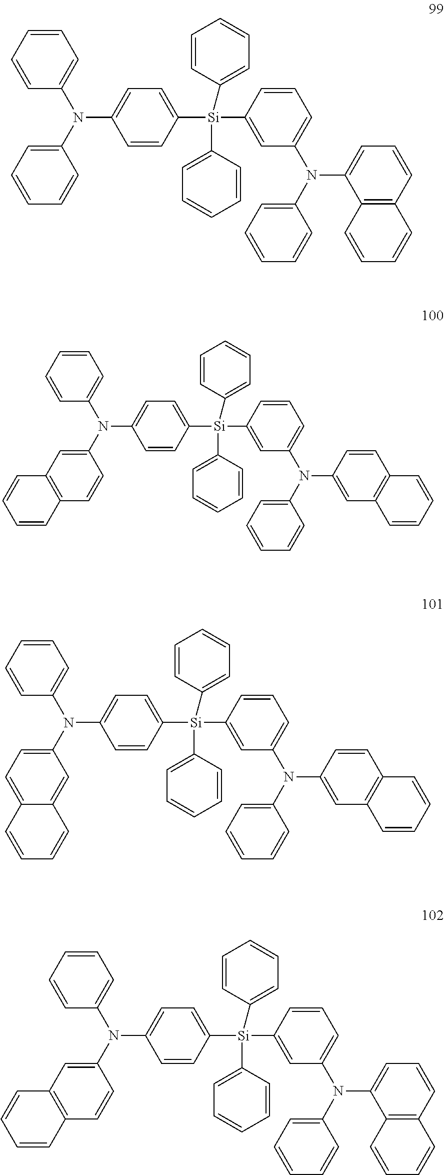 [SMILES: c1ccc(N(c2ccccc2)c2ccc([Si](c3ccccc3)(c3ccccc3)c3cccc(N(c4ccccc4)c4cccc5ccccc45)c3)cc2)cc1 ; c1ccc(N(c2ccc([Si](c3ccccc3)(c3ccccc3)c3cccc(N(c4ccccc4)c4ccc5ccccc5c4)c3)cc2)c2ccc3ccccc3c2)cc1 ; c1ccc(N(c2ccc([Si](c3ccccc3)(c3ccccc3)c3cccc(N(c4ccccc4)c4ccc5ccccc5c4)c3)cc2)c2ccc3ccccc3c2)cc1 ; c1ccc(N(c2ccc([Si](c3ccccc3)(c3ccccc3)c3cccc(N(c4ccccc4)c4cccc5ccccc45)c3)cc2)c2ccc3ccccc3c2)cc1]

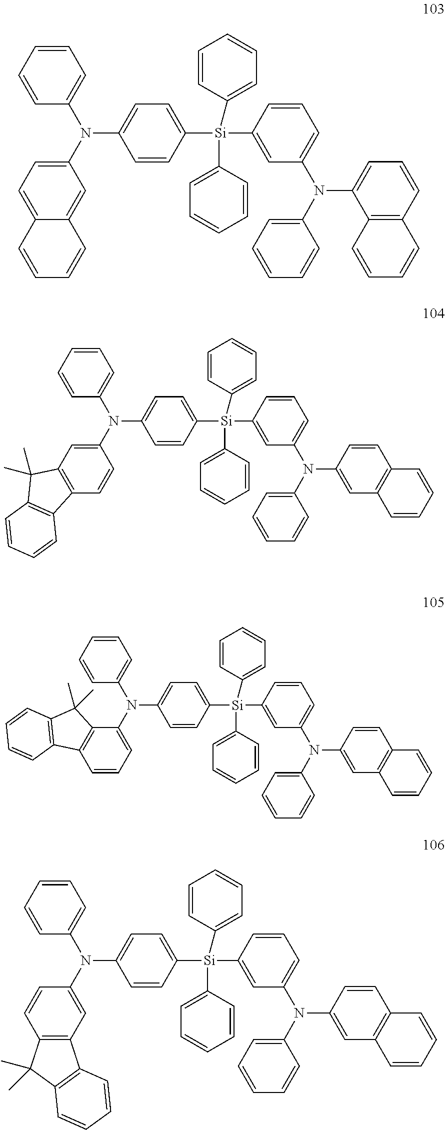 [SMILES: c1ccc(N(c2ccc([Si](c3ccccc3)(c3ccccc3)c3cccc(N(c4ccccc4)c4cccc5ccccc45)c3)cc2)c2ccc3ccccc3c2)cc1 ; CC1(C)c2ccccc2-c2ccc(N(c3ccccc3)c3ccc([Si](c4ccccc4)(c4ccccc4)c4cccc(N(c5ccccc5)c5ccc6ccccc6c5)c4)cc3)cc21 ; CC1(C)c2ccccc2-c2cccc(N(c3ccccc3)c3ccc([Si](c4ccccc4)(c4ccccc4)c4cccc(N(c5ccccc5)c5ccc6ccccc6c5)c4)cc3)c21 ; CC1(C)c2ccccc2-c2cc(N(c3ccccc3)c3ccc([Si](c4ccccc4)(c4ccccc4)c4cccc(N(c5ccccc5)c5ccc6ccccc6c5)c4)cc3)ccc21]

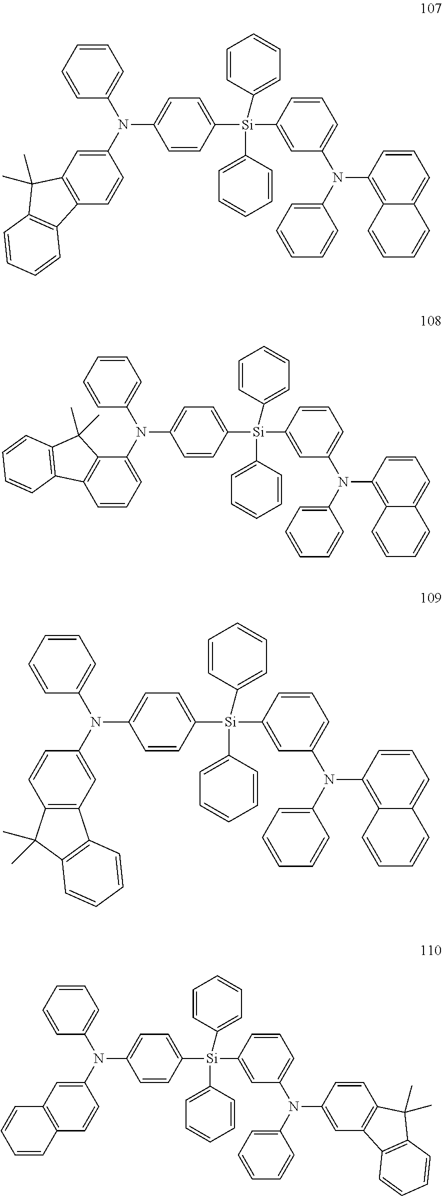 [SMILES: CC1(C)c2ccccc2-c2ccc(N(c3ccccc3)c3ccc([Si](c4ccccc4)(c4ccccc4)c4cccc(N(c5ccccc5)c5cccc6ccccc56)c4)cc3)cc21 ; CC1(C)c2ccccc2-c2cccc(N(c3ccccc3)c3ccc([Si](c4ccccc4)(c4ccccc4)c4cccc(N(c5ccccc5)c5cccc6ccccc56)c4)cc3)c21 ; CC1(C)c2ccccc2-c2cc(N(c3ccccc3)c3ccc([Si](c4ccccc4)(c4ccccc4)c4cccc(N(c5ccccc5)c5cccc6ccccc56)c4)cc3)ccc21 ; CC1(C)c2ccccc2-c2cc(N(c3ccccc3)c3cccc([Si](c4ccccc4)(c4ccccc4)c4ccc(N(c5ccccc5)c5ccc6ccccc6c5)cc4)c3)ccc21]

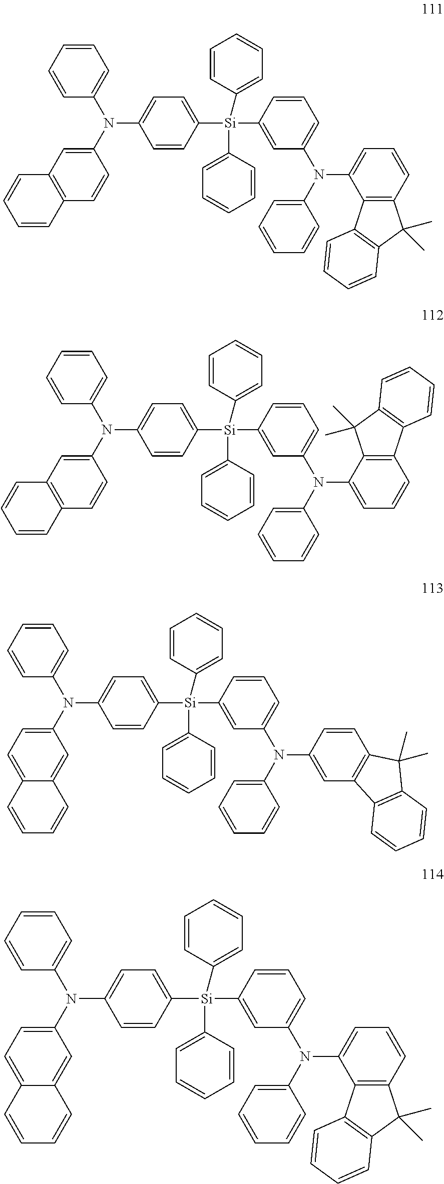 [SMILES: CC1(C)c2ccccc2-c2c(N(c3ccccc3)c3cccc([Si](c4ccccc4)(c4ccccc4)c4ccc(N(c5ccccc5)c5ccc6ccccc6c5)cc4)c3)cccc21 ; CC1(C)c2ccccc2-c2cccc(N(c3ccccc3)c3cccc([Si](c4ccccc4)(c4ccccc4)c4ccc(N(c5ccccc5)c5ccc6ccccc6c5)cc4)c3)c21 ; CC1(C)c2ccccc2-c2cc(N(c3ccccc3)c3cccc([Si](c4ccccc4)(c4ccccc4)c4ccc(N(c5ccccc5)c5ccc6ccccc6c5)cc4)c3)ccc21 ; CC1(C)c2ccccc2-c2c(N(c3ccccc3)c3cccc([Si](c4ccccc4)(c4ccccc4)c4ccc(N(c5ccccc5)c5ccc6ccccc6c5)cc4)c3)cccc21]

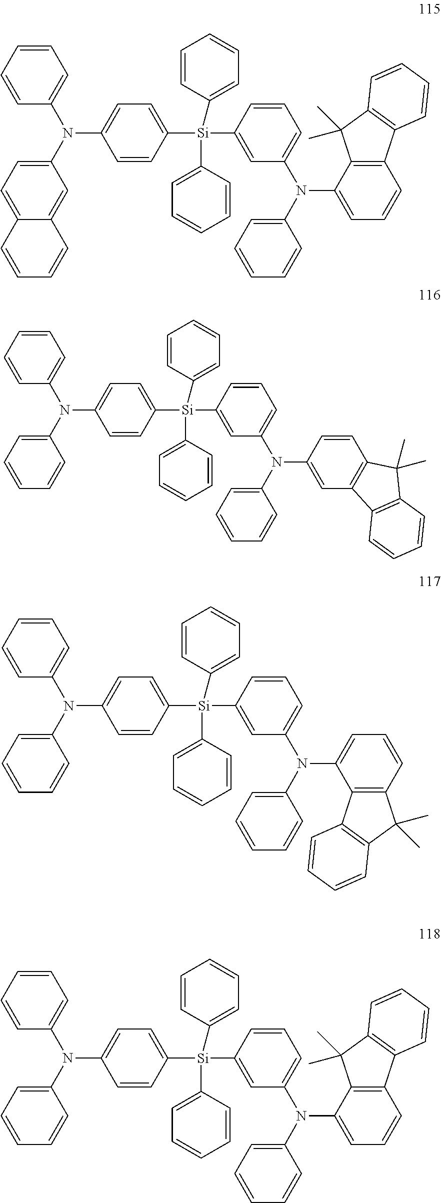 [SMILES: CC1(C)c2ccccc2-c2cccc(N(c3ccccc3)c3cccc([Si](c4ccccc4)(c4ccccc4)c4ccc(N(c5ccccc5)c5ccc6ccccc6c5)cc4)c3)c21 ; CC1(C)c2ccccc2-c2cc(N(c3ccccc3)c3cccc([Si](c4ccccc4)(c4ccccc4)c4ccc(N(c5ccccc5)c5ccccc5)cc4)c3)ccc21 ; CC1(C)c2ccccc2-c2c(N(c3ccccc3)c3cccc([Si](c4ccccc4)(c4ccccc4)c4ccc(N(c5ccccc5)c5ccccc5)cc4)c3)cccc21 ; CC1(C)c2ccccc2-c2cccc(N(c3ccccc3)c3cccc([Si](c4ccccc4)(c4ccccc4)c4ccc(N(c5ccccc5)c5ccccc5)cc4)c3)c21]

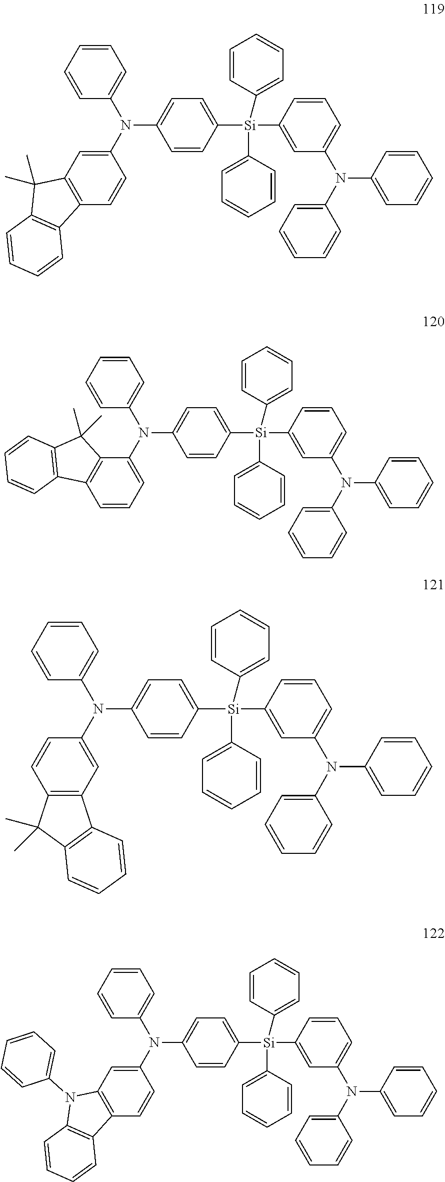 [SMILES: CC1(C)c2ccccc2-c2ccc(N(c3ccccc3)c3ccc([Si](c4ccccc4)(c4ccccc4)c4cccc(N(c5ccccc5)c5ccccc5)c4)cc3)cc21 ; CC1(C)c2ccccc2-c2cccc(N(c3ccccc3)c3ccc([Si](c4ccccc4)(c4ccccc4)c4cccc(N(c5ccccc5)c5ccccc5)c4)cc3)c21 ; CC1(C)c2ccccc2-c2cc(N(c3ccccc3)c3ccc([Si](c4ccccc4)(c4ccccc4)c4cccc(N(c5ccccc5)c5ccccc5)c4)cc3)ccc21 ; c1ccc(N(c2ccccc2)c2cccc([Si](c3ccccc3)(c3ccccc3)c3ccc(N(c4ccccc4)c4ccc5c6ccccc6n(-c6ccccc6)c5c4)cc3)c2)cc1]

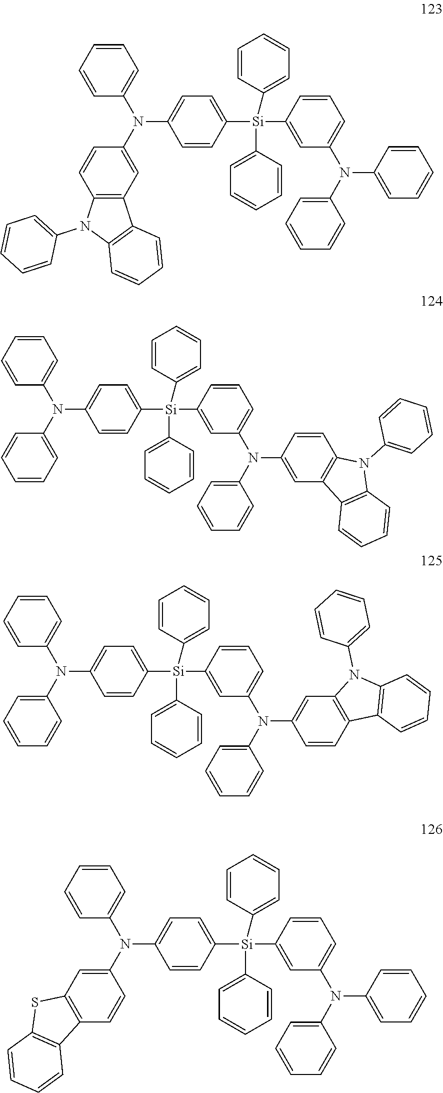 [SMILES: c1ccc(N(c2ccccc2)c2cccc([Si](c3ccccc3)(c3ccccc3)c3ccc(N(c4ccccc4)c4ccc5c(c4)c4ccccc4n5-c4ccccc4)cc3)c2)cc1 ; c1ccc(N(c2ccccc2)c2ccc([Si](c3ccccc3)(c3ccccc3)c3cccc(N(c4ccccc4)c4ccc5c(c4)c4ccccc4n5-c4ccccc4)c3)cc2)cc1 ; c1ccc(N(c2ccccc2)c2ccc([Si](c3ccccc3)(c3ccccc3)c3cccc(N(c4ccccc4)c4ccc5c6ccccc6n(-c6ccccc6)c5c4)c3)cc2)cc1 ; c1ccc(N(c2ccccc2)c2cccc([Si](c3ccccc3)(c3ccccc3)c3ccc(N(c4ccccc4)c4ccc5c(c4)sc4ccccc45)cc3)c2)cc1]

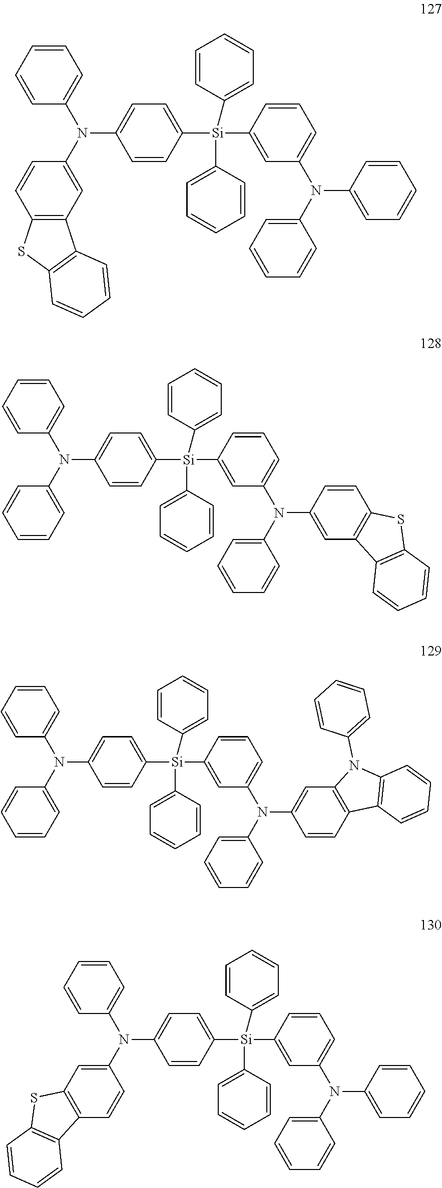 [SMILES: c1ccc(N(c2ccccc2)c2cccc([Si](c3ccccc3)(c3ccccc3)c3ccc(N(c4ccccc4)c4ccc5sc6ccccc6c5c4)cc3)c2)cc1 ; c1ccc(N(c2ccccc2)c2ccc([Si](c3ccccc3)(c3ccccc3)c3cccc(N(c4ccccc4)c4ccc5sc6ccccc6c5c4)c3)cc2)cc1 ; c1ccc(N(c2ccccc2)c2ccc([Si](c3ccccc3)(c3ccccc3)c3cccc(N(c4ccccc4)c4ccc5c6ccccc6n(-c6ccccc6)c5c4)c3)cc2)cc1 ; c1ccc(N(c2ccccc2)c2cccc([Si](c3ccccc3)(c3ccccc3)c3ccc(N(c4ccccc4)c4ccc5c(c4)sc4ccccc45)cc3)c2)cc1]

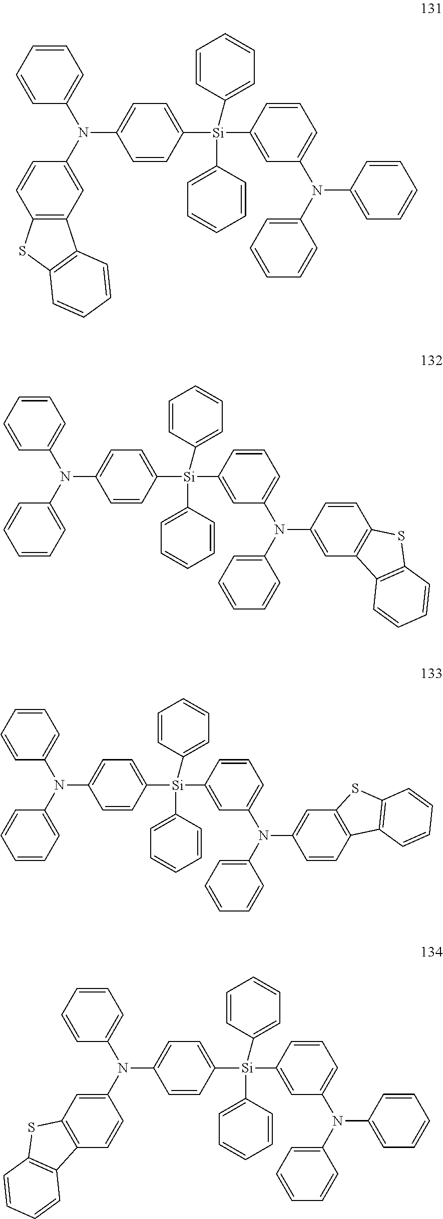 [SMILES: c1ccc(N(c2ccccc2)c2cccc([Si](c3ccccc3)(c3ccccc3)c3ccc(N(c4ccccc4)c4ccc5sc6ccccc6c5c4)cc3)c2)cc1 ; c1ccc(N(c2ccccc2)c2ccc([Si](c3ccccc3)(c3ccccc3)c3cccc(N(c4ccccc4)c4ccc5sc6ccccc6c5c4)c3)cc2)cc1 ; c1ccc(N(c2ccccc2)c2ccc([Si](c3ccccc3)(c3ccccc3)c3cccc(N(c4ccccc4)c4ccc5c(c4)sc4ccccc45)c3)cc2)cc1 ; c1ccc(N(c2ccccc2)c2cccc([Si](c3ccccc3)(c3ccccc3)c3ccc(N(c4ccccc4)c4ccc5c(c4)sc4ccccc45)cc3)c2)cc1]

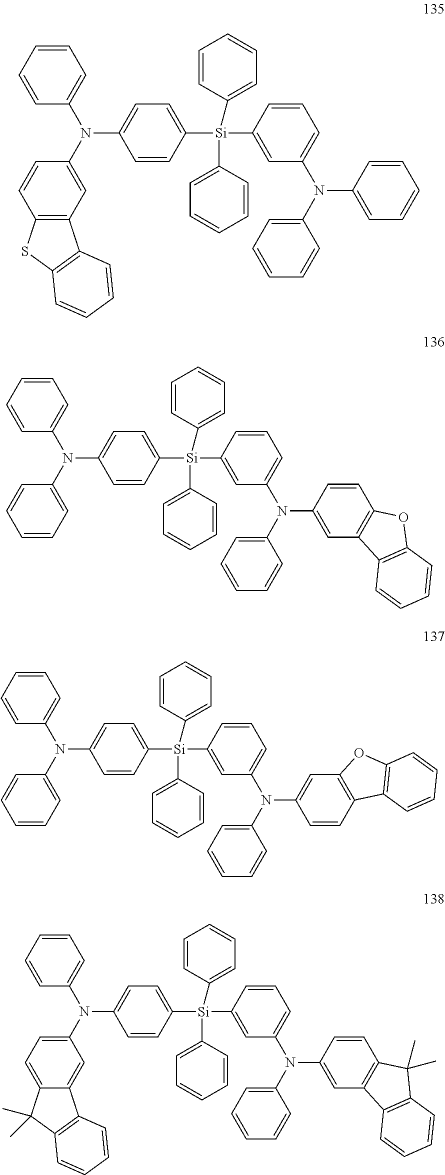

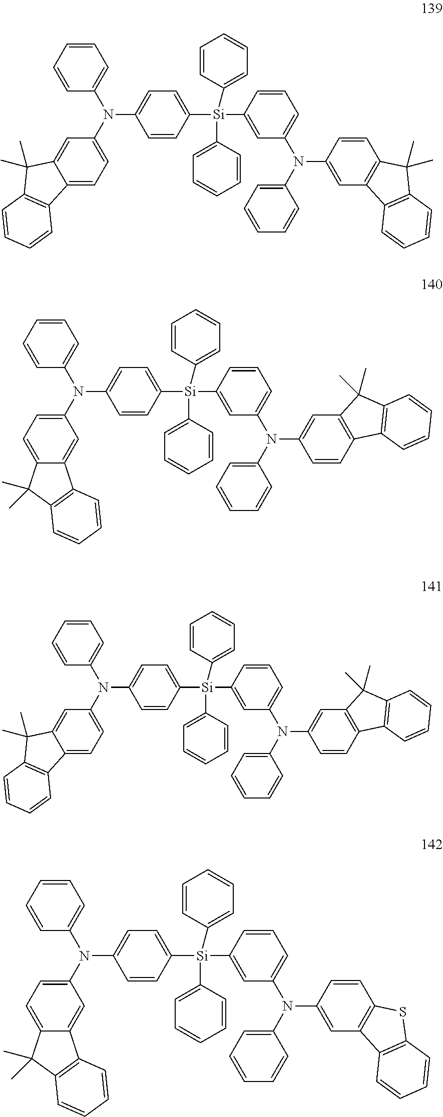

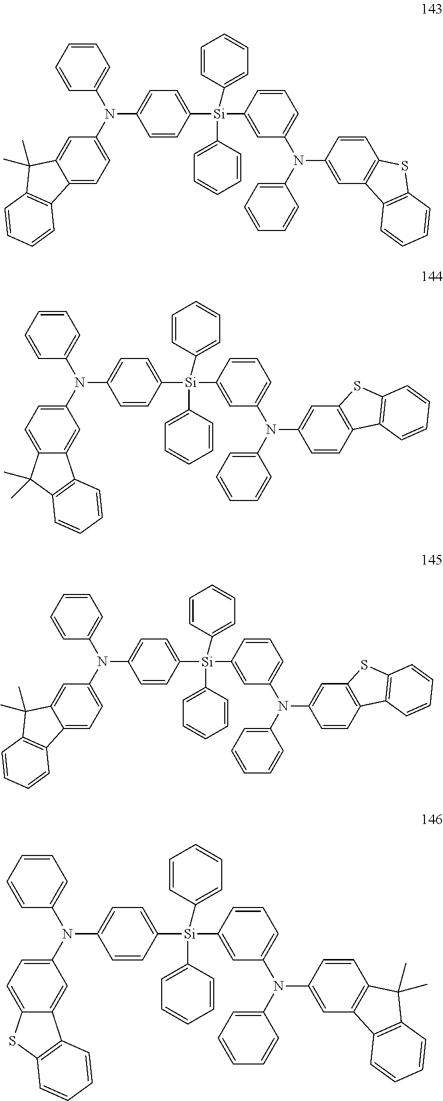 [SMILES: CC1(C)c2ccccc2-c2ccc(N(c3ccccc3)c3ccc([Si](c4ccccc4)(c4ccccc4)c4cccc(N(c5ccccc5)c5ccc6sc7ccccc7c6c5)c4)cc3)cc21 ; CC1(C)c2ccccc2-c2cc(N(c3ccccc3)c3ccc([Si](c4ccccc4)(c4ccccc4)c4cccc(N(c5ccccc5)c5ccc6c(c5)sc5ccccc56)c4)cc3)ccc21 ; CC1(C)c2ccccc2-c2ccc(N(c3ccccc3)c3ccc([Si](c4ccccc4)(c4ccccc4)c4cccc(N(c5ccccc5)c5ccc6c(c5)sc5ccccc56)c4)cc3)cc21 ; CC1(C)c2ccccc2-c2cc(N(c3ccccc3)c3cccc([Si](c4ccccc4)(c4ccccc4)c4ccc(N(c5ccccc5)c5ccc6sc7ccccc7c6c5)cc4)c3)ccc21]

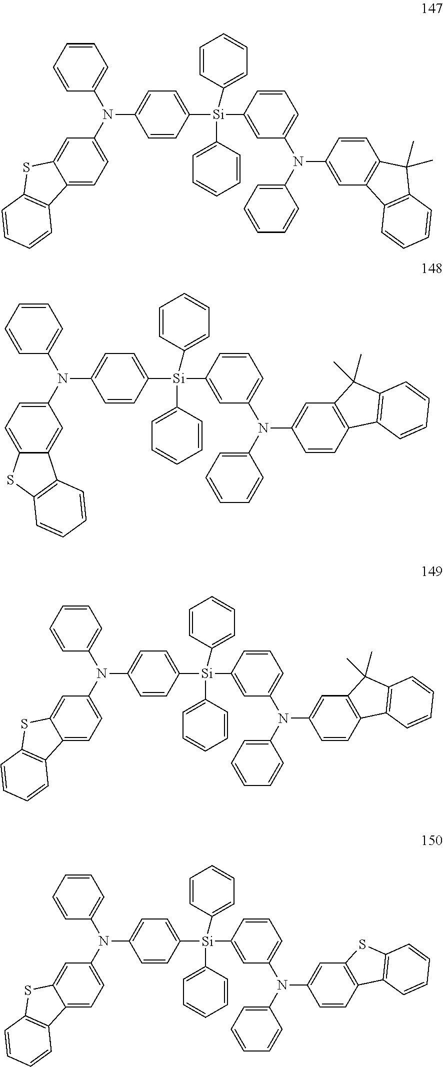 [SMILES: CC1(C)c2ccccc2-c2cc(N(c3ccccc3)c3cccc([Si](c4ccccc4)(c4ccccc4)c4ccc(N(c5ccccc5)c5ccc6c(c5)sc5ccccc56)cc4)c3)ccc21 ; CC1(C)c2ccccc2-c2ccc(N(c3ccccc3)c3cccc([Si](c4ccccc4)(c4ccccc4)c4ccc(N(c5ccccc5)c5ccc6sc7ccccc7c6c5)cc4)c3)cc21 ; CC1(C)c2ccccc2-c2ccc(N(c3ccccc3)c3cccc([Si](c4ccccc4)(c4ccccc4)c4ccc(N(c5ccccc5)c5ccc6c(c5)sc5ccccc56)cc4)c3)cc21 ; c1ccc(N(c2ccc([Si](c3ccccc3)(c3ccccc3)c3cccc(N(c4ccccc4)c4ccc5c(c4)sc4ccccc45)c3)cc2)c2ccc3c(c2)sc2ccccc23)cc1]

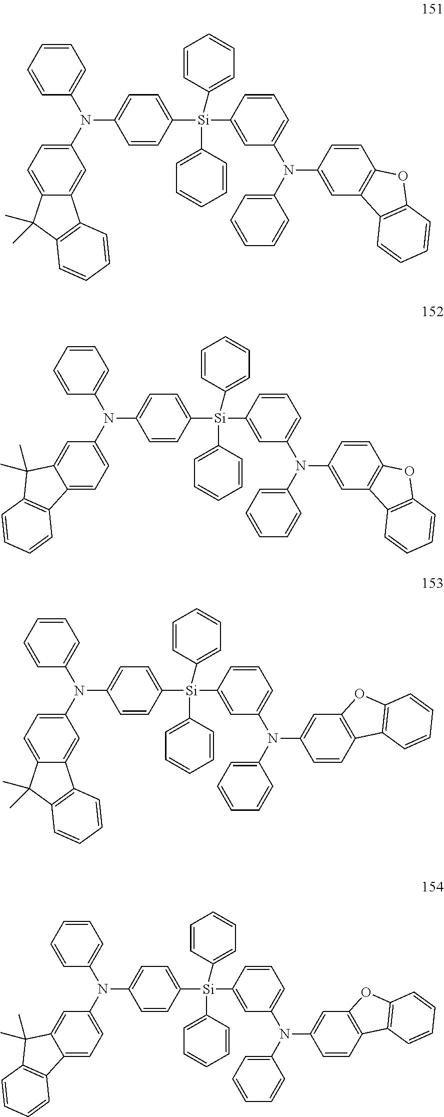 [SMILES: CC1(C)c2ccccc2-c2cc(N(c3ccccc3)c3ccc([Si](c4ccccc4)(c4ccccc4)c4cccc(N(c5ccccc5)c5ccc6oc7ccccc7c6c5)c4)cc3)ccc21 ; CC1(C)c2ccccc2-c2ccc(N(c3ccccc3)c3ccc([Si](c4ccccc4)(c4ccccc4)c4cccc(N(c5ccccc5)c5ccc6oc7ccccc7c6c5)c4)cc3)cc21 ; CC1(C)c2ccccc2-c2cc(N(c3ccccc3)c3ccc([Si](c4ccccc4)(c4ccccc4)c4cccc(N(c5ccccc5)c5ccc6c(c5)oc5ccccc56)c4)cc3)ccc21 ; CC1(C)c2ccccc2-c2ccc(N(c3ccccc3)c3ccc([Si](c4ccccc4)(c4ccccc4)c4cccc(N(c5ccccc5)c5ccc6c(c5)oc5ccccc56)c4)cc3)cc21]

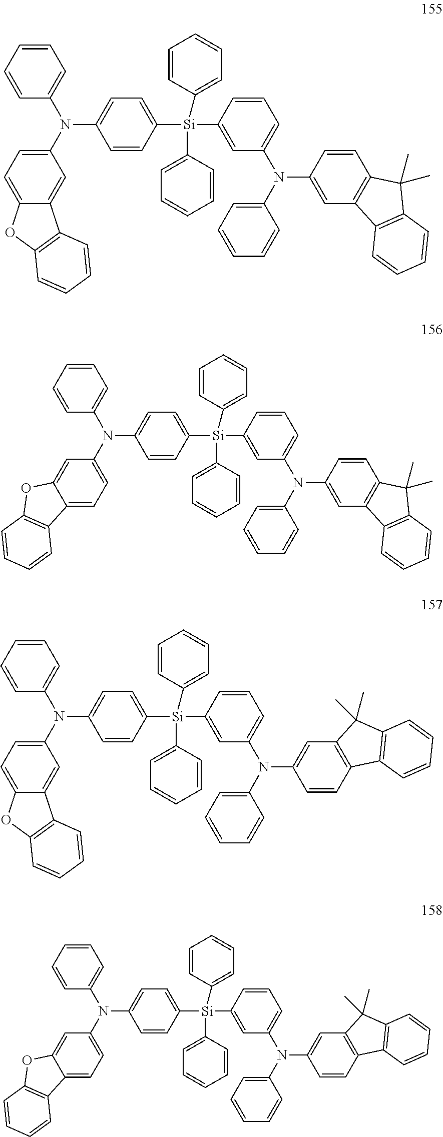 [SMILES: CC1(C)c2ccccc2-c2cc(N(c3ccccc3)c3cccc([Si](c4ccccc4)(c4ccccc4)c4ccc(N(c5ccccc5)c5ccc6oc7ccccc7c6c5)cc4)c3)ccc21 ; CC1(C)c2ccccc2-c2cc(N(c3ccccc3)c3cccc([Si](c4ccccc4)(c4ccccc4)c4ccc(N(c5ccccc5)c5ccc6c(c5)oc5ccccc56)cc4)c3)ccc21 ; CC1(C)c2ccccc2-c2ccc(N(c3ccccc3)c3cccc([Si](c4ccccc4)(c4ccccc4)c4ccc(N(c5ccccc5)c5ccc6oc7ccccc7c6c5)cc4)c3)cc21 ; CC1(C)c2ccccc2-c2ccc(N(c3ccccc3)c3cccc([Si](c4ccccc4)(c4ccccc4)c4ccc(N(c5ccccc5)c5ccc6c(c5)oc5ccccc56)cc4)c3)cc21]

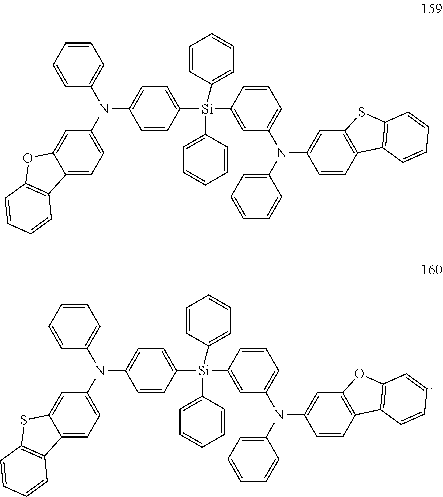 [SMILES: c1ccc(N(c2ccc([Si](c3ccccc3)(c3ccccc3)c3cccc(N(c4ccccc4)c4ccc5c(c4)sc4ccccc45)c3)cc2)c2ccc3c(c2)oc2ccccc23)cc1 ; c1ccc(N(c2cccc([Si](c3ccccc3)(c3ccccc3)c3ccc(N(c4ccccc4)c4ccc5c(c4)sc4ccccc45)cc3)c2)c2ccc3c(c2)oc2ccccc23)cc1]

12. An amine compound represented by Formula 1: 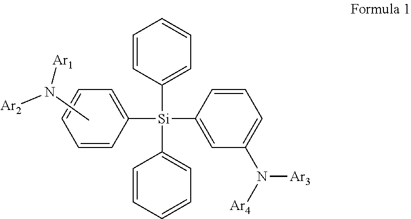
wherein, in Formula 1,
Ar₁ to Ar₄ are each independently a substituted or unsubstituted aryl group having 6 to 30 ring-forming carbon atoms, or a substituted or unsubstituted heteroaryl group having 2 to 30 ring-forming carbon atoms.

13. The amine compound of claim 12, wherein Formula 1 is represented by any one among Formula 1-1 to Formula 1-3: 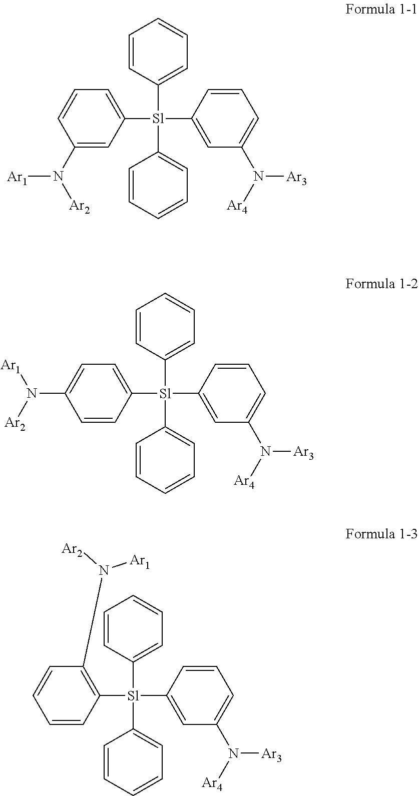
wherein, in Formula 1-1 to Formula 1-3,
Ar₁ to Ar₄ are the same as defined in Formula 1.

14. The amine compound of claim 12, wherein Formula 1 is represented by Formula 2: 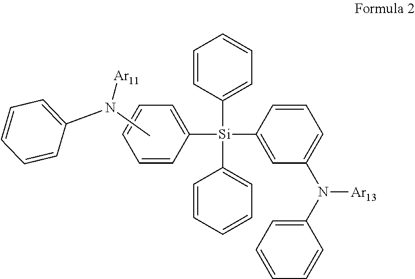
wherein, in Formula 2,
Ar₁₁ and Ar₁₃ are each independently a substituted or unsubstituted aryl group having 6 to 30 ring-forming carbon atoms, or a substituted or unsubstituted heteroaryl group having 2 to 30 ring-forming carbon atoms.

15. The amine compound of claim 14, wherein Formula 2 is represented by Formula 2-1: 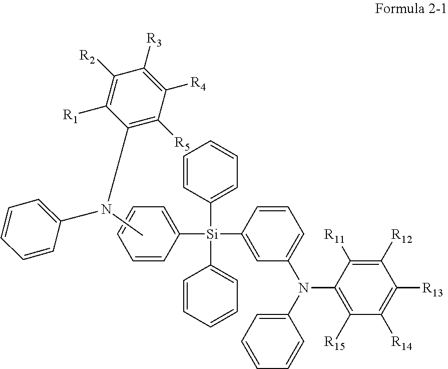
wherein, in Formula 2-1,
R₁ to R₅ and R₁₁ to R₁₅ are each independently a hydrogen atom, a substituted or unsubstituted amine group, a substituted or unsubstituted oxy group, a substituted or unsubstituted thio group, a substituted or unsubstituted alkyl group having 1 to 10 carbon atoms, a substituted or unsubstituted alkenyl group having 2 to 10 carbon atoms, or a substituted or unsubstituted aryl group having 6 to 30 ring-forming carbon atoms, and/or are bonded to an adjacent group to form a ring.

16. The amine compound of claim 14, wherein Formula 2 is represented by Formula 2-2A or Formula 2-2B: 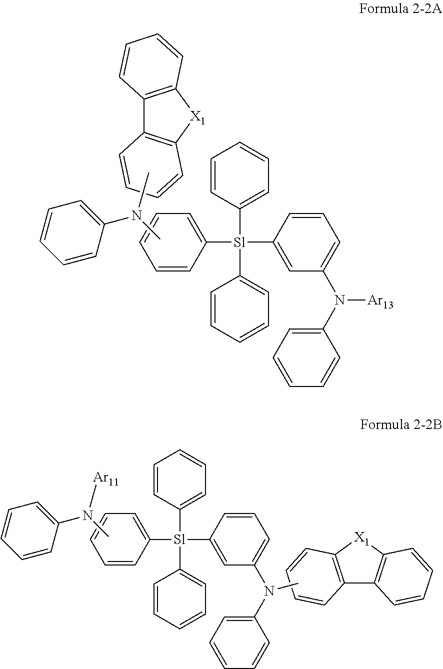
wherein, in Formulae 2-2A and 2-2B,
X₁ is C(CH₃)₂, N(Ph), O, or S, and
Ar₁₁ and Ar₁₃ are the same as defined in Formula 2.

17. The amine compound of claim 12, wherein Ar₁ to Ar₄ are each independently represented by any one among A-1 to A-6:

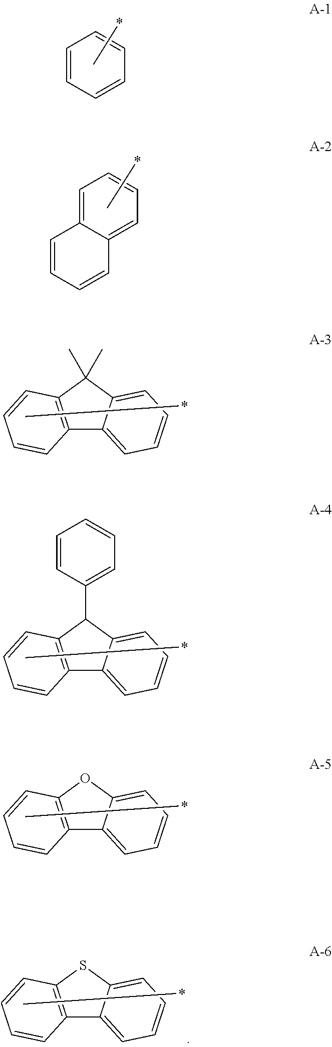

18. The amine compound of claim 12, wherein Ar₁ to Ar₄ are each independently a substituted or unsubstituted phenyl group, a substituted or unsubstituted naphthyl group, a substituted or unsubstituted fluorenyl group, a substituted or unsubstituted carbazole group, a substituted or unsubstituted dibenzofuran group, or a substituted or unsubstituted dibenzothiophene group.

19. The amine compound of claim 12, wherein, in Formula 1, Ar₁ and Ar₃ are the same and Ar₂ and Ar₄ are the same.

20. The amine compound of claim 12, wherein Formula 1 is represented by any one among compounds of Compound Group 1: 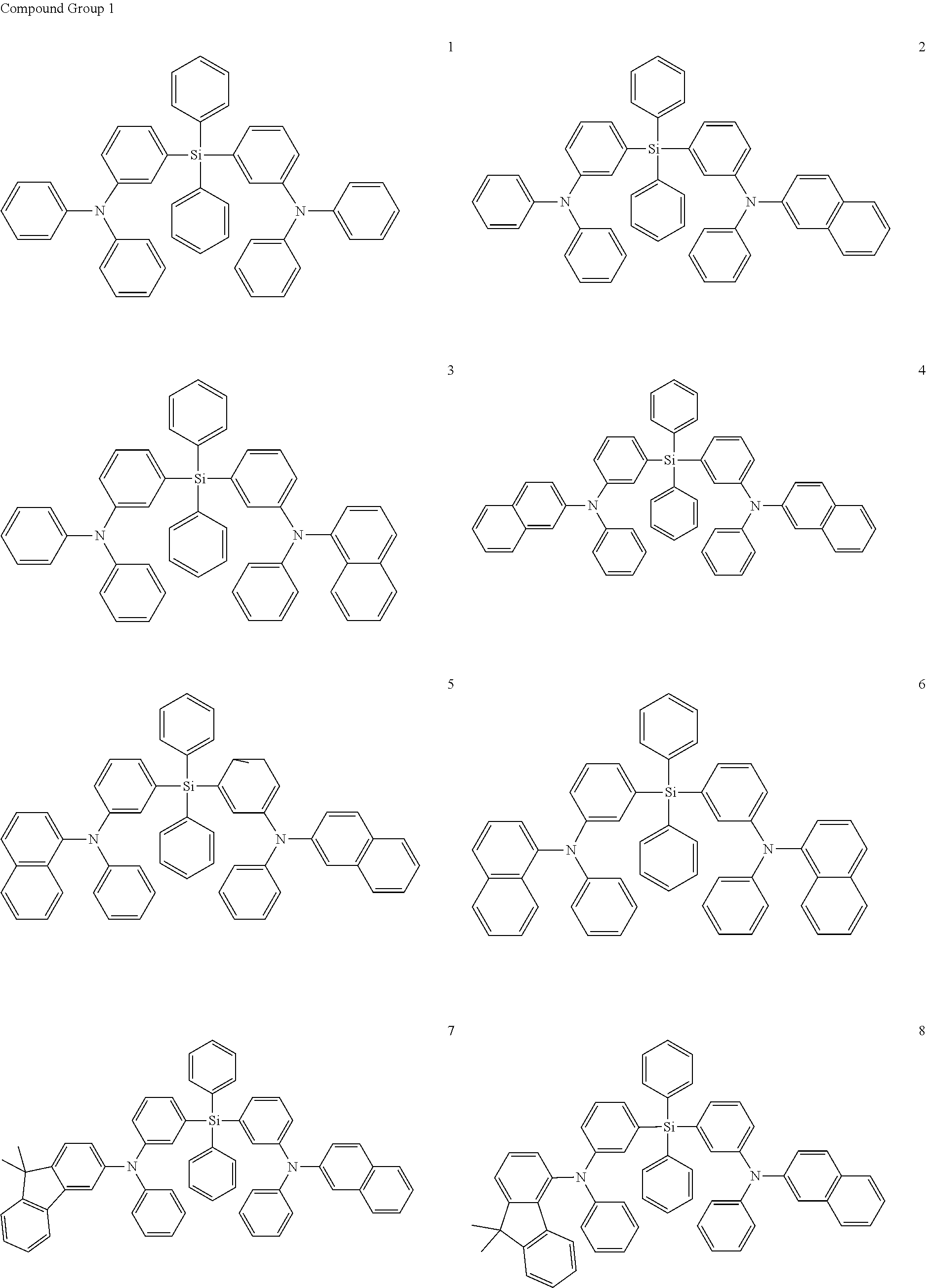 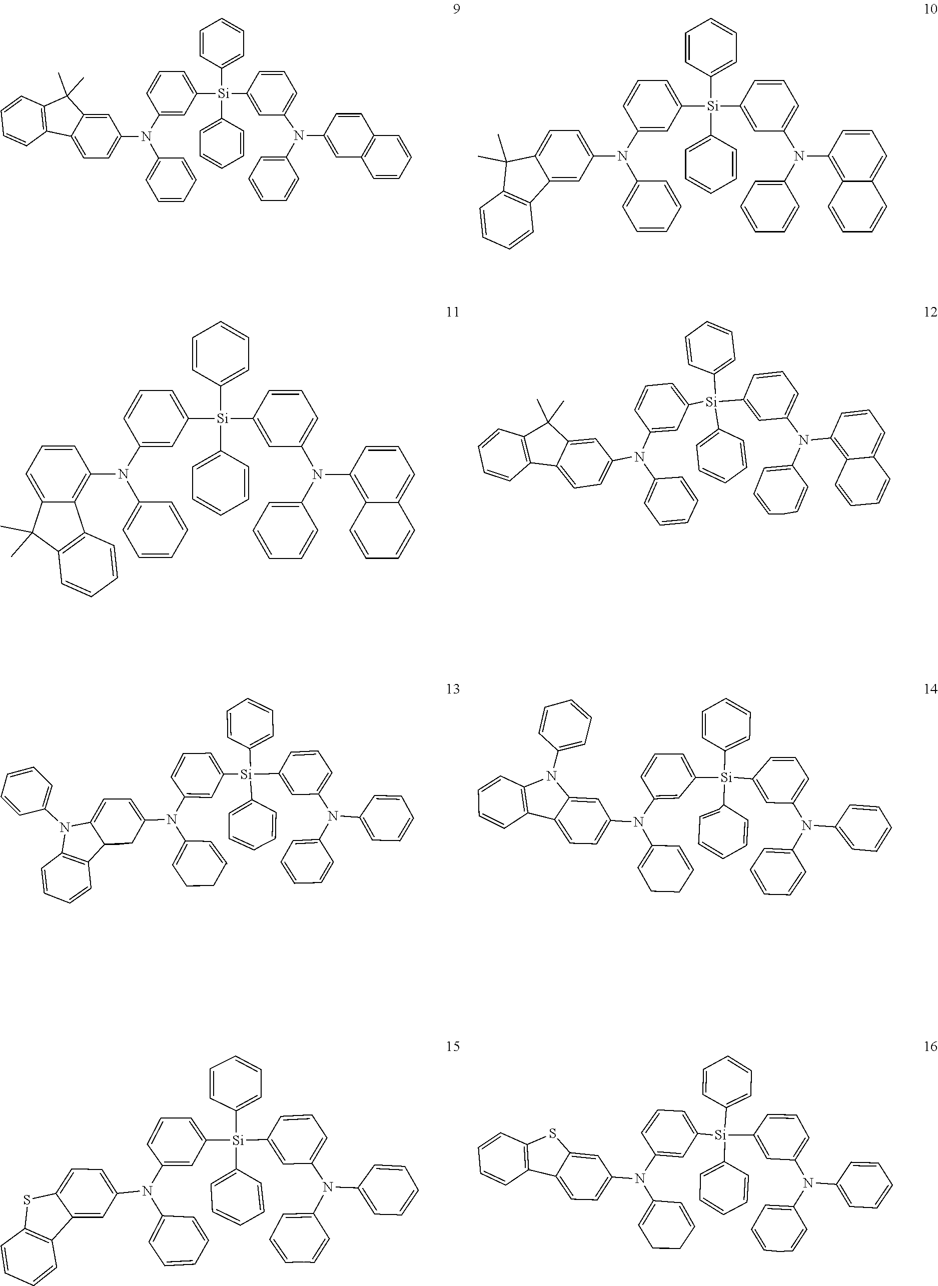 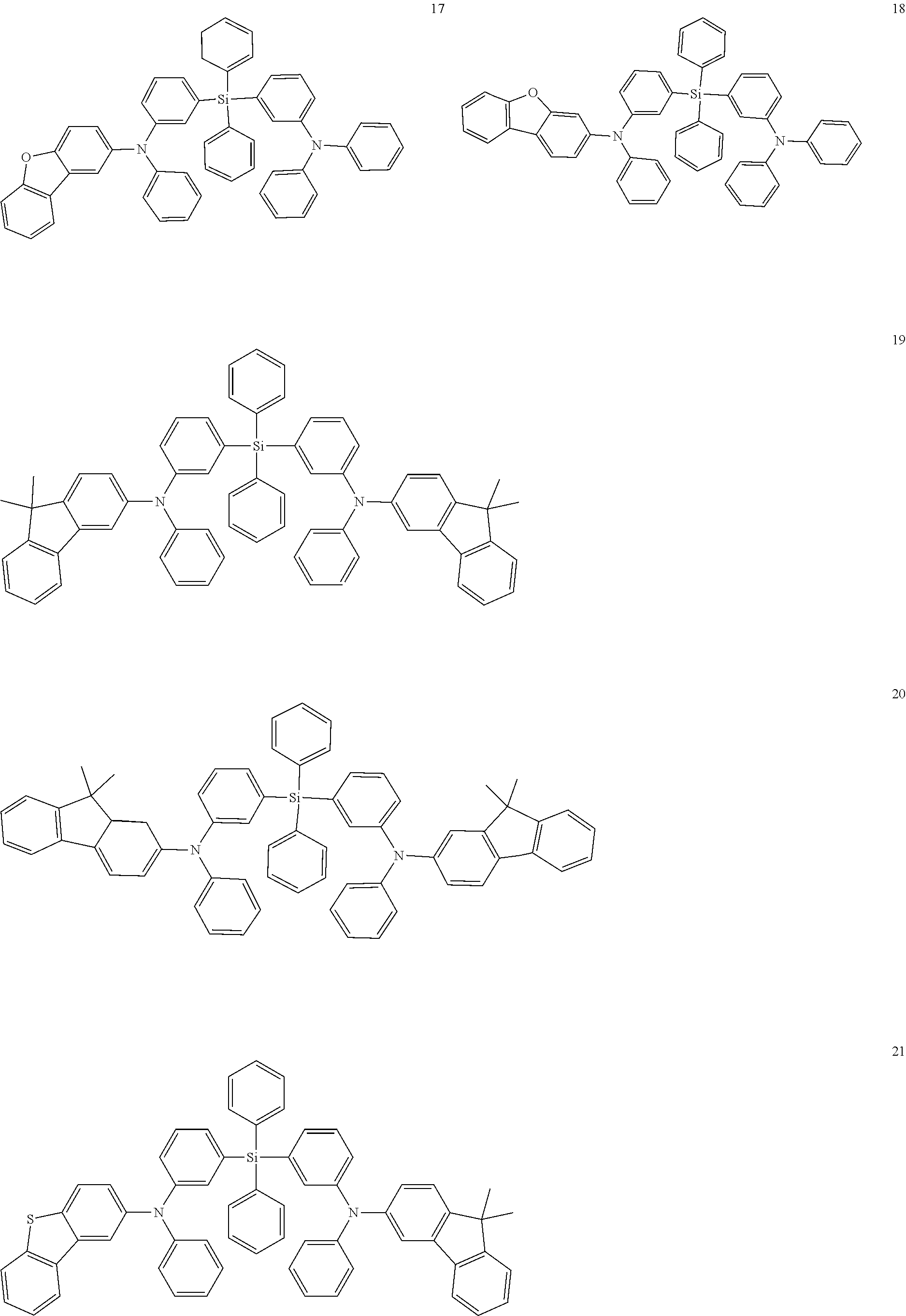 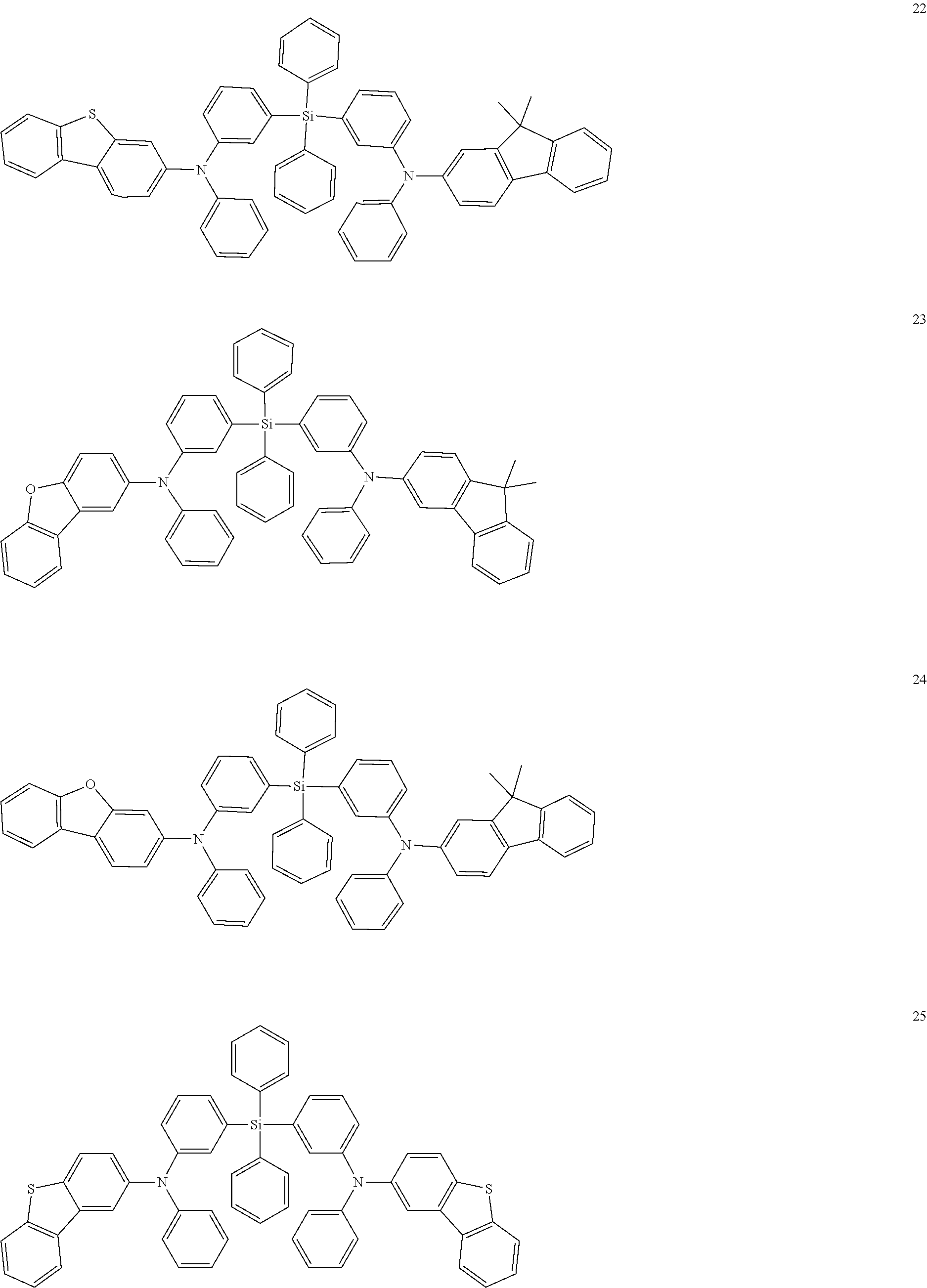 [SMILES: CC1(C)c2ccccc2-c2ccc(N(C3=CCC=CC=C3)c3cccc([Si](c4ccccc4)(c4ccccc4)c4cccc(N(C5=CCC=c6c(sc7ccccc67)=C5)c5ccccc5)c4)c3)cc21 ; CC1(C)c2ccccc2-c2cc(N(c3ccccc3)c3cccc([Si](c4ccccc4)(c4ccccc4)c4cccc(N(c5ccccc5)c5ccc6oc7ccccc7c6c5)c4)c3)ccc21 ; CC1(C)c2ccccc2-c2ccc(N(c3ccccc3)c3cccc([Si](c4ccccc4)(c4ccccc4)c4cccc(N(c5ccccc5)c5ccc6c(c5)oc5ccccc56)c4)c3)cc21 ; c1ccc(N(c2cccc([Si](c3ccccc3)(c3ccccc3)c3cccc(N(c4ccccc4)c4ccc5sc6ccccc6c5c4)c3)c2)c2ccc3sc4ccccc4c3c2)cc1] 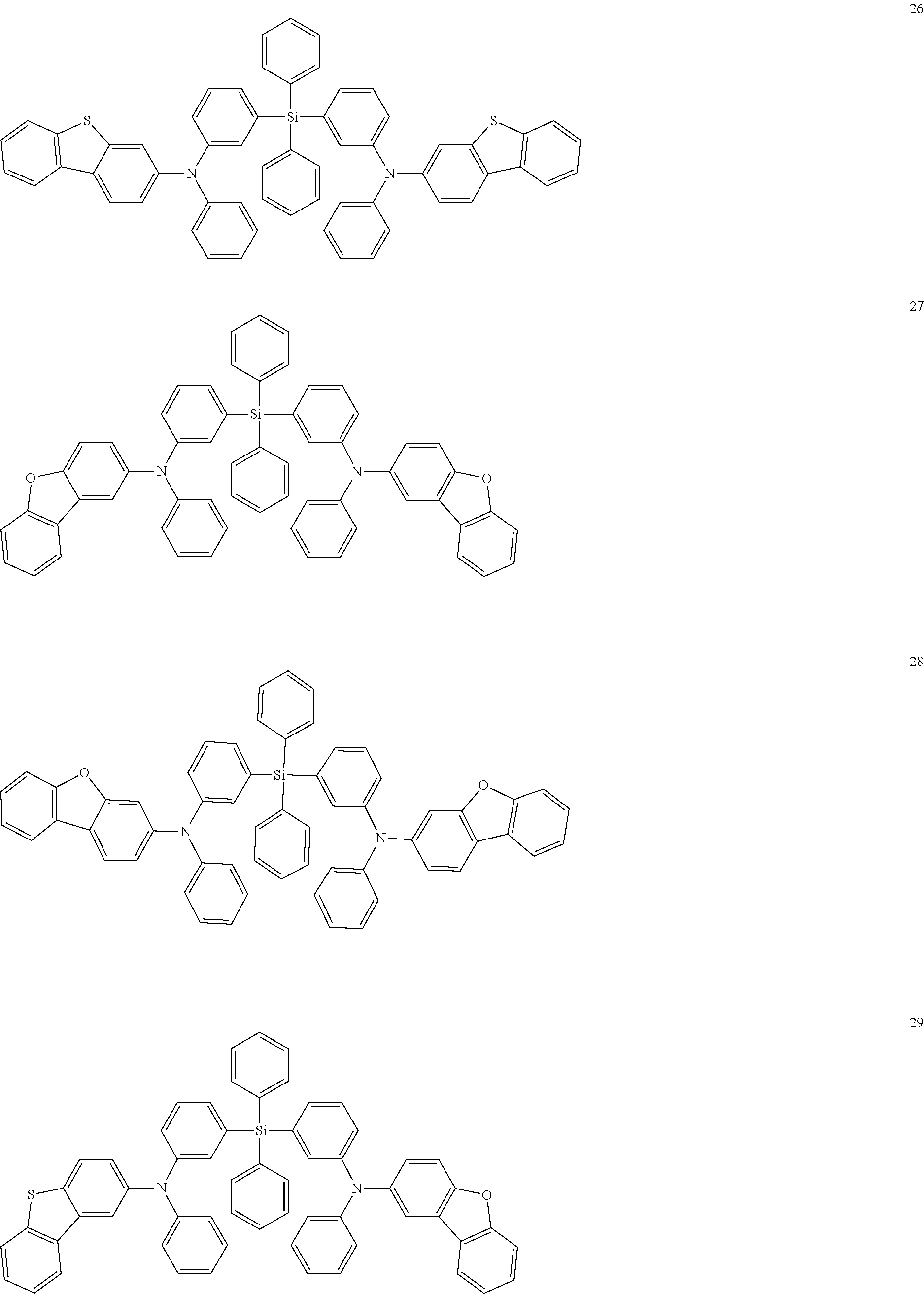 [SMILES: Cc1c(N(c2ccccc2)c2ccc3c(c2)sc2ccccc23)cccc1[Si](c1ccccc1)(c1ccccc1)c1cccc(N(c2ccccc2)c2ccc3c(c2)sc2ccccc23)c1 ; c1ccc(N(c2cccc([Si](c3ccccc3)(c3ccccc3)c3cccc(N(c4ccccc4)c4ccc5oc6ccccc6c5c4)c3)c2)c2ccc3oc4ccccc4c3c2)cc1 ; C1=CCc2oc3cc(N(c4ccccc4)c4cccc([Si](c5ccccc5)(c5ccccc5)c5cccc(N(c6ccccc6)c6ccc7c(c6)oc6ccccc67)c5)c4)ccc3c2C=C1 ; c1ccc(N(c2cccc([Si](c3ccccc3)(c3ccccc3)c3cccc(N(c4ccccc4)c4ccc5sc6ccccc6c5c4)c3)c2)c2ccc3oc4ccccc4c3c2)cc1] 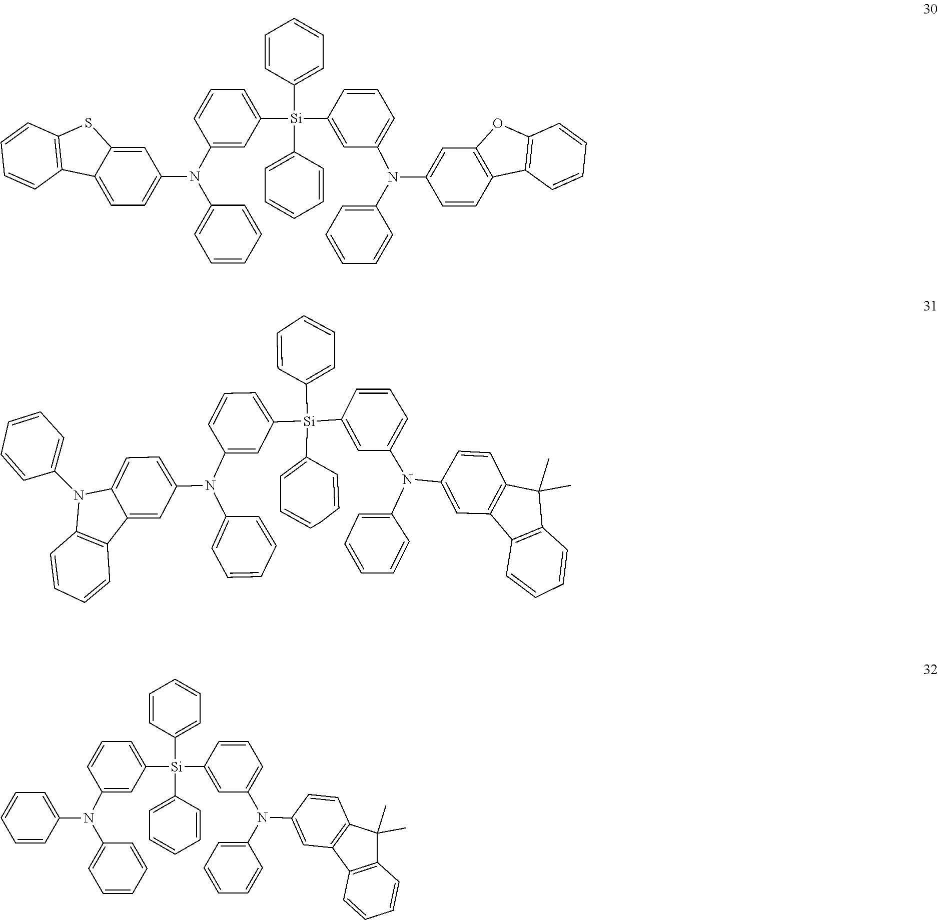 [SMILES: c1ccc(N(c2cccc([Si](c3ccccc3)(c3ccccc3)c3cccc(N(c4ccccc4)c4ccc5c(c4)sc4ccccc45)c3)c2)c2ccc3c(c2)oc2ccccc23)cc1 ; Cc1cc(N(c2ccccc2)c2ccc3c(c2)-c2ccccc2C3(C)C)cc([Si](C2=CC=CCC=C2)(c2ccccc2)c2cccc(N(c3ccccc3)c3ccc4c(c3)c3ccccc3n4-c3ccccc3)c2)c1 ; CC1(C)c2ccccc2-c2cc(N(c3ccccc3)c3cccc([Si](c4ccccc4)(c4ccccc4)c4cccc(N(c5ccccc5)c5ccccc5)c4)c3)ccc21] 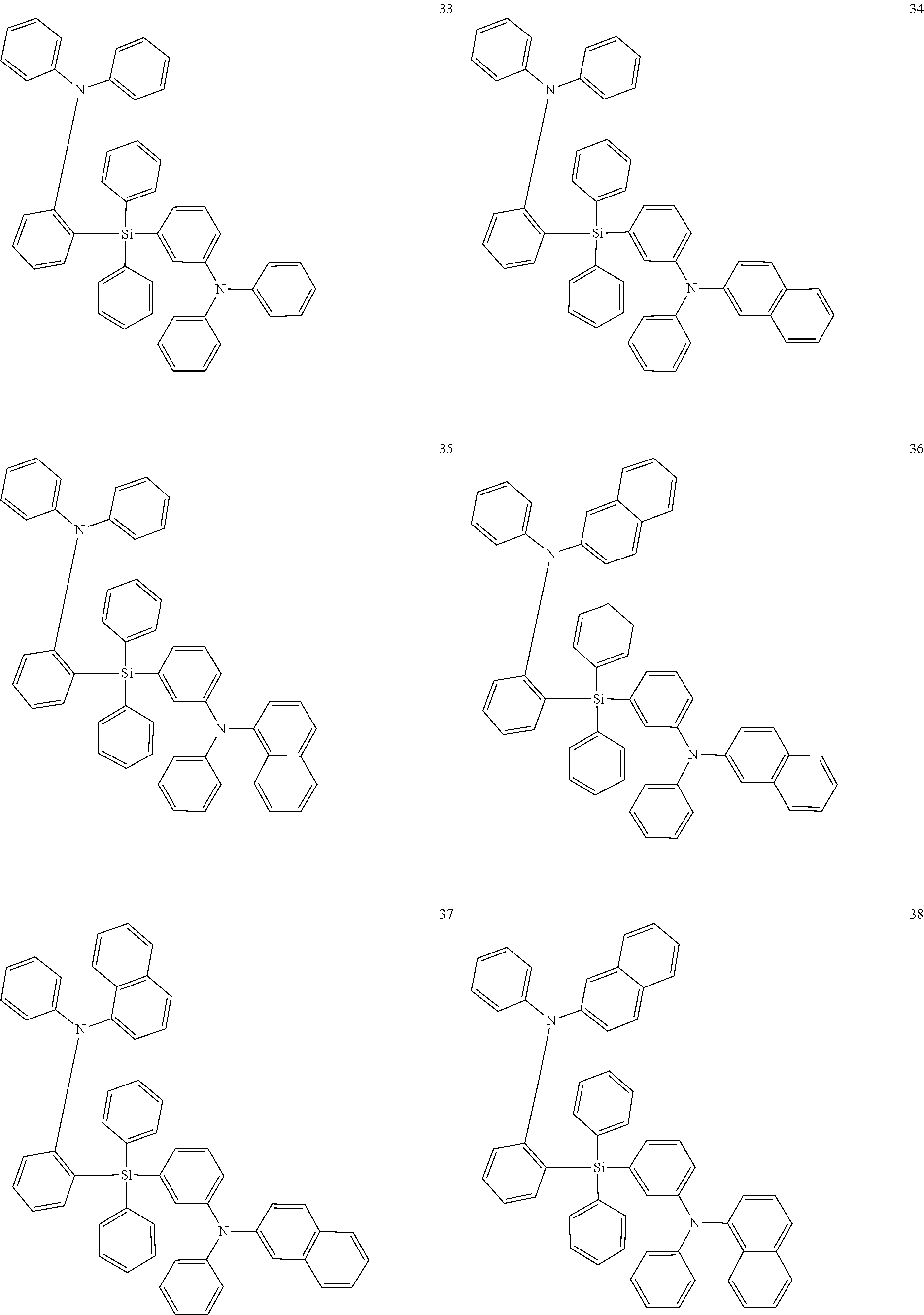 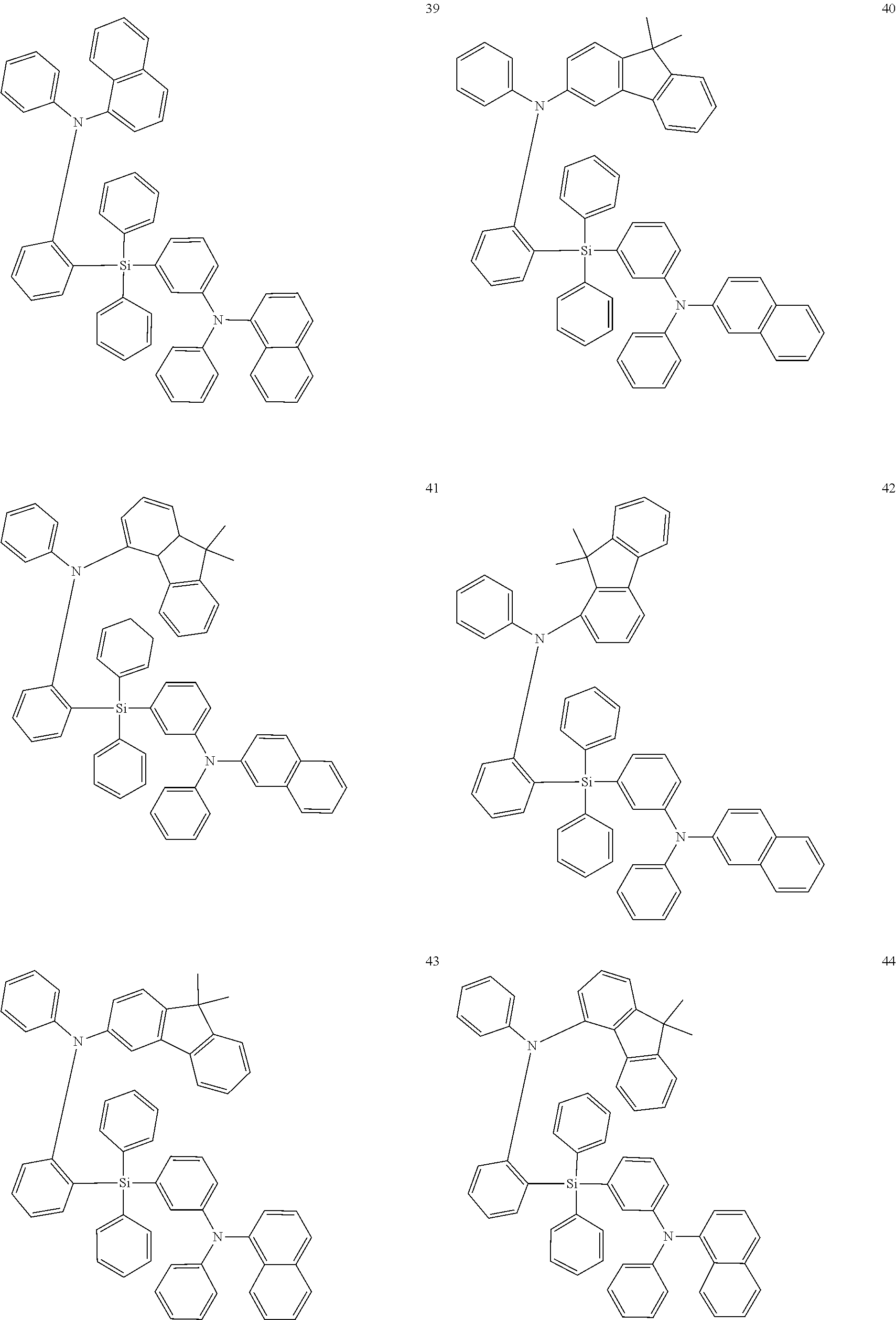 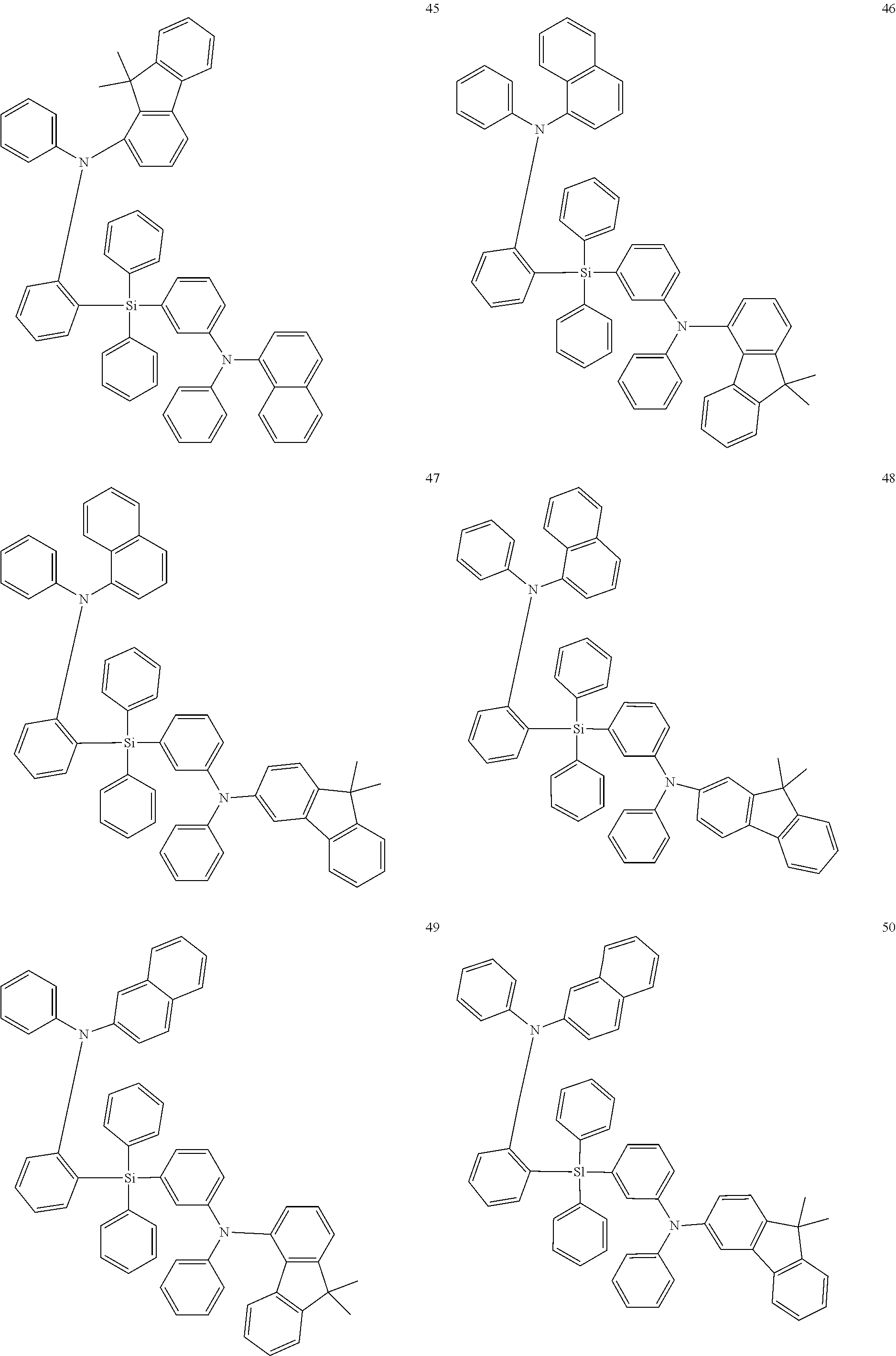 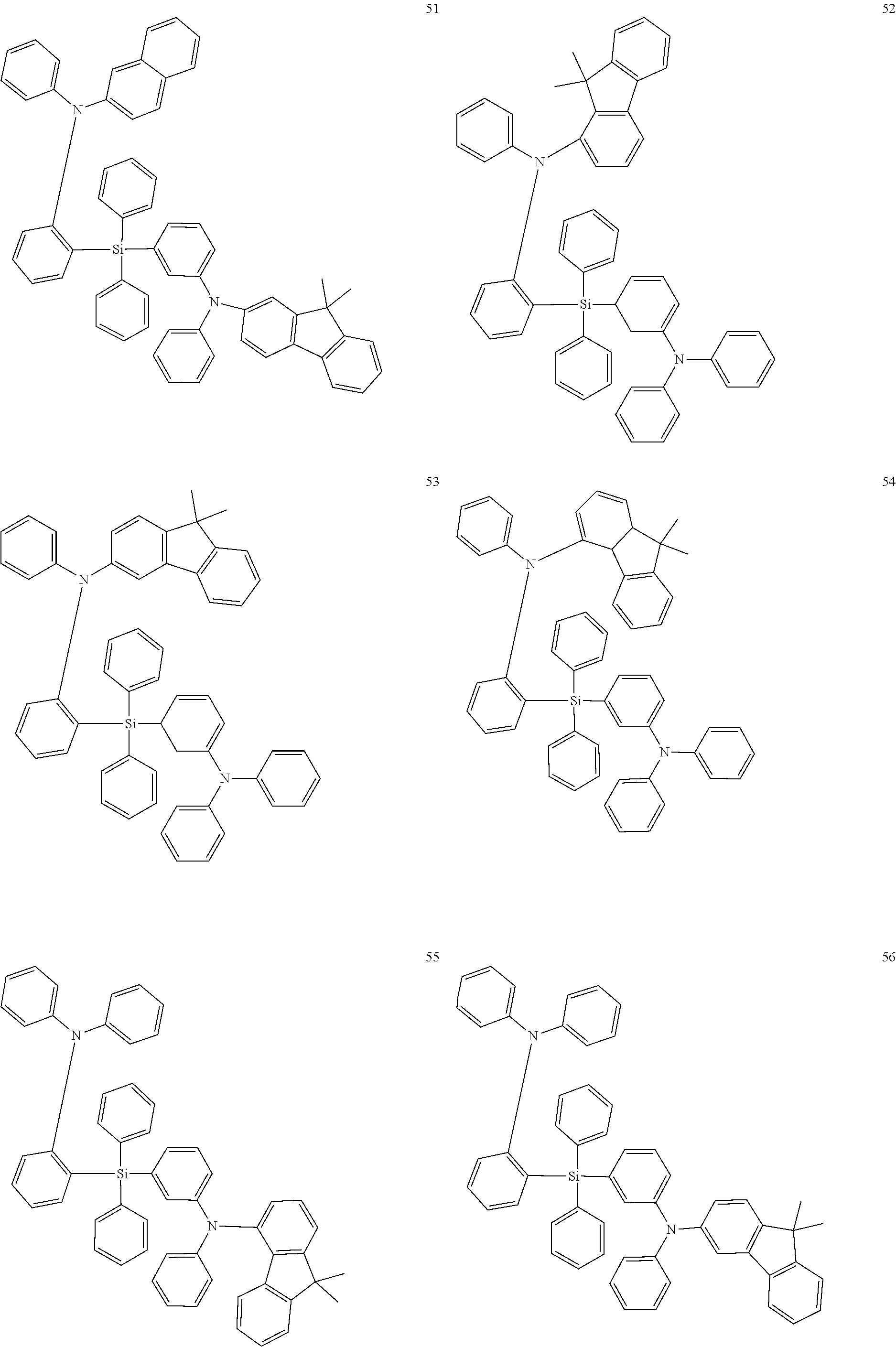 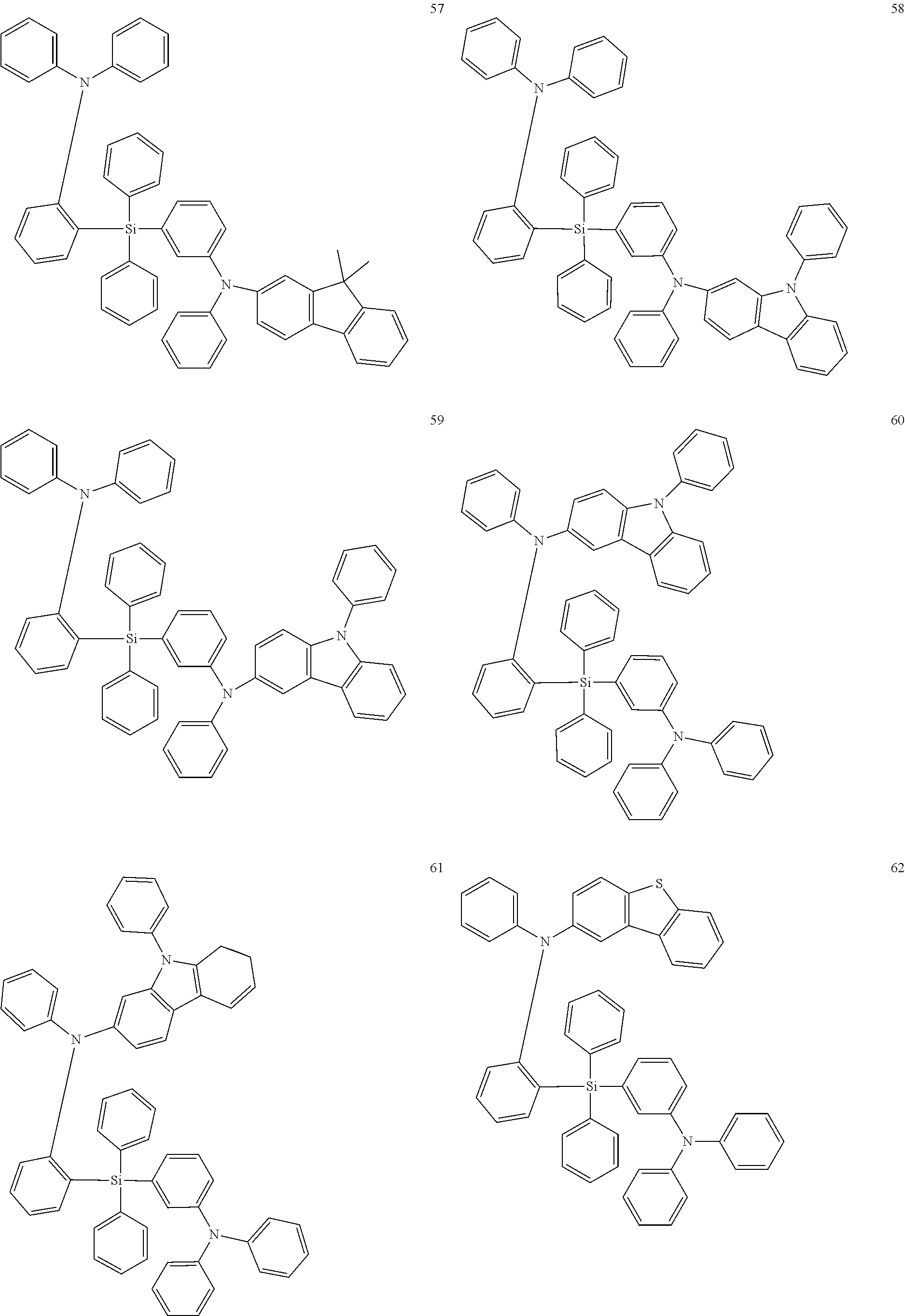 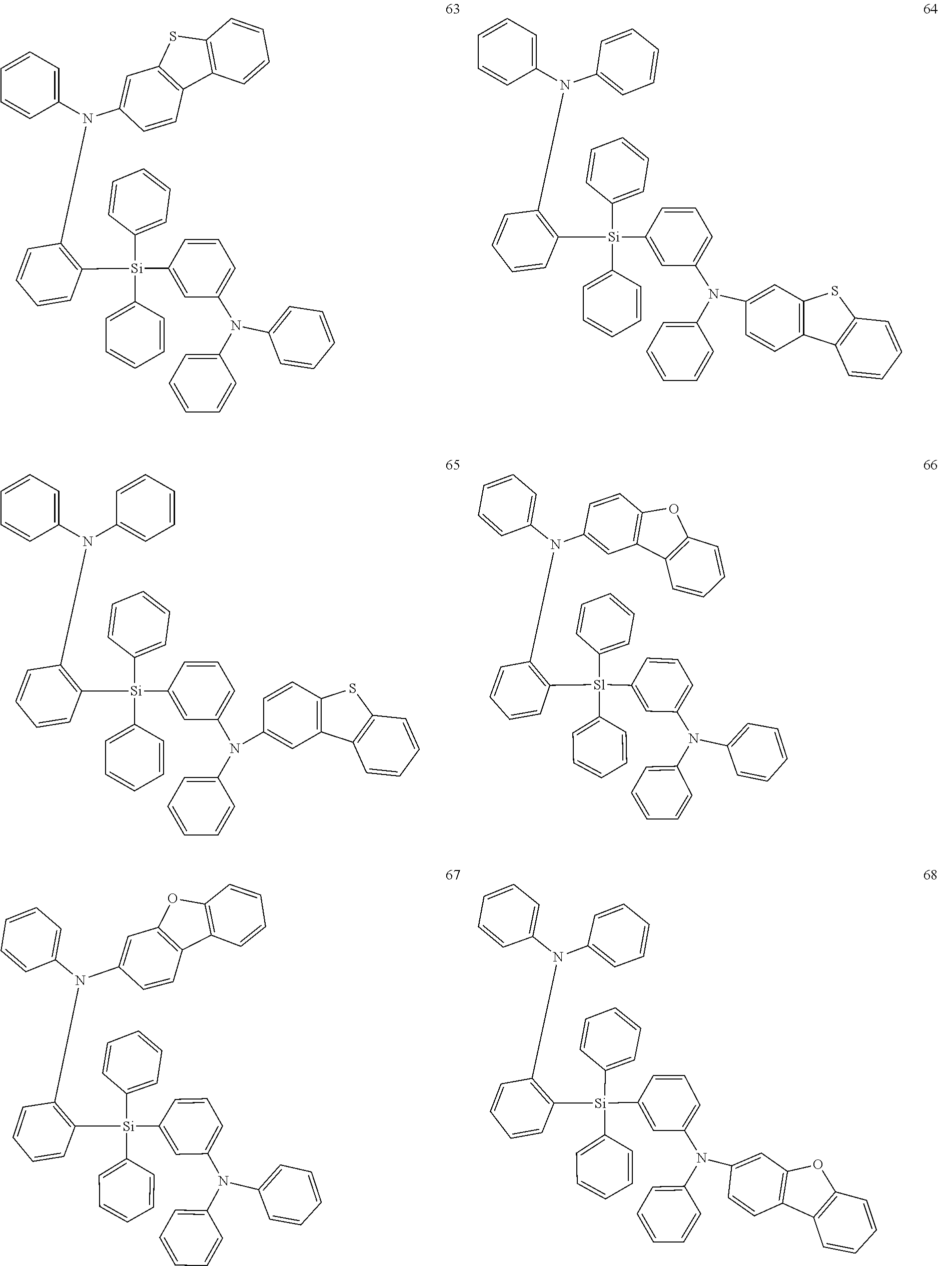 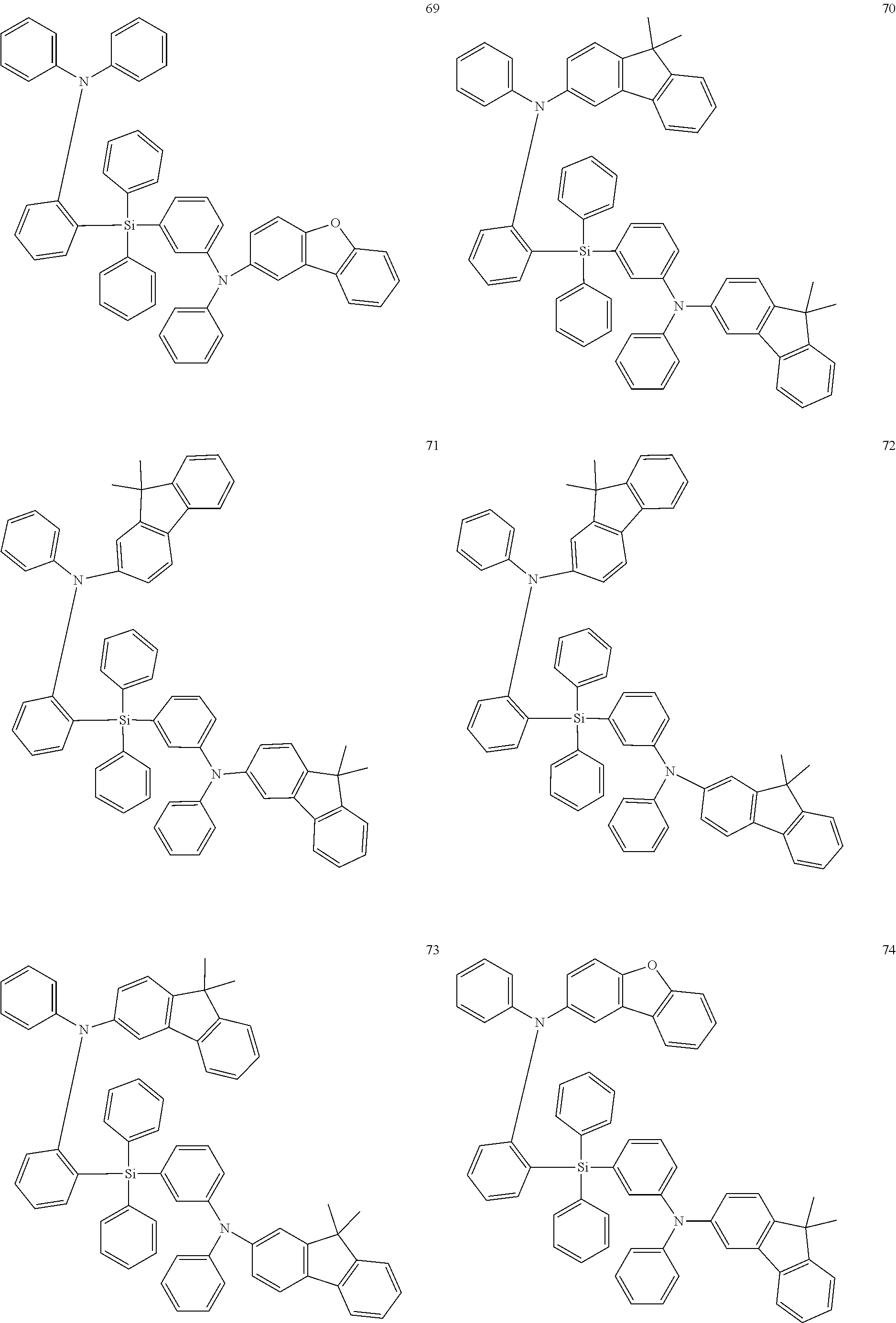 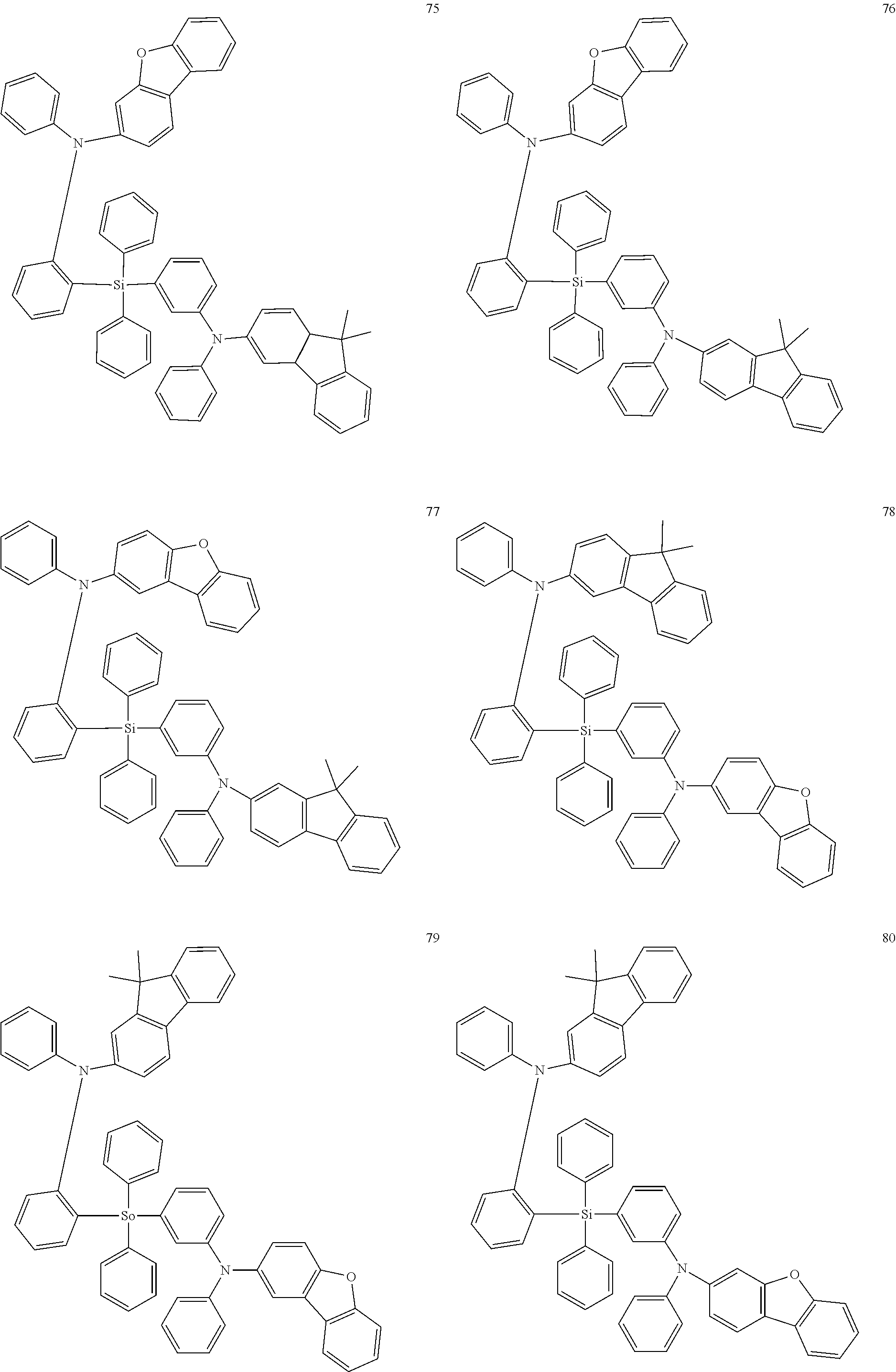 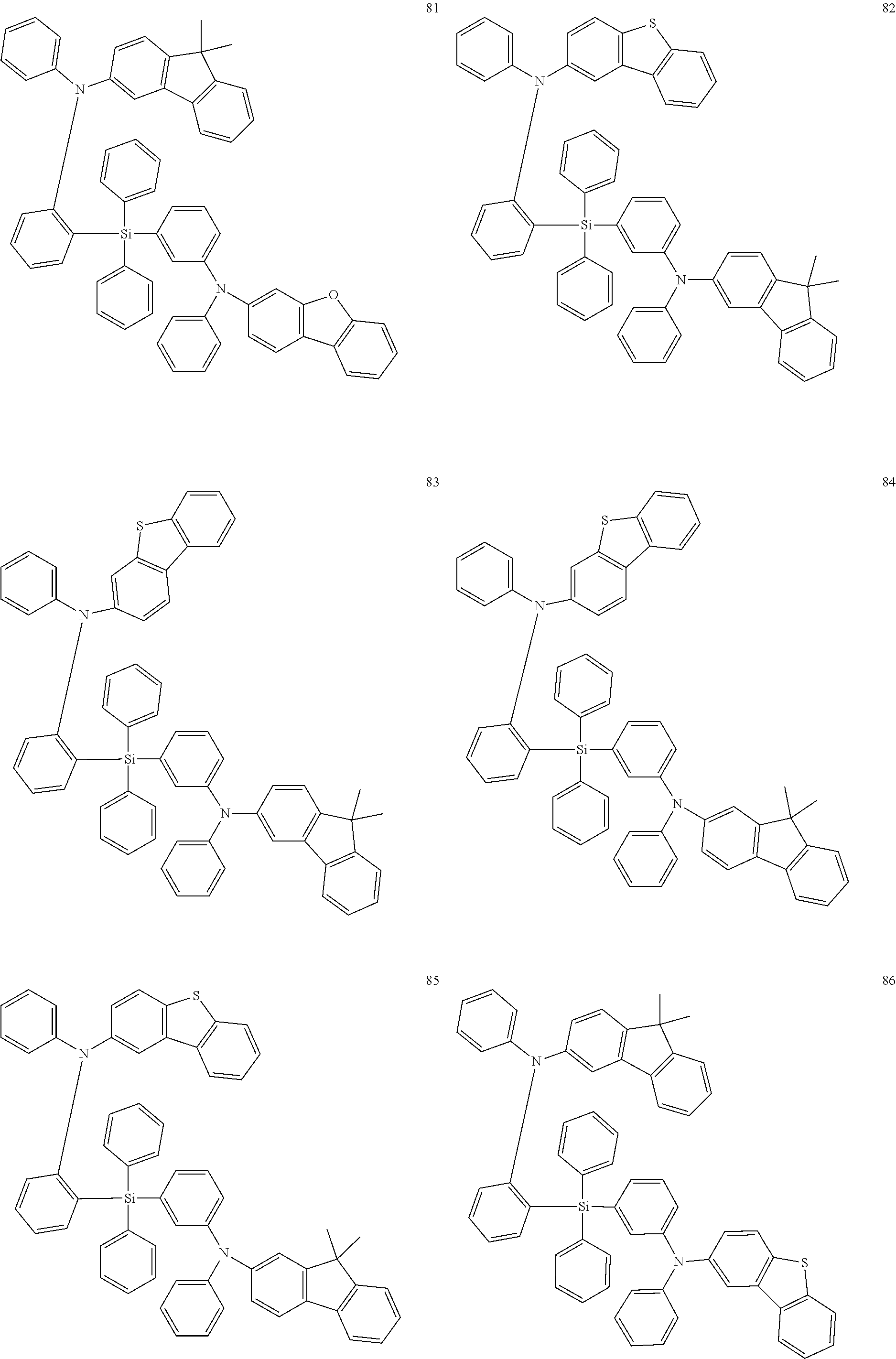 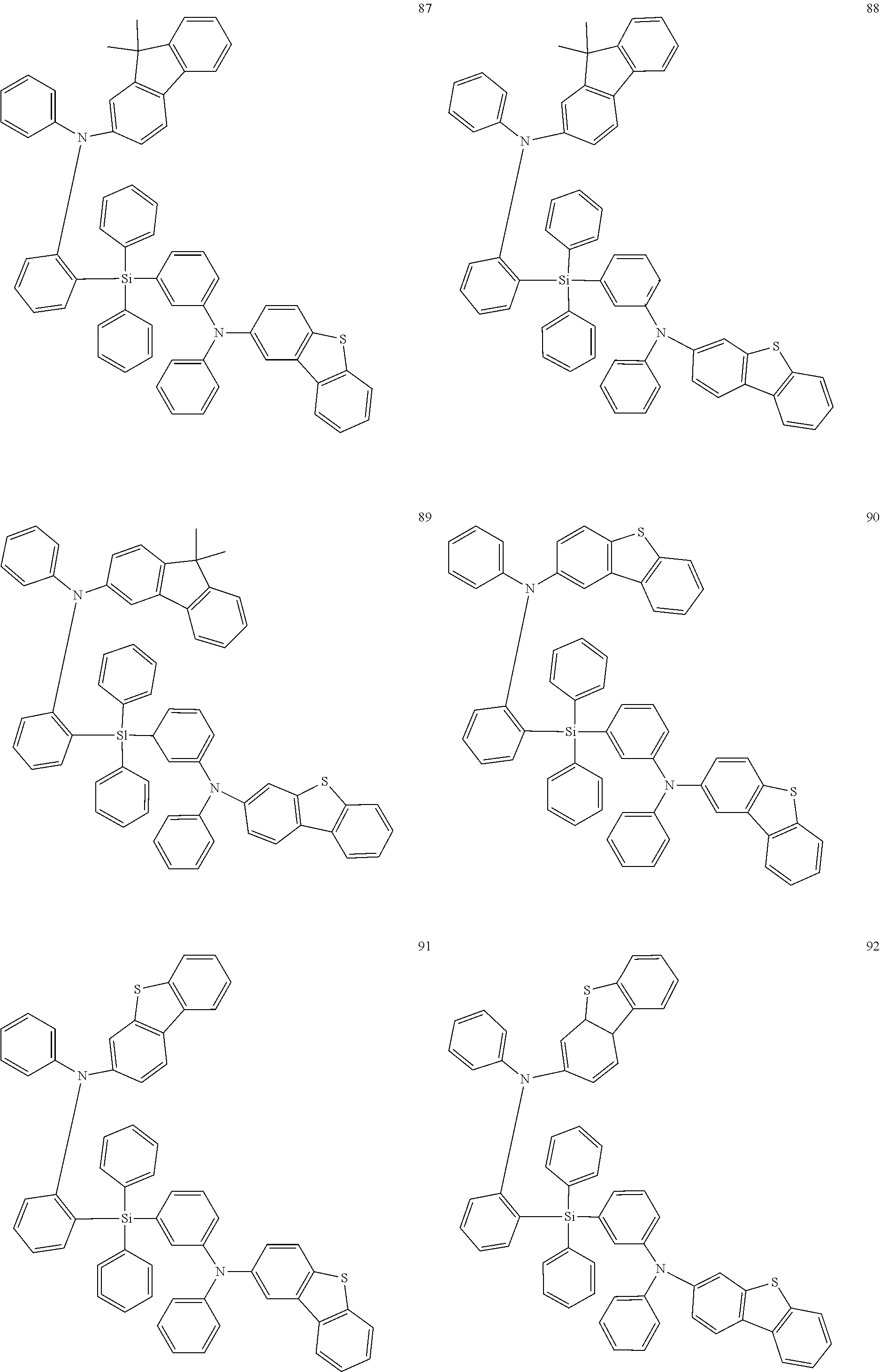 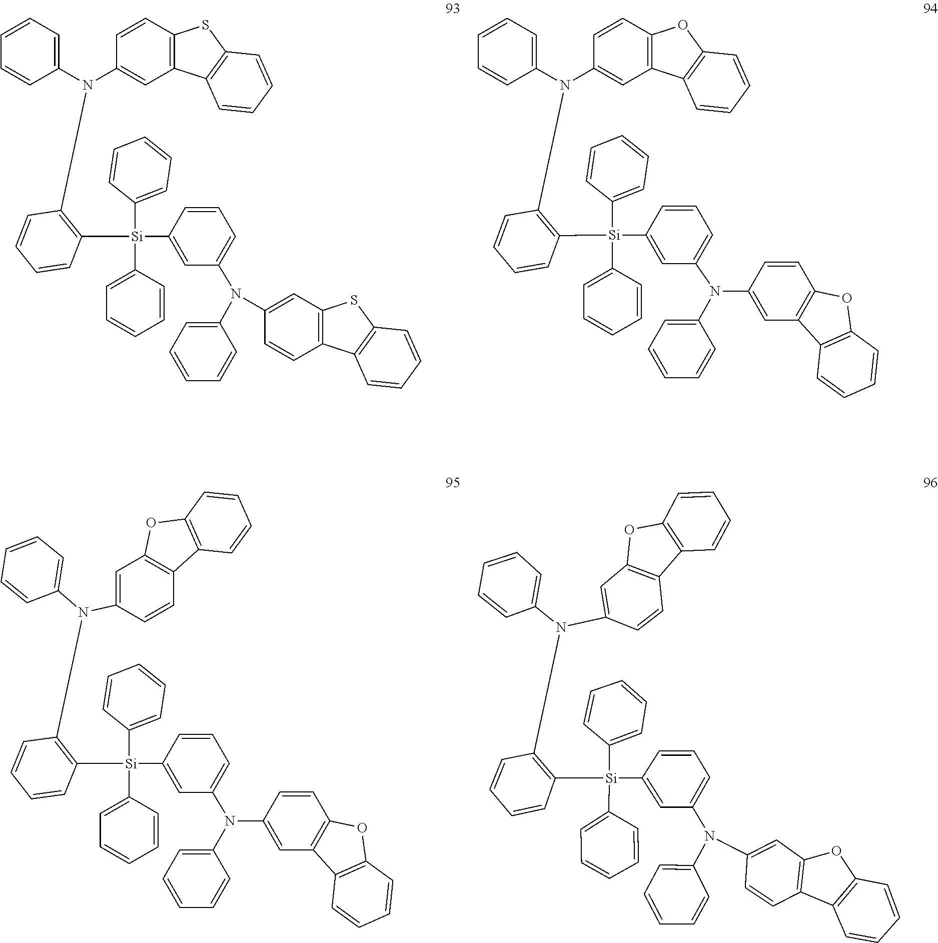 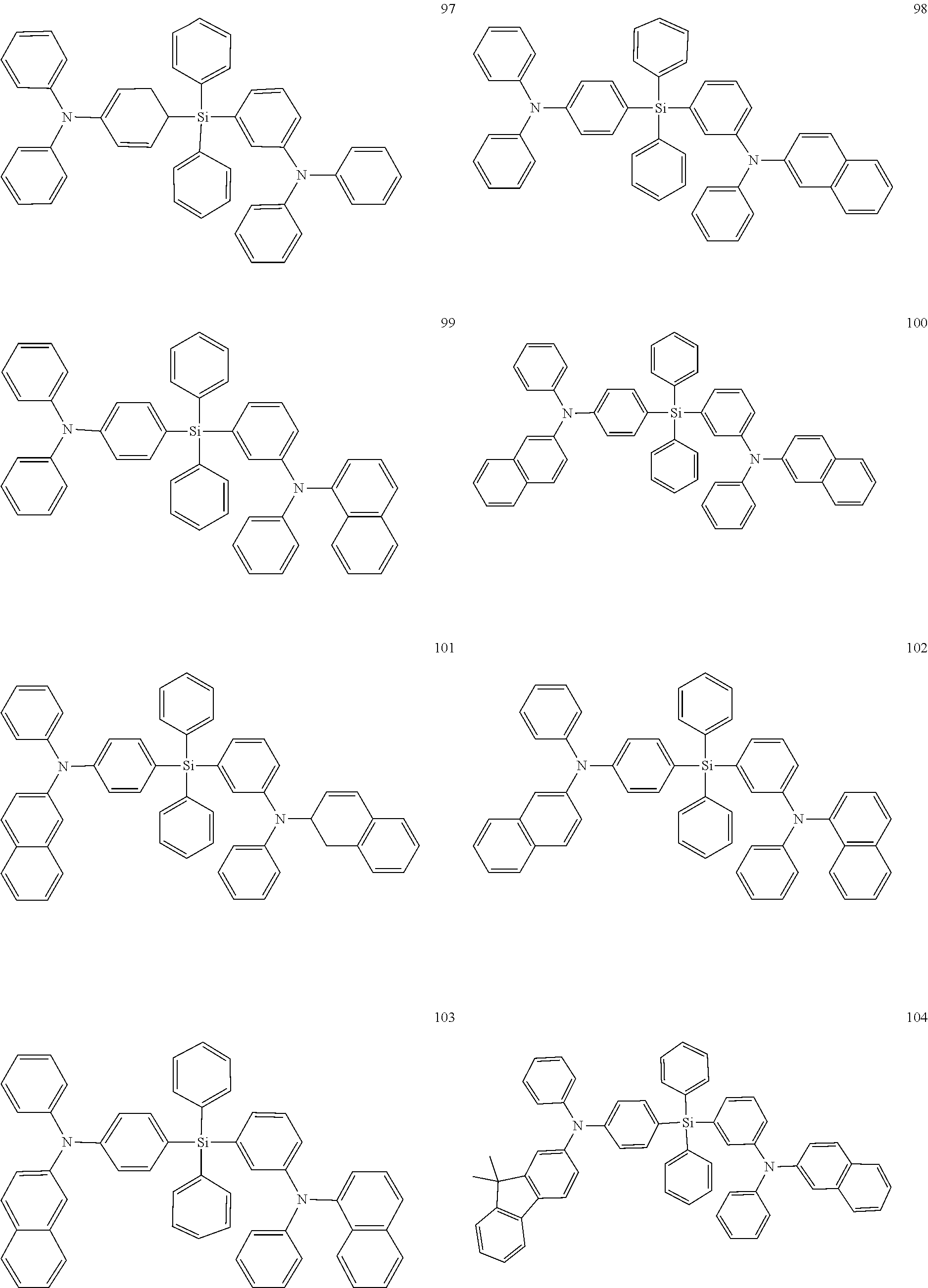 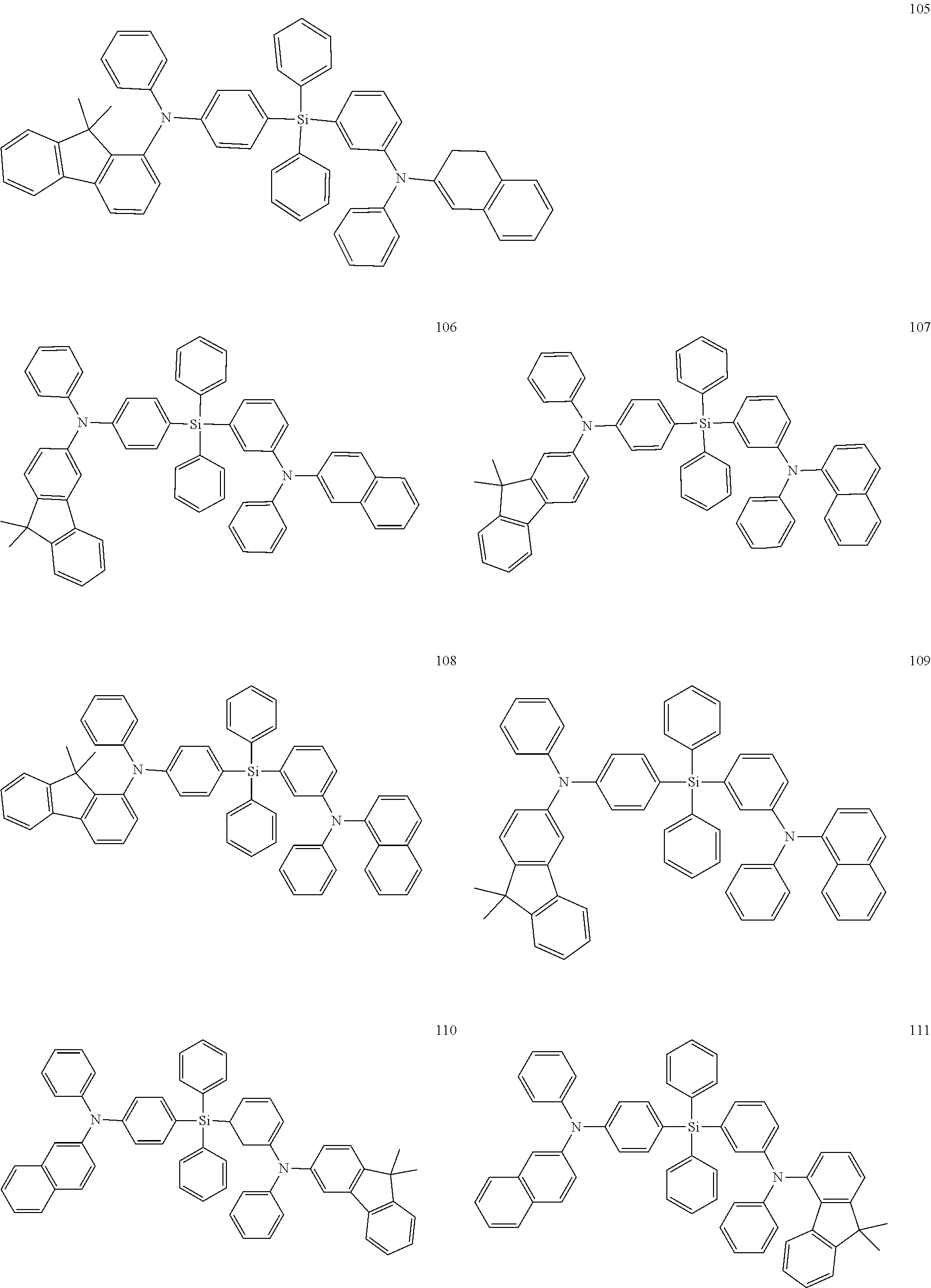 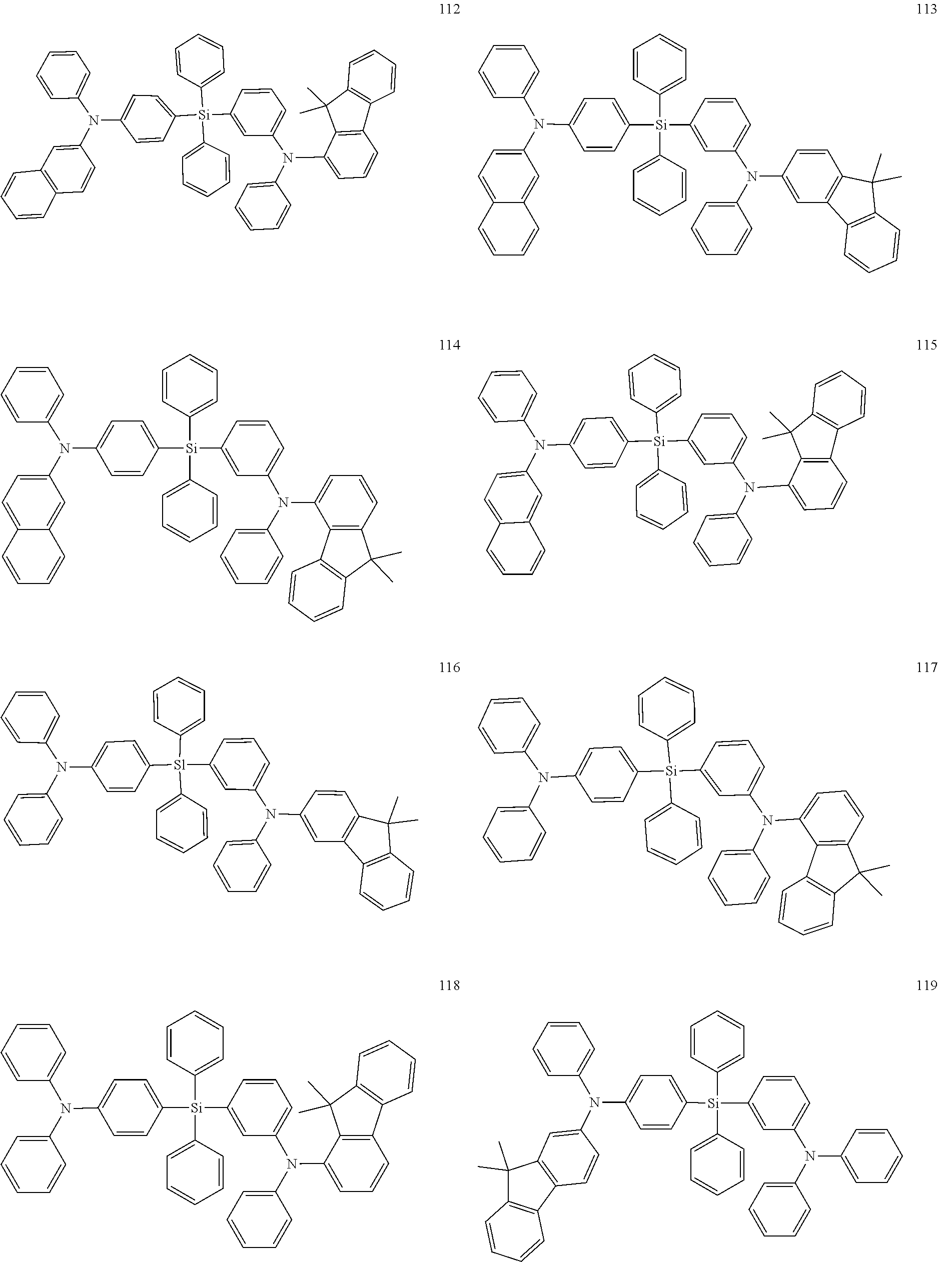 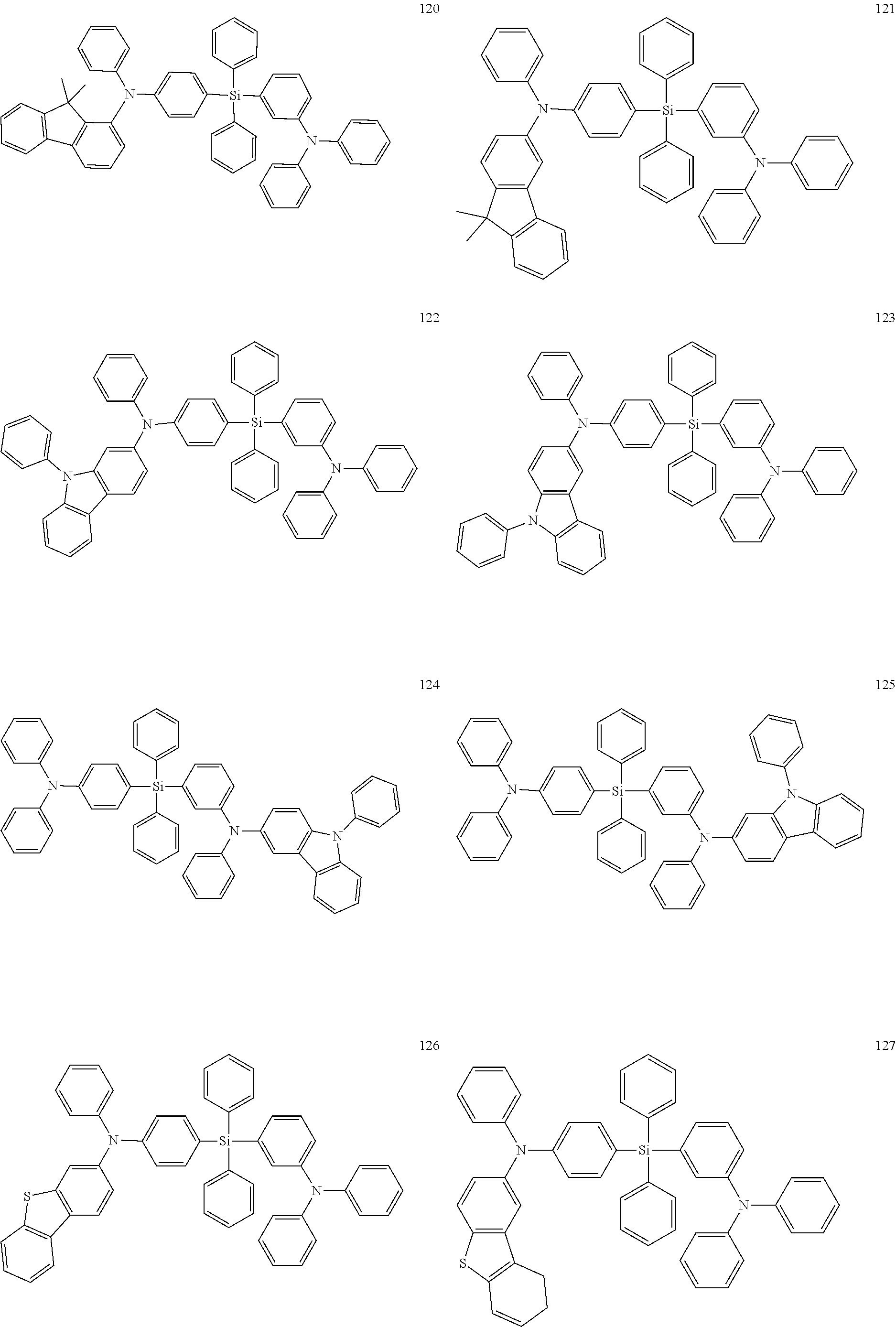 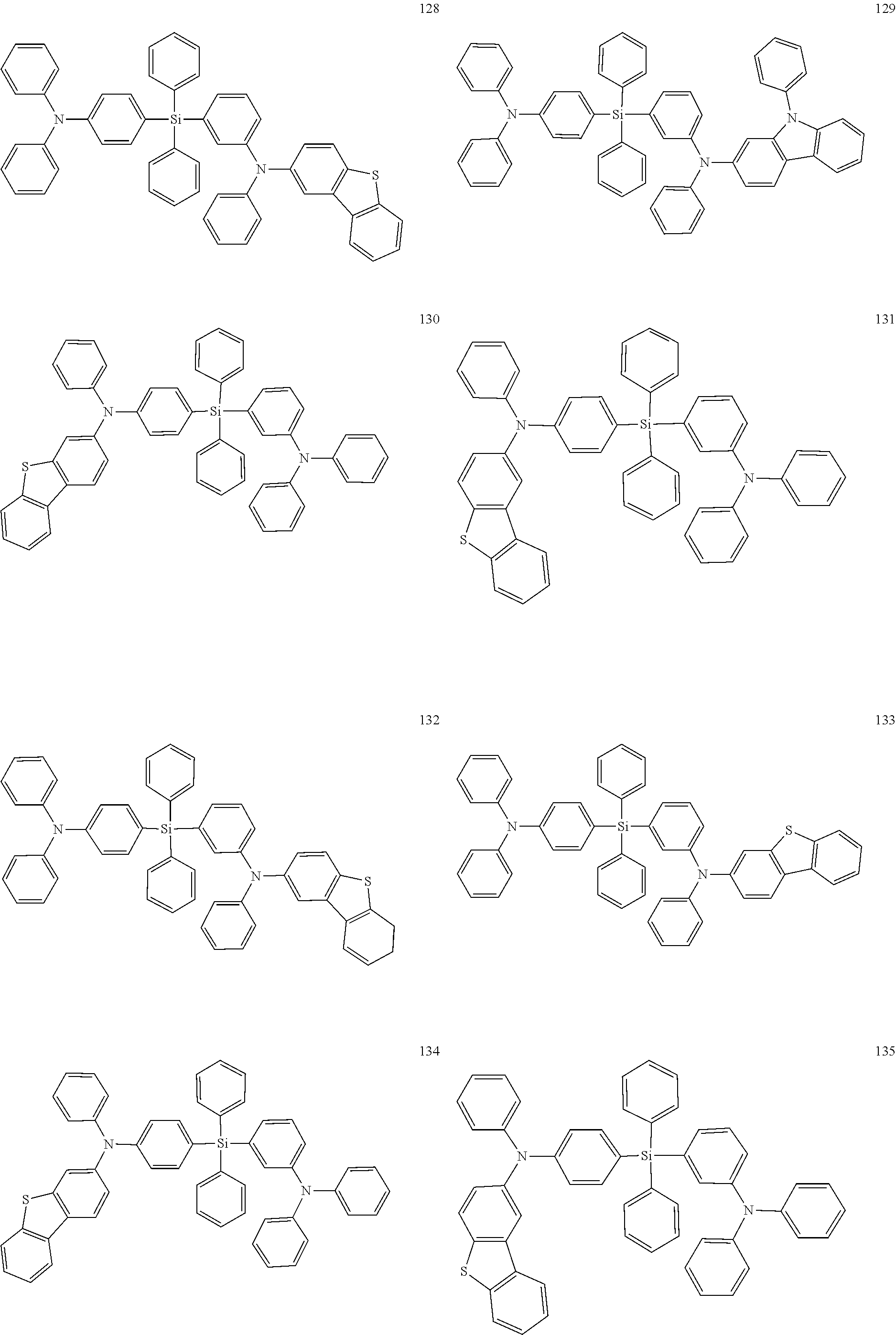 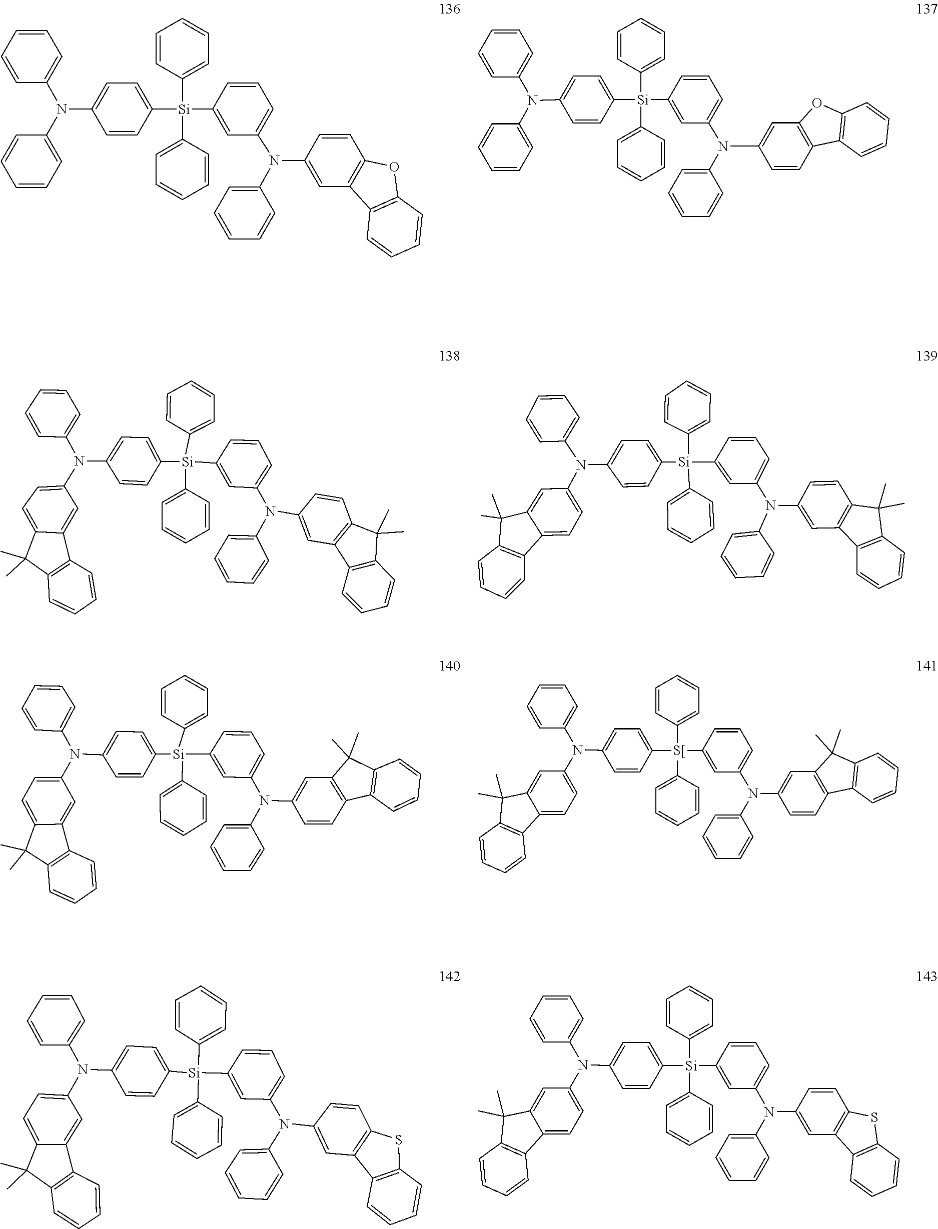 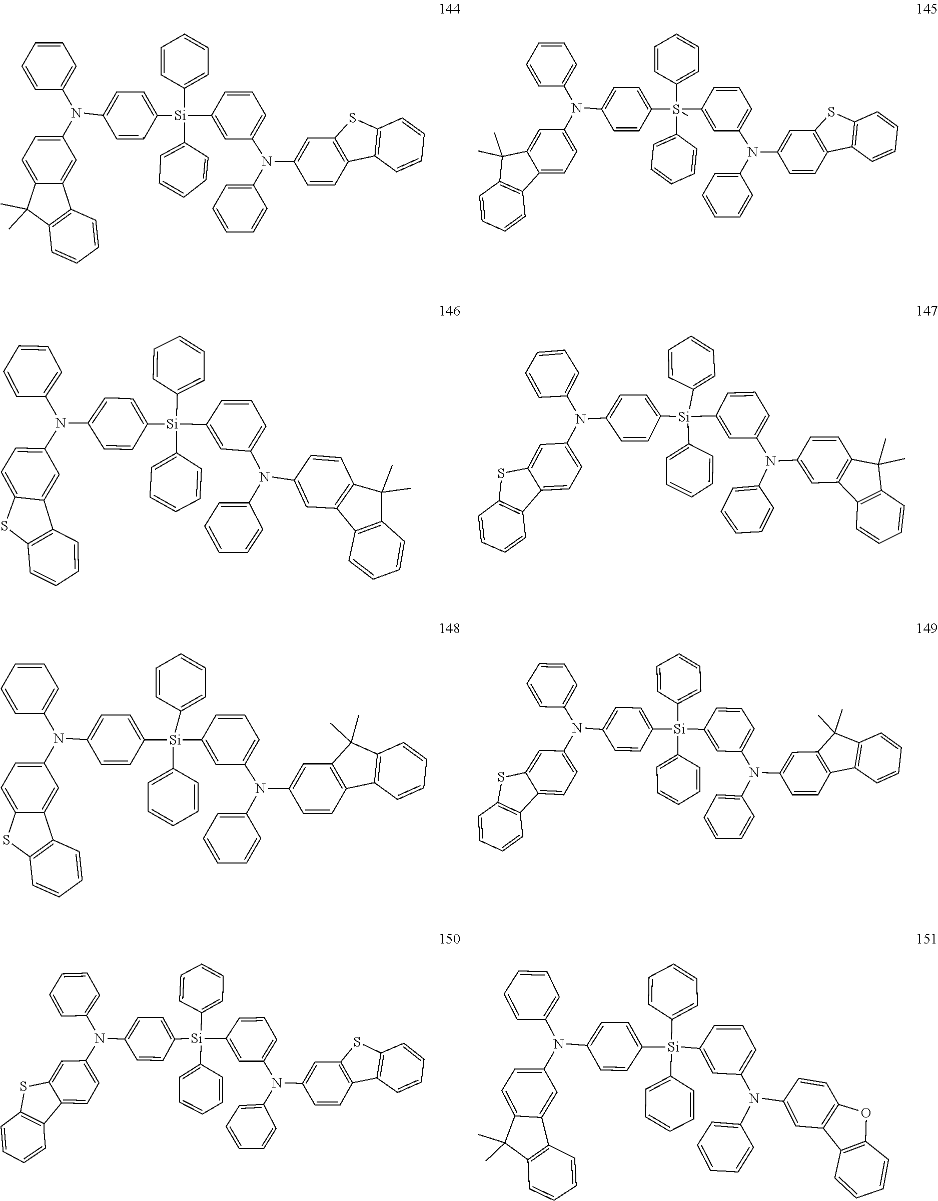 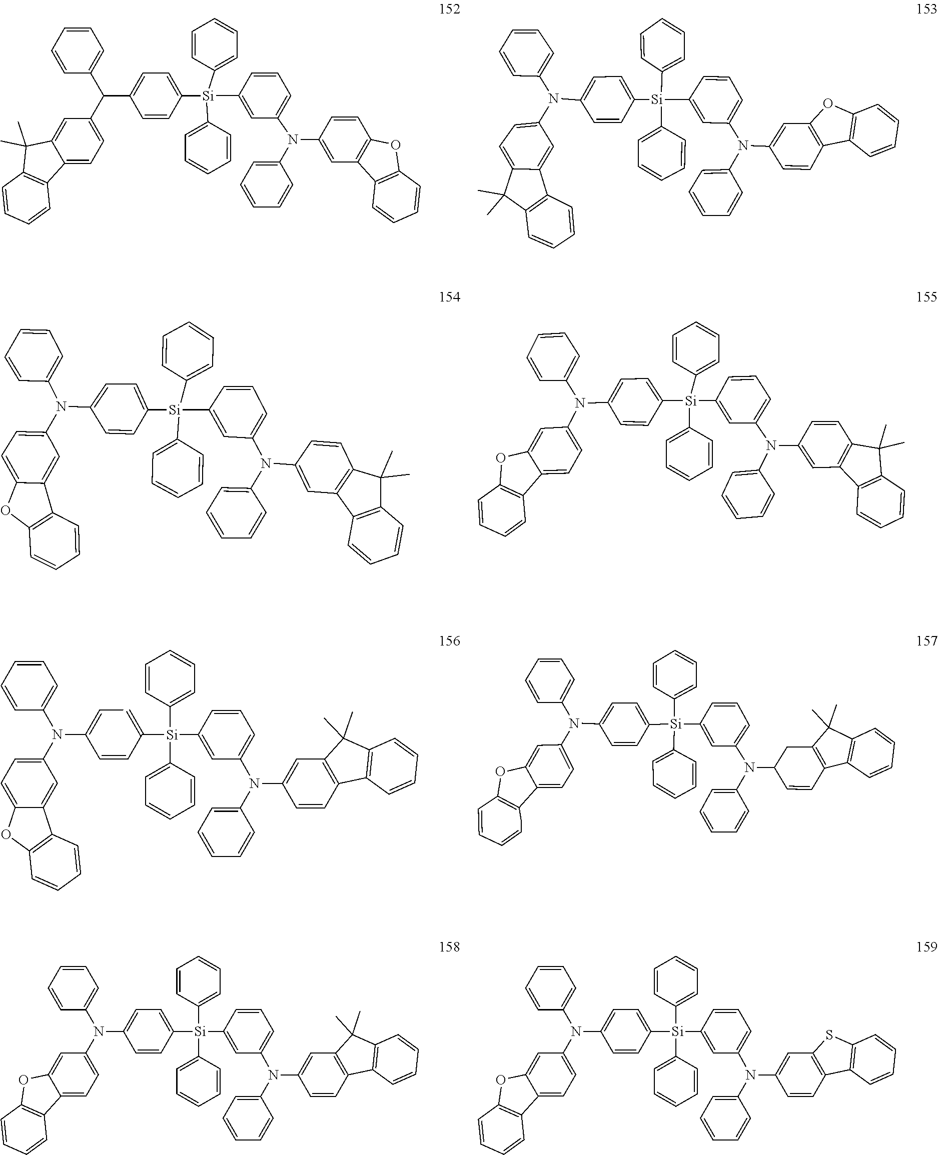 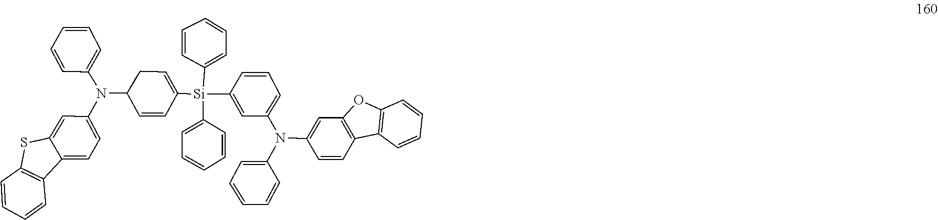 [SMILES: C1=CC2(N(c3ccccc3)c3ccc4c(c3)CSc3ccccc3-4)CC2C=C1[Si](c1ccccc1)(c1ccccc1)c1cccc(N(c2ccccc2)c2ccc3c(c2)oc2ccccc23)c1]
